(19) United States
(12) Patent Application Publication
(10) Pub. No.: US 2011/0113301 A1
(43) Pub. Date: May 12, 2011

(54) Diversity broadcasting of gray-labeled CCC data using 8-VSB AM

(76) Inventor: Allen LeRoy Limberg, Port Charlotte, FL (US)

(21) Appl. No.: 12/927,022

(22) Filed: Nov. 4, 2010

Related U.S. Application Data
(60) Provisional application No. 61/280,626, filed on Nov. 6, 2009.
(60) Provisional application No. 61/283,673, filed on Dec. 7, 2009.
(60) Provisional application No. 61/335,246, filed on Jan. 4, 2010.
(60) Provisional application No. 61/337,680, filed on Feb. 11, 2010.

(51) Int. Cl. H03M 13/45; H03M 13/27; G06F 11/10

(52) U.S. Cl. 714/755; 714/E11.032

(57) ABSTRACT

Receivers for diversity reception of data transmitted by concatenated convolutional code (CCC) from at least one 8-VSB transmitter are described. Each receiver includes a first turbo decoder for the CCC as finally transmitted, a second turbo decoder for the CCC as initially transmitted, and an information-exchange unit connected for exchanging decoding information between the turbo decoders, which perform decoding concurrently. The turbo decoders are designed for decoding CCC formed from an outer convolutional code encoding de-interleaved Gray-coded data and a subsequent binary-coded inner convolutional code forming a 12-phase trellis code in accordance with a Gray-labeling procedure, the outer convolutional code encoding being symbol-interleaved before encoding within said inner convolutional code so said inner convolutional code has implied symbol interleaving in which the original order of data bits is preserved.

This application claims the benefit of the filing dates of provisional U.S. Pat. App. Ser. No. 61/280,626 filed 6 Nov. 2009, of provisional U.S. Pat. App. Ser. No. 61/283,673 filed 7 Dec. 2009, of provisional U.S. Pat. App. Ser. No. 61/335,246 filed 4 Jan. 2010, and of U.S. Pat. App. Ser. No. 61/337,680 filed 11 Febuary 2010.

### FIELD OF THE INVENTION

Various aspects of the invention relate to digital television (DTV) signals for over-the-air broadcasting, transmitters for such broadcast DTV signals, receivers for such broadcast DTV signals and in particular those items as designed for implementing a system of broadcasting concatenated convolutionally coded (CCC) data to mobile and hand-held receivers, collectively referred to as “M/H” receivers.

### BACKGROUND OF THE INVENTION

The Advanced Television Systems Committee (ATSC) published a Digital Television Standard in 1995 as Document A/53, hereinafter referred to simply as “A/53” for sake of brevity. Annex D of A/53 titled “RF/Transmission Systems Characteristics” is particularly pertinent to this specification. In the beginning years of the twenty-first century efforts were made to provide for more robust transmission of data over broadcast DTV channels without unduly disrupting the operation of so-called “legacy” DTV receivers already in the field. These efforts culminated in a candidate ATSC standard directed to broadcasting digital television and digital data to mobile receivers being adopted on 15 Oct. 2009. This standard, referred to as “A/153”, is also pertinent to this specification.

A/153 prescribes forward-error-correction coding of data transmitted to mobile receivers, which FEC coding comprises transversal Reed-Solomon (TRS) coding combined with lateral cyclic-redundancy-check (CRC) codes to locate byte errors for the TRS coding. This FEC coding helps overcome temporary fading in which received signal strength momentarily falls below that needed for successful reception. The strongest TRS codes prescribed by A/153 can overcome such drop-outs in received signal strength that are as long as four tenths of a second.

Another known technique for overcoming temporary fading is iterative diversity. Iterative diversity can also overcome certain types of intermittent radio-frequency interference. Communications systems provide for iterative diversity of received signals by transmitting a composite signal composed of two component content-representative signals, one of which is delayed with respect to the other. The composite signal is broadcast to one or more receivers through a communications channel. At a receiver, delayed response to the initially transmitted component content-representative signal supplied from a buffer memory is contemporaneous in time with the finally transmitted component content-representative signal. Under normal conditions, the receiver detects and reproduces the content of the finally transmitted signal as soon as it is received. However, if a drop-out in received signal strength occurs, then the receiver detects and reproduces the content of the initially transmitted signal as read from buffer memory. If the delay period and the associated delay buffer are large enough, then fairly long drop-outs in received signal strength can be overcome. This capability not only requires a severalfold increase in the amount of memory required in a receiver; it halves the effective code rate of the transmission. However, drop-outs as a long as a few seconds are feasible using memory of the sizes used in flash drives.

Thomson, Inc. proposed forms of iterative diversity its engineers called “staggercasting” for use in robust portions of 8-VSB transmissions. Thomson, Inc. has advocated iterative diversity in which the earlier and final transmissions of the same data are combined in the “transport” layer of the receiver. The “transport” layer of the receiver is subsequent to the “physical layer” of the receiver, which “physical layer” comprises the initial stages of the receiver that recover transport-stream packets from the robust portions of 8-VSB transmissions. Transport stream (TS) packets from the earlier one of the iterated transmissions replace missing TS packets in the later one of the iterated transmissions in staggercasting. For a brief time Thomson, Inc. and Micronas GmbH representatives within ATSC took the position that the earlier and final transmissions of the same data could be advantageously combined in the physical layer of the receiver, rather in its transport layer, but later withdrew from that position. Thomson and Micronas jointly proposed a concatenation of outer block coding with inner 2/3 trellis coding per 8-VSB for each component transmission, pointing out that earlier and final transmissions of the same coded data could be combined along the lines used in digital audio broadcasting (DAB).

### SUMMARY OF THE INVENTOR'S WORK

The inventor perceived that the processing of “soft” decisions in turbo decoding allows a more sophisticated approach to be taken for iterative-diversity reception. “Soft” decisions concerning the contents of an earlier transmitted turbo codeword and concerning the contents of a later transmitted repeat of the earlier transmitted turbo codeword can be analyzed for selecting which of corresponding portions of the two turbo codewords as received is more likely to be correct. The selection procedure can synthesize a turbo codeword that is more likely to be correct than either of the turbo codewords from which the parts of the synthesized turbo codeword are drawn. The synthesized turbo codeword can then be subjected to turbo decoding and R-S decoding procedures.

The inventor subsequently invented a form of iterative diversity in which parallel concatenated convolutional coding (PCCC) was dissected for transmission. Data and the parity bits for one of the two convolutional codes used in the PCCC are transmitted at an earlier time. Subsequently, at a later time, the data are retransmitted together with the parity bits for the other of the two convolutional codes used in the PCCC. In the receiver “soft” decisions concerning the originally transmitted data and “soft” decisions concerning the re-transmitted data are compared, and a best estimate of the data is developed for PCCC decoding. Deep fading conditions that prevent successful reception of one of the transmissions may not affect the other transmission severely enough to prevent its being successfully received.

Some time after this, the inventor realized that this concept can be applied to SCCC of the types used in A-VSB and in MPH. Of especial interest is the application of this concept to SCCC in which the initial transmission and the final transmission are each at a code rate that is nominally one half that of ordinary 8-VSB. Overall, a code rate that is nominally one quarter that of ordinary 8-VSB results, and AWGN performance is expected to be similar to that of previously proposed A-VSB or MPH signals having a code rate that is nominally one quarter that of ordinary 8-VSB. However, except when SNR is very low for both transmissions of the iterative-diversity signals, reception should be possible. Deep fading conditions can be tolerated that would not be successfully received using the previously proposed A-VSB or MPH signals having a code rate that is nominally one quarter that of ordinary 8-VSB.

A problem receivers for iterative-diversity SCCC or PCCC DTV signals are prone to is difficulty in changing channels quickly owing to the latent delay involved in combining the earlier transmitted signals with later transmitted signals. The inventor discerned that this problem can be alleviated when strong signals are received. When a channel is initially tuned to, only the later transmitted codewords of the iterative-diversity SCCC or PCCC are decoded until earlier transmitted words that have been temporarily stored for combining with the later transmitted words of the iterative-diversity SCCC or PCCC become available.

In his earlier work on iterative diversity, the inventor sought to use half-code-rate outer convolutional coding similarly to the ways it was used in the A-VSB and MPH systems. The desire was that either the initial or the final ones of the iterative-diversity transmissions could be usefully received by the first generation of receivers designed for receiving transmissions made in accordance with the emerging A/153 digital televison broadcasting standard. The half-code-rate outer convolutional coding used in the A-VSB and MPH systems was mapped into 8-VSB symbols such that the original data bits occupied the most significant bits (MSBs) of the three-bit symbols. Difficulties were encountered in doing this, which led the inventor to consider mapping the half-code-rate outer convolutional coding into 8-VSB symbols such that the original data bits occupied the secondmost significant bits of the three-bit symbols rather than their MSBs. Later on, these difficulties were overcome. So, the inventor laid aside this mapping in favor of the one employed in the emerging A/153 digital broadcasting standard.

However, before laying it aside, the inventor had observed that the alternative mapping scheme had the following advantage. The data bits were directly involved in both the inner and the outer convolutional coding, so that updating of soft data bits was done both in the inner decoding step(s) and in the outer decoding step(s) of turbo decoding procedures, rather than just in the outer decoding step(s). Interestingly, the set of parity bytes generated by the 2/3 trellis coding used as inner coding in the concatenated convolutional coding was independent of the set of parity bytes generated by the outer coding. So, as the inventor observed, the outer convolutional coding and the inner convolutional coding were in effect parallel concatentated, rather than serial concatenated. PCCC reduces error faster than SCCC in regions where error rate is significantly higher than one in a billion, but error reduction by PCCC tends to slow at lower BERs, which phenomenon is referred to as the “bit-error-rate floor”. Presumably, the A-VSB and MPH systems mapped the half-code-rate outer convolutional coding into 8-VSB symbols such that the original data bits occupied the most significant bits (MSBs) of the three-bit symbols in order to avoid the BER floor problem.

The slowing of error reduction by PCCC at lower BERs is reported to be more noticeable if the PCCC codes have lower ratios of ONEs to ZEROes. PCCC designers accordingly try to design the convolutional codes such that almost all codewords have a reasonably high ratio of ONEs to ZEROes. When the inventor considered iterative-diversity transmssion of PCCC at one-half the code rate of 8-VSB symbol rate, he observed that ones' complementing one of two component transmissions and not the other would have the following effect. The ratio of ONEs to ZERO would have to be reasonably high in one of the two component transmissions, over one half unless both component transmissions had a respective ratio of ONEs to ZEROes of one-half. If the respective turbo-decoding loops for the earlier and later transmissions exchanged error-probability information with each other, the onset of the “bit-error-rate floor” would be deferred until substantially lower BER.

Published U.S. Pat. App. No. 2001-0025358 caught the inventor's attention in a review of patent literature concerning concatenated convolutional coding that he conducted later on, in October 2008. This patent application filed by D. B. Eidson, A. Krieger and R. Murali of Conexant Systems, Inc. is titled “Iterative decoder employing multiple external code error checks to lower the error floor”. The abstract suggests that cyclic-redundancy-check (CRC) codes may be used to improve the performance of turbo decoding procedures for parallel concatenated convolutional coding (PCCC). CRC codes can be used to check whether or not strings of data bits in the results of decoding outer convolutional coding are presumably correct. Those strings of data bits with checksums indicating they are very likely to be correct can have the confidence levels associated with their parent soft bits heightened. Re-interleaving will scatter the parent soft bits descriptive of data that have the heightened confidence levels throughout the extrinsic information fed back via the turbo loop, to be used in the next iteration of decoding of inner convolutional coding. The inventor perceived that this general approach to solving “bit-error-rate floor” problems promised to be applicable to one-time transmissions of M/H data as well as to iterated transmissions.

As mentioned above, the SCCC proposed for the emerging A/153 digital broadcasting standard included CRC codes used for locating byte errors for the TRS decoding. This suggested to the inventor that he try to use the CRC codes to improve the performance of turbo decoding procedures for the SCCC proposed for the emerging A/153 ATSC standard. Straightforward attempts to do this will not work, the inventor subsequently found. The reason is that the CRC codes prescribed by A/153 are applicable only to the data bits in the SCCC as de-interleaved for processing by the decoder for the outer convolutional coding. When the results of decoding the outer convolutional coding are re-interleaved for processing by the decoder for the inner convolutional coding, the problem that is encountered is that the decoder for the inner convolutional coding does not respond to data bits. The scattered data bits with heightened confidence levels are de-interleaved so as to be supplied in the same data string order for outer convolutional decoding as they originally were. There is no appreciable increase in coding gain.

The inventor realized, casting back to his earlier work, that this problem was avoided by mapping the half-code-rate outer convolutional coding into 8-VSB symbols such that the original data bits occupied the secondmost significant bits of the three-bit symbols rather than their MSBs. That is, the data bits would be directly involved in the 2/3 trellis coding procedure, rather than indirectly involved as prescribed by A/153. The inventor realized that heightening the confidence levels associated with the parent soft bits of data in CRC codewords with checksums indicating they are very likely to be correct helped avoid the problem of the BER floor that might otherwise be associated with the resulting PCCC. The inventor further realized that directly involving the data bits in the 2/3 trellis coding procedure should be useful in transmitting signals at half the code rate of conventional 8-VSB signals, even though iterative diversity was not employed.

The inventor was dissatisfied with the lengths of CRC codewords specified by early drafts of A/153 when RS Frames were transmitted in more than five M/H Groups. In the inventor's opinion, having CRC checksums just at the conclusion of each row of bytes in the RS Frame resulted then in CRC codewords that were too long to precisely locate byte errors for the decoding of TRS codewords. Furthermore, the CRC codewords were longer than desired for implementing techniques of the sort described in published U.S. Pat. App. No. 2001-0025358 for postponing BER floor. The inventor advocated including as many CRC codewords in each row of bytes in the RS Frame as there are M/H Groups in an M/H sub-Frame for conveying data pertinent to the RS Frame.

The foregoing concepts were described in U.S. patent application Ser. No. 12/580,534 filed for the inventor A. L. R. Limberg on 16 Oct. 2009 and titled “Digital television systems employing concatenated convolutional coded data”. Another patent application Ser. No. 12/456,608 was filed by the inventor A. L. R. Limberg on 20 Jun. 2009 and is titled “System for digital television broadcasting using modified 2/3 trellis coding”. U.S. patent application Ser. No. 12/456,608 describes Gray-code labeling of the outer convolutional coding in preferred CCC transmissions that are symbol coded using the eight-level 8-VSB symbols used in DTV broadcasting. The preferred embodiments of DTV transmitter apparatus and M/H receiver apparatuses described herein include elements for implementing Gray-code labeling of the outer convolutional coding, which elements were not included in the embodiments described in U.S. patent application Ser. No. 12/580,534 filed on 16 Oct. 2009. Gray-code labeling of the outer convolutional coding increases the robustness of the secondmost significant bits of the three-bit 8-VSB symbols to be closer to that of their most significant bits.

Concatenated convolutional coding (CCC), whether of SCCC type or of PCCC type, is ordinarily decoded using turbo decoding procedures. The decoding of the inner convolutional coding is followed by the decoding of the outer convolutional coding in each cycle of concatenated decoding. The results of each cycle of concatenated decoding are used to update the signal to be decoded in a subsequent cycle of concatenated decoding in what is referred to as an “iteration” of turbo decoding procedure. The feeding back to the inner decoder of extrinsic information obtained by comparing decoding results from the outer decoder and from the inner decoder has been fancied to be analogous to turbo charging in an internal combustion engine, whence the name “turbo decoding” for this decoding procedure. Part of the ingeniousness of turbo decoding is that very long codewords can be coded using a very simple encoder for the outer coding and a very simple encoder for the inner coding. Using very simple encoders both for the outer coding and for the inner coding allows receivers to use simpler decoders for the outer coding and for the inner coding.

Some turbo decoders exploit the fact that the decoding of the inner convolutional coding and the decoding of the outer convolutional coding are staggered in time to reduce decoding hardware requirements. These turbo decoders use the same apparatus to perform both the decoding procedures, rather than using duplicate apparatuses each operating half the time and resting half the time while the other is operating. The SCCC prescribed by A/153 does not lend itself to using the same apparatus to perform both the 12-phase decoding of the inner convolutional coding and the single-phase decoding of the outer convolutional coding.

One of the inventor's insights was that PCCC lends itself to essentially the same simple decoder used for the 12-phase 2/3 trellis code of 8-VSB also being used for decoding the 12-phase outer convolutional coding as well. Furthermore, each of the twelve phases of turbo decoding can be performed independently of the others. This insight was not disclosed in U.S. patent application Ser. No. 12/580,534 filed on 16 Oct. 2009.

In DTV broadcasting as specified in A/53 and A/153 the most significant bits (MSBs) of the three-bit symbols of 2/3 trellis coding that are mapped into 8-level 8-VSB symbols are each pre-coded. These MSBs are referred to in A/53 and A/153 as Z-sub-2 bits, the bits of intermediate significance being referred to as Z-sub-1 bits, and the least significant bits (LSBs) being referred to as Z-sub-0 bits. The MSBs are applied as a first of two input signals to an exclusive-OR gate, the response of which besides being the pre-coder response is delayed twelve symbol epochs and applied as a second of the two input signals to the exclusive-OR gate. The pre-coding and the half-code-rate trellis coding of the less significant bits of the three-bit symbols complement a comb-filtering procedure that was performed in a legacy DTV receiver. In this comb-filtering procedure, designed to suppress interference from co-channel NTSC signals, the 8-VSB symbols were supplied as minuend input signals to an analog-regime subtractor and after being delayed twelve 8-VSB symbol epochs were supplied as subtrahend input signals to that subtractor. Principal energy components of an NTSC co-channel interfering signal were suppressed in the difference output signal, which was data-sliced with a 15-level data slicer. The data slicing results were then interpolated to reproduce the three-bit symbols of the 2/3 trellis coding. Using an analog-regime comb filter to suppress co-channel NTSC signal is known to degrade the noise performance of the receiver, owing to the imposition of the comb filter response upon the generally flat frequency spectrum of noise in the baseband signal supplied to the comb filter. In the absence of an NTSC co-channel interfering signal, a modulo-8 digital-regime subtractor differentially combines the results of 8-level data slicing of the baseband signal received as minuend input signal with the those results as delayed twelve symbol epochs and received as subtrahend input signal. The modulo-8 difference signal from the digital-regime subtractor reproduces the three-bit symbols of the 2/3 trellis coding without degradation in noise performance caused by the effects of comb-filtering to suppress interference from co-channel NTSC signals.

The proponents of pre-coding Z-sub-2 bits did not disclose any possibility of other types of degradation of noise performance that might persist following modulo-8 subtraction digital regime. However, clearly, the subtraction procedure doubles the peak variance in data slicing results from the norm, owing to noise of a given average power level and with substantially flat frequency spectrum. If these peak variance conditions occur infrequently, the trellis decoding procedures will diminish their effect upon decoding results. Nonetheless, pre-coding Z-sub-2 bits will cause some direct degradation of noise performance in M/H receivers and might be better avoided.

Modulo-8 subtraction in the digital regime also clouds issues as to which bits of 2/3 trellis coding are most likely to be in error according to the results of data-slicing the plural-level 8-VSB symbols. At least two of the 3-bit symbols of the 2/3 trellis coding are affected by a single 8-VSB symbol exhibiting a large variance from the norm during data slicing. Trellis decoding helps to resolve such issues, but they might be better avoided by not pre-coding Z-sub-2 bits.

The intrusion of the modulo-8 subtraction between data slicing and 2/3 trellis decoding vitiates one of the principles strengths of 2/3 trellis coding of eight-level symbols—namely, that the decoding procedure is relevant not just to the two bits directly involved in the half-rate trellis coding, but further extends to the other bit not directly involved. Resolution of the value of a Z-sub-1 bit by 2/3 trellis decoding has implications with regard to the resolution of the Z-sub-2 bit if those two bits are paired within the mapping of the 2/3 trellis code symbols to the eight-level symbols. The intrusion of the modulo-8 subtraction between data slicing and 2/3 trellis decoding interferes with the pairing of the Z-sub-2 and Z-sub-1 bits within the mapping of the 2/3 trellis code symbols to the eight-level symbols. Gray-code labeling of the outer convolutional coding relies on pairing of the Z-sub-2 and Z-sub-1 bits within the mapping of the 2/3 trellis code symbols to the eight-level symbols.

Pre-coding of Z-sub-2 bits in the M/H signals impairs the usefulness of short sequences of 8-VSB symbols encoding M/H data in CCC. The 2/3 trellis coding used as inner convolutional coding is continuous in nature across the successively transmitted segments of fields of interleaved 8-VSB symbols. There are no breaks in this inner convolutional coding owing to the intrusion of 8-VSB symbols encoding ordinary data per A/53 as originally published. In some segments of the fields of interleaved 8-VSB symbols, the symbol-interleaved outer convolutional coding is not interrupted by the intrusion of one or more 8-VSB symbols encoding ordinary data. However, in others segments of the fields of interleaved 8-VSB symbols, the symbol-interleaved outer convolutional coding is fragmented by intrusions of 8-VSB symbols encoding ordinary data. It is desirable in the decoding of the symbol-interleaved outer convolutional coding that its fragments be consolidated into a continuous stream of symbols not interrupted by intrusions of 8-VSB symbols encoding ordinary data, with each successive fragment of the symbol-interleaved outer convolutional coding seamlessly joined to the previous one. Such seamless joinder is imperfectly accomplished if the Z-sub-2 bits in the 8-VSB symbols encoding M/H data are pre-coded, so as not to be independent of the Z-sub-2 bits in the 8-VSB symbols encoding ordinary data.

With the 2008 demise of high-power NTSC broadcasting in the United States, there is little if any need for comb filtering to suppress interference from co-channel NTSC signals. Even so, A/153 prescribed continued use of the pre-coding of the MSBs of the three-bit symbols of 2/3 trellis coding that are mapped into 8-level 8-VSB symbols. The proffered rationale for this was that many legacy receivers were not equipped for decoding 8-VSB in which the Z-sub-2 bits were not pre-coded. Legacy DTV receivers are not equipped for decoding M/H signals, whether or not the Z-sub-2 bits in the M/H signals are pre-coded. So long as the ordinary 8-VSB signals authorized by A/53 as originally published in 1995 use pre-coding of Z-sub-2 bits, legacy DTV receivers will continue to receive ordinary 8-VSB signals as originally specified by A/53. This suggests that selectively discontinuing pre-coding of Z-sub-2 bits just for M/H signals should have no deleterious effects for receivers designed just to receive ordinary 8-VSB signals as originally specified by A/53. Selectively discontinuing pre-coding of Z-sub-2 bits for M/H signals was not disclosed in U.S. patent application Ser. No. 12/580,534 filed on 16 Oct. 2009.

However, simply selectively discontinuing pre-coding of Z-sub-2 bits just for M/H signals can discommode legacy DTV receivers that estimate the signal-to-noise ratio (SNR) of received DTV signals by counting the number of (207, 187) Reed-Solomon codewords per data field or frame that are correct or correctable. Post-comb filtering in these legacy receivers mutilates the (207, 187) RS codewords for MHE packets, so that the RS decoder in such a legacy DTV receiver is likely to find all or almost all of them to be in error. The number of RS codewords per data field or frame that will found to be in error becomes large enough to cause such a legacy DTV receiver to conclude that the SNR of the received DTV signal is too low to be useful. Accordingly, the receiver is de-activated.

The inventor's provisional U.S. Pat. App. Ser. No. 61/337,680 filed 11 Feb. 2010 and titled “Coding and decoding of 8-VSB digital television signals intended for reception by mobile/handheld receivers” describes selective pre-coding procedures that avoid the problem of unwanted de-activation of legacy DTV receivers. The Z-sub-2 bits of bytes from RS-coded main-service packets are pre-coded, together with the Z-sub-2 bits of the initial two bytes from each MHE packet. The convolutionally byte-interleaved RS codewords as so selectively pre-coded are then post-comb filtered and de-interleaved. This recovers the RS codewords in the form in which a DTV legacy receiver would receive them for RS decoding were no further steps taken in the M/H DTV transmitter to avoid erroneously RS-coded MHE packets appearing in the de-interleaved post-comb filter response. The RS-coded main-service packets are recovered as valid (207, 187) RS codewords free of any error. However, the RS-coded M/H-service packets that are recovered are very unlikely to be valid (207, 187) RS codewords, owing to their having been post comb-filtered without previous pre-coding of the Z-sub-2 bits in most of their bytes. The apparent error in the RS-coded M/H-service packets is ascribed to inappropriate RS parity bytes, and the transmitter replaces these inappropriate RS parity bytes by recalculated RS parity bytes. The bytes of the M/H data as they appear in the de-interleaved post-comb filter response are considered to be free of error and will be restored to their original condition during the subsequent modified 2/3 trellis coding.

The inventor's provisional U.S. Pat. App. Ser. No. 61/335,246 filed 4 Jan. 2010 and titled “Coding and decoding of RS frames in 8-VSB digital television signals intended for reception by mobile/handheld receivers” describes other selective pre-coding procedures that avoid the problem of unwanted de-activation of legacy DTV receivers. These other selective pre-coding procedures differ from those described in U.S. Pat. App. Ser. No. 61/337,680 in that no RS coding step precedes the step of selective pre-coding of Z-sub-2 bits and the subsequent step of post-comb filtering. RS coding steps are deferred until after the steps of selective pre-coding and post-comb filtering. The alternative procedures for selectively pre-coding Z-sub-2 bits that are described in U.S. Pat. App. Ser. No. 61/335,246 and in U.S. Pat. App. Ser. No. 61/337,680, respectively, are based on the same insight. Namely, the RS coding of the MHE packets is based on the form that the bytes of those packets appear in after post-comb filtering in a legacy DTV receiver.

Simply discontinuing pre-coding of Z-sub-2 bits for M/H signals can present another problem for DTV receivers, as noted by C. H. Strolle et affi in U.S. Pat. App. Pub. No. 20040028076 of 12 Feb. 2004 titled “Robust data extension for 8-VSB signaling”. The problem is that of the receiver having to restore the correct sense of logic for main-service signal each time it resumes after the intrusion of M/H-service signal. The selective precoding procedures described in U.S. patent application Ser. Nos. 61/335,246 and 61/337,680 provide for continuous pre-coding of the Z-sub-2 bits of the multiplexed main-service and M/H-service components of the transmitted 8-VSB signal. The DTV receiver does not have to pursue particular measures for maintaining the correct senses of logic for the Z-sub-2 bits of the main-service data and the M/H-service data. The correct senses are maintained automatically.

U.S. patent application Ser. No. 12/924,074 filed 20 Sep. 2010 by A. L. R. Limberg and titled “Terminated concatenated convolutional coding of M/H Group data in 8-VSB digital television signals” describes wrap-around coding of each M/H Group. This patent application describes how to wrap around the one-half-rate inner convolutional coding used for 2/3 trellis coding of 8 VSB signals, as well as how to wrap around the one-half-rate outer convolutional coding. Selective pre-coding procedures that avoid precoding the Z-sub-2 bits of the outer convolutional coding simplify wrapping that coding around each M/H Group, while avoiding the problem of unwanted de-activation of legacy DTV receivers. U.S. patent application Ser. No. 12/924,074 describes the desirability of using various strengths of 230-byte transverse Reed-Solomon (TRS) coding, rather than the (235, 187), (223, 187) and (211, 187) TRS coding prescribed by A/153. This specification is written presuming that the alternatives of (230, 182), (230, 194) and (230, 206) TRS coding will replace the alternatives of (235, 187), (223, 187) and (211, 187) TRS coding prescribed by A/153.

The inventor discerned that, in the M/H receivers designed to turbo-decode A/153 SCCC transmissions, the de-interleaving of soft decisions as to the 2-bit symbols of outer convolutional coding tends to disperse short bursts of noise that corrupt the M/H data from the decoder of the de-interleaved outer convolutional coding. He perceived that this dispersion of noise-corrupted data caused it to affect more transverse Reed-Solomon (TRS) codewords during the plural-dimension decoding procedures subsequent to turbo decoding. That is, the interleaving of the 2-bit symbols of outer convolutional coding at the transmitter is detrimental to the decoding of TRS codewords in the A/153 system for M/H broadcasting. The inventor continues to point out that a technique known generally by the name “implied interleaving” overcomes this problem. This technique has also been referred to by the name “code interleaving”. In the DTV transmitter apparatus the M/H data are subjected to prefatory bit de-interleaving in a pattern complementary to the pattern of 2-bit-symbol interleaving that succeeds outer convolutional coding. In the M/H receiver the decoder of the de-interleaved outer convolutional coding recovers the M/H data as subjected to the prefatory bit de-interleaving. Noise-corrupted portions of this de-interleaved data are dispersed owing to the de-interleaving of soft decisions as to the 2-bit symbols of outer convolutional coding. However, when this de-interleaved data is re-interleaved, the noise-corrupted data is consolidated by its restoration to the order in which it was received. So, the noise-corrupted data will affect fewer bytes of the data recovered by turbo decoding and consequently fewer TRS codewords. The use of implied 2-bit-symbol interleaving for outer convolutional coding of CCC signals was described in U.S. patent application Ser. No. 12/800,559 filed 18 May 2010 by A. L. R. Limberg and titled “Burst-error correction methods and apparatuses for wireless digital communications systems”.

### BRIEF SUMMARY OF THE CLAIMED INVENTION

The invention is directed to receivers for diversity reception of data transmitted by concatenated convolutional code (CCC) from at least one 8-VSB transmitter. Each receiver includes a first turbo decoder for the CCC as finally transmitted, a second turbo decoder for the CCC as initially transmitted, and an information-exchange unit connected for exchanging decoding information between the turbo decoders, which perform decoding concurrently. The turbo decoders are designed for decoding CCC formed from an outer convolutional code encoding de-interleaved Gray-coded data and a subsequent binary-coded inner convolutional code forming a 12-phase trellis code in accordance with a Gray-labeling procedure, the outer convolutional code encoding being symbol-interleaved before encoding within said inner convolutional code so said inner convolutional code has implied symbol interleaving in which the original order of data bits is preserved.

### BRIEF DESCRIPTION OF THE DRAWING

FIG. 1 is a schematic diagram of DTV transmitter apparatus for broadcasting signals to mobile receivers and to hand-held receivers.

FIG. 2 is a detailed schematic diagram of a preferred M/H post-processor for the FIG. 1 DTV transmitter apparatus, which M/H post-processor discontinues interference-filter pre-coding of X-sub-2 bits during the transmission of coded M/H data and that provides wrap-around trellis coding of the X-sub-1 bits in each M/H Group.

FIG. 3 is a schematic diagram showing in more detail the switched interference-filter pre-coder for the X-sub-2 bits of main-service data and the post-comb filter that are preferably used in the FIG. 2 M/H post-processor.

FIG. 4 is a detailed schematic diagram of an M/H Frame encoder preferably used in DTV transmitter apparatus as depicted in FIG. 1, which M/H Frame encoder is depicted in combination with buffer memory that supports iterative-diversity transmissions.

FIGS. 5, 6, 7, 8, 9, 10, 11 and 12 are tables showing alternative ways of allocating Slots for CCC transmissions employing iterative diversity and frequency-diversity.

FIG. 13 is a detailed schematic diagram of one of the RS Frame encoders in the FIG. 4 M/H Frame encoder.

FIG. 14 is a diagram of the bit order of half-rate outer convolutional coding when M/H data are encoded in SCCC.

FIG. 15 is a diagram of the bit order of half-rate outer convolutional coding when M/H data are encoded in PCCC.

FIG. 16 is a detailed schematic diagram of the block processor in the FIG. 1 DTV transmitter apparatus.

FIG. 17 is a detailed schematic diagram of an encoder for generating half-rate outer convolutional coding for PCCC, which encoder is included in preferred embodiments of the FIG. 16 block processor.

FIG. 18 is a schematic diagram of a representative embodiment of the signaling encoder in the FIG. 1 DTV transmitter apparatus.

FIG. 19 is a table showing a preferred bit syntax for the Transmission Parameter Channel (TPC) that the novel signaling encoder of the FIG. 1 DTV transmitter apparatus uses during the initial two sub-Frames of each M/H Frame, which bit syntax differs from that prescribed by A/153 and provides for signaling receivers concerning iterative-diversity transmissions.

FIG. 20 is a table showing a preferred bit syntax for the Transmission Parameter Channel (TPC) that the novel signaling encoder of the FIG. 1 DTV transmitter apparatus uses during the final three sub-Frames of each M/H Frame, which bit syntax differs from that prescribed by A/153 and provides for signaling receivers concerning iterative-diversity transmissions.

FIG. 21 is a table showing a preferred bit syntax for a CCC_outer_code_mode that the FIG. 19 and FIG. 20 TPC tables use in place of the SCCC_outer_code_mode used in the TPC tables specified by A/153.

FIG. 22 is a table showing a representative bit syntax for a subchannel_interleaving field included in each of the FIG. 19 and FIG. 20 bit syntax tables for TPC.

FIG. 23 is a table showing a representative bit syntax for an iterative_diversity_mode field included in each of the FIG. 19 and FIG. 20 bit syntax tables for TPC.

FIG. 24 is a table showing a representative bit syntax for an iterative_diversity_delay field included in each of the FIG. 19 and FIG. 20 bit syntax tables for TPC.

FIG. 25 is a table showing a representative bit syntax for a multiple_ensemble_service field included in FIC-Chunks and in Service Map Tables for M/H transmissions (SMT-MHs).

FIG. 26 is an assembly drawing indicating how FIGS. 26A, 26B, 26C and 26D combine to provide a schematic diagram of receiver apparatus for receiving M/H transmissions sent over the air from the FIG. 1 DTV transmitter apparatus, which receiver apparatus is novel and embodies aspects of the invention.

FIG. 27 is a detailed schematic diagram of a representative embodiment of the delay memory used in the FIG. 26B portion of the FIG. 26 receiver apparatus for delaying initial transmissions of M/H data to align them in time with final transmissions of the same M/H data, when iterative-diversity transmissions are being received.

FIG. 28 is a detailed schematic diagram of the structure of apparatus for decoding RS Frames in accordance with aspects of the invention.

FIG. 29 is a schematic diagram showing the selective interconnection of the adaptive equalization filters in a preferred embodiment the FIG. 26A portion of the FIG. 26 receiver apparatus, which selective interconnection provides for parallel updating of their filter coefficients when frequency-diversity reception is not being employed.

FIG. 30 is a diagram showing how checksum bytes of CRC coding are located in RS Frames, portions of each of which RS Frames are transmitted as one-third-code-rate PCCC in ten M/H Groups within an M/H Frame.

FIG. 31 is a diagram showing how checksum bytes of CRC coding are located in RS Frames, portions of each of which RS Frames are transmitted as one-third-code-rate PCCC in fifteen M/H Groups within an M/H Frame.

FIG. 32 is a diagram showing how checksum bytes of CRC coding are located in RS Frames, portions of each of which RS Frames are transmitted as one-third-code-rate PCCC in twenty M/H Groups within an M/H Frame.

FIG. 33 is a schematic diagram of an arrangement for determining the total number of Groups in an M/H sub-Frame by counting sequences of prescribed 8-VSB signals.

Each of FIGS. 34-48 is a schematic diagram of a respective embodiment of the parallelly-operated turbo decoders for iterative-diversity reception shown in the FIG. 26C portion of the FIG. 26 receiver apparatus.

FIG. 49 is a detailed schematic diagram of an arrangement used in the turbo decoders of FIGS. 34-48 for converting 2-bit symbols either from natural binary coding to reflected binary (Gray) coding or from reflected binary (Gray) coding to natural binary coding, which arrangement was disclosed and claimed by A. L. R. L. Limberg in U.S. patent application Ser. No. 12/456,608 filed 20 Jun. 2009.

FIG. 50 is a detailed schematic diagram of a novel arrangement used in the turbo decoders of FIGS. 34-48 for converting 2-bit symbols either from natural binary coding to reflected binary (Gray) coding.

FIG. 51 is a diagram illustrating that a cascade connection of a Gray-to-binary-code converter followed by a 2-bit-symbol de-interleaver may replace a cascade connection of a 2-bit-symbol de-interleaver followed by a Gray-to-binary-code converter, and vice-versa.

FIG. 52 is a diagram illustrating that a cascade connection of a binary-to-Gray-code converter followed by a 2-bit-symbol interleaver may replace a cascade connection of a 2-bit-symbol interleaver followed by a binary-to-Gray-code converter, and vice-versa.

FIG. 53 is a detailed schematic diagram of a first embodiment of the information-exchange unit that the parallelly-operated turbo decoders of FIGS. 26C and 34-48 use during iterative-diversity reception to exchange information between respective loops for turbo decoding initially transmitted data and for turbo decoding finally transmitted corresponding data.

FIG. 54 is a schematic diagram of a second embodiment of the information-exchange unit that the parallelly-operated turbo decoders of FIGS. 26C and 34-48 use during iterative-diversity reception to exchange information between respective loops for turbo decoding initially transmitted data and for turbo decoding finally transmitted corresponding data.

FIG. 55 is a schematic diagram of modifications applicable to turbo decoding circuitry per any of FIGS. 34-38 and 46-48, inclusive, which modifications use CRC decoding results to modify the confidence levels of soft data bits supplied from the binary-to-Gray-code re-mappers of the turbo-decoding loops.

FIG. 56 is a schematic diagram of modifications applicable to turbo decoding circuitry per any of FIGS. 39, 42 and 45, which modifications use CRC decoding to update the confidence levels of soft data bits in soft decisions supplied from the binary-to-Gray-code re-mappers of the turbo-decoding loops.

FIG. 57 is a schematic diagram of modifications applicable to turbo decoding circuitry per any of FIGS. 34, 36, 39, 42, 43, 46, 47 and 48 which modifications use CRC decoding results to modify the confidence levels of soft data bits supplied from the re-interleavers of soft decisions from the outer decoders of the turbo-decoding loops before Gray-to-binary-code re-mapping.

FIG. 58 is a schematic diagram of modifications for the FIG. 35 turbo decoding circuitry, which modifications use CRC decoding to update the confidence levels of soft data bits supplied to the Gray-to-binary-code re-mappers in the turbo-decoding loops.

Connections for control signals are indicated by successions of short dashes. Shim delays that a person of ordinary skill in the art would customarily introduce to make signal timings precisely correct may in some instances be omitted in the figures of the drawing. This is done to conform to drafting limitations, while keeping the figures easier to understand.

### DETAILED DESCRIPTION

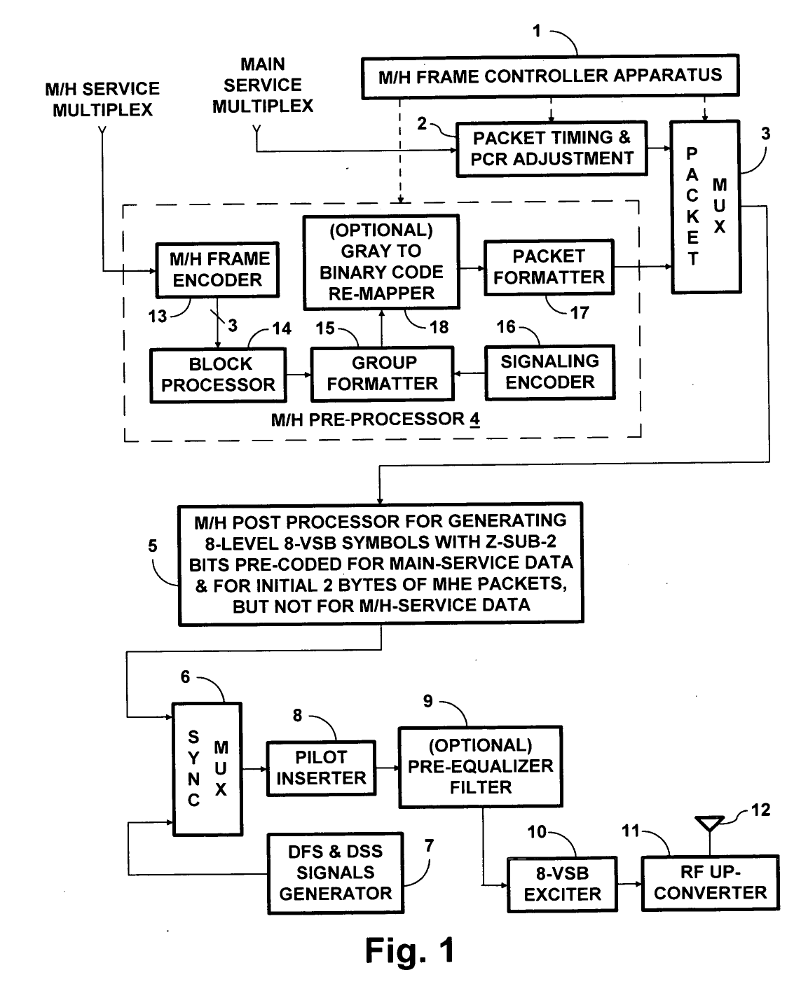

FIG. 1 shows transmitter apparatus for broadcast DTV signals including those intended for reception by mobile receivers and by hand-held receivers, which receivers are collectively referred to as “M/H receivers”. The transmitter apparatus receives two sets of input streams, one composed of the MPEG transport-stream (TS) packets of the main-service data and the other composed of IP TS packets of the M/H-service data. The M/H-service data are encapsulated in 208-byte-long MPEG-like TS packets before emission, which MPEG-like TS packets are called “M/H encapsulating packets” or “MHE packets”. This avoids disrupting the reception of the main-service data by legacy 8-VSB receivers. The FIG. 1 transmitter apparatus combines the MPEG TS packets of the main-service data and the internet-protocol TS packets of the M/H-service data within one stream of MPEG or MPEG-like TS packets, then processes the combined stream to be transmitted as an ATSC trellis-coded 8-VSB signal.

M/H Frame controller apparatus 1 controls these procedures. The main-service multiplex stream of data is supplied to packet timing and PCR adjustment circuitry 2 before the packets of that stream are routed to a packet multiplexer 3 to be time-division multiplexed with MHE packets encapsulating M/H-service data. (PCR is the acronym for “Program Clock Reference”.) Because of their time-division multiplexing with the MHE packets encapsulating M/H-service data, changes have to be made to the time of emission of the main-service stream packets compared to the timing that would occur with no M/H stream present. The packet timing and PCR adjustment circuitry 2 makes these timing changes responsive to control signals supplied thereto from the M/H Frame controller apparatus 1. The packet multiplexer 3 time-division multiplexes the main-service TS packets with TS packets encapsulating M/H-service data, as directed by control signals from the M/H Frame controller apparatus 1. The operations of the M/H transmission system on the M/H data are divided into two stages: the M/H pre-processor 4 and the M/H post-processor 5.

The M/H-service multiplex stream of data is supplied to the M/H pre-processor 4 for processing. The pre-processor 4 rearranges the M/H-service data into an M/H data structure, enhances the robustness of the M/H-service data by additional coding procedures, inserts training sequences, and subsequently encapsulates the processed enhanced data within MHE packets, thus to generate an ancillary transport stream (TS). The MHE packets are supplied to the packet multiplexer 3 after data encapsulation within their payload fields is completed. The operations performed by the pre-processor 4 include M/H Frame encoding, block processing, Group formatting, optional Gray-code-to-natural-binary-code conversion, packet formatting, and encoding M/H signaling. The M/H Frame controller apparatus 1 provides the necessary transmission parameters to the pre-processor 4 and controls the multiplexing of the main-service TS packets and the M/H-service TS packets by the packet multiplexer 3 to organize the M/H Frame. Preferably, the pre-processor 4 differs from that described in A/153 in regard to the M/H Frame encoding, in regard to the block processing and in regard to Gray-code-to-natural-binary-code conversion. The block processing includes capability for the generation of parallel concatenated convolutional coding (PCCC) that has half the code rate of 8-VSB transmissions of the type originally prescribed by A/53.

The post-processor 5 processes the main-service TS packets by normal 8-VSB encoding and re-arranges the pre-processed M/H-service TS packets in the combined stream to assure backward compatibility with ATSC 8-VSB. The post-processor 5 differs from that described in A/153 in that pre-coding of the most significant bits of 8-VSB symbols is disabled when the symbols describe M/H-service data. Consequently, receivers need not use post-comb filtering of the most significant bits of 8-VSB symbols during reception of M/H-service data, avoiding the loss in signal-to-noise ratio associated with such filtering. Disabling the pre-coding of the most significant bits of 8-VSB symbols descriptive of M/H-service data allows the use of Gray-code labeling of outer convolutional coding of the CCC and also allows the use of PCCC. The most significant bits of 8-VSB symbols descriptive of main-service TS packets are pre-coded, so as not to disrupt the operation of legacy receivers. So are the most significant bits of 8-VSB symbols descriptive of the initial two bytes of the header of each MHE packet, to facilitate legacy receivers being able to discriminate against MHE packets when routing TS packets to packet decoders. Main-service data in the combined stream are processed exactly the same way as for ordinary 8-VSB transmission: randomizing, Reed-Solomon (RS) encoding, convolutional byte interleaving, and trellis encoding. The M/H-service data in the combined stream are processed differently from the main-service data, with the pre-processed M/H-service data bypassing data randomization. The pre-processed MHE packets are subjected to non-systematic RS encoding, which re-arranges the bytes of those packets within RS codewords. The non-systematic RS encoding allows the insertion of the regularly spaced long training sequences so as not to disrupt the operation of legacy receivers. Additional operations are done on the pre-processed M/H-service data to initialize the trellis encoder memories at the beginning of each training sequence included in the pre-processed M/H-service data.

A synchronization multiplexer 6 is connected for receiving, as the first of its two input signals, the 2/3 trellis-coded data generated by the post-processor 5. The sync multiplexer 6 is connected for receiving its second input signal from a generator 7 of synchronization signals comprising the data segment sync (DSS) and the data field sync (DFS) signals. Per custom, the DSS and DFS signals are time-division multiplexed with the 2/3 trellis-coded data in the output signal from the sync multiplexer 6, which is supplied to a pilot inserter 8 as input signal thereto. The pilot inserter 8 introduces a direct-component offset into the signal to cause a pilot carrier wave to be generated during subsequent balanced modulation of a suppressed intermediate-frequency (IF) carrier wave. The output signal from the pilot inserter 8 is a modulating signal with offset, which optionally is passed through a pre-equalizer filter 9 before being supplied as input signal to an 8-VSB exciter 10 to modulate the suppressed IF carrier wave. Alternatively, the pre-equalizer filter 9 precedes the pilot inserter 8 in their cascade connection with each other. Other transmitter designs omit the pre-equalizer filter 9 in favor of a direct connection. The 8-VSB exciter 10 is connected for supplying the suppressed IF carrier wave to a radio-frequency (RF) up-converter 11 to be converted upward in frequency to repose within the broadcast channel. The up-converter 11 also amplifies the power of the RF signal it supplies to a broadcast antenna 12.

More specifically, the M/H pre-processor 4 comprises an M/H Frame encoder 13, a block processor 14, a Group formatter 15, a signaling encoder 16, a packet formatter 17 and optionally a Gray-code-to-binary-code re-mapper 18. The M/H-service multiplex stream of data supplied to the M/H pre-processor 4 is applied as input signal to the M/H Frame encoder 13, which provides transverse Reed-Solomon (TRS) coding of that data. Each M/H Frame is composed of one or more RS Frames, each comprising a TRS Frame of TRS coding. The data in eachTRS Frame are randomized independently from each other and from the data of the main-service multiplex. The TRS-coded M/H data are subsequently further coded with a byte-error-locating block code that M/H receivers can utilize for locating byte errors in the TRS codewords. This byte-error-locating block coding replaces the periodic cyclic-redundancy-check (CRC) coding prescribed by A/153. In a departure from the prior art, the codewords of this byte-error-locating block coding have a prescribed standard length in number of 8-bit bytes, irrespective of TNoG, the total number of M/H Groups in each M/H Frame. This byte-error-locating block coding can be CRC coding or can be lateral Reed-Solomon (LRS) forward-error-correction (FEC) coding. The inventor's patent application Ser. No. 12/580,534 filed 16 Oct. 2009, teaches that byte-error-locating CRC coding is better done for each the M/H Groups in an M/H Frame on an individual basis, rather than for all those M/H Groups on a collective basis. This is particularly advantageous for PCCC transmissions, since the CRC coding can be used to mitigate any BER floor problem that is experienced during reception of such transmissions. LRS FEC coding can be used for this purpose in place of the CRC coding and can be used to facilitate turbo coding further by correcting errors. The standard length of the codewords of the byte-error-locating block coding is chosen such that an integral number of those codewords fits exactly within the portion of each RS Frame conveyed by an individual M/H Group. This permits the M/H Frame encoder 13 to use a single encoder for the byte-error-locating block coding for every RS Frame, no matter its size. This departs from the prior-art practice of having a respective encoder for the CRC coding of each RS Frame in an M/H Frame.

The M/H Frame encoder 13 is connected for supplying the byte-error-locating block codewords to the block processor 14, as input signal thereto. The block processor 14 includes apparatus for generating outer convolutional coding in response to the byte-error-locating block codewords of TRS-coded M/H-service data. This apparatus includes an encoder for outer convolutional coding at a code rate one half the 8-VSB symbol rate. This encoder is preferably preceded by a bit de-interleaver and succeeded by a symbol interleaver for the two-bit symbols generated at the code rate one half the 8-VSB symbol rate. The bit de-interleaver and the symbol interleaver are complementary to each other to provide “implied interleaving” for M/H data bits (sometimes referred to “code interleaving” in view of the processing of parity bits). Implied symbol interleaving preserves the original order of the successive M/H data bits bits within the CCC, whether it be SCCC or PCCC. Implied symbol interleaving of CCC avoids dispersion of burst errors in the received CCC. Such dispersion would adversely effect the capability of TRS coding to overcome burst errors.

The Group formatter 15 is connected for receiving the interleaved outer convolutional coding from the block processor 14 as input addressing signal. The Group formatter 15 includes an interleaved Group format organizer that operates on the Group format as it will appear after the ATSC data interleaver. The interleaved Group format organizer maps the FEC coded M/H-service data from the block processor into the corresponding M/H blocks of a Group, adding pre-determined training data bytes and data bytes to be used for initializing the trellis encoder memories. The interleaved Group format organizer inserts headers for the MHE packets, preferably truncated to just 2-byte length to accommodate more bytes of M/H data in those packets. The interleaved Group format organizer also inserts place-holder bytes for main-service data and for non-systematic RS parity. The interleaved Group format organizer inserts a few dummy bytes to complete construction of the intended Group format. The interleaved Group format organizer assembles a group of 118 consecutive TS packets. Some of these TS packets are composed of the interleaved outer convolutional coding supplied by the block processor 14. A signaling encoder 16 generates others of these TS packets.

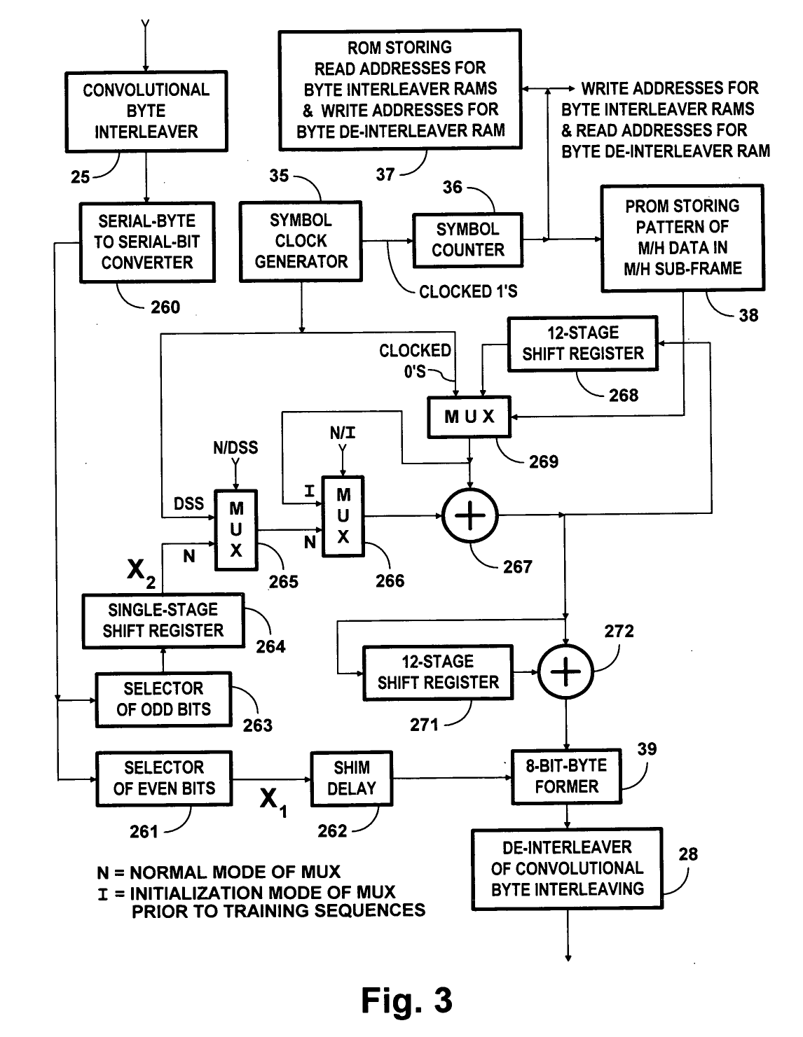

Still others of these TS packets are prescribed training signals stored in read-only memory within the Group formatter 15 and inserted at prescribed intervals within the group. The prescribed training signals inserted by the Group formatter 15 in FIG. 1 will differ from those described in A/153 if the Z-sub-2 bits of the training signal symbols are modified to take into account the pre-coding of those bits being selectively discontinued during M/H signals. The apparatus for selective discontinuation of such pre-coding is described in more detail further on in this specification, with reference to FIG. 3 of the drawing. However, because transmitter apparatus constructed for implementing A/153 is already in the field, it is more likely that the Z-sub-2 bits of the training signal symbols will be pre-coded, avoiding the Group formatter 15 having to be modified in this regard.

The Group formatter 15 may differ from that prescribed by A/153 in the way that RS Frames are mapped into M/H Groups. U.S. patent application Ser. No. 12/924,074 filed 20 Sep. 2010 describes wrap-around coding of each M/H Group. This facilitates a respective portion of a coded primary RS Frame beginning in M/H Block 4 of each M/H Group and a respective portion of a coded secondary RS Frame beginning in M/H Block 9 of a respective M/H Group and wrapping around to conclude in M/H Block 3 of the same M/H Group.

The M/H transmission system has two kinds of signaling channels generated by the signaling encoder 16. One is the Transmission Parameter Channel (TPC), and the other is the Fast Information Channel (FIC). The TPC is for signaling the M/H transmission parameters, such as various FEC modes and M/H Frame information. The FIC is provided to enable a receiver to acquire a broadcast service quickly, and the FIC contains cross-layer information between the physical layer of the receiver and its upper layer(s). The “physical layer” of the receiver is that portion of the receiver used to recover the IP transport stream, and the succeeding “upper layer” processes the IP transport stream. The TPC and FIC signals are encoded within parallel concatenated convolutional coding that has a code rate one-quarter the 8-VSB symbol rate.

Within the Group formatter 15 the interleaved Group format organizer is followed in cascade connection by a byte de-interleaver that complements the ATSC convolutional byte interleaver. The Group formatter 15 is connected for supplying the response of this de-interleaver as its output signal, which is applied as input signal to the Gray-code-to-binary-code re-mapper 18. The re-mapper 18 recodes 2-bit symbols of its input signal which is considered to be in reflected-binary (Gray) code to the natural-binary code that governs the modulating signal used in 8-VSB amplitude modulation. This implements a procedure known as “Gray-code labeling”. The conversion is performed by exclusive-ORing the least significant bit (LSB) of each 2-bit symbol of the re-mapper 18 input signal with the most significant bit (MSB) thereof to generate the LSB of the re-mapper 18 output signal. The MSB of the re-mapper 18 output signal reproduces the MSB of the re-mapper 18 input signal. The MSB and the LSB of the re-mapper 18 output signal respectively correspond to bits referred to as the “X-sub-2 bit” and the “X-sub-1 bit” during subsequent trellis coding procedure. The Gray-code-to-binary-code re-mapper 18 recodes the quarter-rate PCCC encoding the TPC and FIC signals unless provision is made for the re-mapper 18 not to do so. The re-mapper 18 output signal is supplied to the packet formatter 17.

The inclusion of the Gray-code-to-binary-code re-mapper 18 in the FIG. 1 transmitter apparatus is optional. If the re-mapper 18 is not included, the output signal from the Group formatter 15 is supplied directly to the packet formatter 17 as input signal thereto. In an initial procedure therein, the packet formatter 17 expunges the main-service data place holders and the RS parity place holders that were inserted by the interleaved Group format organizer for proper operation of the byte de-interleaver in the Group formatter 15. The packet formatter 17 inserts an MPEG TS sync byte before each 187-byte data packet as a prefix thereof. The packet formatter 17 supplies 118 M/H-service transport-stream packets per group to the packet multiplexer 3, which time-division multiplexes the M/H-service TS packets and the main-service TS packets to construct M/H Frames.

The M/H Frame controller apparatus 1 controls the packet multiplexer 3 in the following way when the packet multiplexer schedules the 118 TS packets from the packet formatter 17. Thirty-seven packets immediately precede a DFS segment in a 313-segment VSB field of data, and another eighty-one packets immediately succeed that DFS segment. The packet multiplexer 3 reproduces next-in-sequence main-service TS packets in place of MPEG null packets that contain place-holder bytes for main-service data in their payload fields. The packet multiplexer 3 is connected to supply the TS packets it reproduces to the M/H post-processor 5 as input signal thereto.

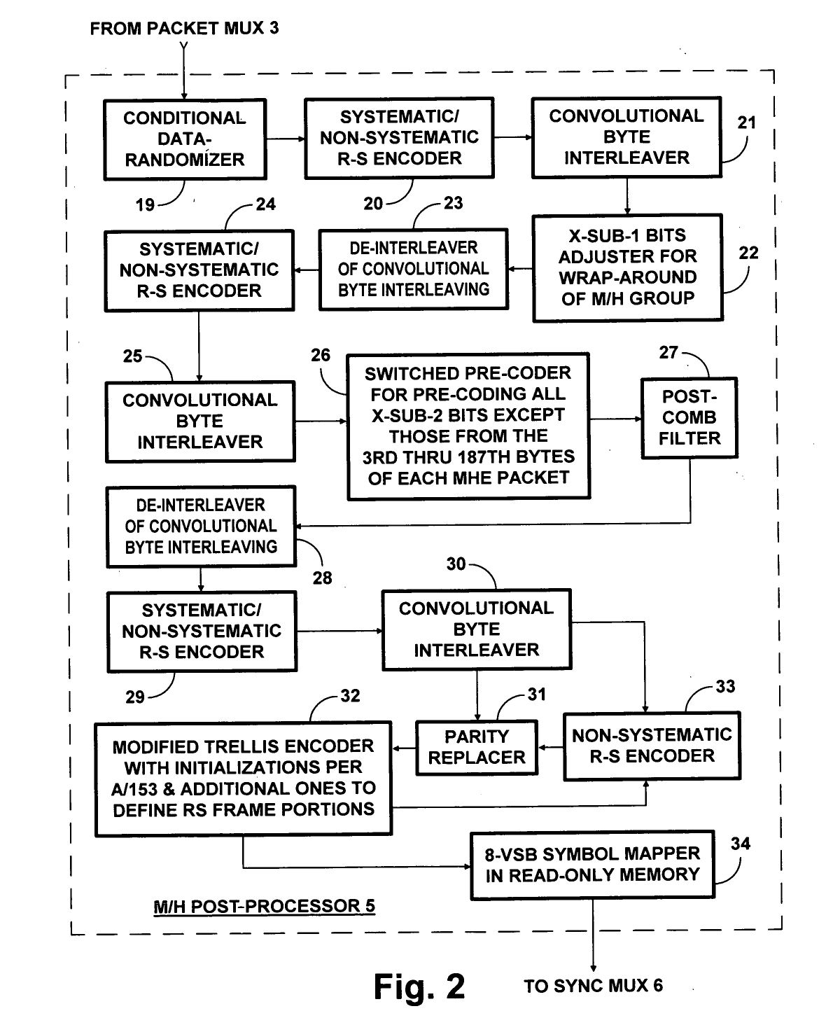

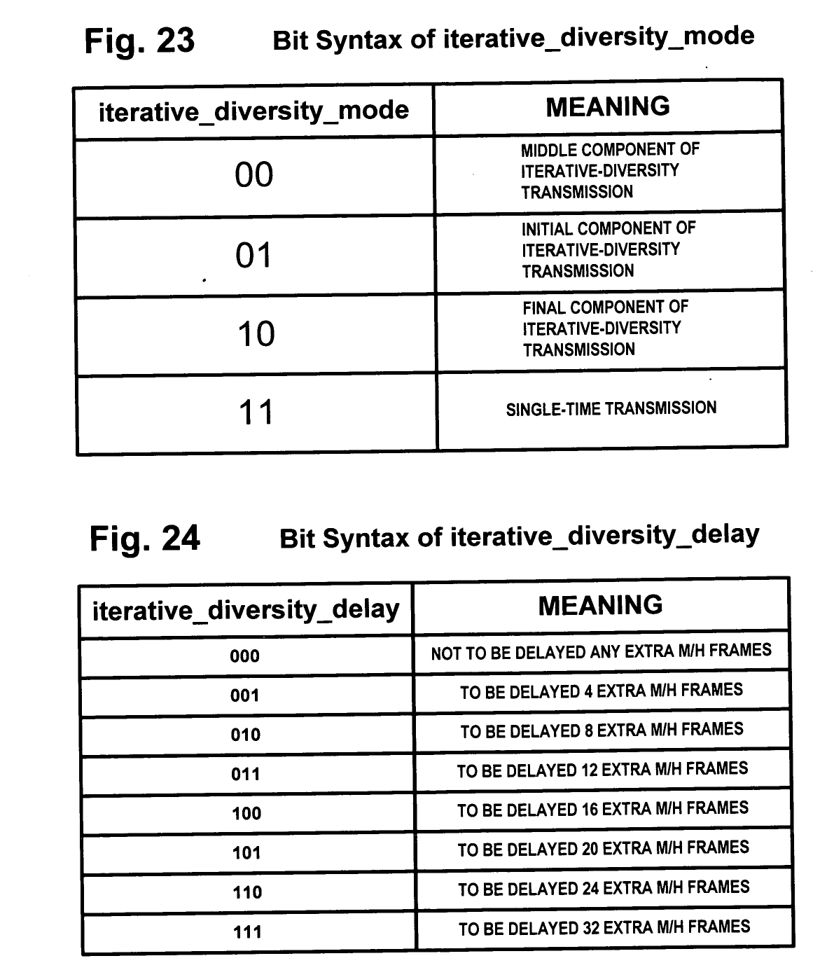

FIG. 2 shows in more detail a representative embodiment of the M/H post-processor 5 as constructed in accordance with inventive precepts disclosed herein. The M/H post-processor 5 includes a conditional data randomizer 19 operated as prescribed by A/153, Part 2, §5.3.2.2.1.1 “M/H Randomizer”. FIG. 2 shows the packet multiplexer 3 connected to apply the TS packets it reproduces to the conditional data randomizer 19 as the input signal thereto. The conditional data randomizer 19 suppresses the sync bytes of the 188-byte TS packets and randomizes the remaining data in accordance with conventional 8-VSB practice, but only on condition that it is not within an M/H-service TS packet. The M/H-service TS packets bypass data randomization by the conditional data randomizer 19. The other remaining data are randomized per A/53, Annex D, §4.2.2. The conditional data randomizer 19 is connected for supplying the conditionally randomized data packets that it generates to an encoder 20 for preliminary systematic/non-systematic (207, 187) Reed-Solomon coding. The Reed-Solomon encoder 20 is as prescribed by A/153, Part 2, §5.3.2.9 “Systematic/Non-Systematic RS Encoder”. The RS parity generator polynomial and the primitive field generator for the RS encoder 20 are the same as those that A/53, Annex D, FIG. 23 prescribes for (207, 187) Reed-Solomon coding. The RS encoder 20 is connected for supplying the resulting segments of the data field generated therein as input signal to a convolutional byte interleaver 21. When the RS encoder 20 receives a main-service data packet, the RS encoder 20 performs the systematic RS coding process prescribed in A/53, Annex D, §4.2.3. The resulting twenty bytes of RS parity data are appended to the conclusion of the 187-byte packet in the main-service data packet subsequently supplied to the input port of the convolutional byte interleaver 21. When the RS encoder 20 receives an M/H-service data packet, the RS encoder 20 performs a non-systematic RS encoding process. The twenty bytes of RS parity data obtained from the non-systematic RS encoding process are inserted in various parity byte locations within each M/H-service TS packet subsequently supplied to the input port of the convolutional byte interleaver 21. These insertions correspond to what A/153 prescribes for M/H-service TS packets similarly located within an 8-VSB data field. The convolutional byte interleaver 21 is of the type specified in Section 5.3.2.10 “Convolutional Data Byte Interleaver” of Part 2 of A/153 or of a type equivalent in function. The byte-interleaver 21 response is supplied as a serial stream of 2-bit symbols, each composed of a respective X-sub-2 bit and a respective X-sub-1 bit.

Preferably, the serial stream of 2-bit symbols from the convolutional byte interleaver 21 is applied as input signal to an X-sub-1 bits adjuster 22 that resets the 2/3 trellis coding used as inner convolutional coding of the each M/H Group at the beginning of each M/H Group. The X-sub-1 bits adjuster 22 also resets that 2/3 trellis coding at the conclusion of each M/H Group. U.S. patent application Ser. No. 12/924,074 filed 20 Sep. 2010 provides a detailed description of the construction of an X-sub-1 bits adjuster suitable for inclusion in the M/H post-processor 5. The resetting of the 2/3 trellis coding at the conclusion of each M/H Group as well as its beginning allows for wrap-around decoding of the 2/3 trellis coding of each individual M/H Group. The response from the X-sub-1 bits adjuster 22 includes both M/H-service data segments and forwarded main-service data segments. This response is applied as input signal to a convolutional byte de-interleaver 23 of a type complementary to the convolutional byte interleaver 21. Still another encoder 24 for systematic/non-systematic (207, 187) Reed-Solomon codes per A/153, Part 2, §5.3.2.9 is connected to receive, as its input signal, the output signal from the byte de-interleaver 23. The Reed-Solomon encoder 24 recalculates the RS parity bytes in the M/H-service data segments affected by the X-sub-1 bits adjuster 22 resetting the 2/3 trellis coding at the beginning of each M/H Group and at the conclusion of each M/H Group. The RS encoder 24 response is supplied to the input port of a convolutional byte interleaver 25. The byte-interleaver 25 response is supplied as a serial stream of 2-bit symbols, each composed of a respective X-sub-2 bit and a respective X-sub-1 bit. The RS parity bytes from just two M/H-service data segments from each M/H Group need to be re-calculated to correct for X-sub-1 bits adjustment. So, the byte de-interleaver 23, the RS encoder 24 and the byte interleaver 25 can be replaced by simpler circuitry providing equivalent operation.

The serial stream of 2-bit symbols supplied as byte-interleaver 25 response is applied as input signal to a switched interference-filter pre-coder 26 for precoding all the X-sub-2 bits from the main-service (207, 187) RS codewords, the X-sub-2 bits from just the first two bytes of each MHE packet, and the X-sub-2 bits from the M/H-service (207, 187) RS codewords. The pre-coder 26 provides selective pre-coding of the X-sub-2 bits received as input signal, skipping over the X-sub-2 bits of the M/H-service data from the final 185 bytes of each MHE packets. If the Group formatter 15 inserts M/H training signals that have their X-sub-2 bits already pre-coded, the pre-coder 26 skips over pre-coding those X-sub-2 bits as well. If the Group formatter 15 inserts M/H training signals that do not have their X-sub-2 bits already pre-coded, the pre-coder 26 pre-codes those X-sub-2 bits. The pre-coder 26 response is applied as input signal to a post-comb filter 27 similar to those used in DTV receivers, and the post-comb filter 27 response is applied as input signal to a convolutional byte de-interleaver 28 of a type complementary to the convolutional byte interleaver 25. Another encoder 29 for systematic/non-systematic (207, 187) Reed-Solomon codes per A/153, Part 2, §5.3.2.9 is connected to receive, as its input signal, the output signal from the byte de-interleaver 28. The Reed-Solomon encoder 29 recalculates the parity bytes both in the main-service data segments and in the M/H-service data segments. Except for changes apt to be subsequently introduced into a few of the MHE packets during deterministic trellis-resetting, the response of the convolutional byte de-interleaver 28 resembles the data segments that a DTV receiver is expected to supply to its decoder of (207, 187) Reed-Solomon forward-error-correction coding.

A convolutional byte interleaver 30 is connected for receiving, as its input signal, the main-service and M/H-service data segments with re-calculated RS parity bytes from the RS encoder 29. The byte interleaver 30 is as specified by A/153, Part 2, §5.3.2.10 “Convolutional Data Byte Interleaver” or an equivalent thereof. The byte interleaver 30 is connected for supplying byte-interleaved 207-byte RS codewords to a parity replacer 31 that reproduces portions of those codewords in its response. This response is applied as input signal to a modified trellis encoder 32 of a type similar to that specified by A/153, Part 2, §5.3.2.11 “Modified Trellis Encoder” or an equivalent thereof. The modified trellis encoder 32 converts the byte-unit data from the parity replacer 31 to successive 2-bit symbols and performs a 12-phase trellis coding process on those symbols.

In order for the output signal from the trellis encoder 32 to include pre-defined known training data, initialization of the memories in the trellis encoder 32 is required, as described in A/153. This initialization is very likely to cause the RS parity data calculated by the RS encoder 29 prior to the trellis initialization to be erroneous. The RS parity data must be replaced to ensure backward compatibility with legacy DTV receivers. Accordingly, as described in A/153, Part 2, §5.3.2.11 “Modified Trellis Encoder”, the modified trellis encoder 32 is connected for supplying the changed initialization bytes to an encoder 33 for non-systematic (207, 187) Reed-Solomon codes, as described in A/153, Part 2, §5.3.2.12 “Non-Systematic RS Encoder and Parity Replacer”. The RS encoder 33 re-calculates the RS parity of the affected M/H packets. The RS encoder 33 is connected for supplying the re-calculated RS parity bytes to the RS parity replacer 31, which substitutes the re-calculated RS parity bytes for the original RS parity bytes before they can be supplied to the modified trellis encoder 32. That is, the RS parity replacer 31 reproduces the output of the byte interleaver 30 as regards the data bytes for each packet in its output signal, but reproduces the output of the non-systematic RS encoder 33 as regards the RS parity bytes for each packet in its output signal.

The modified trellis encoder 32 is connected for supplying its output signal to a read-only memory (ROM) 34 that responds to successive 3-bit input addresses to map them to respective ones of eight possible 8-VSB symbol levels. These 8-VSB symbol levels are supplied as the output signal from the M/H post-processor 5 and are applied as input signal to the sync multiplexer 6 shown in FIG. 1. If RS Frames are mapped into M/H Groups as described in U.S. patent application Ser. No. 12/924,074 filed 20 Sep. 2010, rather than as prescribed by A/153, the modified trellis encoder 32 will differ slightly from that described in A/153, Part 2, §5.3.2.11. This is because a further trellis initialization is introduced in data segment 132 of each M/H Group to introduce separation between a portion of a primary RS Frame and a portion of secondary RS Frame that appears in some M/H Groups.

FIG. 3 shows in more detail representative constructions of the switched interference-filter pre-coder 26 and of the post-comb filter 27 cascaded thereafter. The precoder 26 for the X-sub-2 bits of main-service data comprises elements 260-269. The post-comb filter 27 comprises a 12-stage shift register 271 and a modulo-2 adder 272 (which is an exclusive-OR gate). A symbol clock generator 35 generates clocked ONEs and clocked ZEROes during 8-VSB data segments. The clocked ONEs are applied to a symbol counter 36 that counts the symbols in each M/H sub-Frame. This count is most convenient to use if made on a symbol-per-data-segment and data-segment-per-M/H-sub-Frame basis, since such count can be used with suitable delays as write addressing of respective random-access memories (RAMs) within the byte interleavers 21, 25 and 30. With suitable delay, such count can also be used as read addressing of random-access memory (RAM) within the byte de-interleavers 23 and 28. Portions of the count from the symbol counter 36 are applied as read addressing to a read-only memory 37 and as read addressing to a programmable read-only memory 38. With suitable delays, the response from the ROM 37 provides read addressing of the RAM within the byte de-interleavers 23 and 28. With suitable delays, the response from the ROM 37 provides write addressing of the respective RAMs within the byte interleavers 21, 25 and 30. With suitable delay, the response from the PROM 38 maps the pattern of M/H data symbols within each M/H sub-Frame to control the selective precoding of the X-sub-2 bits of main-service data by the interference-filter pre-coder 26. The programmability of the PROM 38 permits the broadcaster to change the number of M/H Groups per M/H sub-Frame.

More particularly, the PROM 38 stores a pattern of ONEs and ZEROes descriptive of the pattern of M/H-service and main-service 8-VSB symbols in an M/H sub-Frame. The pattern of ONEs and ZEROes descriptive of the pattern of M/H-service and main-service 8-VSB symbols in an M/H sub-Frame is read from the PROM 38 for controlling the operation of the pre-coder 26 in the M/H post processor 5 as shown in FIG. 2. Since the pattern changes only at boundaries between bytes, the size of the PROM 38 can be reduced if byte pattern information, rather than symbol pattern information, is stored therein. If the PROM 38 is reduced in size by storing byte pattern information, the two least significant bits of the symbol count from the symbol counter 35 are not included in the input addressing applied to the PROM 38.

The convolutional byte interleaver 25 is connected for applying successive eight-bit bytes of its response to the input port of a byte-to-bit converter 260 for conversion to serial-bit format at the input of the pre-coder 26. A selector 261 is connected for selectively reproducing just the even-occurring X-sub-1 bits from the serial-bit response of the byte-to-bit converter 260. These X-sub-1 bits are forwarded via shim delay 262 to an 8-bit byte former 39 to be bit-interleaved with processed X-sub-2 bits from the post-comb filter 27 as a preparatory step in forming 8-bit bytes for application to the byte de-interleaver 28. A selector 263 is connected for selectively reproducing just the odd-occurring X-sub-2 bits from the serial-bit response of the byte-to-bit converter 261. The selector 263 is connected for applying the reproduced X-sub-2 bits to the input port of a single-stage shift register 264. The output port of the shift register 264 is connected for applying the reproduced X-sub-2 bits to a first of two input ports of a multiplexer 265, which port is labeled ‘N’ in FIG. 3. The single-stage shift register 264 delays X-sub-2 bits selected from the serial-bit response of the byte-to-bit converter 260 for better aligning them temporally with X-sub-1 bits selected from that serial-bit response. A second of the two input ports of the multiplexer 265, which port is labeled ‘DSS’ in FIG. 3, is connected for receiving clocked ZEROes generated by the symbol clock generator 35. The multiplexer 265 is conditioned by a control signal (labeled N/DSS in FIG. 3) to reproduce at an output port thereof two selected ones of these clocked ZEROes during each data segment synchronization (DSS) interval. At times other than DSS intervals the multiplexer 265 is conditioned by its control signal to reproduce at its output port the X-sub-2 bits supplied to its first input port. The output port of the multiplexer 265 is connected to a first of two input ports of a multiplexer 266, which input port is labeled ‘N’ in FIG. 3. During normal operation the multiplexer 266 is conditioned by a normal/initialize (N/I) control signal to reproduce at its output port the multiplexer 265 response. The output port of the multiplexer 266 is connected for applying a first of two summand input signals applied to a modulo-2 adder 267 (which is an exclusive-OR gate). The modulo-2 adder 267 is connected for applying a serial-bit sum output signal therefrom to the post-comb filter 27.

The modulo-2 adder 267 is also connected for applying its serial-bit sum output signal to the input port of a 12-stage shift register 268. The output port of the 12-stage shift register 268 is connected to one of two input ports of a multiplexer 269, the output port of which is connected for supplying a second of the two summand input signals applied to the modulo-2 adder 267. The other input port of the multiplexer 269 is connected for receiving ZERO bits clocked at symbol rate from the symbol clock generator 35. When the multiplexer 269 receives a control signal conditioning it to reproduce the serial-bit sum output signal of the adder 267 as delayed by the 12-stage shift register 268, the bits supplied to the post-comb filter 27 are pre-coded. When the multiplexer 269 receives a control signal conditioning it to reproduce the clocked ZEROes supplied from the symbol clock generator 35, the bits supplied to the post-comb filter 27 are not pre-coded. Rather, they are identical to the X-sub-2 bits supplied from the output port of the multiplexer 269.

FIG. 3 shows the modulo-2 adder 267 connected for applying the selectively pre-coded X-sub-2 bits of its serial-bit sum output signal to the input port of a 12-stage shift register 271 in the post-comb filter 27. The output port of the 12-stage shift register 268 is connected for supplying delayed response to the adder 267 sum output signal as one of the two summand input signals of the modulo-2 adder 272 in the post-comb filter 27. The adder 267 is connected for applying its sum output signal to the modulo-2 adder 272 as the second of the two summand input signals thereof. The adder 272 is connected for applying the selectively post-comb-filtered X-sub-2 bits of its serial-bit sum output signal to the 8-bit byte former 39 to be bit-interleaved with X-sub-1 bits forwarded via shim delay 263. The byte former 39 forms 8-bit bytes from the results of this bit-interleaving, which bytes are supplied to the byte de-interleaver 28 as input signal thereto.

The shift registers 268 and 271 are continuously clocked at symbol epoch rate throughout data fields, even during the data-segment synchronization (DSS) intervals. The FIG. 3 arrangement can be modified to omit the shift register 271. The response of the 12-stage shift register 268 is then applied as the first summand input signal of the modulo-2 adder 272 instead of the response of the 12-stage shift register 271 being so applied. One skilled in the art of designing electronics will recognize that the 12-phase trellis coding procedures can be carried out using commutated operation of twelve single-phase encoders, rather than by a single 12-phase encoder as depicted in FIG. 3. Such equivalent circuitry is more similar to the trellis encoders described in A/53.

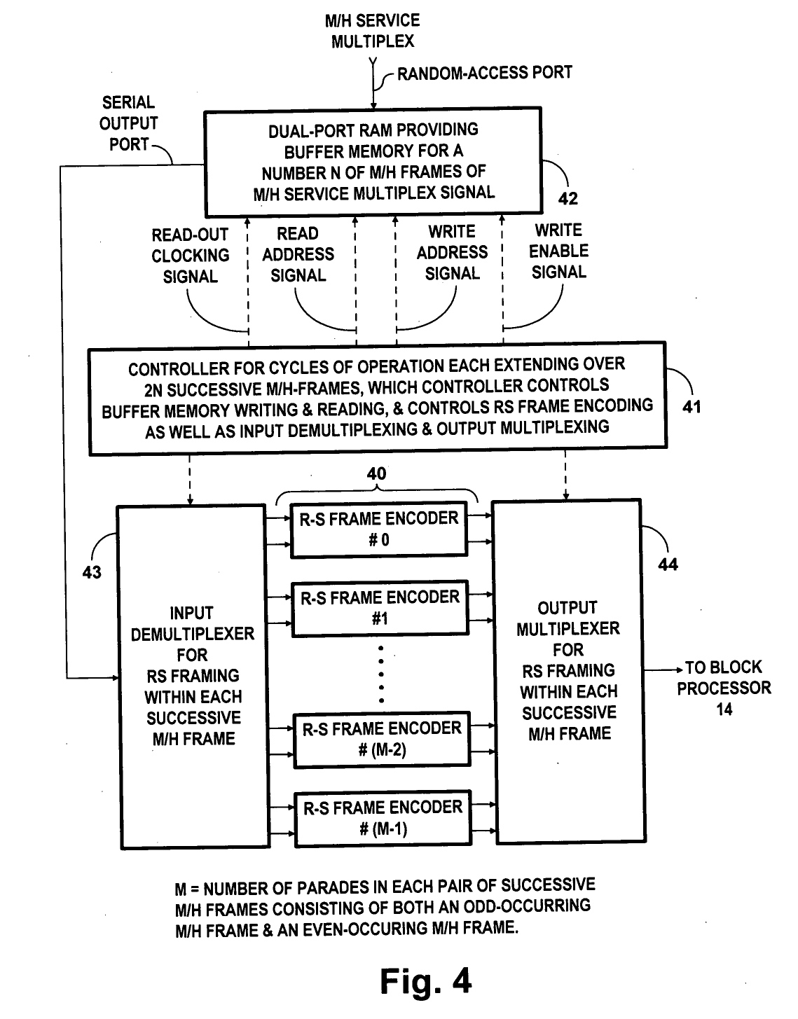

FIG. 4 depicts a novel preferred form for the M/H Frame encoder 13 of the FIG. 1 DTV transmitter apparatus in some detail. The FIG. 4 M/H Frame encoder 13 includes a set 40 of R-S Frame encoders each generally similar to those in prior-art M/H Frame encoders. This set 40 includes as many R-S Frame encoders as there are Parades in two M/H Frames, twice as many as in the M/H Frame encoder described in A/153. A controller 41 is included in the FIG. 2 M/H Frame encoder 13 for controlling its operations, including those of the R-S Frame encoders in the set 40 of them.

The FIG. 4 M/H Frame encoder 13 further includes a dual-port random-access memory 42 connected to provide buffer memory for the Ensembles of M/H Service Multiplex data supplied as input signals to an input de-multiplexer 43 for distribution to the set 40 of R-S Frame encoders. The RAM 42 has the temporary storage capability to store the Ensembles of M/H Service Multiplex data for a number P at least one of successive M/H Frames. Ensembles of M/H Service Multiplex data are applied to the random-access port of the RAM 42 and are written into temporary storage locations therein in accord with write address and write enable signals generated within the controller 41 and supplied to the RAM 42. Read-out clocking signal is generated within the controller 41 and is supplied to the RAM 42 for clocking the read-out of successive Ensembles of M/H Service Multiplex data. These successive Ensembles of M/H Service Multiplex data are read to respective ones of the set 40 of R-S Frame encoders as selected by the input de-multiplexer 43 under the direction of the controller 41. A (partial) read addressing signal is generated within the controller 41 and is supplied to the RAM 42 for selecting the temporarily stored Ensembles of M/H Service Multiplex data to be clocked out through the RAM 42 serial output port to the input port of the input de-multiplexer 43. The RAM 42 allows the Ensembles of M/H Service Multiplex data temporarily stored therewithin to be read via its serial port with timing that facilitates the random-access memories within the set 40 of R-S Frame encoders being over-written during reading therefrom.

The Ensembles of M/H Service Multiplex data that are read from the serial output port of the RAM 42 are applied as input signals to the input de-multiplexer 43. The input de-multiplexer 43 is further connected for distributing those M/H Ensembles to the set 40 of R-S Frame encoders as their respective input signals. This distribution is controlled by respective control signals that the controller 41 generates and supplies to the input de-multiplexer 43. An output multiplexer 44 for RS Sub-Frames is connected for time-division multiplexing Sub-Frame responses from the set 40 of RS Frame encoders for application to the block processor 14. This time-division multiplexing is controlled by respective control signals that the controller 41 generates and supplies to the output multiplexer 44.

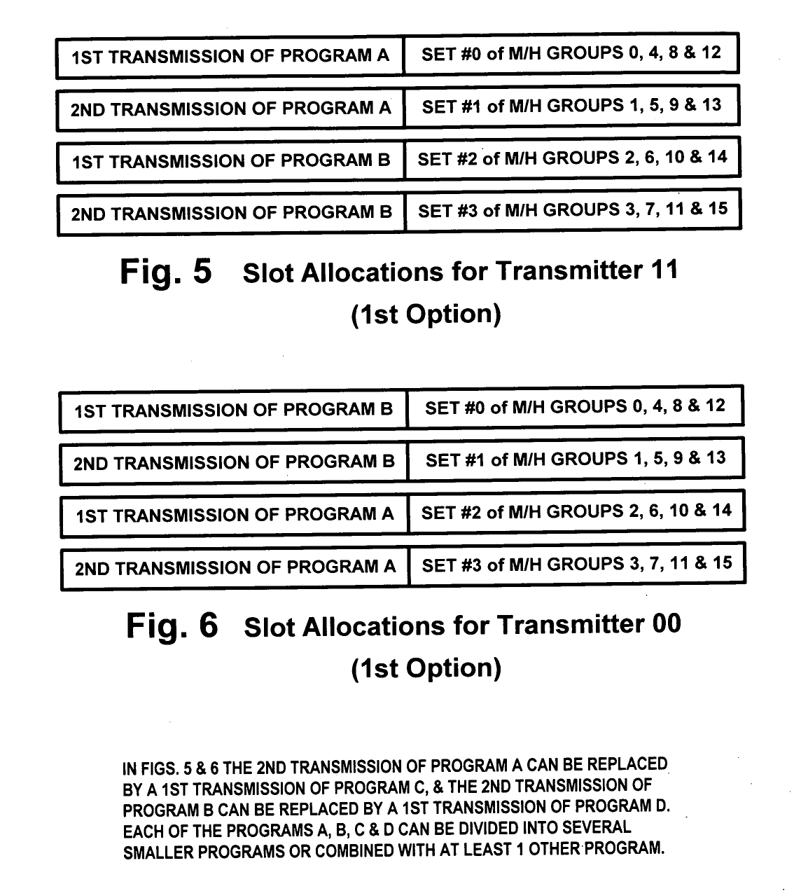

The operations of the M/H Frame encoder 13 differ somewhat during odd-occurring and even-occurring ones of successive M/H Frames. The controller 41 directs the over-writing of half of the set 40 of R-S Frame encoders and the reading of the other half of the set 40 of R-S Frame encoders during each odd-occurring M/H Frame. During each even-occurring M/H Frame, the controller 41 directs the reading of the half of the set 40 of R-S Frame encoders over-written during the preceding odd-occurring M/H Frame. During each even-occurring M/H Frame, the controller 41 also directs the over-writing of the half of the set 40 of R-S Frame encoders read from during the preceding odd-occurring M/H Frame. These procedures are carried out so as to avoid the need for the block processor 14 to include memory for implementing the RS Frame portion to SCCC Block converter depicted in FIG. 5.19 of A/153, Part 2, §5.3.2.3. The output multiplexer 44 for reading from the set 40 of R-S Frame encoders is operated to provide RS Frame portion to SCCC Block conversion for the block processor 14. Considering the operation of the output multiplexer 44 more generally, it converts RS Frame portions to concatenated-convolutional-coding (CCC) Blocks, which CCC Blocks may be considered as being either SCCC Blocks or PCCC Blocks depending on the subsequent processing of these CCC Blocks.

The controller 41 is designed to be capable of conducting the writing and reading of the RAM 42 so as to support iterative-diversity transmissions when the RAM 42 is capable of storing the Ensembles of M/H Service Multiplex for several M/H Frames. That is, when the number P of stored M/H Frames of data has a value of ten or so. Each Ensemble of M/H Service Multiplex data is read a first time from the RAM 42 to a respective one of the set 40 of R-S Frame encoders to be processed for its first transmissionn earlier in time than a second transmission of that same Ensemble. Each Ensemble of M/H Service Multiplex data is subsequently read a second time from the RAM 42 to a respective one of the set 40 of R-S Frame encoders to be processed for its second transmission later in time than the first transmission of that same Ensemble. These first and second transmissions could be separated by as many as P M/H Frames, but will be separated by only (P−1) M/H Frames in some designs.

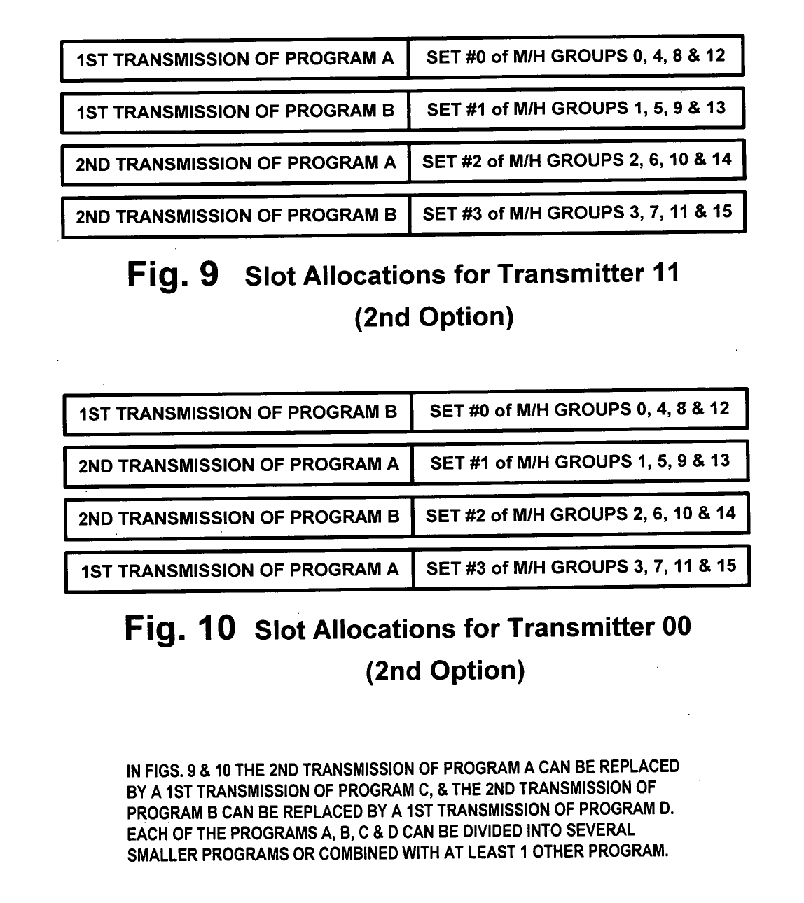

FIGS. 5, 6, 7 and 8 are tables showing a preferred option for allocating Slots to different transmitters that have overlapping coverage, for facilitating frequency-diversity reception. FIGS. 9, 10, 11 and 12 are tables showing an alternative option for allocating Slots to different transmitters that have overlapping coverage. Each M/H sub-Frame includes four sets of Slots that are separated by intervening sequences of three Slots. Transmitters that have overlapping coverage areas transmit similar program material in different ones of these sets of Slots so that an M/H receiver located in an overlapping coverage area can receive the similar program material twice, as time-division multiplexed between two of these sets of Slots. The time-division multiplexing accommodates an M/H receiver with just a single front-end tuner of a frequency-agile type that can rapidly switch tuning between the different carrier frequencies of two 8-VSB transmitters.

A second transmission of Program A information repeats a first transmission of Program A information in an earlier M/H Frame when Program A information is transmitted twice to implement interative-diversity reception. A second transmission of Program A information repeats the first transmission of Program A information within the same or next M/H sub-Frame when Program A information is transmitted twice principally to implement decoding the outer convolutional coding of the M/H CCC at one-quarter the 8-VSB symbol rate. A first transmission of Program C replaces the second transmission of Program A information if the Program A information is transmitted only one time. While each of the FIGS. 5-12 shows the Program A information being transmitted in four M/H Groups, the Program A information can be divided into smaller individual programs transmitted in all or just some of the four M/H Groups.

A second transmission of Program B information repeats a first transmission of Program B information in an earlier M/H Frame when Program B information is transmitted twice to implement interative-diversity reception. A second transmission of Program B information repeats the first transmission of Program B information within the same or next M/H sub-Frame when Program B information is transmitted twice principally to implement decoding the outer convolutional coding of the M/H CCC at one-quarter the 8-VSB symbol rate. A first transmission of Program D information replaces the second transmission of Program B information if the Program B information is transmitted only one time. While each of the FIGS. 5-12 shows the Program B information being transmitted in four M/H Groups, the Program B information can be divided into smaller individual programs transmitted in all or just some of the four M/H Groups.

The FIG. 5 table shows how Slots for diversity transmissions are allocated for a 8-VSB transmitter with a ‘11’ binary identification number. The set of Slots #0, #4, #8 and #12 is used for a first transmission of Program A information. The set of Slots #1, #5, #9 and #13 is used for a second transmission of Program A information, presuming it to be transmitted twice. The set of Slots #1, #5, #9 and #13 is used for a single transmission of Program C information, however, if Program A information is transmitted only once. The set of Slots #2, #6, #10 and #14 is used for a first transmission of Program B information. The set of Slots #3, #7, #11 and #15 is used for a second transmission of Program B information, presuming it to be transmitted twice. The set of Slots #3, #7, #11 and #15 is used for a single transmission of Program D information, however, if Program B information is transmitted only once.

The FIG. 6 table shows how Slots for diversity transmissions are allocated for a 8-VSB transmitter with a ‘00’ binary identification number. The set of Slots #0, #4, #8 and #12 is used for a first transmission of Program B information. The set of Slots #1, #5, #9 and #13 is used for a second transmission of Program B information, presuming it to be transmitted twice. The set of Slots #1, #5, #9 and #13 is used for a single transmission of Program D information, however, if Program B information is transmitted only once. The set of Slots #2, #6, #10 and #14 is used for a first transmission of Program A information. The set of Slots #3, #7, #11 and #15 is used for a second transmission of Program A information, presuming it to be transmitted twice. The set of Slots #3, #7, #11 and #15 is used for a single transmission of Program C information, however, if Program A information is transmitted only once.

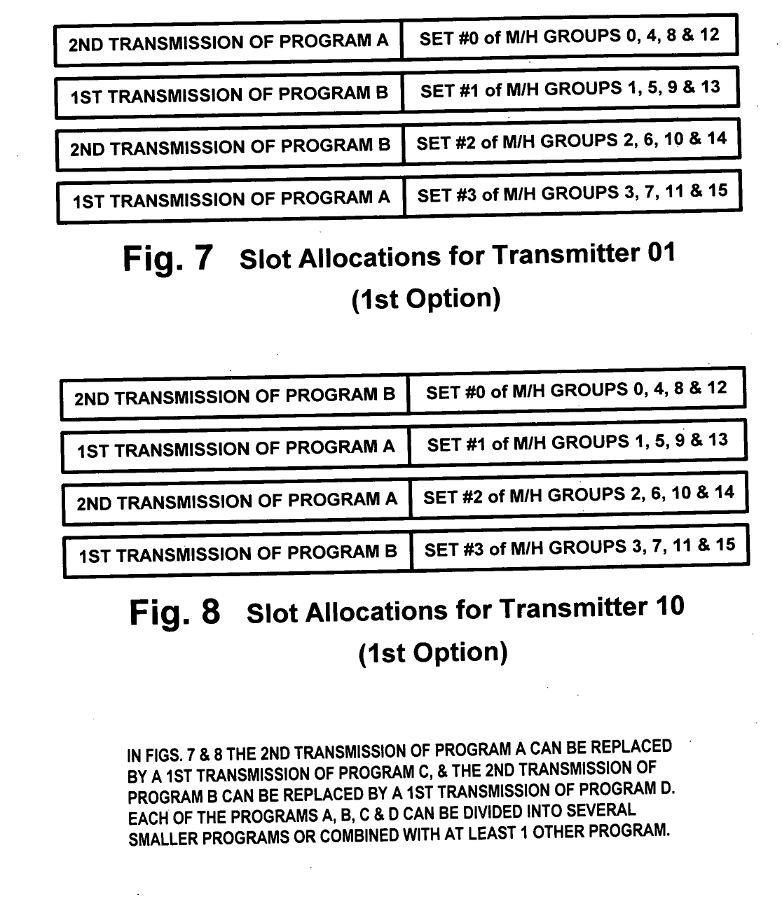

The FIG. 7 table shows how Slots for diversity transmissions are allocated for a 8-VSB transmitter with a ‘01’ binary identification number. The set of Slots #0, #4, #8 and #12 is used for a second transmission of Program A information, presuming it to be transmitted twice. The set of Slots #0, #4, #8 and #12 is used for a single transmission of Program C information, however, if Program A information is transmitted only once. The set of Slots #1, #5, #9 and #13 is used for a first transmission of Program B information. The set of Slots #2, #6, #10 and #14 is used for a second transmission of Program B information, presuming it to be transmitted twice. The set of Slots #2, #6, #10 and #14 is used for a single transmission of Program D information, however, if Program B information is transmitted only once. The set of Slots #3, #7, #11 and #15 is used for a first transmission of Program A information.

The FIG. 8 table shows how Slots for diversity transmissions are allocated for a 8-VSB transmitter with a ‘10’ binary identification number. The set of Slots #0, #4, #8 and #12 is used for a second transmission of Program B information, presuming it to be transmitted twice. The set of Slots #0, #4, #8 and #12 is used for a single transmission of Program D information, however, if Program B information is transmitted only once. The set of Slots #1, #5, #9 and #13 is used for a first transmission of Program A information. The set of Slots #2, #6, #10 and #14 is used for a second transmission of Program A information, presuming it to be transmitted twice. The set of Slots #2, #6, #10 and #14 is used for a single transmission of Program C information, however, if Program A information is transmitted only once. The set of Slots #3, #7, #11 and #15 is used for a first transmission of Program B information.

The FIG. 9 table shows how Slots for diversity transmissions are allocated for a 8-VSB transmitter with a ‘11’ binary identification number. The set of Slots #0, #4, #8 and #12 is used for a first transmission of Program A information. The set of Slots #1, #5, #9 and #13 is used for a first transmission of Program B information. The set of Slots #2, #6, #10 and #14 is used for a second transmission of Program A information, presuming it to be transmitted twice. The set of Slots #2, #6, #10 and #14 is used for a single transmission of Program C information, however, if Program A information is transmitted only once. The set of Slots #3, #7, #11 and #15 is used for a second transmission of Program B information, presuming it to be transmitted twice. The set of Slots #3, #7, #11 and #15 is used for a single transmission of Program D information, however, if Program B information is transmitted only once.

The FIG. 10 table shows how Slots for diversity transmissions are allocated for a 8-VSB transmitter with a ‘00’ binary identification number. The set of Slots #0, #4, #8 and #12 is used for a first transmission of Program B information. The set of Slots #1, #5, #9 and #13 is used for a first transmission of Program A information. The set of Slots #2, #6, #10 and #14 is used for a second transmission of Program B information, presuming it to be transmitted twice. The set of Slots #2, #6, #10 and #14 is used for a single transmission of Program D information, however, if Program B information is transmitted only once. The set of Slots #3, #7, #11 and #15 is used for a second transmission of Program A information, presuming it to be transmitted twice. The set of Slots #3, #7, #11 and #15 is used for a single transmission of Program C information, however, if Program A information is transmitted only once.

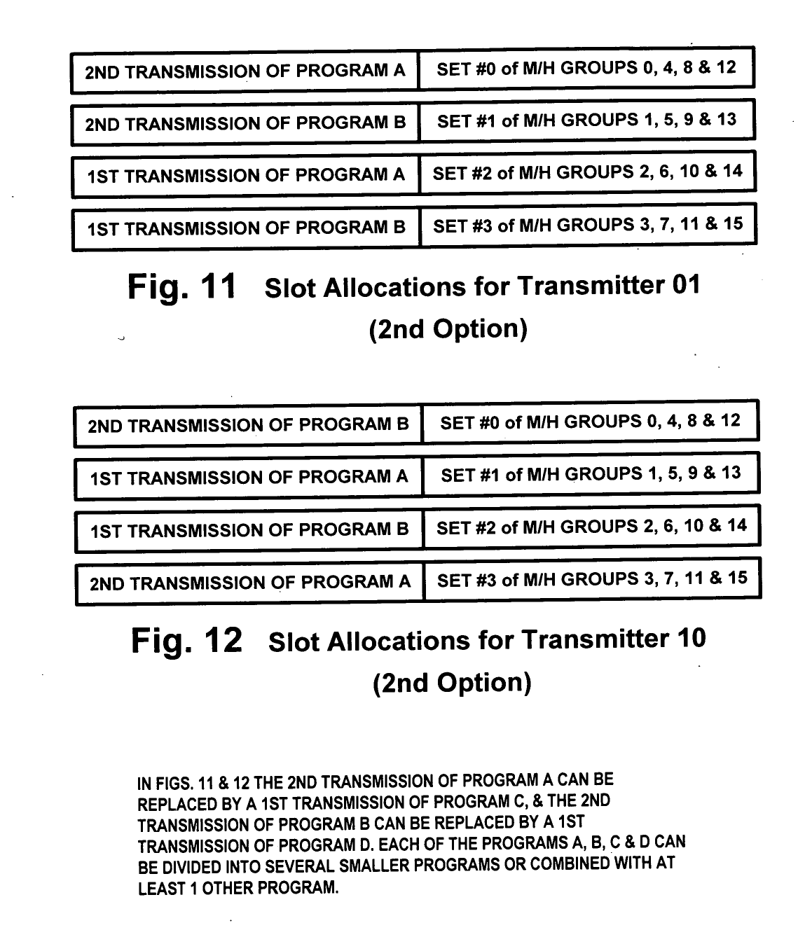

The FIG. 11 table shows how Slots for diversity transmissions are allocated for a 8-VSB transmitter with a ‘01’ binary identification number. The set of Slots #0, #4, #8 and #12 is used for a second transmission of Program A information, presuming it to be transmitted twice. The set of Slots #0, #4, #8 and #12 is used for a single transmission of Program C information, however, if Program A information is transmitted only once. The set of Slots #1, #5, #9 and #13 is used for a second transmission of Program B information, presuming it to be transmitted twice. The set of Slots #1, #5, #9 and #13 is used for a single transmission of Program D information, however, if Program B is transmitted only once. The set of Slots #2, #6, #10 and #14 is used for a first transmission of Program A information. The set of Slots #3, #7, #11 and #15 is used for a first transmission of Program B information.

The FIG. 12 table shows how Slots for diversity transmissions are allocated for a 8-VSB transmitter with a ‘10’ binary identification number. The set of Slots #0, #4, #8 and #12 is used for a second transmission of Program B information, presuming it to be transmitted twice. The set of Slots #0, #4, #8 and #12 is used for a single transmission of Program D information, however, if Program B information is transmitted only once. The set of Slots #1, #5, #9 and #13 is used for a first transmission of Program A information. The set of Slots #2, #6, #10 and #14 is used for a first transmission of Program B information. The set of Slots #3, #7, #11 and #15 is used for a second transmission of Program A information, presuming it to be transmitted twice. The set of Slots #3, #7, #11 and #15 is used for a single transmission of Program C information, however, if Program A information is transmitted only once.

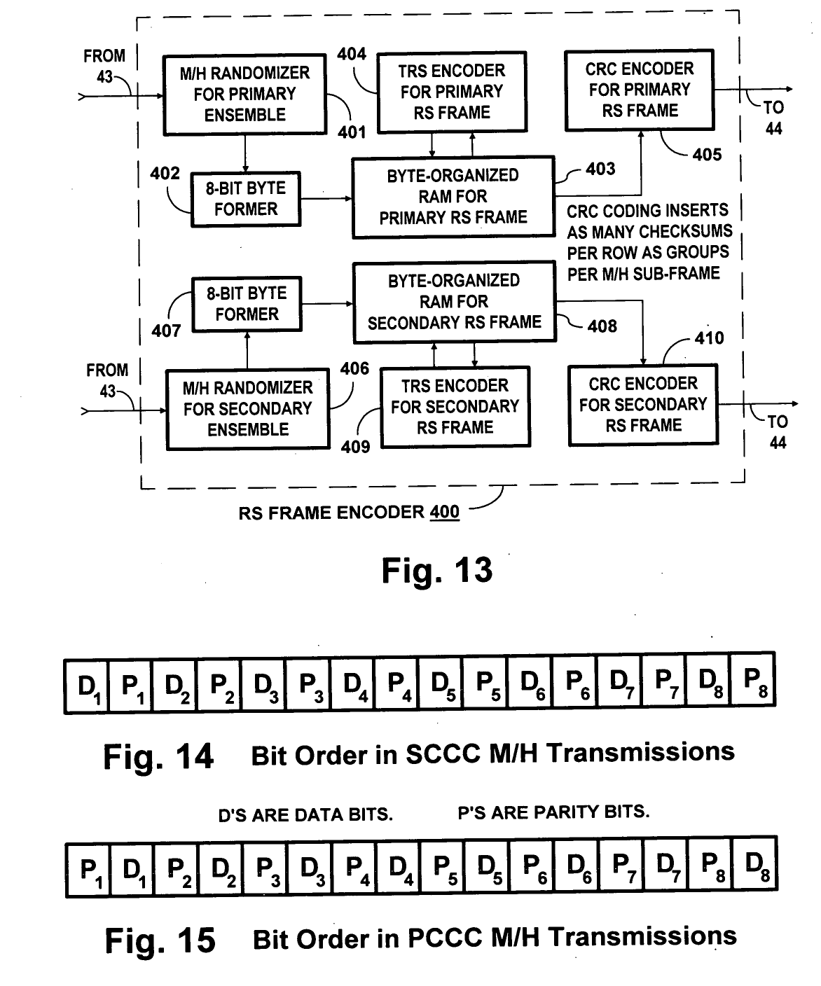

FIG. 13 shows in more detail the structure of a representative R-S Frame encoder 400 included in the set 40 of R-S Frame encoders. An M/H data randomizer 401 is connected for receiving as input signal thereto a primary Ensemble from the input multiplexer 43 of the M/H Frame encoder 13. The M/H data randomizer 401 is further connected for supplying its response to an 8-bit byte former 402, which forms 8-bit bytes of randomized M/H data to be written into rows of byte-storage locations in a byte-organized random-access memory 403. Thereafter, the byte-storage locations in the RAM 403 are read one partial column at a time to an encoder 404 for transverse Reed-Solomon coding, which generates parity bytes to write the remaining byte-storage locations in the column. This completes the primary RS frame stored within the RAM 403 and successive rows of its byte-storage locations are subsequently read to provide input signal for a cyclic-redundancy-check encoder 405. The response of the CRC encoder 405 reproduces the successive bytes read from the RAM 403, breaking up the succession of bytes into shorter sequences of a prescribed number of bytes, and appending a respective 2-byte checksum to each shorter sequence of a prescribed number of bytes. The response of the CRC encoder 405 is supplied to the output multiplexer 44 of the M/H Frame encoder 13.

An M/H data randomizer 406 is connected for receiving as input signal thereto a secondary Ensemble from the input multiplexer 43 of the M/H Frame encoder 13. The M/H data randomizer 406 is further connected for supplying its response to an 8-bit byte former 407, which forms 8-bit bytes of randomized M/H data to be written into rows of byte-storage locations in a byte-organized random-access memory 408. Thereafter, the byte-storage locations in the RAM 408 are read one partial column at a time to an encoder 409 for transverse Reed-Solomon coding which generates parity bytes to write the remaining byte-storage locations in the column. This completes the secondary RS frame stored within the RAM 408 and successive rows of its byte-storage locations are subsequently read to provide input signal for a cyclic-redundancy-check encoder 410. The response of the CRC encoder 410 reproduces the successive bytes read from the RAM 408, breaking up the succession of bytes into shorter sequences of a prescribed number of bytes, and appending a respective 2-byte checksum to each shorter sequence of a prescribed number of bytes. The response of the CRC encoder 410 is supplied to the output multiplexer 44 of the M/H Frame encoder 13.

A respective 2-byte CRC checksum would be inserted after each row of bytes in the primary RS Frame read from the RAM 402 if the M/H transmission complied with the prescription of A/153. A respective 2-byte CRC checksum would be inserted after each row of bytes in the secondary RS Frame read from the RAM 407 if the M/H transmission complied with the prescription of A/153. A fundamental question is whether this periodicity of CRC checksum is frequent enough to supply enough multiple external code error checks to lower the error floor for PCCC using methodology similar to that described in published U.S. Pat. App. No. 2001-0025358. If 230-byte-long transversal R-S codewords are used, there will be 230 rows of bytes in each RS Frame, 230/5=46 rows per each of the five M/H sub-Frames. The 46 CRC checksums at the ends of rows will be split up among the number of Groups (NoG) in the M/H sub-Frame, which can be as large as eight. If the outer convolutional code halves the code rate, there are 9660 CCC payload bytes per M/H Group. When there is only one M/H Group per subFrame, the 9660 CCC payload bytes can be apportioned among 46 CRC codewords each 210 bytes long. There are 77,280 bytes in eight M/H Groups, which divided by 46 means CRC codewords as defined in A/153 could consist of as many as 1680 bytes, however.

Even if CRC checksums at the ends of rows of bytes in the RS Frames are frequent enough to be effective to lower the error floor for PCCC, there is the additional problem of whether those CRC checksums are timed so that they are reasonably convenient to utilize in turbo decoding procedures performed on a Group-by-Group basis. If the number of columns in an RS Frame is a multiple M of NoG, appending a 2-bit CRC checksum to each of the M aliquot portions of the rows will apportion the CRC checksums evenly among the Groups. The CRC codewords will be the same length no matter what the NoG is. By way of example, suppose that each RS Frame had 2-byte CRC checksums for every 210 bytes of half-rate outer convolutional coding. The checksum bytes reduce available payload by a factor of 210/208=1.0096. The percentage cost in available payload would be (210−208)/210=0.95%.

Using transversal R-S codewords that do not contain a multiple of five bytes in them tends to cause problems with CRC codewords beginning in one M/H sub-Frame and concluding in the next M/H sub-Frame. This can be accommodated using special procedures, but introduces undue complication into the system.

FIG. 13 includes a legend to indicate that the CRC coding in the CRC encoder 404 inserts into each row of bytes read from the RAM 402 for the primary RS Frame a respective checksum for each Group per M/H sub-Frame. The same legend is included to indicate further that the CRC coding in the CRC encoder 409 inserts into each row of bytes read from the RAM 407 for the secondary RS Frame a respective checksum for each Group per M/H sub-Frame. The respective final checksum that the CRC encoder 409 appends to each row of bytes of the primary RS Frame read from the RAM 402 does not necessarily correspond to that prescribed by A/153, one should note. Possibly, the respective final checksum that the CRC encoder 404 appends to each row of bytes will relate to only a concluding “sub-row” aliquot portion of that row of bytes, rather than the entire row of bytes. The respective final checksum that the CRC encoder 409 appends to each row of bytes of the secondary RS Frame read from the RAM 407 does not necessarily correspond to that prescribed by the candidate M/H Standard 1.0 either. Possibly, the respective final checksum that the CRC encoder 409 appends to each row of bytes will relate to only a concluding “sub-row” aliquot portion of that row of bytes, rather than the entire row of bytes.

FIG. 14 shows the bit order in SCCC generated responsive to a byte of data composed of successive bits D₁, D₂, D₃, D₄, D₅, D₆, D₇ and D₈ of data. The parity bits P₁, P₂, P₃, P₄, P₅, P₆, P₇ and P₈ succeed respective ones of the data bits D₁, D₂, D₃, D₄, D₅, D₆, D₇ and D₈ in the 2-bit symbols generated by the block processor 14 and ultimately supplied to the modified trellis encoder 32.

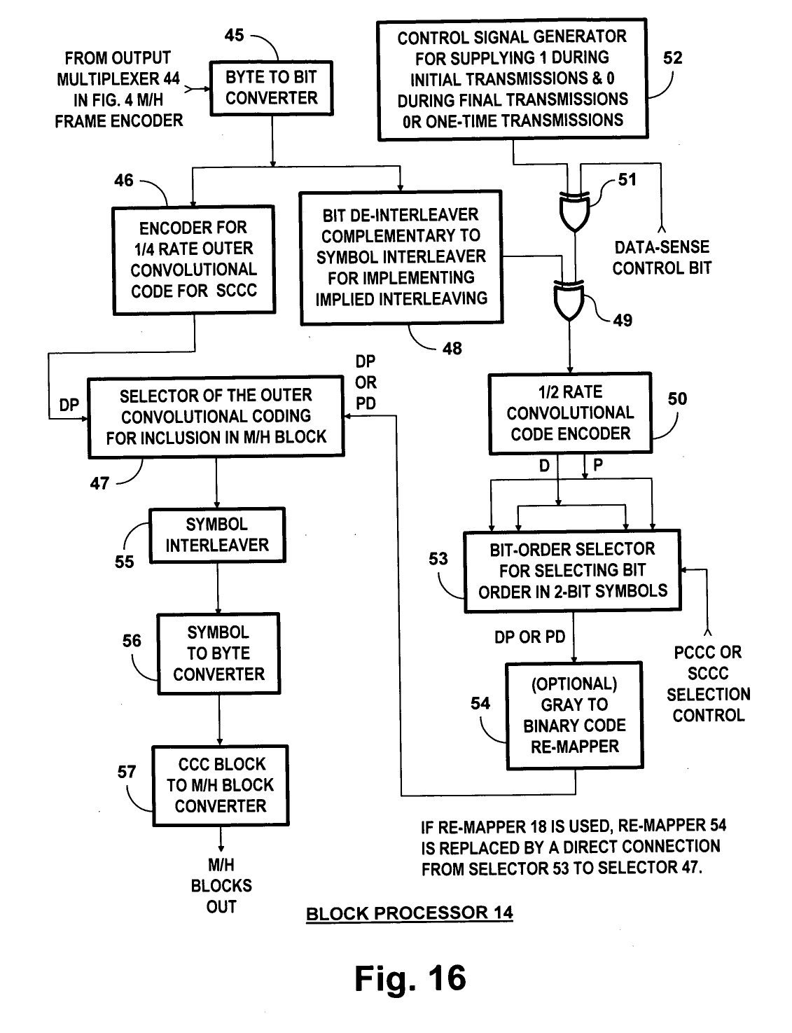

FIG. 15 shows the bit order in PCCC generated responsive to a byte of data composed of successive bits D₁, D₂, D₃, D₄, D₅, D₆, D₇ and D₈ of data. The parity bits P₁, P₂, P₃, P₄, P₅, P₆, P₇ and P₈ precede respective ones of the data bits D₁, D₂, D₃, D₄, D₅, D₆, D₇ and D₈ in the 2-bit symbols generated by the block processor 14 and ultimately supplied to the modified trellis encoder 32.

FIG. 16 is a detailed schematic diagram of the novel block processor 14 in the FIG. 1 DTV transmitter apparatus. As noted supra the output multiplexer 44 in the FIG. 4 M/H Frame encoder 13 is operated to convert RS Frame Portions to CCC Blocks of TRS-CRC-coded M/H Service data supplied to the block processor 14. Either single M/H Blocks or pairs of M/H Blocks are converted into respective CCC Blocks of TRS-CRC-coded M/H Service data that are supplied to a byte-to-bit converter 45 in the block processor 14.

An encoder 46 1/4 rate outer convolutional coding of SCCC per A/153 is connected for receiving TRS-CRC-coded M/H Service data in serial-bit form from the byte-to-bit converter 45. The encoder 46 generates 2-bit symbols, each with the data bit before the parity bit as FIG. 14 depicts. The encoder 46 is connected to supply these 2-bit symbols as a first of two input signals applied to a selector 47 of the outer convolutional coding for inclusion in each M/H Block.

The byte-to-bit converter 45 is connected for supplying its bitstream response to a prefatory data-bit de-interleaver 48 to be de-interleaved in accordance with a pattern complementary to that employed for 2-bit symbols in a symbol interleaver used in later processing. This is done to implement implied interleaving of outer convolutional coding supplied as a second of the two input signals applied to the selector 47 of the outer convolutional coding for inclusion in each M/H Block. An exclusive-OR gate 49 is connected for supplying its response to an encoder 50 for one-half-rate convolutional coding. One input port of the exclusive-OR gate 49 is connected for receiving for receiving the de-interleaved TRS-CRC-coded M/H Service data that the bit de-interleaver 48 generates as its response. The other input port of the exclusive-OR gate 49 is connected for receiving a control signal from a control signal generator 51. The control signal generator 51 generates a logic ONE control signal when the de-interleaved TRS-CRC-coded M/H Service data is to be transmitted an initial time as part of an iterative-diversity transmission. This ONE conditions the exclusive-OR gate 49 to ones' complement the de-interleaver 48 response in its own response that is applied as input signal to the encoder 50, which responds generating an initial set of parity bits for the iterative-diversity transmission. The control signal generator 51 generates a logic ZERO control signal when the de-interleaver 48 response is to be used to determine the final part of an iterative-diversity transmission. This ZERO conditions the exclusive-OR gate 49 to reproduce the de-interleaver 48 response in its own response that is applied as input signal to the encoder 50, which responds generating a final set of parity bits for the iterative-diversity transmission. This final set of parity bits differs from the initial set of parity bits for the iterative-diversity transmission. The control signal generator 51 also generates a logic ZERO control signal when the de-interleaver 48 response is used to define a single transmission of CCC at one-half the 2/3 code-rate of ordinary 8-VSB signals as originally specified by A/53.

If there are portions of the response of the de-interleaver 48 response that are only sparsely populated by ONEs, the convolutional coding generated by the encoder 50 will also be sparsely populated by ONEs and consequently will be less powerful. A desirable feature of a parallel concatenated convolutional code is for its additional set of parity bits to be densely populated by ONEs where the original set of parity bits is sparsely populated by ONEs. If there are portions of the de-interleaver 48 response that are only sparsely populated by ONEs, the ones' complemented de-interleaver 48 response will be densely populated by ONEs. The additional set of parity bits that the encoder 50 generates in response to this denser population of ONEs will tend to be less under-populated by ONEs than the set generated in response to the non-complemented response of the bit de-interleaver 48.

The encoder 50 generates 2-bit symbols, each consisting of one data bit and one accompanying parity bit. The 2-bit symbols generated by the encoder 50 are supplied to a bit-order selector 52 controlled by a PCCC OR SCCC SELECTION CONTROL signal. If PCCC is selected for transmitting the encoder 50 response, the parity bit precedes the data bit in each 2-bit symbol reproduced by the bit-order selector 52. If SCCC is chosen for transmitting the encoder 50 response, the data bit precedes the parity bit in each 2-bit symbol reproduced by the bit-order selector 52. FIG. 16 shows the bit-order selector 52 connected for applying its response to a Gray-to-binary-code re-mapper 53 used for Gray-code labeling the outer convolutional coding supplied. The response of the Gray-to-binary-code re-mapper 53 is the second of the two input signals applied to the selector 47 of the outer convolutional coding for inclusion in each M/H Block. The Gray-to-binary-code re-mapper 53 is replaced by a direct connection from the bit-order selector 52 to the selector 47 if Gray-to-binary-code re-mapping is instead done by the Gray-to-binary-code re-mapper 18 following the M/H Group formatter 15.

The selector 47 is connected for supplying the 2-bit symbols that it selectively reproduces to a symbol interleaver 54 as input symbols thereto. The symbol interleaver 54 is connected for supplying the output symbols in its symbol-interleaved response to a symbol-to-byte converter 55 for conversion to 8-bit bytes for being written into a byte-organized random-access memory operated an CCCC Block to M/H Block converter 56. M/H Blocks are subsequently read from this RAM to the Group formatter 15 shown in the FIG. 1 general schematic diagram.

The Group formatter 15 in the FIG. 1 DTV transmitter apparatus is operated for placing the initial and final transmissions of data for iterative-diversity reception into different sets of Slots within M/H Sub-Frames. The general principle for delaying the final transmissions from the corresponding initial transmissions is that the delay is always the same, being an integral number of M/H Sub-Frames plus or minus an odd integral number of Slots. This places the initial transmissions in even-numbered Slots and the final transmissions in odd-numbered Slots within M/H Sub-Frames, or vice versa. Slot allocations for facilitating iterative-diversity reception are made first, with leftover Slots then being allocated to other services. Delaying the final transmissions from the corresponding initial transmissions by an integral number of M/H Frames plus or minus one Slot facilitates the iterative-diversity transmissions being confined within a prescribed number of M/H Frames, which simplifies program scheduling. At the time the invention was made this integral number of M/H Frames was preferably ten, which provides for withstanding drop-outs in received signal strength that are almost a second in duration.

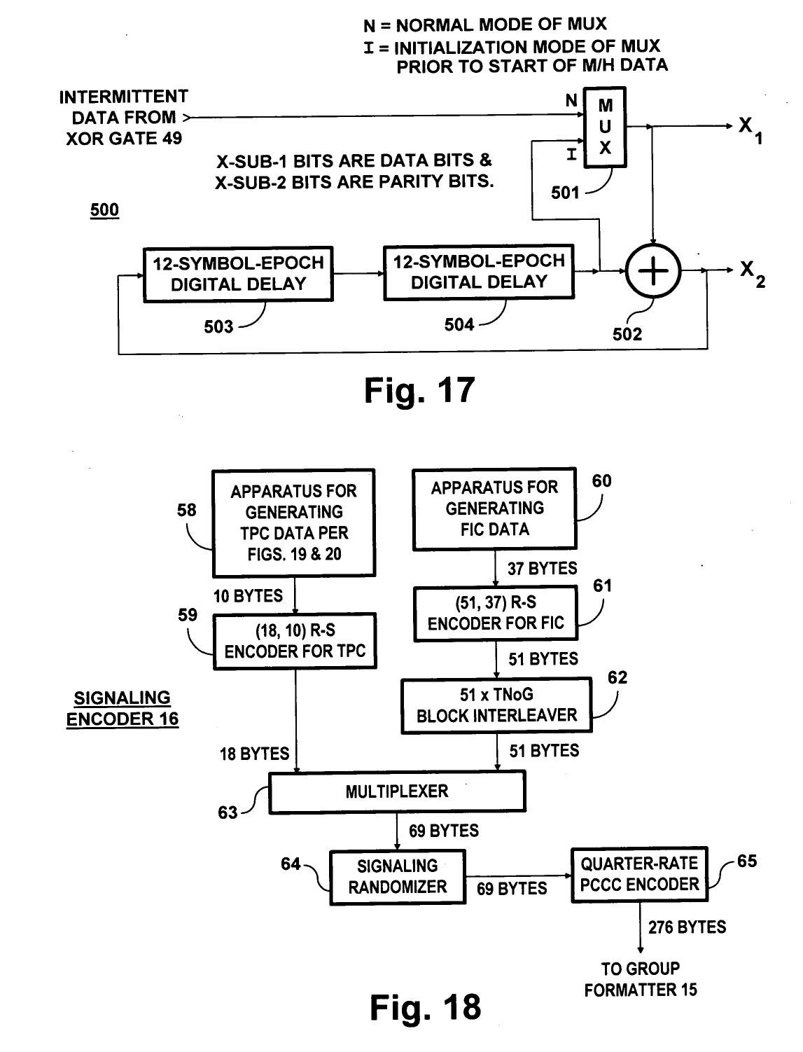

FIG. 17 details a construction of the FIG. 16 encoder 50 for generating half-rate outer convolutional coding for PCCC. The FIG. 17 construction is preferred in that it allows a receiver to utilize the same basic decoder structure for decoding both inner convolutional coding and outer convolutional coding on a staggered-in-time basis. The FIG. 1 DTV transmitter apparatus includes a source of ZEROes 500 clocked at 8-VSB symbol rate to the respective first input ports of time-division multiplexers 501 and 502, each of which has a respective pair of input ports. The second input port of the multiplexer 501 is connected for receiving the X-sub-1 bits of M/H data. The response from the multiplexer 501 is applied as a first summand input signal to a clocked modulo-2 adder 503, which essentially comprises a two-input exclusive-OR gate. The sum output response from the adder 503 is subjected to a 12-symbol-epoch digital-bit delay 504 before its application to the second input port of the multiplexer 502. The response from the multiplexer 502 is subjected to a 12-symbol-epoch digital-bit delay 505 before application of the delay 505 response to the clocked modulo-2 adder 503 as a second summand input signal. FIG. 17 shows the delay 505 response supplying X-sub-2 parity bit responses to successive X-sub-1 M/H data bits.

Usually, the time-division multiplexers 501 and 502 respond to their respective input signals as received at the second ones of their respective input ports. Typically, two 12-stage shift registers, each clocked at 8-VSB symbol rate, provide respective ones of the clocked digital-bit delays 502 and 504. When the M/H coding of a portion of an RS Frame included within an M/H Group concludes, there is a zero-flushing procedure for sweeping out the stored contents of the clocked digital-bit delays 502 and 504. During each such zero-flushing procedure, which lasts for twenty-four 8-VSB symbol epochs, the time-division multiplexers 501 and 502 respond to the clocked ZEROes as received at the first ones of their respective input ports.

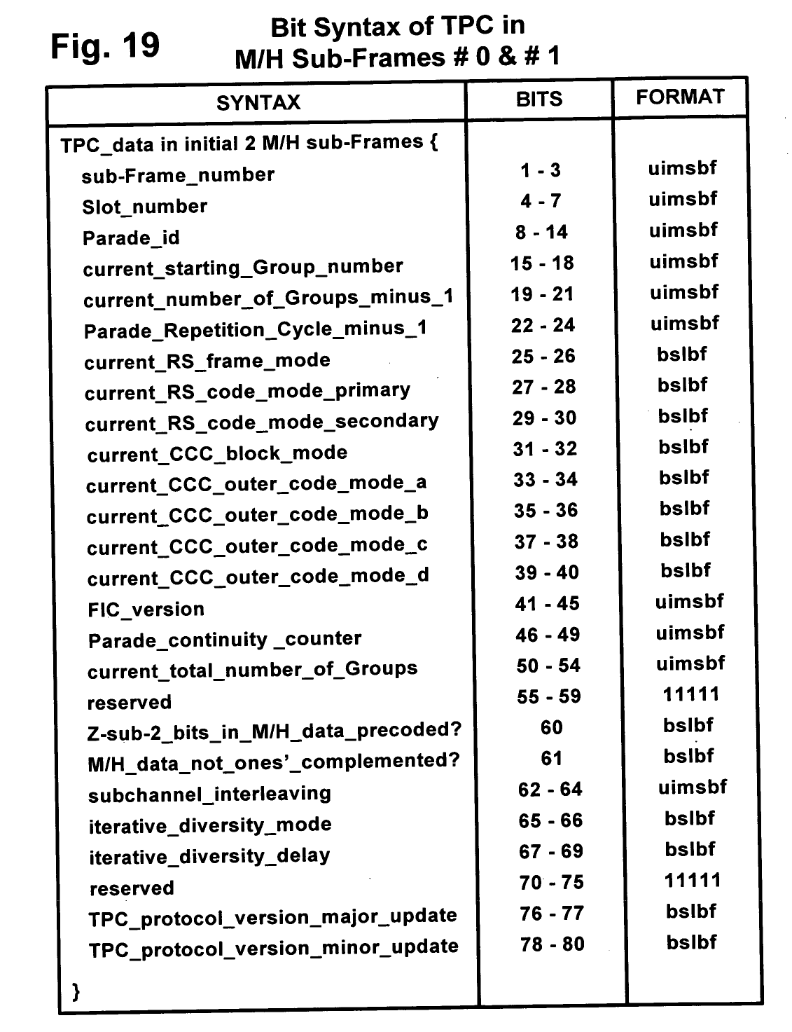

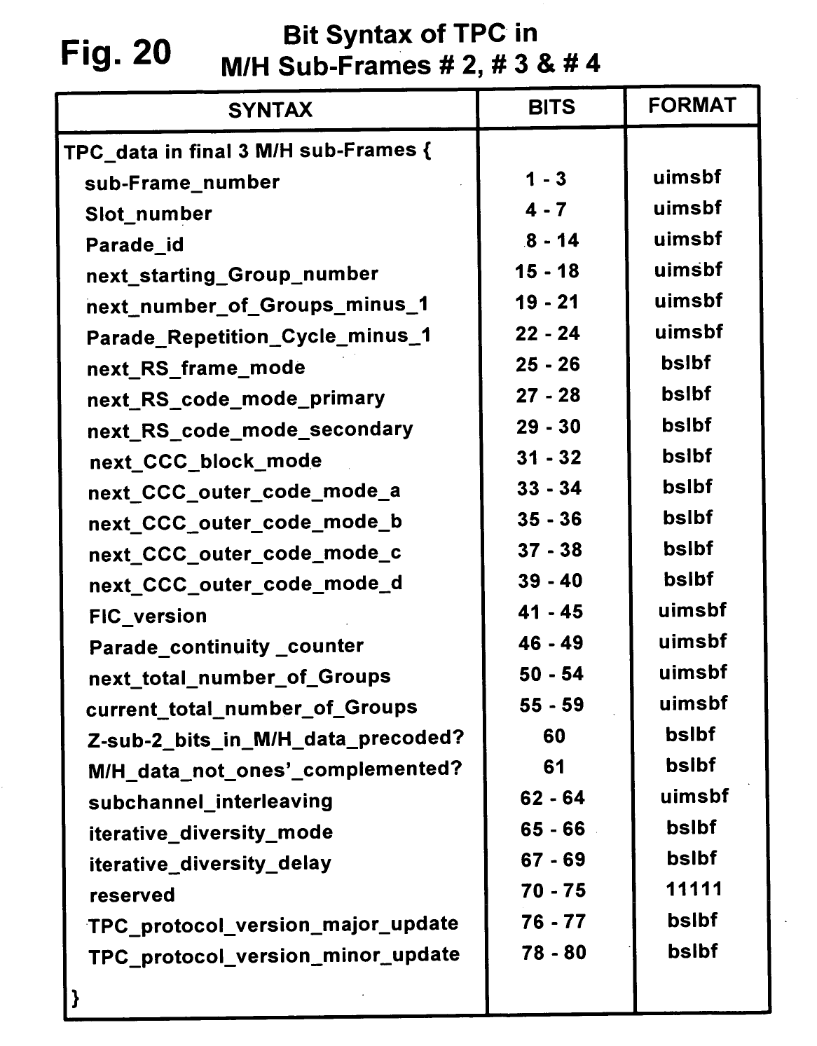

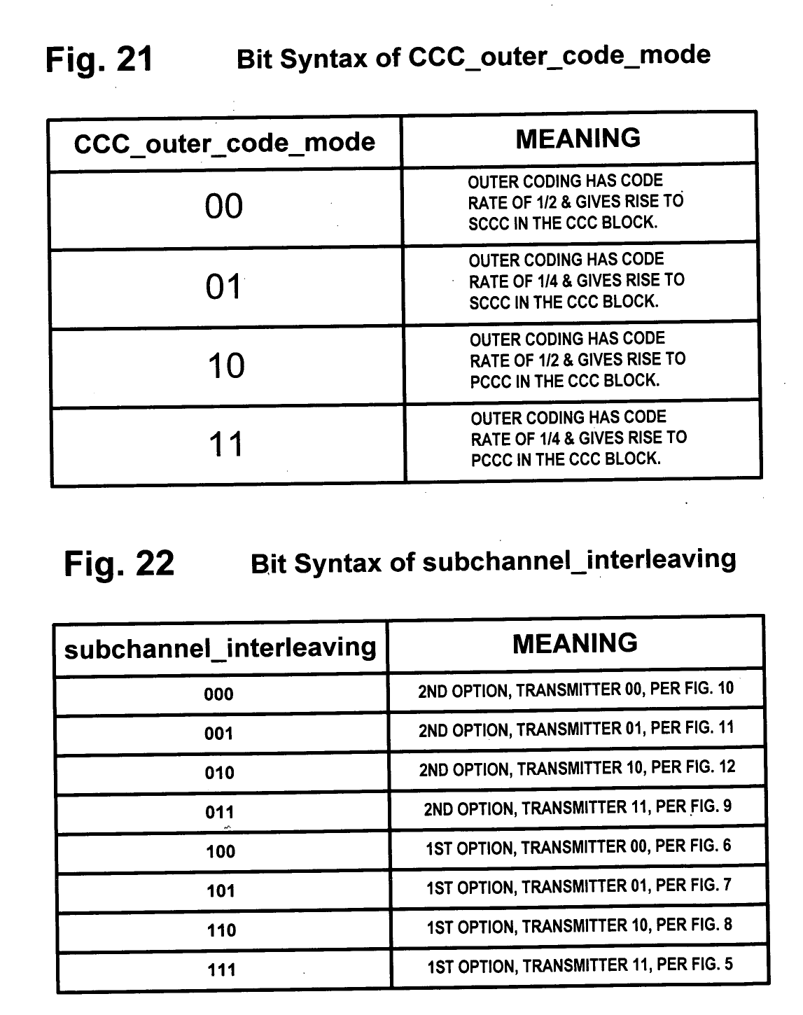

FIG. 18 is a detailed schematic diagram of a representative embodiment of the signaling encoder 16 in the FIG. 1 DTV transmitter apparatus. Apparatus 58 for generating Transmission Parameter Channel (TPC) data using the bit syntax shown in FIGS. 19 and 20 is connected for supplying that TPC data to an encoder 59 for (18, 10) Reed-Solomon coding bytes of that TPC data. Apparatus 60 for generating Fast Information Channel (FIC) data per A/153 is connected for supplying that FIC data to an encoder 61 for (51, 37) Reed-Solomon coding FIC bits. The encoder 61 encodes thirty-seven bits per Group and is connected for supplying the resulting 51 bits of RS-coded FIC to a matrix-type block interleaver 62. A time-division multiplexer 63 is connected for supplying a response that interleaves 51 bytes of block interleaver 62 response as received at a first input port of the multiplexer 63 between each 18-byte RS codeword received from the encoder 59 at a second input of the multiplexer 63. The multiplexer 63 is connected for supplying its response to a signaling randomizer 64. The signaling randomizer 64 is connected for supplying its response as input signal to a quarter-rate PCCC encoder 65, which is in turn connected to supply the quarter-rate PCCC that it generates to the Group formatter 15.

Each of the FIGS. 19 and 20 is a table showing a preferred syntax of bits in the TPC data. The FIG. 19 table specifies the bit syntax for TPC signal transmitted in each M/H Group contained in the initial two sub-Frames #0 and #1 of each M/H Frame. The FIG. 20 table specifies the bit syntax for TPC signal transmitted in each M/H Group contained in the final three sub-Frames #2. #3 and #4 of each M/H Frame. There are eighty bits in the TPC data transmitted with each Group, and in this specification they are referred to by number according to the order of their transmission within the Group. The bits 1-59 and 70-80 of the TPC bit syntax shown in the tables of FIGS. 19 and 20 have syntax similar to that specified in A/153.

In both the FIG. 19 and FIG. 20 tables the bits 1-3 specifying sub_Frame_number the bits 4-7 specifying Slot_number and the bits 8-14 specifying the Parade_ID always apply to the M/H Group being currently received, as well as to the corresponding M/H Group in the next M/H Frame in the Parade repetition cycle (PRC). The Parade_repetition_cycle_minus_one number appearing in bits 22-24 of the TPC bit syntax ranges from zero to seven. It applies to the M/H Group being currently received and signals the number of M/H Frames skipped over from one M/H Frame containing parts of a Parade to the next Frame containing parts of the Parade. The bits 41-45 specify FIC version as a modulo-32 number. This number is usually the same as that for the corresponding M/H Group in the previous M/H Frame. However, it increments by one when an FIC-Chunk in the current M/H Frame that describes the next M/H Frame differs from a previous FIC-Chunk of like FIC_chunk_major_protocol_version that described the current M/H Frame. The bits 46-49 specify Parade_continuity_counter count as a modulo-16 number that increments by one every M/H Frame in the Parade Repetition Cycle. (Specification of a count of zero or of one, rather than an expected consecutive count, can be used to signal the beginning of a new Parade.)

The last five bits of the TPC data signal the version of TPC data syntax that is being used. Bits 76 and 77 signal major changes in the TPC data used in the M/H Standard. These major changes cause the TPC data to be indecipherable to receivers designed for receiving transmissions made in accordance with earlier versions of the M/H Standard. Bits 78, 79 and 80 signal minor changes in the TPC data used in the M/H Standard. These minor changes leave parts of the TPC data decipherable to receivers designed for receiving transmissions made in accordance with earlier versions of the M/H Standard. In A/153 all the bits 78, 79 and 80 in TPC are ONEs, and each of them shall be rolled to ZERO when the first change in TPC version is adopted by ATSC. In A/153 the bits 76 and 77 in TPC are both ONEs, and each of them shall be rolled to ZERO when the initial major change in TPC version is adopted by ATSC.

In the FIG. 19 TPC syntax table, bits 15-18 specify the current_starting_Group_number, bits 19-21 specify the current_number_of_Groups_minus_one, bits 25-40 describe forward-error-correction (FEC) coding for the M/H Frame that is currently received, and bits 50-54 specify the current_total_number_of_Groups. The current_starting_Group_number is the Slot number of the initial M/H Group beginning or resuming the Parade identified by bits 8-14 in each sub-Frame of the M/H Frame that is currently received. The current_number_of_Groups_minus_one is one less than the number of M/H Groups assigned to the Parade identified by bits 8-14 in each sub-Frame of the M/H Frame that is currently received. The current_total_number_of_Groups specifies the total number of M/H Groups in each sub-Frame of the M/H Frame that is currently received. The bits 55-59 are reserved.

In the FIG. 20 TPC syntax table bits 15-18 specify the next_starting_Group_number, bits 19-21 specify the next_number_of_Groups_minus_one, and bits 25-40 describe FEC coding for the M/H Frame to be received next. The bits 55-59 specify the current_starting_Group_number. The next_starting_Group_number is the Slot number of the initial M/H Group beginning or resuming the Parade identified by bits 8-14 in each sub-Frame of the M/H Frame that will be received next. The next_number_of_Groups_minus_one is one less than the number of M/H Groups assigned to the Parade identified by bits 8-14 in each sub-Frame of the M/H Frame that will be received next. The bits 55-59 in the FIG. 20 table specify the next_total_number of_Groups. That is, the total number of M/H Groups in each sub-Frame of the M/H Frame that will be received next after the M/H Frame being currently received.

In the TPC syntax tables of FIGS. 19 and 20 the bits 15-18 specifying a starting Group number and the bits 25-40 prescribing forward-error-correction coding constitute “normally continuing” TPC information. This “normally continuing” TPC information not only stays the same for each Slot of the same number in the sub-Frames of one M/H Frame, but also usually is the same for each Slot of the same number in the sub-Frames of the next M/H Frame in the PRC. The specification of CCC coding conditions in bits 31-40 of the FIG. 19 and FIG. 20 tables encompass PCCC coding conditions, as well as the SCCC coding conditions specified in A/153. A/153 specifies the TPC bits 60-75 as being reserved, but the tables in FIGS. 19 and 20 show only bits 70-75 of this sequence of bits as being reserved.

The FIG. 19 TPC syntax table shows bits 25 and 26 specifying current_RS_frame_mode, bits 27 and 28 specifying current_RS_code_mode_primary, and bits 29 and 30 specifying current_RS_code_mode_secondary, which corresponds to the prescription of A/153 for TPC bit syntax in M/H sub-Frames #0 and #1. The FIG. 19 table shows bits 31 and 32 specifying current_CCC_block_mode, bits 33 and 34 specifying current_CCC_outer_code_mode_a, bits 35 and 36 specifying current_CCC_outer_code_mode_b, bits 37 and 38 specifying current_CCC_outer_code_mode_c, and bits 39 and 40 specifying current_CCC_outer_code_mode_d.

The FIG. 20 TPC syntax table shows bits 25 and 26 specifying next_RS_frame_mode, bits 27 and 28 specifying next_RS_code_mode_primary, and bits 29 and 30 specifying next_RS_code_mode_secondary, which corresponds to the prescription of A/153 for TPC bit syntax in M/H sub-Frames #2, #3 and #4. The FIG. 20 table shows bits 31 and 32 specifying next_CCC_block_mode, bits 33 and 34 specifying next_CCC_outer_code_mode_a, bits 35 and 36 specifying next_CCC_outer_code_mode_b, bits 37 and 38 specifying next_CCC_outer_code_mode_c, and bits 39 and 40 specifying next_CCC_outer_code_mode_d.

FIG. 21 is a table showing a preferred syntax of the pair of bits in each of the four CCC_outer_code_mode fields in the TPC signal for an M/H Frame that is either currently received or is next to be received. The FIG. 19 TPC syntax table includes current_CCC_outer_code_mode_a, cu rrent_CCC_outer_code_mode_b, current_CCC_outer_code_mode_c and current_CCC_outer_code_mode_d fields regarding an M/H Frame that is being currently received. The FIG. 20 TPC syntax table includes a next_CCC_outer_code_mode_a, next_CCC_outer_code_mode_b, next_CCC_outer_code_mode_c and next_CCC_outer_code_mode_d fields regarding for an M/H Frame that is next to be received. The bit syntax specified by the FIG. 21 table is applicable all eight of these fields. The values ‘00’ and ‘01’ provide signaling similar to that prescribed by A/153. A value of ‘00’ signals that the outer convolutional coding has a code rate of 1/2 and its bit pairs are coded in the CCC block so as to give rise to SCCC response after 2/3 trellis coding. A value of ‘01’ signals that the outer convolutional coding has a code rate of 1/4 and its bit pairs are coded in the CCC block so as to give rise to SCCC response after 2/3 trellis coding. The values ‘10’ and ‘11’ are reserved in A/153, but FIG. 21 shows these values being used to signal PCCC transmissions. A value of ‘10’ signals that the outer convolutional coding has a code rate of 1/2 and its bit pairs are coded in the CCC block so as to give rise to PCCC response after 2/3 trellis coding. A value of ‘11’ signals that the outer convolutional coding has a code rate of 1/4 and that its bit pairs are coded in the CCC block so as to give rise to PCCC response after 2/3 trellis coding.

In each of the TPC syntax tables of FIGS. 19 and 20 the bit 65 transmits a Z-sub-2_bits_in_M/H_data_precoded? datum. Preferably, the bit 60 is a ZERO indicating that the Z-sub-2 bits in the M/H data are not pre-coded. However, the bit 60 is allowed to be a ONE to signal that the Z-sub-2 bits in the M/H data are pre-coded per A/153, which may be done to accommodate legacy M/H receivers designed only for receiving signals as specified by A/153.

The TPC bit syntax in A/153 does not specify the different ways in which similar program material is broadcast by cooperating DTV transmitters that transmit over different RF channels and have respective coverage areas that partially overlap at least one of the coverage areas of the other DTV transmitters. In each of the TPC syntax tables of FIGS. 19 and 20 the bit 61 transmits an M/H_data_not_one's_complemented? datum. Bit 61 is a ONE if the M/H data bits are not ones' complemented, but is a ZERO if the M/H data bits are ones' complemented. The bits 62-64 specify subchannel_interleaving per the FIG. 22 table.

M/H signals may be transmitted using iterative diversity in which earlier and later transmissions of the same data are designed to be combined during turbo decoding procedures. When such transmissions are received by an M/H receiver capable of combining earlier and later transmissions of the same data during turbo decoding procedures, the M/H receiver needs to know whether the currently received Group belongs to the earlier transmission or to the later transmission. If the currently received Group belongs to the earlier transmission, it is diverted to a digital delay line. The digital delay line is usually implemented as a first-in/first-out memory and delays the earlier transmission so its turbo decoding takes place concurrently with the turbo decoding of the later transmission of the same data. The TPC bit syntax in A/153 does not provide for signaling when broadcast transmissions are made that are specifically designed for iterative-diversity reception.

The FIG. 19 and FIG. 20 TPC syntax tables each show the bits 65 and 66 being used as an iterative_diversity_mode datum. FIG. 23 shows representative bit syntax for the iterative_diversity_mode datum. The iterative_diversity_mode being ‘11’ signals that an M/H Group is one not being iteratively transmitted, which simplifies design of a receiver that can also receive transmissions made in accordance with A/153. The following other values of the iterative_diversity_mode datum signals are suggested by way of example. The iterative_diversity_mode datum being ‘01’ signals that the Group currently being received is an initial one of a pair of iteratively transmitted Groups designed for being combined during turbo decoding procedures. The iterative_diversity_mode datum being ‘10’ signals that the Group currently being received is a final one of a pair of iteratively transmitted Groups designed for their respective data being combined later on in the receiver using procedures that combine transport stream packets. The iterative_diversity_mode datum being ‘00’ signals that the Group currently being received is an intermediate one of a trio of iteratively transmitted Groups.

FIG. 24 is a table showing a preferred syntax of the bits 67-69 specifying iterative_diversity_delay in the FIG. 19 and FIG. 20 TPC bit syntax tables. The iterative_diversity_delay datum specifies the time interval between the initial-component and final-component transmissions of the iterative-diversity broadcast, rounded off to the nearest whole number of M/H Frames. There will be an additional component of differential delay between the initial-component and final-component transmissions of the iterative-diversity broadcast. This additional component of differential delay will be only a fraction of an M/H sub-Frame interval. This additional component of differential delay may add to or subtract from the time interval between the initial-component and final-component transmissions of the iterative-diversity broadcast that the bits 67-69 of the iterative_diversity_delay datum specify. An M/H receiver can determine the specifics of this additional component of differential delay from the bits 62-64 specifying subchannel_interleaving in the FIG. 19 and FIG. 20 TPC bit syntax tables. The iterative_diversity_delay being ‘000’ signals that the delay between the initial-component and final-component transmissions of the iterative-diversity broadcast is less than an M/H sub-Frame interval. This degenerate case is used for CCC transmission at code rate one-quarter the 8-VSB symbol rate when overcoming protracted drop-outs in received signal strength is not of particular concern, but overcoming random noise interference is of particular concern.

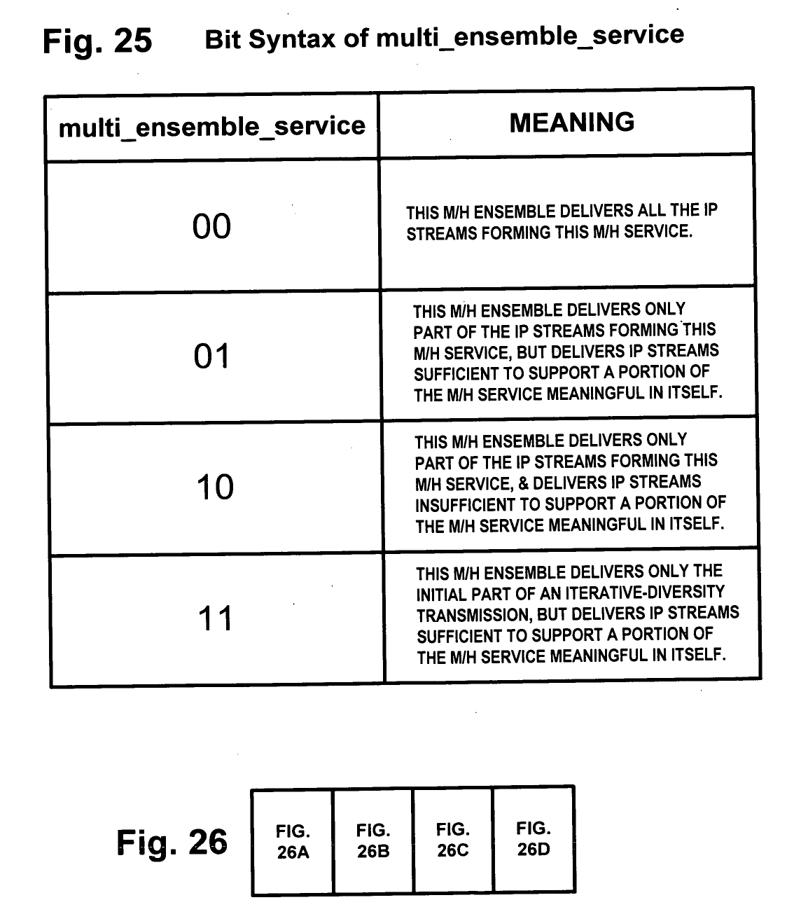

FIG. 25 is a table showing a preferred syntax of the pair of bits in the 2-bit field multi_ensemble_service included in the FIC-Chunk payload. The bit syntax of the FIC-Segment header and the bit syntax of the FIC-Chunk header are assumed to be as prescribed by A/153. The bit syntax of the FIC-Chunk payload is similar to that prescribed by A/153, except for the 2-bit multi_ensemble_service field. A value of ‘00’ signals continues to indicate that this M/H Ensemble delivers all the IP streams forming this M/H Service. A value of ‘01’ continues to indicate that this M/H Ensemble delivers only part of the IP streams forming this M/H Service, but delivers IP streams sufficient to support a portion of this M/H Service that is meaningful in and of itself. The value ‘01’ will be associated with final-component transmission of a complete iterative-diversity transmission. A value of ‘10’ continues to indicate that this M/H Ensemble delivers only part of the IP streams forming this M/H Service, delivering IP streams insufficient to support a portion of this M/H Service that is meaningful in and of itself. A value of ‘11’ indicates that this M/H Ensemble delivers an initial component of a complete iterative-diversity transmission. When applicable, the value of ‘11’ should be used rather than any other value of the multi_ensemble_service field that might also be considered to be applicable.

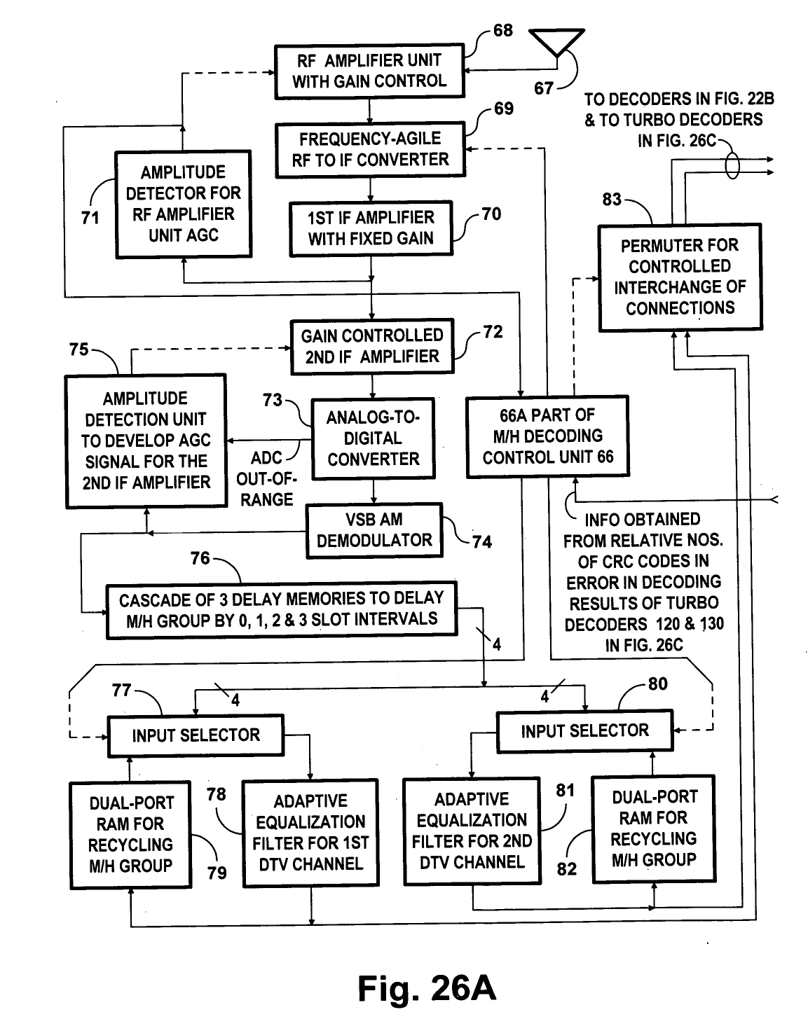

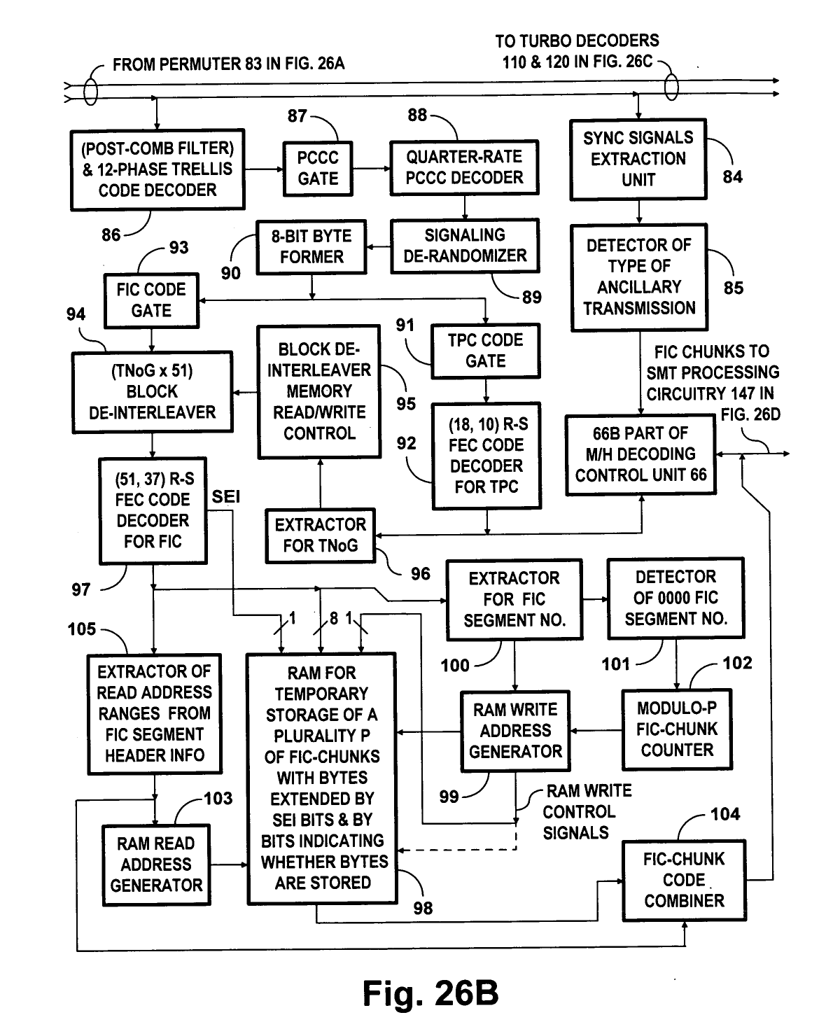

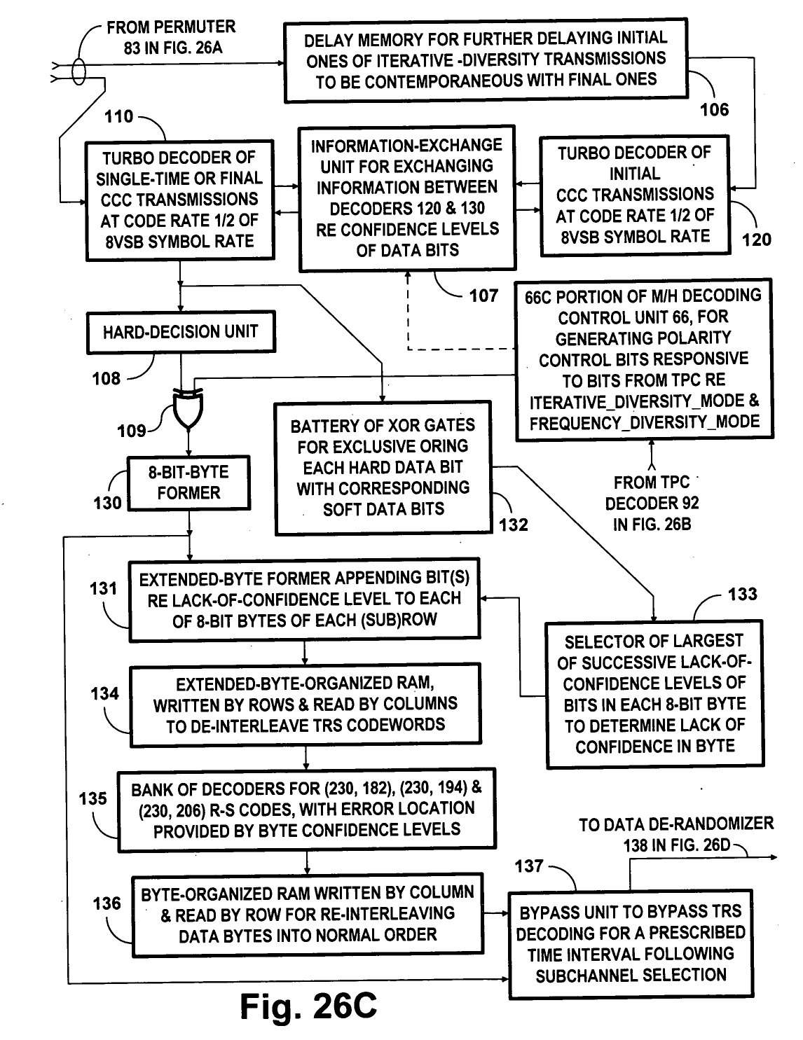

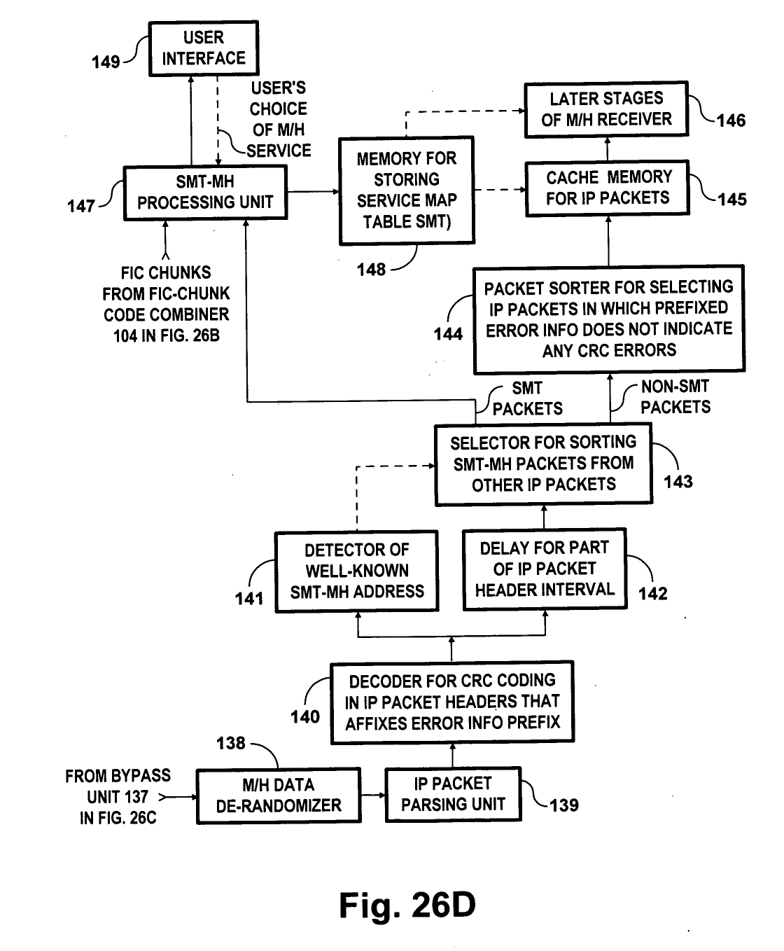

FIG. 26 is an assembly drawing that shows how FIGS. 26A, 26B, 26C and 26D combine to provide a schematic diagram of a DTV receiver apparatus for receiving M/H transmissions broadcast from two DTV transmitters, each of the sort shown in FIG. 1. The two DTV transmitters broadcast similar program material over different radio-frequency (RF) channels, and their coverage areas partially overlap. The FIG. 26 DTV receiver apparatus is designed for having continuing reception of the similar program material as it is moved from the coverage area of one of the two DTV transmitters to the coverage area of the other of the two DTV transmitters. Continuing reception of the similar program material requires that the movement of the FIG. 26 DTV receiver apparatus remain within the coverage area of at least one of the DTV transmitters broadcasting the similar program material. The number of the DTV transmitters broadcasting the similar program material can exceed two, and there may be regions where the coverage areas of more than two of these DTV transmitters overlap. If the FIG. 26 DTV receiver apparatus is moved into such a region, its reception will be primarily directed towards receiving the stronger two of the RF signals available to it. The DTV transmitters that broadcast similar program material and that have overlapping coverage areas are presumed to transmit different subchannel_interleaving numbers as components of their respective TPC signals. One of the several functions of the first part 66A of the M/H decoding control unit 66 is the selection of the radio-frequency (RF) DTV signals to be received. The M/H decoding control unit 66 is connected to respond to the subchannel_interleaving numbers received in the TPC signals of the DTV signals selected for reception.

FIG. 26A shows an antenna 67 for capturing RF DTV signals applied as input signal to an RF amplifier unit 68 with automatic gain control (AGC). The antenna 67 and the RF amplifier unit 68 are capable of capturing and amplifying ultra-high-frequency (UHF) DTV signals. In some embodiments of the FIG. 26 DTV receiver apparatus the antenna 67 and the RF amplifier unit 68 are further capable of capturing and amplifying very-high-frequency (VHF) DTV signals, or at least the higher-frequency VHF DTV signals. The RF amplifier unit 68 is connected for supplying amplified RF DTV signals to a frequency-agile RF-to-IF converter 69 that converts radio-frequency (RF) DTV signals to intermediate-frequency (IF) DTV signals for application to a first intermediate-frequency amplifier 70 as input signal thereto. The first part 66A of the M/H decoding control unit 66 is connected for selecting the beat frequency oscillations that the frequency-agile RF-to-IF converter 69 generates for implementing its RF-to-IF conversion. The first IF amplifier 70 has fixed gain and the amplified RF signal it supplies as output signal is applied as input signal to an amplitude detector 71, which responds to supply gain-control signal to the RF amplifier unit 68, thus completing a loop for its AGC. The gain-control signal developed by the amplitude detector 71 is also supplied to the first part 66A of the M/H decoding control unit 66, which includes circuitry for comparing the gain-control signals developed for RF DTV signals received at different times from different DTV transmitters. The results of this comparison are used to help in deciding when the signal received from a DTV transmitter is no longer of sufficient strength to be turbo decoded usefully.

The output signal from the first IF amplifier 70 is also applied as input signal to a second IF amplifier 72, which is gain-controlled. The second IF amplifier 72 is connected for supplying an amplified IF signal as its output signal. An analog-to-digital converter 73 is connected for digitizing the amplified IF signal supplied by the second IF amplifier 72. The ADC 73 is connected for supplying digitized amplified IF signal to a demodulator 74 for the digitized vestigial-sideband amplitude-modulated IF carrier wave in that digitized amplified IF signal. The demodulator 74 supplies a digital signal descriptive of the baseband DTV signal that modulated the amplitude of the RF carrier wave from a DTV transmitter that was selected for reception by the FIG. 26 receiver apparatus. An amplitude detection unit 75 is used to develop automatic-gain-control (AGC) signal supplied to the second IF amplifier 72 for controlling the gain thereof. FIG. 26A shows the amplitude detection unit 75 developing AGC signal partly in response to indications from the ADC 73 that its input signal from the first IF amplifier 70 is so large as to be out of range for proper digitization. FIG. 26A shows the amplitude detection unit 75 developing AGC signal in further response to the amplified IF signal that the second IF amplifier 72 supplies as its output signal. A sophisticated design of the amplitude detection unit 75 data-slices the second IF amplifier 72 output signal using a bin comparator. Then, the amplitude detection unit 75 adjusts the gain of the second IF amplifier 72 to make the positive and negative variances of the output signal from bin centers substantially equal to each other. The portion of the FIG. 26 receiver apparatus described in this paragraph has a number of known substantial equivalents, some of which demodulate the amplified VSB AM IF signal before analog-to-digital coversion to recover digital signal descriptive of baseband DTV signal.

The demodulator 74 is connected for supplying the baseband DTV signal to a cascade connection 76 of three delay memories operated to delay each M/H Group by 0, 1, 2 and 3 slot intervals. This cascade connection 76 of the three delay memories is used to compensate for the differential delay between signals that contain the same program information and are received from different DTV transmitters used to implement frequency-diverse transmissions that have different types of subchannel interleaving as well. This compensation for the differential delay between signals that contain the same program information aligns the signals temporally, permitting them to be turbo-decoded contemporaneously by respective turbo decoders that interchange information concerning the confidence levels of data bits of that same program information.

An input selector 77 is connected for selectively reproducing one of five input signals thereto for subsequent application to the input port of an adaptive equalization filter 78. The adaptive equalization filter 78 performs adaptive channel equalization solely for the baseband DTV signal received from a first DTV transmitter. The first, second, third and fourth of the five input signals to the input selector 77 are the variously delayed responses to the baseband DTV signal from the demodulator 74, as supplied from the cascade connection 76 of three delay memories. A dual-port random-access memory 79 has a random-access port connected for being written to from the output port of the equalization filter 78 and has a serial output port connected for supplying a fifth of the five input signals to the input selector 77. The RAM 79 and the input selector 77 are operated for recycling the output signal of the adaptive equalization filter 78 to its input port when baseband DTV signal from the first DTV channel is not otherwise available for updating adaptation of the equalization filter 78.

An input selector 80 is connected for selectively reproducing one of five input signals thereto for subsequent application to the input port of an adaptive equalization filter 81. When frequency-diversity reception using first and second DTV receivers is being performed, the adaptive equalization filter 81 performs adaptive channel equalization solely for the baseband DTV signal received from a second DTV transmitter. The first, second, third and fourth of the five input signals to the input selector 80 are the variously delayed responses to the baseband DTV signal from the demodulator 74, as supplied from the cascade connection 76 of three delay memories. A dual-port random-access memory 82 has a random-access port connected for being written to from the output port of the equalization filter 81 and has a serial output port connected for supplying a fifth of the five input signals to the input selector 80. The RAM 82 and the input selector 80 are operated for recycling the output signal of the adaptive equalization filter 81 to its input port when baseband DTV signal from the second DTV channel is not otherwise available for updating adaptation of the equalization filter 81.

The part 66A of the M/H decoding control unit 66 generates respective control signals applied to the input selector 77 and to the input selector 80, taking into account the subchannel_interleaving information supplied from the FIG. 26B portion of the FIG. 26 receiver apparatus. When two or more DTV transmitters broadcast the same program material and their respective coverage areas overlap, each DTV transmitter will broadcast that same program material in a different set of M/H Groups than the other DTV transmitter(s). This is done as described supra with reference to FIGS. 5-8, or as described supra with reference to FIGS. 9-12. The M/H decoding control unit relies on the subchannel_interleaving information for determining the time offset(s) between the same program material being transmitted at different radio frequencies by respective DTV transmitters. The FIG. 26 receiver may be situated where the coverage areas of two or more of these DTV transmitters overlap. The first part 66A of the M/H decoding control unit 66 can then arrange for the frequency-agile RF-to-IF converter 69 to convert the RF signals from these DTV transmitters on a time-staggered basis to IF signal for amplification by the IF amplifiers 70 and 72. The amplified IF signals can then be digitized by the ADC 73 and subsequently demodulated by the VSB AM demodulator 74 to recover baseband DTV signals from two transmissions of the same program material on the time-staggered basis. The first part 66A of the M/H decoding control unit 66 can then arrange for the earlier received duplicate program material to be delayed so as to be contemporaneous with the duplicate program material as later received. Then, a subsequent part 66B of the M/H decoding control unit 66 shown in FIG. 26B can arrange for both the earlier received and the later received duplicate program material to be turbo decoded contemporaneously with respective turbo decoders shown in FIG. 26C. The turbo decoders can exchange information with each other concerning the confidence levels of the data bits they each decode, improving the decoding capability of the FIG. 26 receiver when it is situated where the coverage areas of two DTV transmitters overlap.

The equalization filter 78 for the first DTV channel and the equalization filter 81 for the second DTV channel are connected for supplying their respective output signals as input signals to a permuter 83, the operation of which is controlled by a binary control signal generated within the first part 66A of the M/H decoding control unit 66. Responsive to a first value of the binary control signal, the permuter 83 reproduces at the first and second output connections thereof the output signal of the equalization filter 78 and the output signal of the equalization filter 81, respectively. Responsive to a second value of the binary control signal complementary to the first, the permuter 83 reproduces at the first and second output connections thereof the output signal of the equalization filter 81 and the output signal of the equalization filter 78, respectively.

FIG. 26B shows a synchronization signals extraction unit 84 that is connected for receiving equalized baseband DTV signal from the first output connection of the permuter 83. Responsive to data-field-synchronization (DFS) signals, the sync extraction unit 84 detects the beginnings of data frames and fields. Responsive to data-segment-synchronization (DSS) signals, the sync extraction unit 84 detects the beginnings of data segments. The FIG. 26 DTV receiver apparatus uses the DSS and DFS signals for controlling its operations similarly to the way this is conventionally done in DTV receivers. None of FIGS. 26A, 26B, 26C and 26D explicitly shows the apparatus and connections thereof for effecting these operations.

A decoder 85 for detecting the type of ancillary transmission responds to 8-bit sequences contained in final portions of the reserved portions of DFS signals separated by the sync extraction unit 84. The decoder 85 is connected for indicating the type of ancillary transmission to part 66B of the M/H decoding control unit 66, which controls turbo decoding of CCC and plural-dimensional decoding of RS Frames in the FIG. 26 DTV receiver apparatus. The type of ancillary transmission that the decoder 85 detects may be one that conditions the decoder 85 to extract further information concerning the ancillary transmission from the initial portions of the reserved portions of DFS signals separated by the sync extraction unit 84. The decoder 85 is connected for supplying such further information to part 66B of the M/H decoding control unit 66. Many of the connections of the M/H decoding control unit 66 to the elements involved in turbo decoding of CCC and in plural-dimensional decoding of RS Frames are not explicitly shown in FIGS. 26A, 26B, 26C and 26D. This is so as to keep those figures from being too cluttered to be understood readily.

FIG. 26B shows a 12-phase trellis decoder 86 connected for receiving equalized baseband DTV signal from the first output connection of the permuter 83 directly, which presumes that Gray-to-binary-code re-mapping was done in the block processor 14, rather than after the M/H Group formatter 15. If Gray-to-binary-code re-mapping is done by the re-mapper 18 following the M/H Group formatter 15, the equalized baseband DTV signal from the first output connection of the permuter 83 is recoded using a binary-to-Gray-code re-mapper to generate input signal for the trellis decoder 86. The trellis decoder 86 postcombs the Z-sub-2 bits of the quarter-rate PCCC signals supplied as input signal thereto, if those bits are precoded at the transmitter. If the Z-sub-2 bits of the quarter-rate PCCC signals are not so precoded, the trellis decoder 86 will not postcomb the Z-sub-2 bits supplied thereto as input signal. The trellis decoder 86 is connected for supplying trellis-decoding results to a PCCC gate 87 connected for extracting the PCCC'd signaling within each Group and reproducing the PCCC'd signaling for application as input signal to a decoder 88 for quarter-rate PCCC. The decoder 88 reproduces randomized signaling decoded (possibly with some errors) from the quarter-rate PCCC supplied thereto and is connected for supplying that randomized signaling as input signal to a signaling de-randomizer 89. The signaling de-randomizer 89 is connected for supplying de-randomized coded signaling to an 8-bit byte former 90.

FIG. 26B shows a TPC code gate 91 connected for extracting bytes of TPC code from bytes of the de-randomized signaling supplied by the byte former 90 and for supplying those extracted bytes of TPC code as input signal to a decoder 92 for (18, 10) Reed-Solomon coding. The decoder 92 recovers TPC information and is connected for supplying the TPC information to part 66B of the M/H decoding control unit 66 and to other elements of the receiver apparatus. The M/H decoding control unit 66 is able to respond to the TPC information to control selection of the type of outer convolutional decoding to be used on CCC portions of each M/H Group.

FIG. 26B shows an FIC code gate 93 connected for extracting byte-interleaved FIC code bytes from the bytes of de-randomized signaling supplied by the byte former 90 and reproducing those extracted bytes for application as input signal to a block de-interleaver 94. The block de-interleaver 94 is of matrix type and complements the block interleaving done by the block interleaver 66 described supra with reference to FIG. 18. In this specification (over)writing refers both to memory writing procedures in which storage locations are empty of content when written by new content and to memory writing procedures in which storage locations have their original contents overwritten by new content. The block de-interleaver 94 is essentially a byte-organized random access memory (RAM) with byte-storage locations arrayed in rows and columns to be (over)written and read in accordance with addressing and read/write control signals supplied from a block de-interleaver memory read/write control unit 95. The byte-storage locations are arrayed in 51-byte rows for being (over)written by R-S coded FIC data from respective Groups within each M/H sub-Frame. The memory read/write control unit 95 needs to know the total number of Groups, TNoG, within each M/H sub-Frame in order to know the number of these 51-byte rows. The memory read/write control unit 95 uses this knowledge to control the addressing of successive columns of TNoG byte-storage locations when writing to them. An extractor 96 is connected to extract TNoG for the current M/H sub-Frame (current_TNoG) from the response of the decoder 92 of the (18, 10) Reed-Solomon coded TPC data. The value of current_TNoG appears NoG times in the TPC data recovered by the decoder 92 from the previous M/H sub-Frame. The extractor 96 selects from the TPC data those bit sequences descriptive of current_TNoG estimates and decides the value of current_TNoG based on the majority of concurring estimates. The extractor 96 is connected to supply that value of current_TNoG to the memory read/write control unit 95.

After the final Group of each M/H sub-Frame concludes, the read/write control unit 95 generates read addresses for reading rows of 35×TNoG bytes from the RAM in the block de-interleaver 94. The reading is completed before the initial Group of the next M/H sub-Frame begins and the contents of the memory in the block de-interleaver 94 will be overwritten. The block de-interleaver 94 is connected for supplying its de-interleaved FIC code response as input signal to a decoder 97 for (51, 37) Reed-Solomon coding. The decoder 97 recovers FIC information and is connected for supplying that FIC information to be written into addressed temporary-storage locations within a random-access memory 98. The decoder 97 generates a Signaling Error Indication (SEI) bit whenever a (51, 37) Reed-Solomon codeword is found to contain byte error(s) that cannot be corrected. An SEI bit is likely to be generated if there is a momentary fade in received radio-frequency signal strength, for example.

The RAM 98 provides temporary storage for the bytes of the FIC information for one entire M/H Frame, plus two-bit extensions of those bytes. One of these extension bits is the SEI bit from the decoder 97 for (51, 37) R-S coding. A further one of these extension bits is used for signaling whether or not byte-storage locations in the RAM 98 contain FIC information content. When the M/H receiver is initially powered up, or when there is a change in selection of the major reception channel, the contents of the RAM 98 are erased in bulk. This erasure sets the further one-bit extensions to signal the erasure—e.g., the further one-bit extensions are all set to ZERO.

A write address generator 99 is connected for supplying write addressing to the RAM 98 such that FIC information is stored at appropriate locations within the M/H Frame, even if that FIC information begins to be furnished part way through the M/H Frame. An extractor 100 is connected for extracting the current FIC-Segment number from the header of the FIC Segment being currently written into the RAM 98 and supplying that current FIC-Segment number to the write address generator 99. The extractor 100 is further connected for supplying the current FIC-Segment number to a detector 101 for generating a pulse response to the current FIC-Segment number being 0000. The detector 101 can be a four-input NOR gate operating as a decoder for 0000. An FIC-Chunk counter 102 is connected for receiving pulse responses from the detector 101 as count input signal. The write address generator 99 combines the FIC-Chunk count supplied from the counter 102 with the current FIC-Segment number supplied from the extractor 100 to generate each write address that the write address generator 99 supplies to the RAM 98.

The write addresses that the write address generator 99 supplies to the RAM 98 are accompanied by write control signals, which write control signals are also supplied as the further extension bits of the extended bytes supplied for being written into storage locations of the RAM 98. The value of these write control signals is the opposite—e.g., ONE—of the value indicating that a byte-storage location is empty of content. Accordingly, the further extension bits temporarily stored in respective extended-byte-storage locations of the RAM 98 are indicative of whether or not those locations store bytes of FIC information.

A read address generator 103 is connected for supplying read addressing to the RAM 98 when the RAM 98 reads its stored FIC information to provide input signal for an FIC-Chunk code combiner 104 at the conclusion of each M/H Frame interval. The FIC-Chunk code combiner 104 is connected for supplying processed FIC Chunks to part 66B of the M/H decoding control unit 66. (FIG. 26D shows processed FIC Chunks from the FIC-Chunk code combiner 104 being supplied to SMT-MH processing unit 147 to be integrated with SMT-MH information during the generation of Service Map Data written into memory 148 for temporary storage therewithin.)

The decoder 97 for (51, 37) R-S coding is connected for supplying FIC-Segments to a read-address-ranges extractor 105 for extracting information from their headers concerning the FIC_last_segment_num(ber) of each of the P FIC-Chunks temporarily stored in the RAM 98. This information is temporarily stored in memory within the read-address-ranges extractor 105 to be used for controlling the operation of the read address generator 103 when reading FIC-Chunks in parallel from the RAM 98 to the FIC-Chunk code combiner 104.

FIG. 26C shows a turbo decoder 110 for CCC signal and a delay memory 106 connected for receiving respective input signals from the first output connection and from the second output connection of the permuter 83 in FIG. 26A. The delay memory 106 is operated for temporally aligning the initial-component transmissions of an iterative-diversity broadcast as reproduced in its delayed response with the final-component transmissions of the iterative-diversity broadcast as applied to the turbo decoder 110. The response of the delay memory 106 is applied as input signal to a turbo decoder 120 for CCC signal, which turbo decoder 120 is selectively operated in parallel with the turbo decoder 110. The delay memory 106 provides a number of M/H Frame intervals of delay as determined by the M/H decoding control unit 66 in response to the iterative_diversity_delay bits extracted from the TPC signal that the decoder 92 for (18, 10) RS FEC code supplies. This number of M/H Frame intervals will be zero if a code rate one-quarter the 8-VSB symbol rate is desired without resort to iterative diversity, but is more likely to be eight or twelve.

The delay memory 106 facilitates the parallel operation of the turbo decoders 110 and 120 to decode respectively the initial-component transmissions and the final-component transmissions of an iterative-diversity CCC broadcast contemporaneously. Furthermore, the parallel operation of the turbo decoders 110 and 120 permits exchanging information between them concerning the confidence levels of soft data bits. An information-exchange unit 107 is connected between corresponding points in the turbo loops of the decoders 110 and 120 for performing such exchange. The turbo decoder 110 may be operated alone when receiving a single-time SCCC broadcast that does not employ iterative diversity. The delay memory 106, the turbo decoder 110 and the information-exchange unit 107 are not operated when receiving a single-time SCCC broadcast and do not need to be fully powered at such time.

When a DTV transmitter is operated to permit iterative-diversity reception of its signals alone, the data bits of the early-component transmissions preferably one's complement the data bits of the corresponding late-component transmissions. If similar program material is broadcast by two cooperating DTV transmitters having respective coverage areas that overlap, it is advantageous for one of the cooperating DTV transmitters to transmit the similar program material in one's complemented form. When broadcasting is of a sort described in the foregoing two sentences, the information-exchange unit 107 needs to compare the confidence levels of two sets of data bits that are complementary to each other. If similar program material is broadcast by three cooperating DTV transmitters having respective coverage areas all of which overlap in certain regions, two of the transmitters will have to transmit respective sets of data bits that are alike, rather than complementary to each other. Depending on the location of the FIG. 26 receiver apparatus, the information-exchange unit 107 is apt to have to compare the confidence levels of two sets of data bits that are similar to each other, rather than complementary to each other. Accordingly, the information-exchange unit 107 is constructed so it can be modified to accommodate comparison of the confidence levels of the two sets of data bits from the turbo loops of decoders 110 and 120 when those sets of data bits are similar to each other, rather than complementary to each other. FIG. 26C shows a portion 66C of the M/H decoding control unit 66 connected for supplying the information-exchange unit 107 a binary control signal. This binary control signal indicates which of the two modes of comparison of the confidence levels of the two sets of data bits from the turbo loops of decoders 110 and 120 is appropriate to use. The M/H decoding control unit 66 generates this binary control signal, which has a first value during iterative-diversity reception of a single DTV channel. When first and second DTV channels are being received in a region where the coverage areas of their transmitters overlap, the M/H decoding control unit 66 generates the binary control signal responsive to the subchannel_interleaving bits in the TPC signals of the first and second DTV channels.

The turbo decoder 110 is connected for supplying its decoding results to a hard-decision unit 108 that essentially comprises a hard limiter for soft data bits. As noted in the previous paragraph, some transmitters send a single transmission or the late component-transmission for iterative-diversity reception with one's complemented data bits. So, the turbo decoding results when receiving M/H data from such transmitters need to be one's complemented to regenerate the original data bits. The hard-decision unit 108 is connected for supplying hard-decisions concerning data bits to one of two input connections to an exclusive-OR gate 109. The portion 66C of the M/H decoding control unit 66 is connected for supplying the other input connection of the XOR gate 109 a binary control signal. The M/H decoding control unit 66 generates this binary control signal dependent on the subchannel_interleaving bits in the TPC signal of the baseband DTV signal being decoded by the turbo decoder 110. If the hard-decisions concerning data bits supplied to the XOR gate 109 regenerate the original data bits, the value of the binary control signal supplied to the XOR gate 109 is ZERO. If the hard-decisions concerning data bits supplied to the XOR gate 109 need to be one's complemented to regenerate the original data bits, the value of the binary control signal supplied to the XOR gate 109 is ONE. In either case the data bits in the output signal of the XOR gate 109 reproduce the original M/H data bits, presuming them not to be corrupted by noise. A 8-bit-byte former 130 forms the serial-bit response of the XOR gate 109 into eight-bit bytes.

An extended-byte former 131 is connected for receiving the 8-bit bytes formed by the 8-bit-byte former 130 and appending to each of those bytes a number of bits indicative of the likelihood that that bytes is in error. These bits indicative of the level of lack of confidence that a byte is correct are generated in the following way. A battery 132 of exclusive-OR gates is connected for exclusive-ORing the hard bit of each successive soft data bit from the turbo decoder 110 output signal with each of the soft bits descriptive of the level of confidence that hard bit is correct. The battery 132 of XOR gates so generates a respective set of bits indicative of the level of lack of confidence that each successive hard bit is correct. A selector 133 selects the largest of the successive lack-of-confidence levels regarding the eight bits in each 8-bit-byte to provide the bits indicative of the level of lack of confidence that the byte is correct.

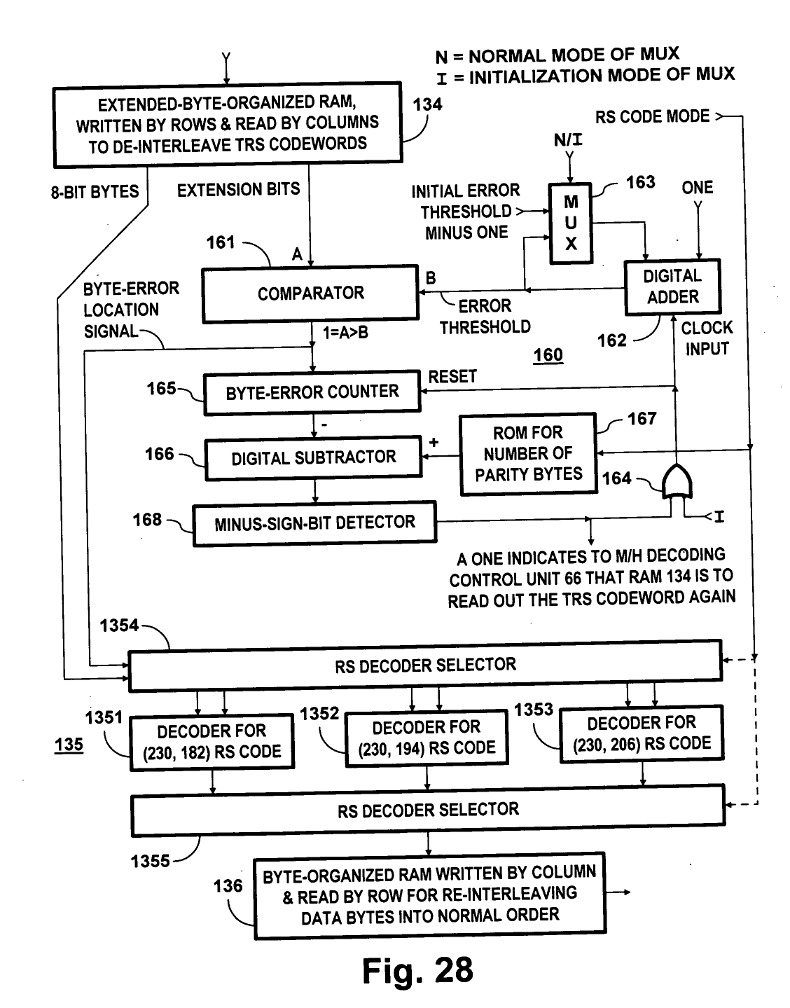

The resulting extended bytes are written row by row into respective rows of extended-byte storage locations in a random-access memory 134 operated to perform the matrix-type block de-interleaving procedure that is a first step of the TRS decoding routine. The RAM 134 is subsequently read one column of 9-bit extended bytes at a time to a selected one of a bank 135 of decoders for (230, 182), (230, 194) and (230, 206) Reed-Solomon codes, respectively. The bank 135 of decoders will further comprise decoders for (235, 187), (223, 187) and (211, 187) Reed-Solomon codes prescribed by A/153 if those TRS codes continue to be used. The M/H decoding control unit 66 selects the appropriate decoder in response to information extracted from the TPC. The extension bits accompanying the 8-bit bytes of the TRS code are used to help locate byte errors for the TRS code, as will be described in further detail infra with reference to FIG. 28 of the drawings. Such previous location of byte errors facilitates successful use of a Reed-Solomon algorithm capable of correcting more byte errors than an algorithm that must locate byte errors as well as correct them. The 8-bit data bytes that have been corrected insofar as possible by the selected one of the RS decoders in the bank 135 are written, column by column, into respective columns of byte-storage locations of a random-access memory 136. The RAM 136 is operated to perform the matrix-type block re-interleaving procedure for data in further steps of the TRS decoding routine. In a final step of the TRS decoding routine, the byte-storage locations in the RAM 136 are read from row by row for supplying reproduced randomized M/H data to a bypass unit 137. The bypass unit 137 usually relays this reproduced randomized M/H data to an M/H data de-randomizer 138 in the FIG. 26D portion of the FIG. 26 M/H receiver. The bypass unit 137 is connected to bypass TRS decoding for a prescribed time interval following selection of a new sub-channel for reception, however, supplying the data de-randomizer 138 with bytes of randomized M/H data taken directly from the response of the byte former 130. A representative construction of the bypass unit 137 is shown in FIG. 19 of the above-referenced U.S. patent application Ser. No. 12/580,534.

Referring now to FIG. 26D, the M/H data de-randomizer 138 is connected for receiving the output signal from the bypass unit 137 in FIG. 26C. The M/H data de-randomizer 138 de-randomizes the bytes of that signal by converting them to serial-bit form and exclusive-ORing the bits with the prescribed PRBS. The M/H data de-randomizer 138 converts the de-randomized bits into bytes of M/H data and supplies those bytes to a parsing unit 139 for parsing the data stream into internet-protocol (IP) packets. The IP-packet parsing unit 139 performs this parsing responsive to two-byte row headers respectively transmitted at the beginning of each row of IP data in the RS Frame. This row header indicates where the earliest start of an IP packet occurs within the row of IP data bytes within the RS Frame. If a short IP packet is completely contained within a row of the RS Frame, the IP-packet parsing unit 139 calculates the start of a later IP packet proceeding from the packet length information contained in the earlier IP packet within that same row of the RS Frame.

The IP-packet parsing unit 139 is connected for supplying IP packets to a decoder 140 for cyclic-redundancy-check coding in IP packets. Each IP packet contains a two-byte, 16-bit checksum for CRC coding that IP packet. The decoder 140 is constructed to preface each IP packet that it reproduces with a prefix bit indicating whether or not error has been detected in that IP packet. The decoder 140 is connected to supply these IP packets as so prefaced to a detector 141 of a “well-known” SMT-MH address and to a delay unit 142. The delay unit 142 delays the IP packets supplied to a packet selector 143 for selecting SMT-MH packets from other IP packets. The delay unit 142 provides delay of a part of an IP packet header interval, which delay is long enough for the detector 141 to ascertain whether or not the “well-known” SMT-MH address is detected.

If the detector 141 does not detect the “well-known” SMT-MH address in the IP packet, the detector 141 output response conditions the packet selector 143 to reproduce the IP packet for application to a packet sorter 144 as input signal thereto. The packet sorter 144 sorts out those IP packets in which the preface provides no indication of CRC coding error for writing to a cache memory 145 for IP packets. The prefatory prefix bit before each of the IP packets that indicates whether there is CRC code error in its respective bytes is omitted when writing the cache memory 145. The cache memory 145 temporarily stores at least those IP packets not determined to contain CRC code error for possible future reading to the later stages 146 of the receiver.

If the detector 141 does detect the “well-known” SMT-MH address in the IP packet, establishing it as an SMT-MH packet, the detector 141 output response conditions the packet selector 143 to reproduce the SMT-MH packet for application to an SMT-MH processing unit 147, which includes circuitry for generating control signals for the later stages 146 of the M/H receiver. FIG. 26D shows the SMT-MH processing unit 147 connected for receiving FIC information from the FIC-Chunk code combiner 104 in FIG. 26B. The SMT-MH processing unit 147 integrates this FIC information with information from SMT-MH packets during the generation of Service Map Data. The Service Map Data generated by the SMT-MH processing unit 147 is written into memory 148 for temporary storage therewithin and subsequent application to the later stages 146 of the M/H receiver. The SMT-MH processing unit 147 relays those SMT-MH packets that have bit prefixes that do not indicate error in the packets to a user interface 149, which includes an Electronic Service Guide (ESG) and apparatus for selectively displaying the ESG on the viewing screen of the M/H receiver. U.S. patent application Ser. No. 12/555,248 filed 8 Sep. 2009 for A. L. R. Limberg and titled “Sub-channel Acquisition in a Digital Television Receiver Designed to Receive Mobile/Handheld Signals” provides more detailed descriptions of the operations of the portion of an M/H receiver as shown in FIG. 26D. The description with reference to the drawing FIGS. 12, 13 and 14 of that application describe operations relying on the SMT-MH tables available in A/153. That description and the drawings it refers to are incorporated herein by reference.

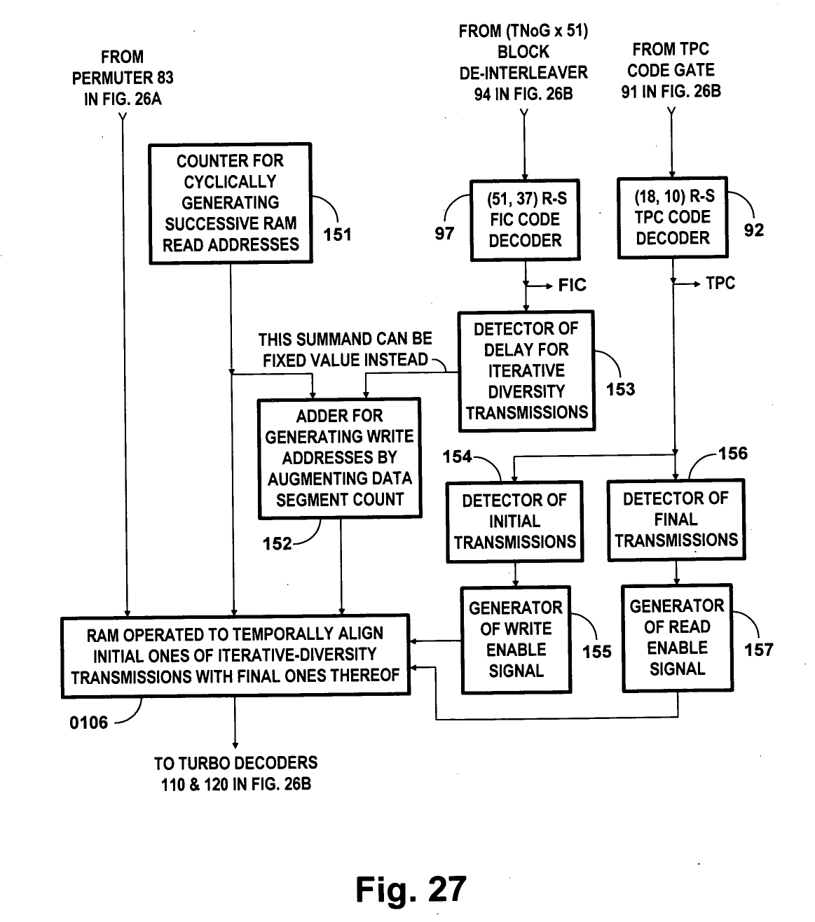

FIG. 27 shows more particularly a random-access memory 0106 being used as the basis of the delay memory 106 that FIG. 26C shows for delaying the initial-component transmissions when receiving an iterative-diversity broadcast of coded M/H data. FIG. 27 also shows, in detail, the circuitry used to support the operation of the RAM 0106. FIG. 27 shows a counter 151 connected for cyclically generating successive read addresses for the RAM 0106. The output count from the counter 151 is partitioned into a data segment count and an 8-VSB symbol count. The counts are reset to appropriate values responsive to information in the data field synchronizing (DFS) signals at the beginning of 8-VSB data fields. The RAM 0106 accepts a full range of data segment count that is an integer multiple M times 312 in number, as partial addresses both for writing and for reading. However, the RAM 0106 need not have actual storage locations for symbols associated with all the full addresses that contain these partial addresses. The full addresses that have partial addresses related to data segments that do not include M/H data do not need actual storage locations for symbols associated with them. This reduces the number of actual storage locations for symbols required in the RAM 0106 by the rather small factor of 156/150. The number of actual storage locations for symbols required in the RAM 0106 can be more substantially reduced if a standardized scheme for allocating Slots is adopted that invariably restricts initial transmissions just to even Slots or that invariably restricts initial transmissions just to odd Slots. Such restriction reduces the number of actual storage locations for symbols required in the RAM 0106 by a further factor of 2.

A digital adder 152 is connected for generating write addresses for the RAM 0106 by augmenting the data segment count portions of the successive read addresses for the RAM 0106 generated by the counter 151. The augmentation can be a fixed value, for offsetting the write addresses from the read addresses that they respectively augment by a specified odd multiple of 156, which multiple is typically 156 times either 81 or 79.

FIG. 27 shows a more sophisticated way of determining the offset between write addresses and read addresses for the RAM 0106. The offset is determined responsive to an indication supplied by bits in the FIC signal from the decoder 97 of the FIC coding. A detector 153 of the delay for iterative diversity transmission responds to these bits to generate the offset between the data segment count portions of the write and read addresses to be supplied to the RAM 0106. This offset is supplied as the summand input signal to the digital adder 152 that augments the data segment count portions of the successive read addresses generated by the counter 151, thus to generate write addresses for the RAM 0106. Programming the offset between write addresses and read addresses for the RAM 0106 responsive to bits of the FIC signal, allows receivers to be made with different amounts of storage capability for bytes of iterative diversity signals. As memory becomes cheaper more receivers can be built with longer delays for overcoming momentary drop-outs in received signal strength. More importantly perhaps, such programming offers the broadcaster some trade-off in the way the RAM 0106 is used in the receiver. If fewer Slots are used for iterative-diversity transmissions, the excess storage capacity of the RAM 0106 can be utilized to provide longer delay for overcoming momentary drop-outs in received signal strength.

A detector 154 for detecting initial transmissions is connected for receiving TPC signal from the TPC code decoder 92. The TPC signal presumably includes an iterative_diversity_mode datum. The detector 154 responds to that iterative_diversity_mode datum indicating an initial transmission being currently made to condition a generator 155 of write-enable signal to begin generating a write-enable signal for application to the RAM 0106. Generation of the write-enable signal continues until the current Slot concludes. The RAM 0106 is conditioned by the write-enable signal to write the permuter 83 response supplied thereto to symbol storage locations specified by the write addressing received from the digital adder 152. These symbol storage locations will not be reached for reading until a second or so later.

A detector 156 for detecting final transmissions is connected for receiving TPC signal from the TPC code decoder 92. The detector responds to the iterative_diversity_mode datum indicating a final transmission being currently made to condition a generator 157 of read-enable signal to begin generating a read-enable signal for application to the RAM 0106. Generation of the read-enable signal continues until the current Slot concludes. The RAM 0106 is conditioned by the read-enable signal to read delayed permuter 83 response from symbol storage locations specified by the read addressing received from the counter 151. The delayed permuter 83 response is read from the RAM 0106 to the FIG. 26C turbo decoder 120 for the initial ones of iterative-diversity transmissions.

FIG. 28 shows the structure of the bank 135 of RS decoders in more detail. The bank 135 of RS decoders is shown as comprising a decoder 1351 for (230, 182) RS code, a decoder 1352 for (230, 194) RS code, a decoder 1353 for (230, 206) RS code, and RS decoder selectors 1354 and 1355. The RS decoder selector 1354 is connected for applying the TRS codeword read from the preceding RAM 134 to one of the decoders 1351, 1352 and 1353 as selected responsive to an RS CODE MODE pair of bits. The M/H decoding control unit 66 supplies this pair of bits responsive either to the current_RS_code_mode_primary or the current_RS_code_mode_secondary bits detected by the TPC decoder 92 in FIG. 26B. The RS decoder selector 1355 is connected for applying to the succeeding RAM 136 the error-corrected results from the one of the decoders 1351, 1352 and 1353 as selected responsive to an RS CODE MODE pair of bits.

FIG. 28 also shows an arrangement 160 of elements 161-168 that locates byte errors for the one of the decoders 1351, 1352 and 1353 selected by the RS decoder selector 1354, which selected decoder initially attempts to correct the TRS codeword using a byte-error-location-and-correction decoding algorithm. If the TRS codeword has too many byte errors to be corrected by this algorithm, the selected decoder then resorts to a byte-error-correction-only decoding algorithm. Selector 1354 is connected for forwarding indications of byte errors to the selected one of the decoders 1351, 1352 and 1353 together with the bytes of each TRS codeword. The extension bits accompanying each successive 8-bit byte of a TRS codeword from the RAM 134 are supplied to a comparator 161 used as a threshold detector. The extension bits indicate the likelihood that the 8-bit byte is in error, and comparator 161 compares them to an error threshold. If the likelihood that the 8-bit byte is in error exceeds the error threshold, the comparator 161 responds with a logic ONE indicative that the byte is presumably in error. Otherwise, the comparator 161 responds with a logic ZERO indicative that the byte is presumably correct.

FIG. 28 shows the sum output signal from a clocked digital adder 162 supplied to the comparator 161 as the error threshold. The value of the error threshold is initialized in the following way at the outset of each TRS codeword being read from the RAM 134. A two-input multiplexer 163 is connected to supply its response as a first of two summand signals supplied to the adder 162, the second summand signal being arithmetic one. The sum output signal from the clocked adder 162 is applied as one of two input signals to the multiplexer 163, and an initial error threshold value less one is applied as the other input signal to the multiplexer 163. Just before each TRS codeword is read from the RAM 134 a respective pulsed logic ONE is generated by the M/H decoding control unit 66. The pulsed logic ONE is applied as control signal to the multiplexer 163, conditioning it to reproduce the initial error threshold value less one in its response supplied to the adder 162 as a summand input signal. The clocked adder 162 receives its clock signal from an OR gate 164 connected to receive the pulsed logic ONE at one of its input connections. The OR gate 164 reproduces the pulsed logic ONE in its response that clocks an addition by the adder 162. The adder 162 adds its arithmetic one summand input signal to the initial error threshold value less one summand input signal received from the multiplexer 163, generating the initial error threshold value as its sum output signal supplied to the comparator 161.

The pulsed logic ONE also resets to arithmetic zero the output count from a byte-error counter 165 that is connected for counting the number of logic ONEs that the comparator 161 generates during each TRS codeword. This output count is applied as subtrahend input signal to a digital subtractor 166. A read-only memory 167 responds to the RS CODE MODE pair of bits to supply the number of parity bytes in the TRS codewords, which number is supplied as minuend input signal to the digital subtractor 166. A minus-sign-bit detector 168 generates a logic ONE if and when the number of byte errors in a TRS codeword counted by the counter 165 exceeds the number of parity bytes in a TRS codeword. This logic ONE is supplied to the M/H decoding control unit 66 as an indication that the current TRS codeword is to be read out from the RAM 134 again. This logic ONE is supplied to the OR gate 164 as an input signal thereto. The OR gate 164 responds with a logic ONE that resets the counter 165 to zero output count and that clocks the clocked digital adder 162. Normally, the multiplexer 163 reproduces the error threshold supplied as sum output from the adder 162. This reproduced error threshold is applied to the adder 162 as a summand input signal, connecting the clocked adder 162 for clocked accumulation of arithmetic ones in addition to the previous error threshold. The logic ONE from the OR gate 164 causes the error threshold supplied as sum output from the adder 162 to be incremented by arithmetic one, which tends to reduce the number of erroneous bytes located within the TRS codeword upon its being read again from the RAM 134.

If and when the number of erroneous bytes located in the TRS codeword is fewer than the number of parity bytes that the ROM 167 indicates that the TRS codeword should have, the M/H decoding control unit 66 will cause the next TRS codeword in the RS Frame to be processed if such there be. The M/H decoding control unit 66 will begin reading such next TRS codeword from the RAM 134 to the bank 135 of RS decoders and writing the RS decoding results from the just previous RS codeword into the RAM 136.

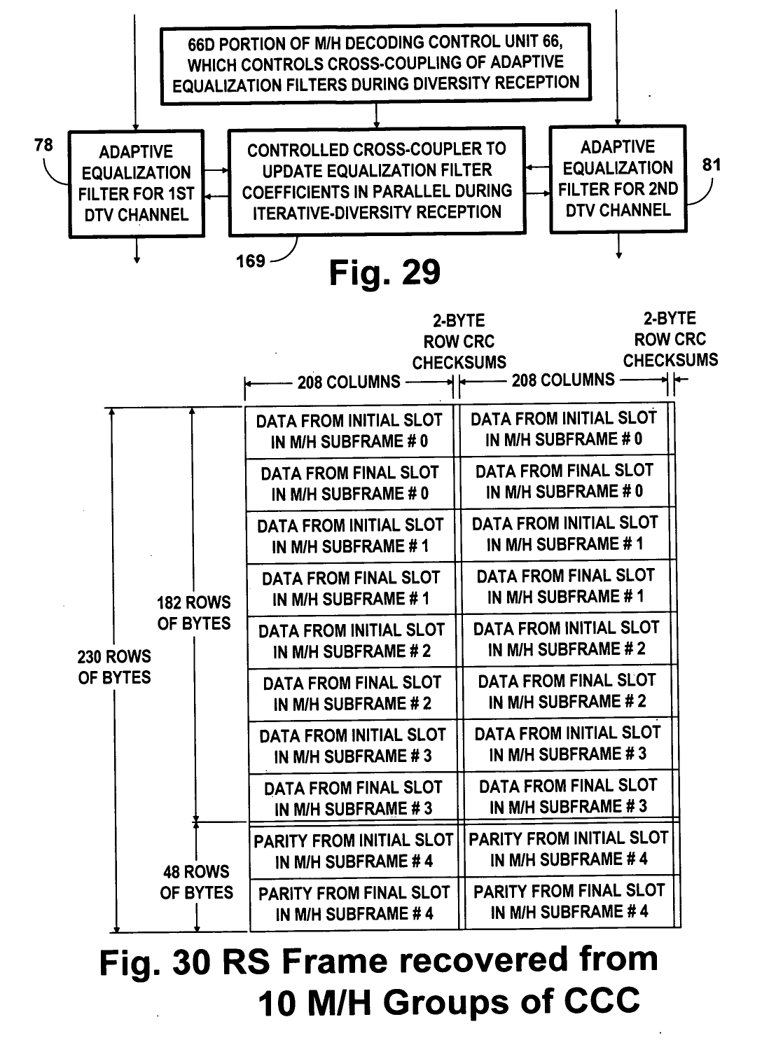

FIG. 29 shows in more detail a selective interconnection of the adaptive equalization filters 78 and 81 in preferred embodiments of the FIG. 26A portion of the FIG. 26 receiver apparatus. This selective interconnection of the adaptive equalization filters 78 and 81 provides for parallel incremental updating of their respective filter coefficients during iterative-diversity reception. The adaptive equalization filters 78 and 81 are structurally similar, each of them being of a type that uses a Kalman feedback loop for incrementally adjusting its filter coefficients. FIG. 27 shows a part 66D of the M/H decoding control unit 66 connected for generating control signal for controlling a controlled cross-coupler 169. This control signal indicates the times when frequency-diversity reception is not being used, but iterative diversity reception is being used. During such times a portion of the controlled cross-coupler 169 transmits incremental error information from the Kalman loop of the adaptive equalization filter 78 to the Kalman loop of the adaptive equalization filter 81. Also, during such times the controlled cross-coupler 169 transmits incremental error information from the Kalman loop of the adaptive equalization filter 81 to the Kalman loop of the adaptive equalization filter 78. The one-to-three Slot-interval differential delay between the respective input signals to the equalization filters 78 and 81 is so long that there is no appreciable increase risk of undesired tendency toward self-oscillation in either Kalman loop. However, there appears to be an increase in adaptive gain. The controlled cross-coupler 169 provides no cross-coupling of the Kalman loops of the adaptive equalization filters 78 and 81 during frequency-diversity reception, when the filters 78 and 81 have to equalize respective signals transmitted by two different transmitters.

The part 66D of the M/H decoding control unit 66 generates the control signal indicating the times when frequency-diversity reception is not being used, but iterative diversity reception is being used, using information obtained from the subchannel_interleaving and the iterative_diversity_mode bits in the TPC signals. This information is augmented by the measurements of respective strengths of signal received from different transmitters broadcasting over different DTV channels. The FIG. 26 receiver apparatus as described does not provide for iterative-diversity reception from each RF channel during frequency-diversity reception, but can be modified to allow such operation in accordance with further embodiments of the invention. In such a modification two turbo-decoding procedures are performed in parallel for each RF channel involved in reception. This can be implemented using a separate pair of turbo decoders for each RF channel. Alternatively, the same pair of turbo decoders can be used for each RF channel conducting the decoding of the RF channels on a time-division multiplex basis. In either type of modified receiver, information exchange between all four turbo decoding procedures can at times improve reception.

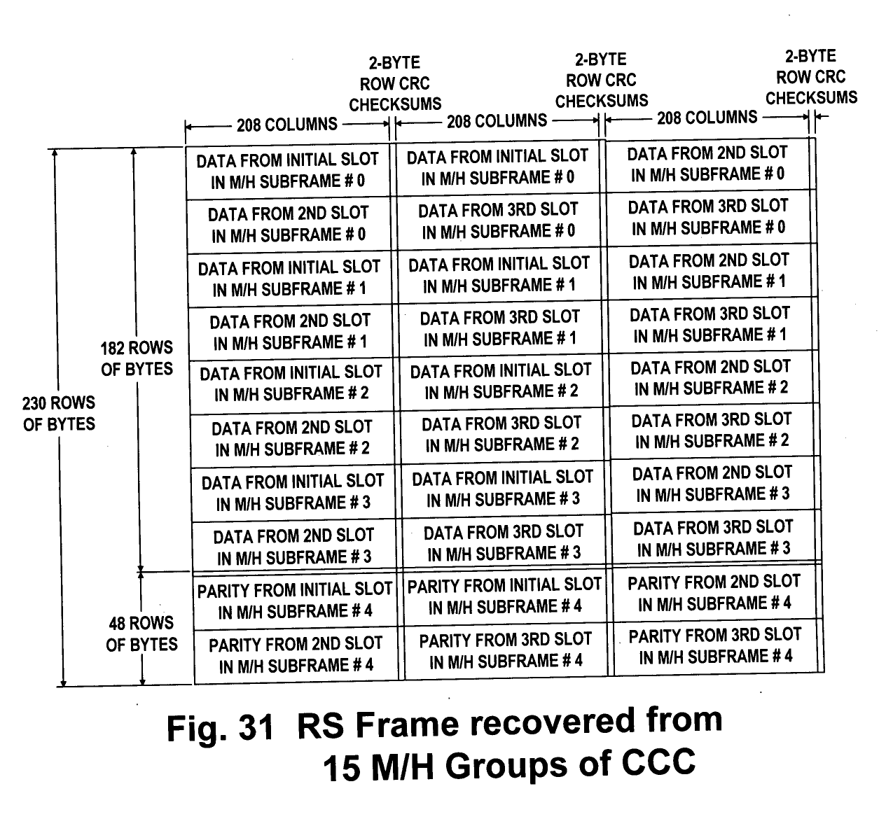

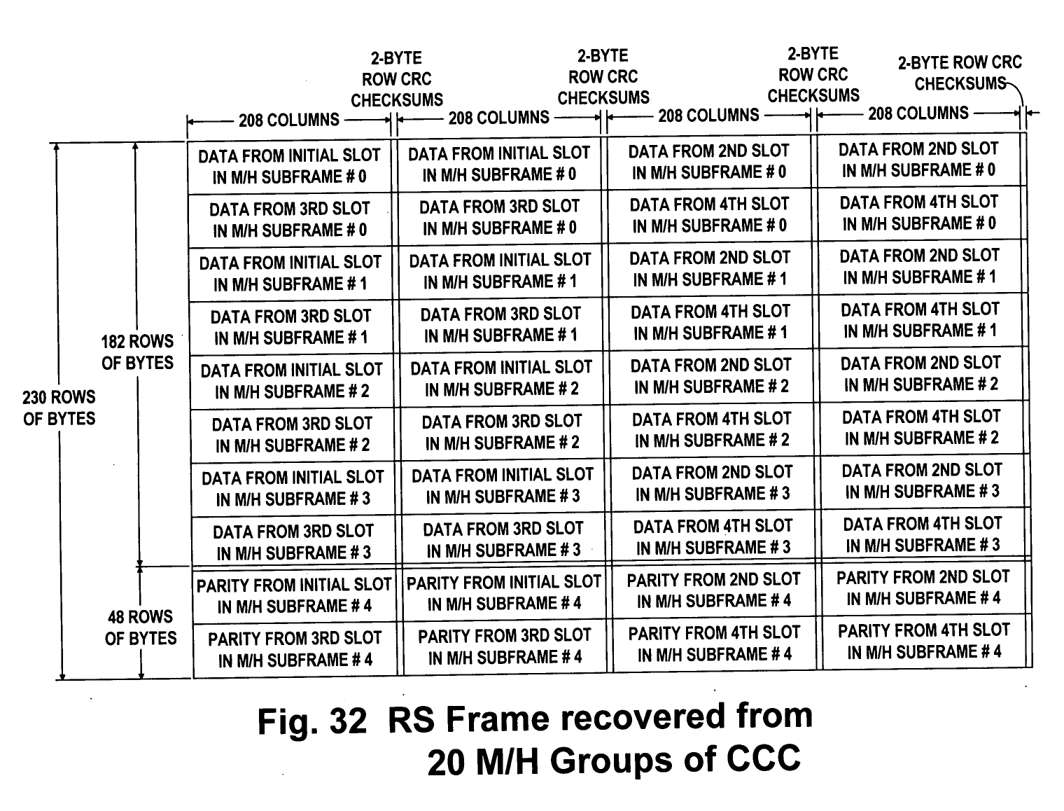

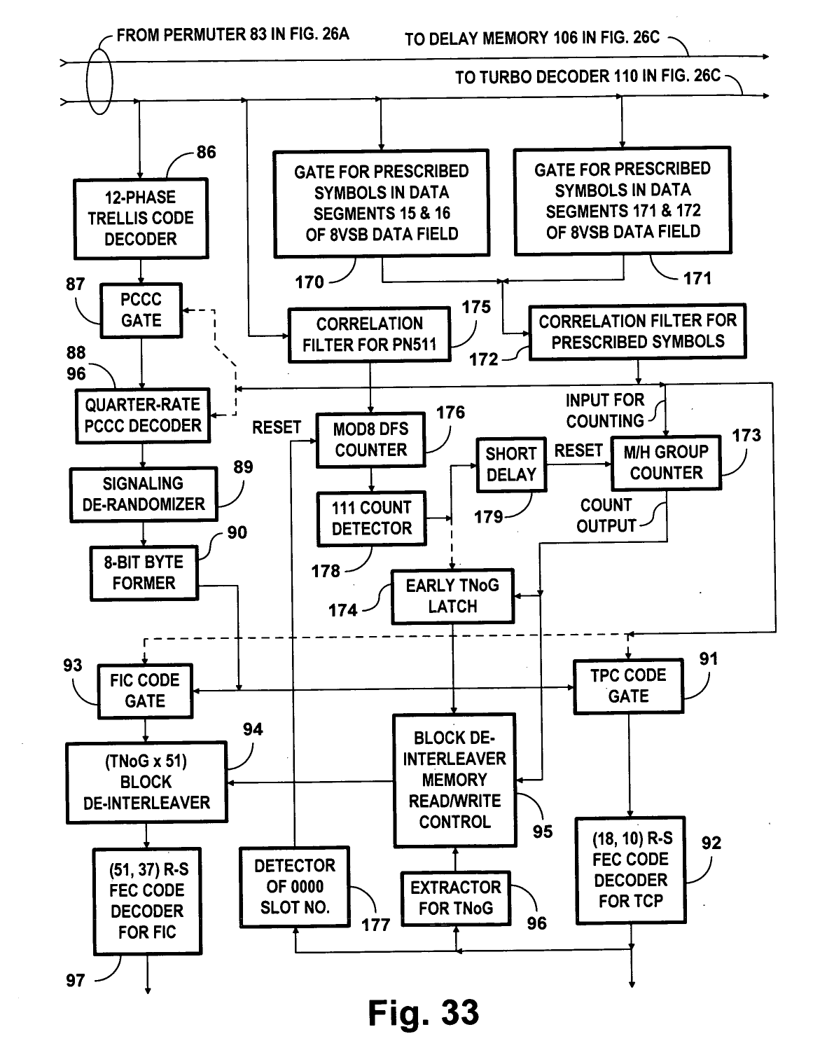

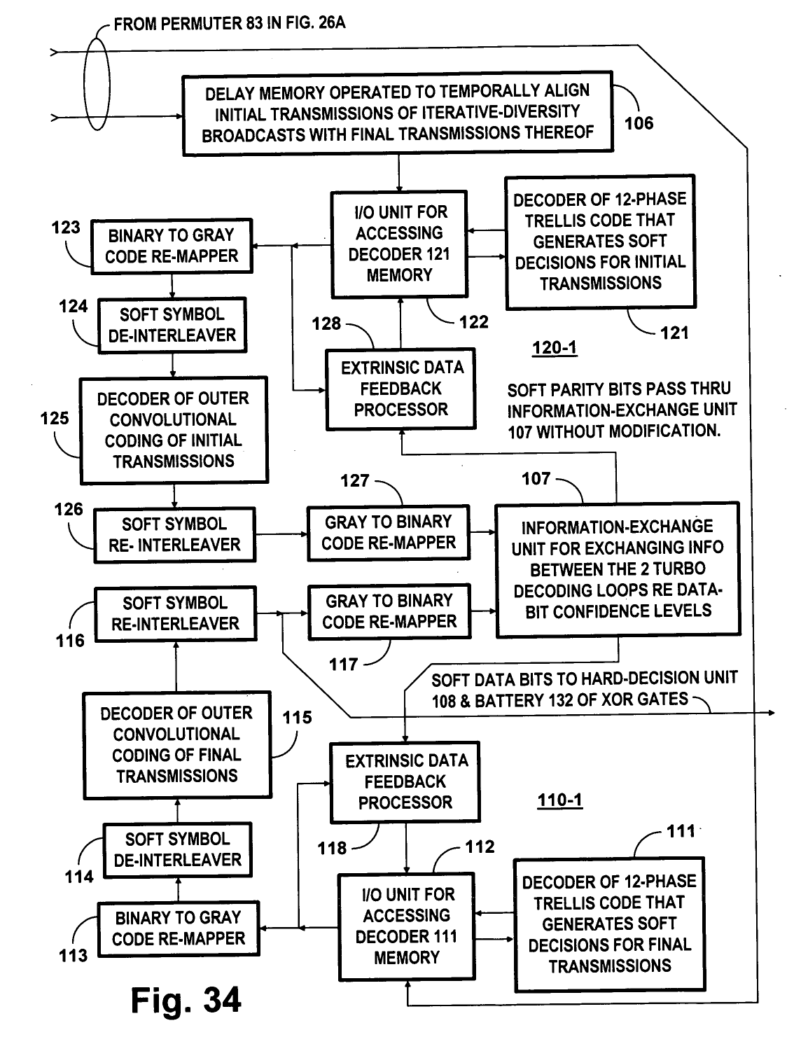

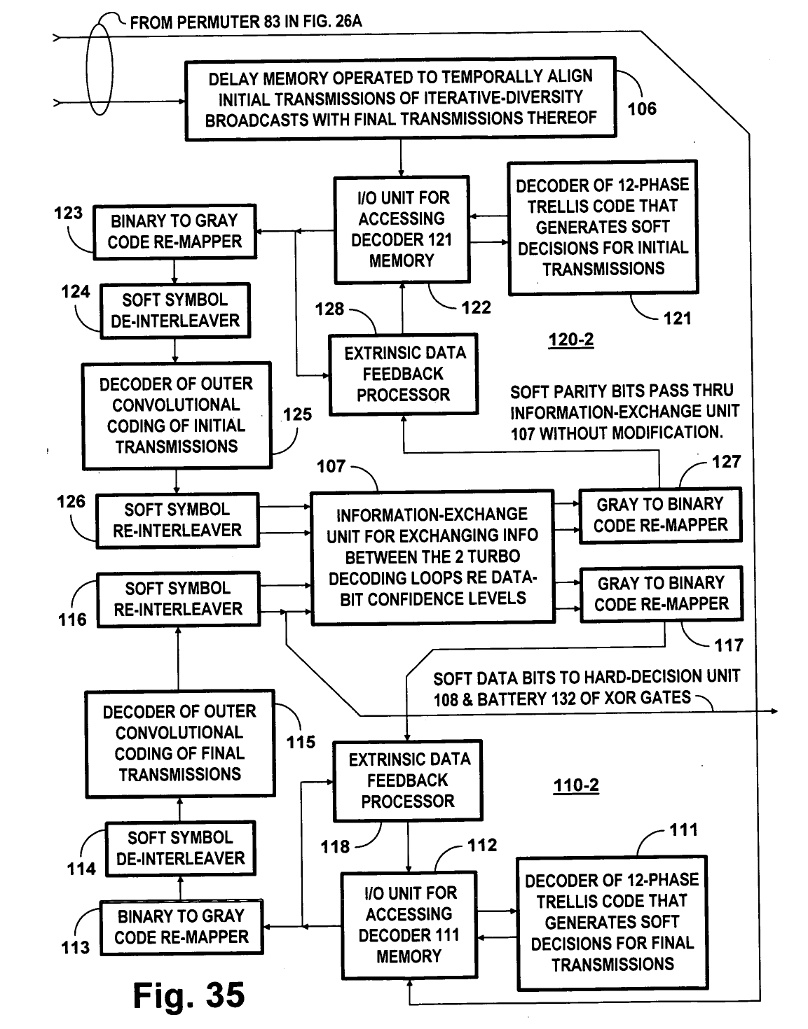

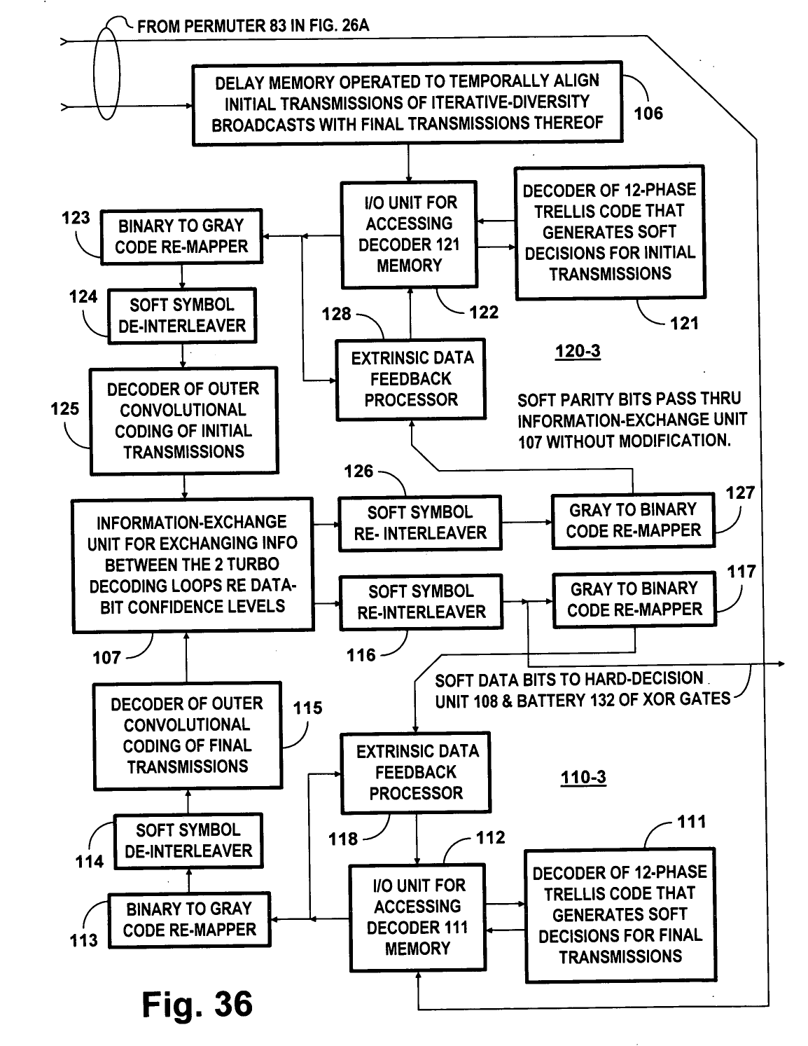

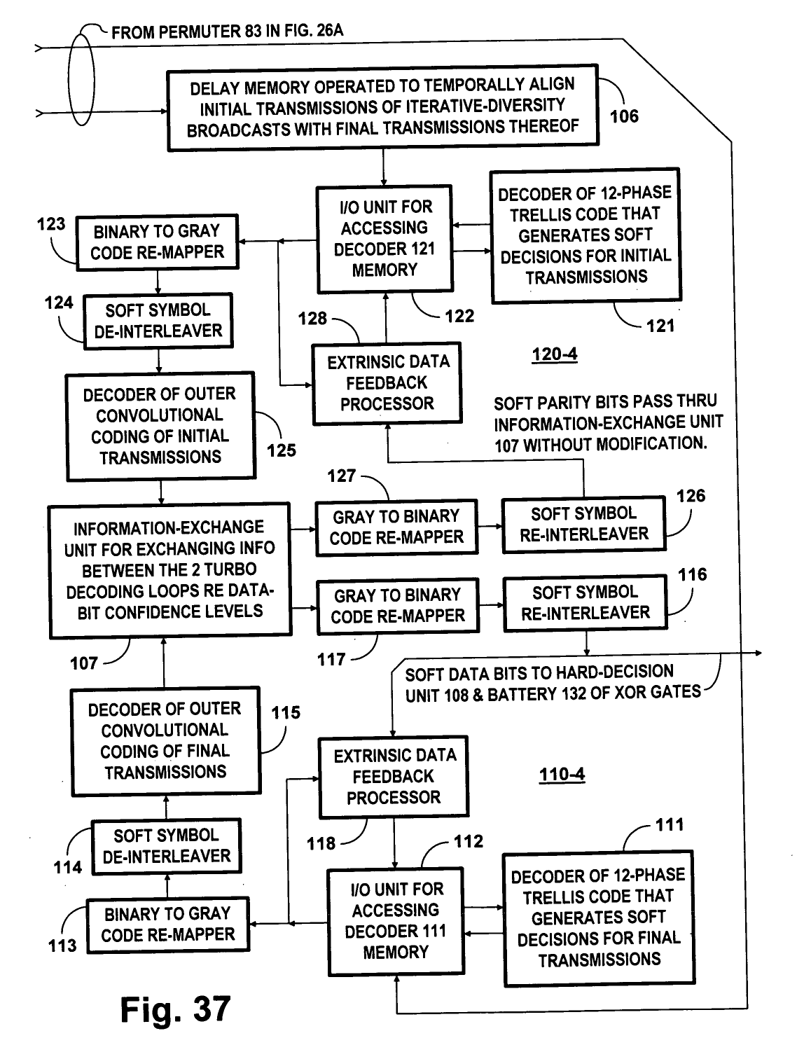

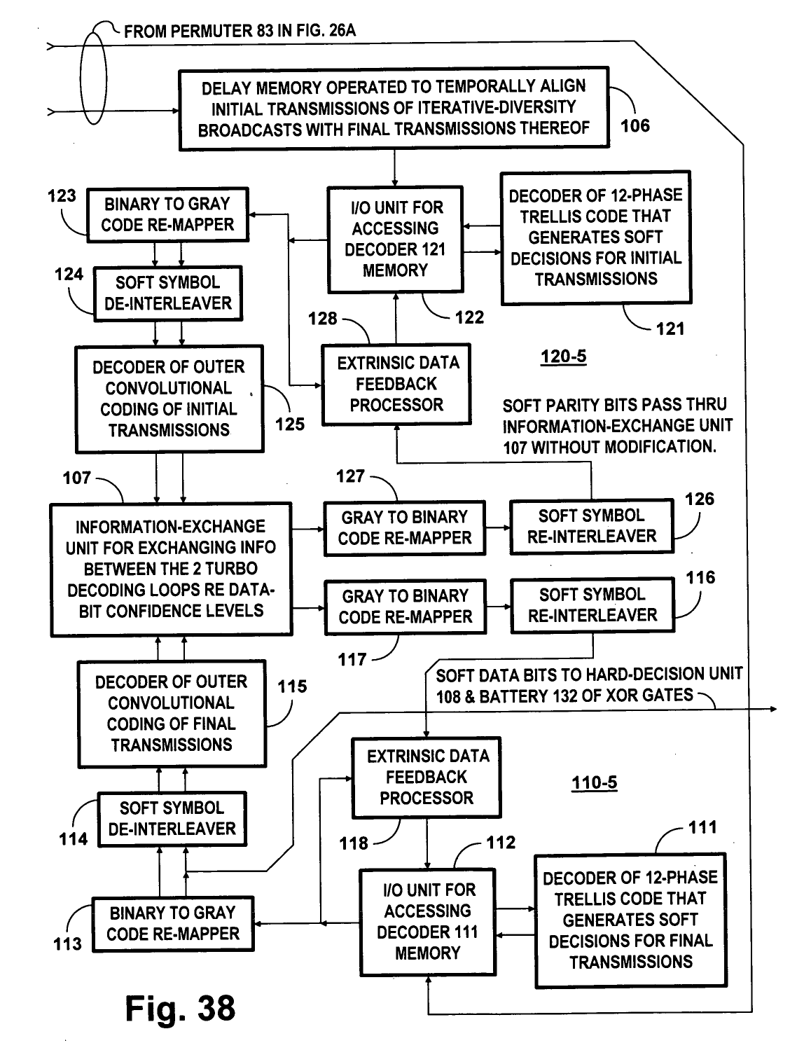

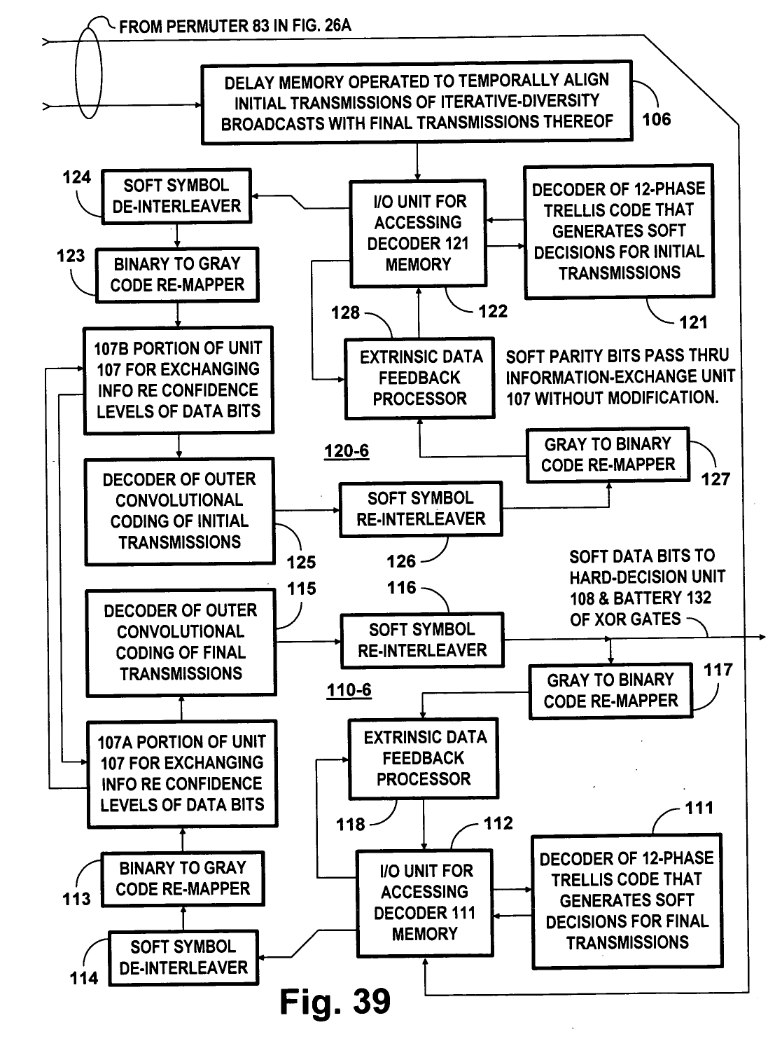

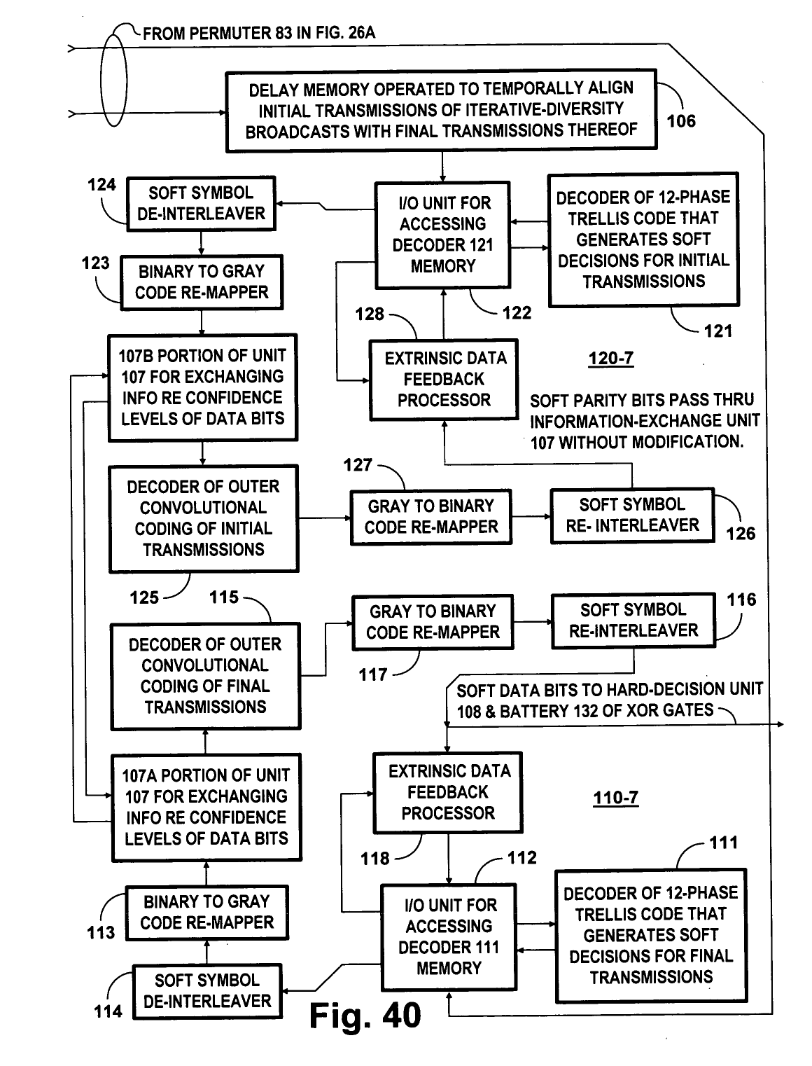

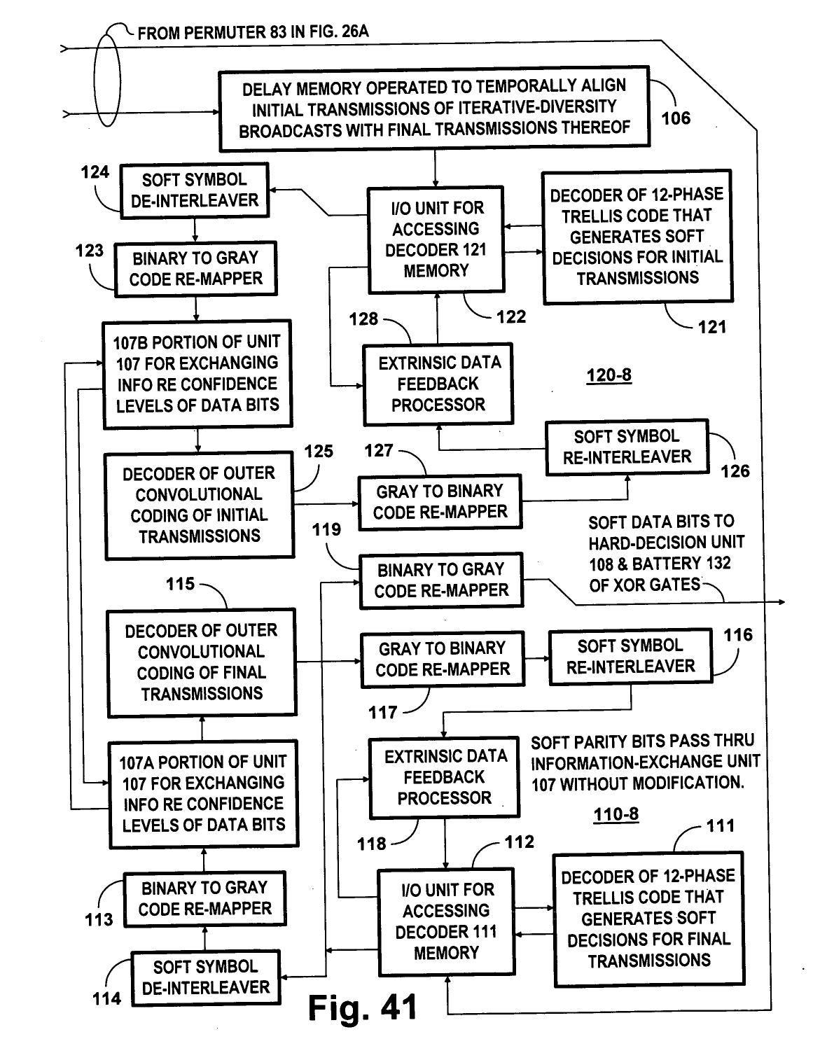

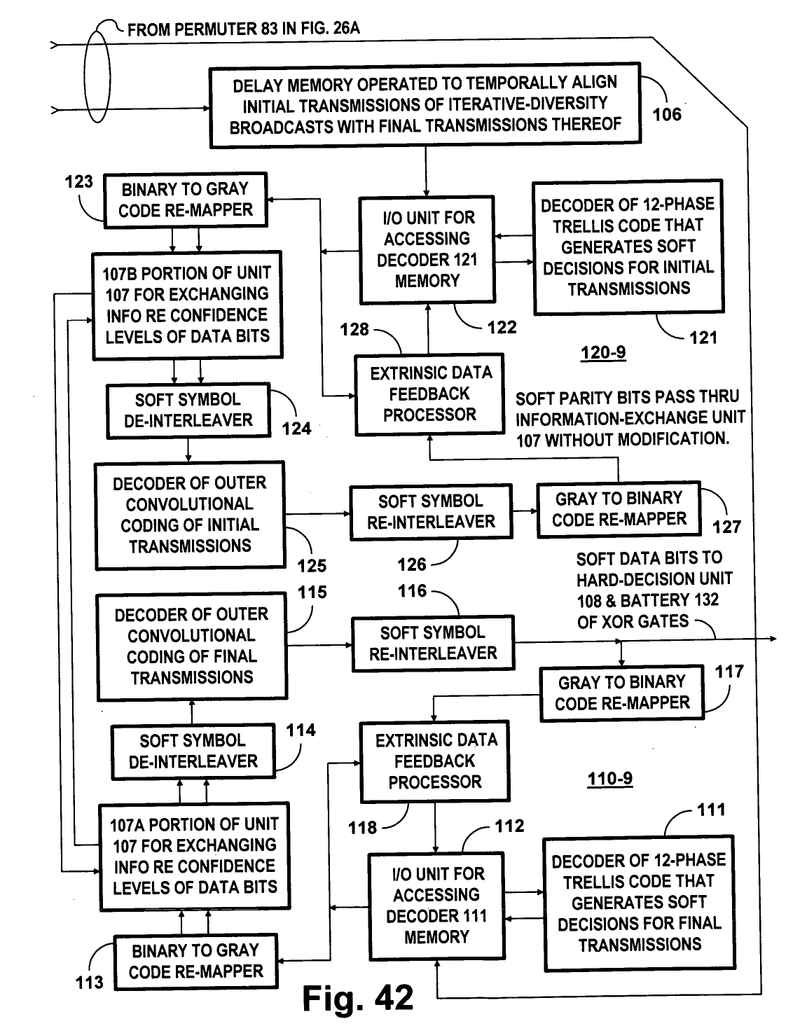

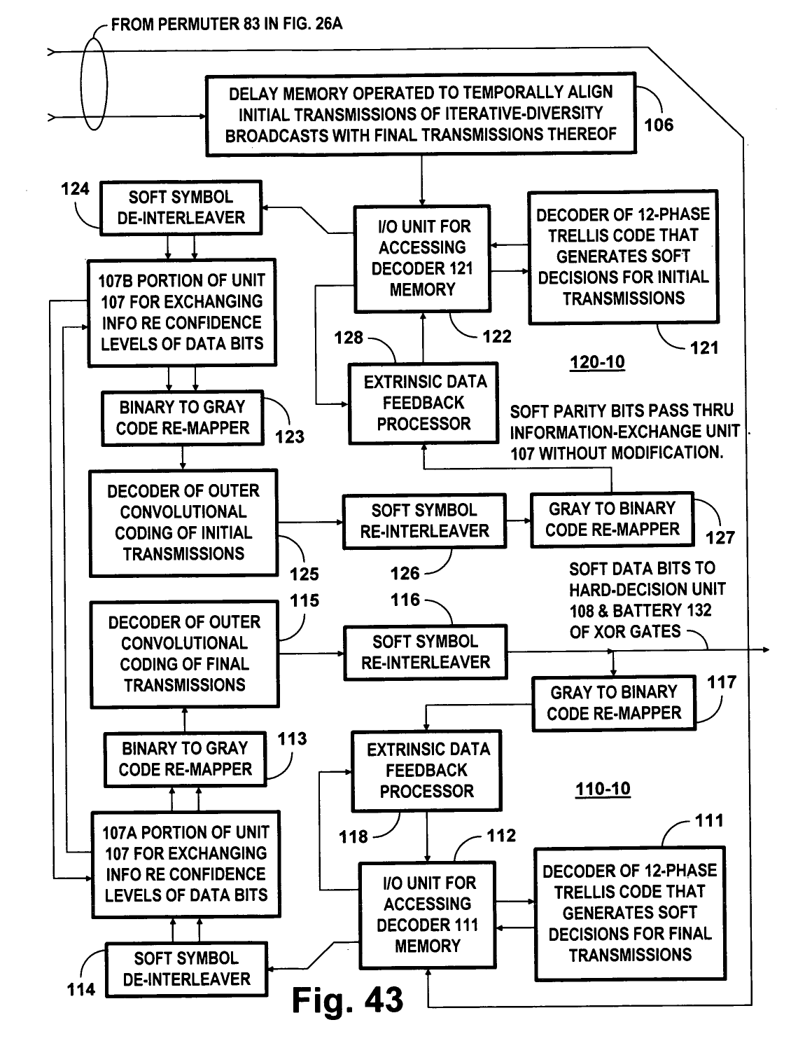

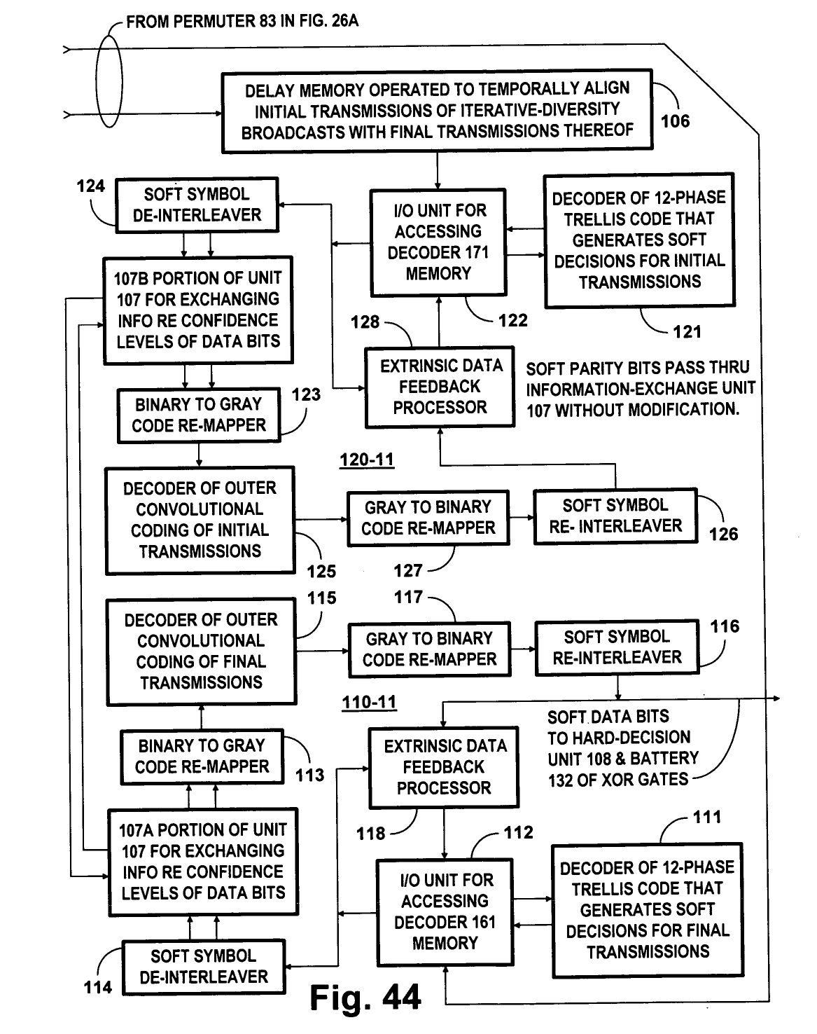

FIG. 30 shows how checksum bytes of CRC coding are located in an RS Frame extracted from ten M/H Groups of one-third-code-rate PCCC transmitted within an M/H Frame. FIG. 31 shows how checksum bytes of CRC coding are located in an RS Frame extracted from fifteen M/H Groups of one-third-code-rate PCCC transmitted within an M/H Frame. FIG. 32 shows how checksum bytes of CRC coding are located in an RS Frame extracted from twenty M/H Groups of one-third-code-rate PCCC transmitted within an M/H Frame. Each of FIGS. 30, 31 and 32 depicts a respective case in which transverse (230, 182) RS coding is used in the RS Frame. If such is indeed the case, the initial 182 rows of bytes in each of the RS Frames comprise mostly M/H data bytes, and the final 48 rows of bytes in each RS Frame comprise parity bytes for the transverse RS codewords.

In FIG. 30 each row of successively received bytes in the RS frame is divided into two sub-rows of similar length. A respective two-byte checksum is located at the conclusion of each sub-row or half-row of bytes in the FIG. 30 RS Frame. Accordingly, two-byte checksums occur as often in the successively received bytes in the FIG. 30 RS frame as they would in the successively received bytes in an RS frame extracted from just five M/H Groups transmitted within an M/H Frame. That is, two-byte checksums occur just as often in the successively received bytes from two M/H Slots in each of the five sub-Frames of an M/H Frame per FIG. 30 as checksums occur in the successively received bytes from a single M/H Slot in each of the five sub-Frames of an M/H Frame.

In FIG. 31 each row of successively received bytes in the RS frame is divided into three sub-rows of similar length. A respective two-byte checksum is located at the conclusion of each sub-row or one-third row of bytes in the FIG. 31 RS Frame. Accordingly, two-byte checksums occur as often in the successively received bytes in the FIG. 31 RS frame as they would in the successively received bytes in an RS frame extracted from just five M/H Groups transmitted within an M/H Frame. That is, two-byte checksums occur just as often in the successively received bytes from three M/H Slots in each of the five sub-Frames of an M/H Frame per FIG. 31 as checksums occur in the successively received bytes from a single M/H Slot in each of the five sub-Frames of an M/H Frame.

In FIG. 32 each row of successively received bytes in the RS frame is divided into foursub-rows of similar length. A respective two-byte checksum is located at the conclusion of each sub-row or one-quarter row of bytes in the FIG. 32 RS Frame. Accordingly, two-byte checksums occur as often in the successively received bytes in the FIG. 32 RS frame as they would in the successively received bytes in an RS frame extracted from just five M/H Groups transmitted within an M/H Frame. That is, two-byte checksums occur just as often in the successively received bytes from four M/H Slots in each of the five sub-Frames of an M/H Frame per FIG. 32 as in the successively received bytes from a single M/H Slot in each of the five sub-Frames of an M/H Frame.

So, no matter how many M/H Slots in an M/H Frame from ten to eighty are used for transmitting the RS Frame, the two-byte checksum at the end of a sub-row will locate byte errors for the same number of TRS codewords as the two-byte checksum at the end of a row of an RS Frame transmitted in only five M/H Slots in an M/H Frame. A single-byte error in a row of an RS Frame will affect error location in the same number of TRS codewords no matter what the size of the RS Frame. So, a single-byte error or a several-byte error contained within a sub-row will diminish the error-correction capability of the same number of TRS codewords no matter what the size of the RS Frame. In larger RS Frames, then, only a fraction of the TRS codewords, rather than all of them, suffer diminished error-correction capability from the single-byte error or the several-byte error contained within a sub-row.

The fact that CRC checksums occur at the same periodic intervals in all M/H data without regard to RS Frame size also facilitates using the technique described in published U.S. Pat. App. No. 2001-0025358 to avoid BER floor effect when turbo decoding PCCC'd M/H data. That is, the probability of error for each bit within a CRC codeword that is found to be correct can be reduced in subsequent iterations of the turbo decoding procedure. The turbo decoder does not have to take into account the different sizes of RS Frame when implementing this technique, owing to the CRC codewords being constrained to a standard length.

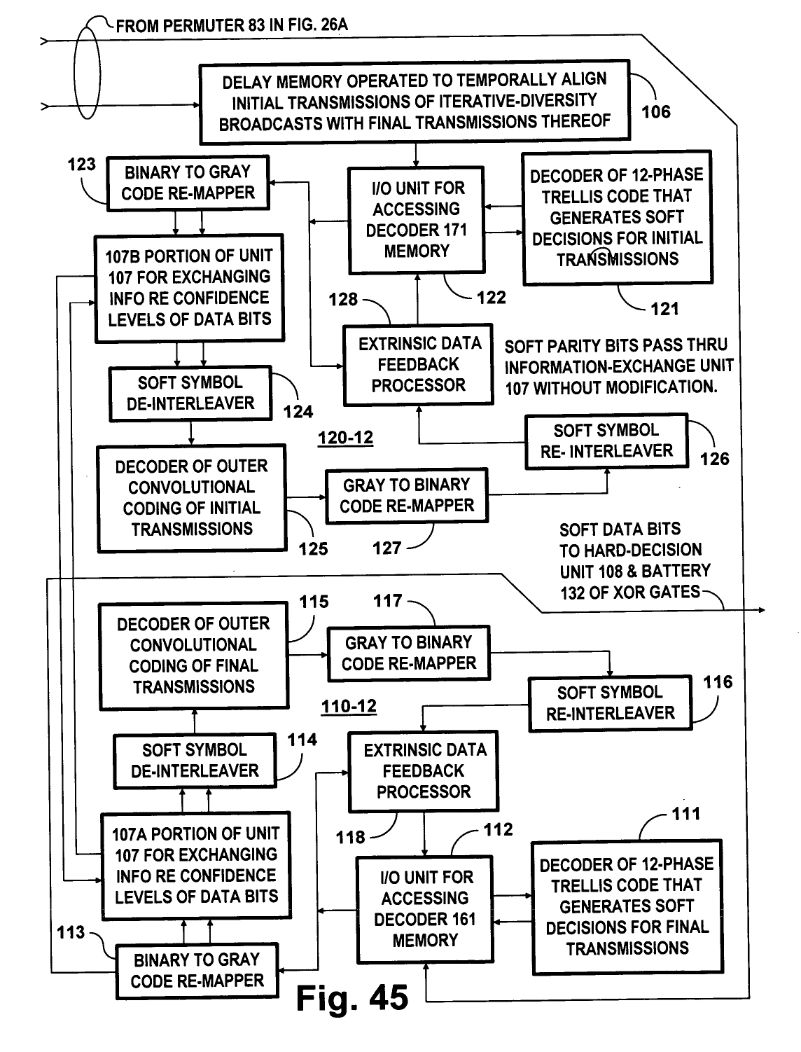

FIG. 33 shows how early TNoG information can be derived from the then current M/H sub-Frame and supplied to the memory read/write control circuitry 95 for directing its operations when the extractor 96 fails to supply TNoG information for the then current M/H sub-Frame. The basic idea for doing this is to detect and count the sequences of prescribed symbols that precede the TPC and FIC signaling in each M/H Group within an M/H sub-Frame. The equalized baseband 8-VSB DTV signal that the permuter 83 supplies to the turbo decoder 110 is also supplied to gates 170 and 171 as their respective input signals. In its response to this baseband 8-VSB DTV signal, the gate 170 selectively reproduces symbols in the portions of the 15th and 16th data segments of each 8-VSB data field that may have prescribed values. In its response to this baseband 8-VSB DTV signal, the gate 171 selectively reproduces symbols in the portions of the 171st and 172nd data segments of each 8-VSB data field that may have prescribed values. These responses are applied in time-division multiplex as the input signal of a correlation filter 172 for the sequence of prescribed symbols that should precede the TPC and FIC signaling in each M/H Group within an M/H sub-Frame. The correlation filter 172 determines when that sequence of prescribed symbols occurs, furnishing a ONE response indicative of such occurrence in place of its otherwise ZERO response. The correlation filter 172 is connected for supplying its response to an M/H Group counter 173 for counting the ONEs in that response, thereby indirectly counting the occurrences of M/H Groups in the baseband 8-VSB signal. The M/H Group counter 173 is reset to zero count at the beginning of each M/H Frame. The M/H Group counter 173 is connected to supply its count output as latch input signal to a latch 174, which is operated to latch the count output at the conclusion of each M/H Frame and to hold it in its output response as early TNoG. The latch 174 is connected to supply the latched count output as early TNoG to the block de-interleaver memory read/write control circuitry 83.

The generation of the signals for resetting the Group counter 173 and controlling the latch 174 will be described next. The equalized baseband 8-VSB DTV signal that the permuter 83 supplies to the turbo decoder 110 is also supplied as input signal to a correlation filter 175 for the PN511 sequence included in the data field synchronization (DFS) signal of each 8-VSB data field. The correlation filter 175 determines when a PN511 sequence occurs, furnishing a ONE response indicative of such occurrence rather than its usual ZERO response. The correlation filter 175 is connected for supplying in its response to a modulo-eight DFS counter 176 for counting the ONEs in that response. A detector 177 for the Slot_number being 0000 in the response of the decoder 92 for TPC (18, 10) R-S FEC coding furnishes a ONE response indicative of such occurrence, rather than its usual ZERO response, which ONE provides an indication of when the M/H Frame has begun. The detector 177 is connected for supplying its response as reset signal for the DFS counter 176, each ONE in the detector 177 response resetting the DFS counter 176 modulo-eight count output to 000. The DFS counter 176 is connected to supply its DFS-count output to a 111 count detector 178 that generates a ZERO response to all values of that DFS-count output except 111. The 111 count detector 178 responds to the DFS-count output being 111 to generate a ONE response that indicates eight 8-VSB data fields have been completed since the detector 177 detected the Slot_number being 0000. The decoder 92 for TPC signal is likely to generate a 0000 Slot_number in the 17th data segment of the new 8-VSB data field. The 111 count detector 178 is connected to supply its response to the latch 174 as control signal. The latch 174 responds to a ONE response from the 111 count detector 178 to sample the then current count from the Group counter 173 and hold that count in the latch 174 response throughout the ensuing M/H sub-Frame, to be used as early TNoG. The 111 count detector 178 response is subjected to a short delay in circuitry 179, and the delayed response of the 111 count detector 178 is supplied from the circuitry 179 to the M/H Group counter 173 as reset signal. The count output from the M/H Group counter 173 is reset to 0000 responsive to a ONE in the delayed response of the 111 count detector 178. The delay provided by the circuitry 179 is long enough for the latch 174 to store the M/H Group count at the conclusion of the M/H sub-Frame before the M/H Group counter 173 is reset. However, this delay is short enough that the M/H Group counter 173 is reset before the correlation filter 172 might respond with a ONE to a sequence of prescribed symbols in the 15th and 16th segments of the new 8-VSB data field.

The selection of the symbols in the portions of the 15th and 16th data segments of each 8-VSB data field that the gate 170 selectively reproduces is controlled by a symbol counter (not explicitly shown in FIG. 33) in the M/H receiver. The selection of the symbols in the portions of the 171st and 172nd data segments of each 8-VSB data field that the gate 171 selectively reproduces is also controlled by the same symbol counter. It is convenient to synchronize the symbol counter with response from the correlation filter 175 that determines when a PN511 sequence occurs in a DFS signal.

FIG. 33 indicates that the response of the correlation filter 172 to the sequence of prescribed symbols that should precede the TPC and FIC signaling in each Group within an M/H sub-Frame is utilized for other purposess besides providing count input signal to the M/H Group counter 173. The response of the correlation filter 172 indicating that an M/H Group is present in a Slot is used as an enabling signal for other operations in the M/H receiver. The operations of the PCCC gate 87, the quarter-rate PCCC decoder 88, the TPC code gate 91 and the FIC code gate 93 occur at times determined by the symbol count from the symbol counter described in the previous paragraph. Such operations are conditional, however, taking place only when the correlation filter 172 indicates that an M/H Group is currently being received in a Slot. FIGS. 26A and 33 show the PCCC gate 87 and the PCCC decoder 88 as cascaded elements, to make it easier for the reader to understand M/H receiver operation. In alternative implementations, the PCCC decoder 88 receives its input signal directly from the trellis decoder 86, and the PCCC gating function is provided by selectively energizing the PCCC decoder 88.

FIGS. 34-48 illustrate various embodiments of pair of turbo decoders 110 and 120 operated in parallel for receiving one-third-code-rate CCC. In each of FIGS. 34-48 the specific embodiments of the turbo decoders 110 and 120 are more specifically identified as turbo decoders 110-N and 120-N, respectively, where N is an integer identifying the particular embodiments by number. The turbo decoder 110 comprises elements 111-118 and possibly 119, and the turbo decoder 120 comprises elements 121-128. The pair of turbo decoders 110 and 120 shown in any one of FIGS. 34-48 can each be of a type for decoding for SCCC. In such case the decoders for the outer convolutional code are connected for receiving soft decisions concerning 2-bit symbols in which the soft data bit precedes the soft parity bit. Each of the two turbo-decoding loops is closed by returning the re-interleaved soft parity bit from the decoder for the outer convolutional code to the decoder for the inner convolutional code, along with returning the re-interleaved soft data bit.

Alternatively, the pair of turbo decoders 110 and 120 shown in any one of FIGS. 34, 35, 36, 39, 41, 42, 45, 46 and 48 can each be of a type for decoding for PCCC. In such case the decoders for the outer convolutional code are connected for receiving soft decisions concerning 2-bit symbols in which the soft data bit succeeds the soft parity bit. Each of the two turbo-decoding loops is closed by returning the re-interleaved soft data bit from the decoder for the outer convolutional code to the decoder for the inner convolutional code.

The preparation of the baseband DTV signal to generate input signals for application to the turbo decoders 110 and 120 differs from that conventionally used for decoders of 8-VSB symbols. This is because, in accordance with an aspect of the invention, the CCC that the turbo decoders 110 and 120 are to decode is transmitted without interference-filter pre-coding of the Z-sub-2 bits of the 8-VSB symbols. The results of data-slicing the 8-level 8-VSB symbols in the baseband DTV signal are not delayed and modularly added to the undelayed results of data-slicing in order to recover Z-sub-2 bits, in a procedure referred to as “post-comb filtering”. The permuter 83 shown in FIG. 26A reproduces the results of 8-level data-slicing the 8-VSB symbols in the response of one of the adaptive equalization filters 77 and 81 for direct application to the turbo decoder 110 as its input signal. The permuter 83 also reproduces the results of 8-level data-slicing the 8-VSB symbols in the response of the other of the adaptive equalization filters 77 and 81 for application to the delay memory 106 as its input signal. The delay memory 106 delays its input signal by a prescribed number of M/H Slots in its response supplied as input signal to the turbo decoder 120.

The fundamental approach used for iterative-diversity reception is to delay initial-component transmissions so that they can be decoded contemporaneously with the final-component transmissions. This facilitates the exchange of information between the turbo decoder 110 for final-component transmissions and the turbo decoder 120 for initial-component transmissions. The delay memory 106 is written with the initial-component transmissions of diversity M/H data supplied from the permuter 83, temporarily storing each of them until the corresponding final-component transmission of that data is supplied from the permuter 83 to the turbo decoder 110 for final-component transmissions. This same approach can be taken for frequency-diversity reception of the two 8-VSB transmitters transmitting similar programming both supply iterative-diversity transmissions. Using the initial-component transmission from one of the 8-VSB transmitters with the final-component transmission from the other 8-VSB transmitter can help overcome simultaneous loss of received signal strength in both RF channels when a mobile receiver is transported through a tunnel, for example.

If both of the 8-VSB transmitters make only single-time transmissions staggered in time respective to each other, the cascade 76 of memories delays the earlier arriving signal to be contemporaneous with the later arriving signal for application to the permuter 83. The permuter 83 supplies the later arriving signal to the turbo decoder 110 and the earlier arriving signal to the turbo decoder 120 with the delay memory 106 being inoperative to delay application of the earlier arriving signal to the turbo decoder 120. When alternatively the initial-component transmission from one of the 8-VSB transmitters is combined with the final-component transmission from the other 8-VSB transmitter, the cascade 76 of memories delays the final-component transmissions from the two transmitters to be contemporaneous with each other as supplied to the permuter 83. The permuter 83 applies the final-component transmission from one of the 8-VSB transmitters to the turbo decoder 110 and applies the initial-component transmission from the other 8-VSB transmitter to the turbo decoder 120 via the delay memory 106. The delay memory 106 is operated to supply the bulk of the delay associated with the iterative diversity of that other 8-VSB transmitter.

FIG. 34 depicts a first arrangement of the generic turbo decoders 110 and 120, in which specific turbo decoders 110-2 and 120-2 are operable in parallel for receiving one-third-code-rate CCC. The SISO decoder 111 for 12-phase trellis coding decodes the inner convolutional coding of the final transmissions for iterative-diversity reception and has an input/output unit 112 for communicating with memory within the decoder 111. A portion of this memory within the decoder 111 temporarily stores soft decisions concerning 8-VSB symbols that the SISO decoder uses for soft input symbols. The successive soft input symbols from the permuter 83 are written to this portion of the memory within the decoder 111 via the input/output unit 112 for communicating with that memory. Another portion of the memory within the decoder 111 temporarily stores soft output symbols that the decoder 111 generates by decoding the 2/3 trellis coding of the 8-VSB symbols. Yet another portion of the memory within the decoder 111 temporarily stores soft extrinsic data derived from the results of the decoding of outer convolutional coding of the CCC. The decoder 111 combines the soft extrinsic data with the soft input symbols originally received from the permuter 83; this is done to update the signal that the decoder 111 attempts to decode. The decoder 111 also combines the soft extrinsic data with the soft output symbols resulting from its decoding PCCC to remove extrinsic data artifacts therefrom.

The SISO decoder 111 supplies soft decisions concerning the interleaved outer convolutional coding of the final transmissions via its input/output unit 112 to the input port of a binary-to-Gray-code converter 113 to be Gray-code labeled. The output port of the binary-to-Gray-code converter 113 is connected for supplying Gray-code-labeled soft decisions concerning the interleaved outer convolutional coding to the input port of a symbol de-interleaver 114 for soft 2-bit symbols. The output port of the symbol de-interleaver 114 is connected for supplying de-interleaved soft decisions concerning the outer convolutional coding extracted from final-component transmissions to the input port of a SISO decoder 115 for one-half-rate outer convolutional coding. A symbol re-interleaver 116 for soft 2-bit symbols is connected for re-interleaving the pairs of soft bits that the SISO decoder 115 supplies via its output port. The output port of the symbol re-interleaver 116 is connected to the input port of a Gray-to-binary-code converter 117. The Gray-to-binary-code converter 117 is operable for converting the re-interleaved pairs of Gray-code-labeled soft bits received from the symbol re-interleaver 116 back to the natural-binary-coded regime employed by the SISO decoder 111 for 12-phase trellis coding.

The SISO decoder 115 includes memory, a portion of which memory temporarily stores soft symbols of the de-interleaved outer convolutional coding of the CCC that the symbol de-interleaver 114 supplies the decoder 115 as input signal. By suitably controlling the write addressing and the read addressing of this portion of memory within the decoder 115 the symbol de-interleaver 114 can be at least partially subsumed within this portion of memory within the decoder 115. Another portion of the memory included within the SISO decoder 115 temporarily stores soft output symbols that the decoder 115 generates from decoding the de-interleaved outer convolutional coding. By suitably controlling the write addressing and the read addressing of this other portion of memory within the decoder 115 the symbol re-interleaver 116 can be at least partially subsumed within this other portion of memory within the decoder 115.

The SISO decoder 121 for 12-phase trellis coding decodes the inner convolutional coding of the initial transmissions for iterative-diversity reception and has an input/output unit 122 for communicating with memory within the decoder 121. A portion of this memory within the decoder 121 temporarily stores soft decisions concerning 8-VSB symbols that the SISO decoder uses for soft input symbols. The successive soft input symbols from the delay memory 106 are written to this portion of the memory within the decoder 111 via the input/output unit 122 for communicating with that memory. Another portion of this memory within the decoder 121 temporarily stores soft output symbols that the decoder 121 generates by decoding the 2/3 trellis coding of the 8-VSB symbols. Yet another portion of the memory within the decoder 121 temporarily stores soft extrinsic data derived from the results of the decoding of outer convolutional coding of the CCC. The decoder 121 combines the soft extrinsic data with the soft input symbols originally received from the delay memory 106; this is done to update the signal that the decoder 121 attempts to decode. The decoder 121 also combines the soft extrinsic data with the soft output symbols resulting from its decoding PCCC to remove extrinsic data artifacts therefrom.

The SISO decoder 121 Is connected for supplying soft decisions concerning the interleaved outer convolutional coding of the initial transmissions via its input/output unit 122 to the input port of a binary-to-Gray-code converter 123 to be Gray-code labeled. The output port of the binary-to-Gray-code converter 123 is connected for supplying Gray-code-labeled soft decisions concerning the interleaved outer convolutional coding to the input port of a symbol de-interleaver 124 for soft 2-bit symbols. The output port of the symbol de-interleaver 124 is connected for supplying de-interleaved soft decisions concerning the outer convolutional coding extracted from initial-component transmission to the input port of a SISO decoder 125 for one-half-rate outer convolutional coding. The SISO decoder 125 has an output port connected for supplying soft decisions concerning de-interleaved M/H data bits, each of which soft bits is accompanied by another soft bit of associated parity in the one-half-rate outer convolutional coding. A symbol re-interleaver 126 for soft 2-bit symbols is connected for re-interleaving the pairs of soft bits in soft decisions that the decoder 125 supplies via its output port. The output port of the symbol re-interleaver 126 is connected to the input port of a Gray-to-binary-code converter 127. The Gray-to-binary-code converter 127 is operable for converting the re-interleaved pairs of Gray-code-labeled soft bits received from the symbol re-interleaver 126 back to the natural-binary-coded regime employed by the SISO decoder 121 for 12-phase trellis coding.

The SISO decoder 125 includes memory, a portion of which memory temporarily stores soft symbols of the de-interleaved outer convolutional coding of the CCC that the symbol de-interleaver 124 supplies the decoder 125 as input signal. By suitably controlling the write addressing and the read addressing of this portion of memory within the decoder 125 the symbol de-interleaver 124 can be at least partially subsumed within this portion of memory within the decoder 125. Another portion of the memory included within the SISO decoder 125 temporarily stores soft output symbols that the decoder 125 generates from decoding the de-interleaved outer convolutional coding. By suitably controlling the write addressing and the read addressing of this other portion of memory within the decoder 125 the symbol re-interleaver 126 can be at least partially subsumed within this other portion of memory within the decoder 125.

The soft-input, soft-output (SISO) decoders 111, 121, 115 and 125 may employ a soft-output Viterbi algorithm (SOVA) for evaluating code trellises, but preferably employ a log-MAP algorithm for such evaluations. Insofar as turbo decoding procedures are concerned, the SISO decoders 111 and 121 decode inner convolutional coding and are alike in construction. The decoders 115 and 125 decode outer convolutional coding and are alike in construction. The operations of the SISO decoders 111 and 115 in the turbo-decoding loop for one-time or final-component transmissions are staggered in time. So, although FIG. 34 shows separate inner decoder 111 and outer decoder 115, in actual practice the decoders 111 and 115 are apt to use a common arithmetic/logic unit (ALU) on a time-share basis. The operations of the SISO decoders 121 and 125 in the turbo-decoding loop for initial-component transmissions are also staggered in time. So, although FIG. 34 shows separate inner decoder 121 and outer decoder 125, in actual practice the decoders 121 and 125 are apt to use a common ALU on a time-share basis.

Each of the Gray-to-binary-code converters 116 and 126 is connected to supply its soft data bits of turbo feedback signal to the information-exchange unit 107 for exchanging information regarding data bits between the turbo-decoding loops of the turbo decoders 110-1 and 120-1. The contemporaneous data bits from the Gray-to-binary-code converters 116 and 126 should be ones' complements of each other, at least during iterative-diversity reception, since the data in the initial-component transmission of an iterative-diversity transmission are the one's complements of the data in the initial-component transmission of an iterative-diversity transmission. If the contemporaneous soft data bits from the Gray-to-binary-code converters 116 and 126 have hard-decision values that are the same, one of the two hard-decision values is correct, and the other is erroneous. So, the confidence levels of the two soft data bits are reduced, at least unless the confidence level of one of the soft data bits is much higher than that of the other. If the confidence level of one of the soft data bits is much higher than that of the other, the hard-decision value of that other soft data bit may be one's complemented for the next iteration of the turbo decoding procedure. If the contemporaneous soft data bits from the Gray-to-binary-code converters 116 and 126 have different hard-decision values, either both of the two hard-decision values are correct, or both of them are erroneous. If the confidence level of at least one of the soft data bits is reasonably high, the confidence levels of both the soft data bits can be incrementally increased. If the confidence levels of both of the soft data bits are low, those confidence levels can just be maintained.

An extrinsic data feedback processor 118 generates the extrinsic data fed back to the input/output unit 112 of the SISO decoder 111. If the turbo decoder 110-1 is used for decoding SCCC, the information-exchange unit 107 reproduces the soft parity bits from the Gray-to-binary-code converter 116. These soft parity bits are applied to a first input port of the extrinsic data feedback processor 118 together with the soft data bits resulting from exchanging information concerning the confidence levels of soft data bits between the respective turbo-decoding loops of the turbo decoders 110-1 and 120-1. The soft decisions regarding 2-bit symbols applied to the first input port of the extrinsic data feedback processor 118 are differentially compared to previous soft decisions regarding the same 2-bit symbols. Those previous soft decisions are supplied to a second input port of the extrinsic data feedback processor 118 from memory within the SISO decoder 111. The results of the differential comparison by the extrinsic data feedback processor 118 are supplied to input/output unit 112 to be forwarded to the SISO decoder 111 for updating soft decisions regarding the 2-bit symbols temporarily stored by memory therein. If the turbo decoder 110-1 is used for decoding PCCC, the information-exchange unit 107 does not need to reproduce the soft parity bits from the Gray-to-binary-code converter 116. The information-exchange unit 107 supplies a first input port of the extrinsic data feedback processor 118 with just the soft data bits resulting from exchanging information concerning the confidence levels of soft data bits between the respective turbo-decoding loops of the turbo decoders 110-1 and 120-1. The output port of the re-interleaver 116 is connected to supply soft 2-bit symbols of the outer convolutional coding as processed by the SISO decoder 115 to the hard-decision unit 108 and to the battery 132 of XOR gates shown in FIG. 26C.

An extrinsic data feedback processor 128 generates the extrinsic data fed back to the input/output unit 122 of the SISO decoder 121. If the turbo decoder 120-1 is used for decoding SCCC, the information-exchange unit 107 reproduces the soft parity bits from the Gray-to-binary-code converter 126. These soft parity bits are applied to a first input port of the extrinsic data feedback processor 128 together with the soft data bits resulting from exchanging information concerning the confidence levels of soft data bits between the respective turbo-decoding loops of the turbo decoders 110-1 and 120-1. The soft decisions regarding 2-bit symbols applied to the first input port of the extrinsic data feedback processor 128 are differentially compared to previous soft decisions regarding the same 2-bit symbols. Those previous soft decisions are supplied to a second input port of the extrinsic data feedback processor 128 from memory within the SISO decoder 121. The results of the differential comparison by the extrinsic data feedback processor 128 are supplied to input/output unit 122 to be forwarded to the SISO decoder 121 for updating soft decisions regarding the 2-bit symbols temporarily stored by memory therein. If the turbo decoder 120-1 is used for decoding PCCC, the information-exchange unit 107 does not need to reproduce the soft parity bits from the Gray-to-binary-code converter 126. The information-exchange unit 107 supplies a first input port of the extrinsic data feedback processor 128 with just the soft data bits resulting from exchanging information concerning the confidence levels of soft data bits between the respective turbo-decoding loops of the turbo decoders 110-1 and 120-1.

FIG. 35 depicts a second arrangement of the generic turbo decoders 110 and 120, in which specific turbo decoders 110-2 and 120-2 are operable in parallel for receiving one-third-code-rate CCC. The FIG. 35 arrangement differs from the FIG. 34 arrangement in that the information-exchange unit 107 is relocated to precede, rather than succeed, the Gray-to-binary-code re-mappers 117 and 127. The information-exchange unit 107 is connected for receiving contemporaneous soft 2-bit symbols from the output ports of the soft-symbol re-interleavers 116 and 126. If the pair of turbo decoders 110-2 and 120-2 are operated in parallel for receiving one-third-code-rate PCCC, the FIG. 34 arrangement avoids the need for the information-exchange unit 107 to pass along soft parity bits to the extrinsic data feedback processors 118 and 128. In the FIG. 35 arrangement the information-exchange unit 107 has to pass along soft parity bits to the Gray-to-binary-code re-mappers 117 and 127 as well as supplying those re-mappers with adjusted soft data bits. The extrinsic data feedback processor 118 is connected for receiving turbo feedback from the output port of the Gray-to-binary-code re-mapper 117. The extrinsic data feedback processor 128 is connected for receiving turbo feedback from the output port of the Gray-to-binary-code re-mapper 127.

FIG. 36 depicts a third arrangement of the generic turbo decoders 110 and 120, in which specific turbo decoders 110-3 and 120-3 are operable in parallel for receiving one-third-code-rate CCC. In the FIG. 36 embodiment the information-exchange unit 107 is relocated to follow the decoders 115 and 125 and to precede the soft-symbol re-interleavers 116 and 126 as well as the Gray-to-binary-code re-mappers 117 and 127. The FIG. 36 embodiment does not allow the soft-symbol re-interleaver 116 to be subsumed into the memory within the decoder 115. Nor does it allow the soft-symbol re-interleaver 126 to be subsumed into the memory within the decoder 125.

FIG. 37 depicts a fourth arrangement of the generic turbo decoders 110 and 120, in which specific turbo decoders 110-4 and 120-4 are operable in parallel for receiving one-third-code-rate SCCC. This fourth arrangement is a modification of FIG. 36 arrangement, in which modification Gray-to-binary-code re-mapping is performed before, rather than after, soft-symbol re-interleaving. The information-exchange unit 107 is connected for receiving contemporaneous soft 2-bit symbols from the output ports of the decoders 115 and 125 for outer convolutional coding. The information-exchange unit 107 is connected for supplying adjusted soft 2-bit symbols to the Gray-to-binary-code re-mapper 127 which supplies soft 2-bit symbols re-mapped to the natural-binary-coding regime to the soft-symbol re-interleaver 127 and thence to the extrinsic data feedback processor 128. Furthermore, the information-exchange unit 107 is connected for supplying adjusted soft 2-bit symbols to the Gray-to-binary-code re-mapper 117 which supplies soft 2-bit symbols re-mapped to the natural-binary-coding regime to the soft-symbol re-interleaver 116 and thence to the extrinsic data feedback processor 118. Gray-to-binary-code re-mapping does not affect the Z-sub-1 data bits of SCCC, so the soft-symbol re-interleaver 116 is connected for supplying soft data bits to the hard-decision unit 108 as input signal thereto. Gray-to-binary-code re-mapping does affect the Z-sub-2 data bits of PCCC, however, which is why the FIG. 37 arrangement is not used for decoding PCCC.

FIG. 38 depicts a fifth arrangement of the generic turbo decoders 110 and 120, in which specific turbo decoders 110-5 and 120-5 are operable in parallel for receiving one-third-code-rate CCC. The FIG. 38 arrangement differs from the FIG. 37 arrangement in that the input port of the hard-decision unit 108 and the battery 132 of XOR gates are connected to receive soft data bits from the output port of the binary-to-Gray-code converter 113, rather than from the output port of the soft-symbol re-interleaver 116. The FIG. 38 arrangement can be used for decoding PCCC, in which case the soft data bits supplied to the input ports of the hard-decision unit 108 and the battery 132 of XOR gates are Gray-labeled Z-sub-1 bits. Alternatively, the FIG. 38 arrangement can be used for decoding SCCC, in which case the soft data bits supplied to the input port of the hard-decision unit 108 and the battery 132 of XOR gates are Z-sub-2 bits. However, as compared to the FIG. 37 arrangement, the soft Z-sub-2 bits are apt to be delayed an extra half cycle of turbo decoding by processing through the SISO decoder 111, which extra half cycle of turbo decoding does not improve the decoding of the Z-sub-2 bits.

FIG. 39 depicts a sixth arrangement of the generic turbo decoders 110 and 120, in which specific turbo decoders 110-6 and 120-6 are operable in parallel for receiving one-third-code-rate CCC. The FIG. 39 arrangement is a modification of FIG. 34 arrangement, in which modification one half 107A of the information-exchange unit 107 is relocated to precede the decoder 115 for outer convolutional coding. The other half 107B of the information-exchange unit 107 is relocated to precede the decoder 125 for outer convolutional coding. The extrinsic data feedback processor 118 is connected for receiving turbo feedback from the output port of the Gray-to-binary-code re-mapper 117. The extrinsic data feedback processor 128 is connected for receiving turbo feedback from the output port of the Gray-to-binary-code re-mapper 127. The halves 107A and 107B of the information-exchange unit 107 are connected for supplying respective successions of adjusted de-interleaved soft 2-bit symbols to the input ports of decoders 115 and 125 for outer convolutional coding.

FIG. 39 modifies the FIG. 34 arrangement in further ways. The cascade connection of the binary-to-Gray-code re-mapper 113 and the soft-symbol de-interleaver 114 is modified so the soft symbol de-interleaver 114 precedes, rather than succeeds, the binary-to-Gray-code re-mapper 113. The cascade connection of the binary-to-Gray-code re-mapper 123 and the soft-symbol de-interleaver 124 is modified so the soft-symbol de-interleaver 124 precedes, rather than succeeds, the binary-to-Gray-code re-mapper 123. The halves 107A and 107B of the information-exchange unit 107 are connected for receiving contemporaneous soft 2-bit symbols from the output ports of the binary-to-Gray-code re-mappers 113 and 123, respectively. These modifications facilitate the still further modifications described in the next paragraph.

The soft-symbol de-interleaver 116 can be subsumed into the memory within the decoder 111, and the soft-symbol de-interleaver 114 can be subsumed into the memory within the decoder 121. FIG. 39 shows the input/output unit 112 for communicating with memory within the decoder 111 having an output port connected to the input port of the extrinsic data feedback processor 118 and another output port connected to the input port of the soft-symbol de-interleaver 114. FIG. 39 further shows the input/output unit 122 for communicating with memory within the decoder 121 having an output port connected to the input port of the extrinsic data feedback processor 128 and another output port connected to the input port of the soft-symbol de-interleaver 124. The memories within the decoders 111 and 121 can share an address generator for conducting their respective operations when generating extrinsic data feedback for each of them. These respective operations are carried out with symbol-interleaved symbols of outer convolutional coding supplied to the input ports of the extrinsic data feedback processors 118 and 128, rather than with de-interleaved symbols of outer convolutional coding. The memories within the decoders 111 and 121 can share another address generator for conducting their respective de-interleaving operations. If the soft-symbol de-interleaver 114 is subsumed into the memory within the decoder 111, a respective output port of the input/output unit 112 for communicating with that memory is connected for supplying the input port of the binary-to-Gray-code re-mapper 113 with de-interleaved symbols of outer convolutional coding. If the soft-symbol de-interleaver 124 is subsumed into the memory within the decoder 121, a respective output port of the input/output unit 122 for communicating with that memory is connected for supplying the input port of the binary-to-Gray-code re-mapper 123 with de-interleaved symbols of outer convolutional coding.

FIG. 40 depicts a seventh arrangement of the generic turbo decoders 110 and 120, in which specific turbo decoders 110-7 and 120-7 are operable in parallel for receiving one-third-code-rate SCCC. The FIG. 40 arrangement is a modification of the FIG. 39 arrangement, in which modification Gray-to-binary-code re-mapping is performed before, rather than after, soft-symbol re-interleaving. The cascade connection of the soft-symbol re-interleaver 116 and the Gray-to-binary-code re-mapper 117 is modified so the Gray-to-binary-code re-mapper 117 precedes, rather than succeeds, the soft-symbol re-interleaver 116. The cascade connection of the soft-symbol re-interleaver 126 and the Gray-to-binary-code re-mapper 127 is modified so the Gray-to-binary-code re-mapper 127 precedes, rather than succeeds, the soft-symbol re-interleaver 126. Gray-to-binary-code re-mapping does not affect the Z-sub-1 data bits of SCCC, so the soft-symbol re-interleaver 116 is connected for supplying soft data bits to the hard-decision unit 108 and the battery 132 of XOR gates as input signal thereto. Gray-to-binary-code re-mapping does affect the Z-sub-2 data bits of PCCC, however, which is why the FIG. 40 arrangement is not used for decoding PCCC. The FIG. 40 arrangement allows both the soft-symbol de-interleaver 114 and the soft-symbol re-interleaver 116 to be subsumed into the memory within the decoder 111, sharing address generators. Also, the FIG. 40 arrangement allows both the soft-symbol de-interleaver 124 and the soft-symbol re-interleaver 126 to be subsumed into the memory within the decoder 121, sharing address generators. Furthermore, the decoders 111 and 121 can share an address generator for de-interleaving operations and can share another address generator for re-interleaving operations.

FIG. 41 depicts an eighth arrangement of the generic turbo decoders 110 and 120, in which specific turbo decoders 110-8 and 120-8 are operable in parallel for receiving one-third-code-rate CCC. The FIG. 41 arrangement differs from the FIG. 40 arrangement in the following respects. The input ports of the hard-decision unit 108 and the battery 132 of XOR gates are connected to receive soft data bits from the output port of a binary-to-Gray-code converter 119. The input port of the binary-to-Gray-code converter 119 is supplied soft symbols of outer convolutional coding from the input/output unit 112 for communicating with memory within the decoder 111. The FIG. 41 arrangement can be used for decoding PCCC, in which case the soft data bits supplied to the input ports of the hard-decision unit 108 and the battery 132 of XOR gates are Gray-labeled Z-sub-1 bits. Alternatively, the FIG. 41 arrangement can be used for decoding SCCC, in which case the soft data bits supplied to the input ports of the hard-decision unit 108 and the battery 132 of XOR gates are Z-sub-2 bits. However, as compared to the FIG. 40 arrangement the soft Z-sub-2 bits are apt to be delayed an extra half cycle of turbo decoding by processing through the SISO decoder 111, which extra half cycle of turbo decoding does not improve the decoding of the Z-sub-2 bits.

FIG. 42 depicts a ninth arrangement of the generic turbo decoders 110 and 120, in which specific turbo decoders 110-9 and 120-9 are operable in parallel for receiving one-third-code-rate CCC. This ninth arrangement is a modification of the FIG. 34 arrangement, in which modification one half 107A of the information-exchange unit 107 is relocated between the output port of the binary-to-Gray-code re-mapper 113 and the input port of the soft-symbol de-interleaver 114. The other half 107B of the information-exchange unit 107 is relocated between the output port of the binary-to-Gray-code re-mapper 123 and the input port of the soft-symbol de-interleaver 124. The extrinsic data feedback processor 118 is connected for receiving turbo feedback from the output port of the Gray-to-binary-code re-mapper 117. The extrinsic data feedback processor 128 is connected for receiving turbo feedback from the output port of the Gray-to-binary-code re-mapper 127.

FIG. 43 depicts a tenth arrangement of the generic turbo decoders 110 and 120, in which specific turbo decoders 110-10 and 120-10 are operable in parallel for receiving one-third-code-rate CCC. The FIG. 43 arrangement is a modification of the FIG. 42 arrangement, in which modification the positions of the binary-to-Gray-code re-mapper 113 and the soft-symbol de-interleaver 114 are interchanged, and in which the positions of the binary-to-Gray-code re-mapper 123 and the soft-symbol de-interleaver 124 are interchanged. The soft-symbol re-interleaver 116 can still be subsumed into the memory within the decoder 115, but the soft-symbol de-interleaver 114 cannot. The soft-symbol re-interleaver 126 can still be subsumed into the memory within the decoder 125, but the soft-symbol de-interleaver 114 cannot. The soft-symbol de-interleaver 114 can be subsumed into the memory within the decoder 111, and the soft-symbol de-interleaver 124 can be subsumed into the memory within the decoder 121. Memories in the decoders 111 and 121 can share the same address generators for de-interleaving operations.

FIG. 44 depicts an eleventh arrangement of the generic turbo decoders 110 and 120, in which specific turbo decoders 110-11 and 120-11 are operable in parallel for receiving one-third-code-rate SCCC. The FIG. 44 arrangement is a modification of the FIG. 43 arrangement, in which modification Gray-to-binary-code re-mapping is performed before, rather than after, soft-symbol re-interleaving. The cascade connection of the soft-symbol re-interleaver 116 and the Gray-to-binary-code re-mapper 117 is modified so the Gray-to-binary-code re-mapper 117 precedes, rather than succeeds, the soft-symbol re-interleaver 116. The cascade connection of the soft-symbol re-interleaver 126 and the Gray-to-binary-code re-mapper 127 is modified so the Gray-to-binary-code re-mapper 127 precedes, rather than succeeds, the soft-symbol re-interleaver 126. Gray-to-binary-code re-mapping does not affect the Z-sub-1 data bits of SCCC, so the soft-symbol re-interleaver 116 is connected for supplying soft data bits to the hard-decision unit 108 and the battery 132 of XOR gates as input signals thereto. Gray-to-binary-code re-mapping does affect the Z-sub-1 data bits of PCCC, however, which is why the FIG. 44 arrangement is not used for decoding PCCC. These modifications facilitate the following still further modifications. The soft-symbol re-interleaver 116 as well as the soft-symbol de-interleaver 114 can be subsumed into the memory within the decoder 111, sharing address generators. The soft-symbol re-interleaver 126 as well as the soft-symbol re-interleaves 124 can be subsumed into the memory within the decoder 121, sharing address generators. Furthermore, the decoders 111 and 121 can share the same address generators for de-interleaving and re-interleaving operations.

FIG. 45 depicts a twelfth arrangement of the generic turbo decoders 110 and 120, in which specific turbo decoders 110-12 and 120-12 are operable in parallel for receiving one-third-code-rate CCC. The FIG. 45 arrangement is a modification of the FIG. 44 arrangement, in which modification binary-to-Gray-code re-mapping and soft-symbol de-interleaving are performed before and after the information-exchange unit 107, respectively. The soft-symbol de-interleavers 114 and 124 are relocated to follow the information-exchange unit 107 and to precede the SISO decoders 115 and 125, respectively, used for decoding de-interleaved outer convolutional coding of the CCC. The binary-to-Gray-code re-mappers 113 and 123 are relocated to precede the information-exchange unit 107. The binary-to-Gray-code re-mapper 113 is connected for supplying the information-exchange unit 107 the first input signal thereto, responsive to binary-coded outer convolutional coding with implied symbol interleaving that the re-mapper 113 receives from the input/output unit 112 for memory within the SISO decoder 111. The binary-to-Gray-code re-mapper 123 is connected for supplying the information-exchange unit 107 the second input signal thereto, responsive to binary-coded outer convolutional coding with implied symbol interleaving that the re-mapper 123 receives from the input/output unit 122 for memory within the SISO decoder 121. The binary-to-Gray-code re-mapper 113 is further connected so soft data bits from its response are supplied to the hard-decision unit 108 and the bank 132 of XOR gates as input signals thereto.

FIG. 46 depicts a thirteenth arrangement of the generic turbo decoders 110 and 120, in which specific turbo decoders 110-13 and 120-13 are operable in parallel for receiving one-third-code-rate CCC. The FIG. 46 arrangement is a modification of the FIG. 34 arrangement, in which modification one half 107A of the information-exchange unit 107 is relocated between an output port of the input/output unit 112 and the input port of the binary-to-Gray-code re-mapper 113. The other half 107B of the information-exchange unit 107 is relocated between an output port of the input/output unit 122 and the input port of the binary-to-Gray-code re-mapper 123. The extrinsic data feedback processor 118 is connected for receiving turbo feedback from the output port of the Gray-to-binary-code re-mapper 117. The extrinsic data feedback processor 128 is connected for receiving turbo feedback from the output port of the Gray-to-binary-code re-mapper 127.

FIG. 47 depicts a fourteenth arrangement of the generic turbo decoders 110 and 120, in which specific turbo decoders 110-14 and 120-14 are operable in parallel for receiving one-third-code-rate SCCC. The FIG. 47 arrangement is a modification of FIG. 37 arrangement, in which modification one half 107A of the information-exchange unit 107 is relocated between an output port of the input/output unit 112 and the input port of the binary-to-Gray-code re-mapper 113. The other half 107B of the information-exchange unit 107 is relocated between the output port of the input/output unit 122 and the input port of the binary-to-Gray-code re-mapper 123. The extrinsic data feedback processor 118 is connected for receiving turbo feedback from the output port of the Gray-to-binary-code re-mapper 117. The extrinsic data feedback processor 128 is connected for receiving turbo feedback from the output port of the Gray-to-binary-code re-mapper 127.

FIG. 48 depicts a fifteenth arrangement of the generic turbo decoders 110 and 120, in which specific turbo decoders 110-15 and 120-15 are operable in parallel for receiving one-third-code-rate CCC. The FIG. 48 arrangement differs from the FIG. 47 arrangement in that the input ports of the hard-decision unit 108 and the bank 132 of XOR gates are connected to receive soft data bits from the output port of the binary-to-Gray-code converter 113. This, rather than from the output port of the soft-symbol re-interleaver 116. The FIG. 48 arrangement can be used for decoding PCCC, in which case the soft data bits supplied to the input ports of the hard-decision unit 108 and the bank 132 of XOR gates are Gray-labeled Z-sub-1 bits. Alternatively, the FIG. 48 arrangement can be used for decoding SCCC, in which case the soft data bits supplied to the input ports of the hard-decision unit 108 and the bank 132 of XOR gates are Z-sub-2 bits. However, as compared to the FIG. 47 arrangement the soft Z-sub-2 bits are apt to be delayed an extra half cycle of turbo decoding by processing through the SISO decoder 111, which extra half cycle of turbo decoding does not improve the decoding of the Z-sub-2 bits.

The soft-symbol de-interleaver 114 and the soft-symbol de-interleaver 124 use respective memories that can be addressed in common with each other. The arrangements of FIGS. 34, 35, 36, 37, 38, 42, 43, 45, 46, 47 and 48 can be constructed such that the soft-symbol de-interleaver 114 is subsumed into the memory within the decoder 115 and the soft-symbol de-interleaver 124 is subsumed into the memory within the decoder 125. The arrangements of FIGS. 39, 40, 41 and 44 can be constructed such that the soft-symbol de-interleaver 114 is subsumed into the memory within the decoder 111 and the soft-symbol de-interleaver 124 is subsumed into the memory within the decoder 121.

The soft-symbol re-interleaver 116 and the soft-symbol re-interleaver 126 use respective memories that can be addressed in common with each other. The arrangements of FIGS. 34, 35, 39, 42, 43 and 45 can be constructed such that the soft-symbol re-interleaver 116 is subsumed into the memory within the decoder 115 and the soft-symbol re-interleaver 126 is subsumed into the memory within the decoder 125. The arrangements of FIGS. 37, 38, 40, 41, 44, 46 and 47 can be constructed such that the soft-symbol de-interleaver 114 is subsumed into the memory within the decoder 111 and the soft-symbol de-interleaver 124 is subsumed into the memory within the decoder 121.

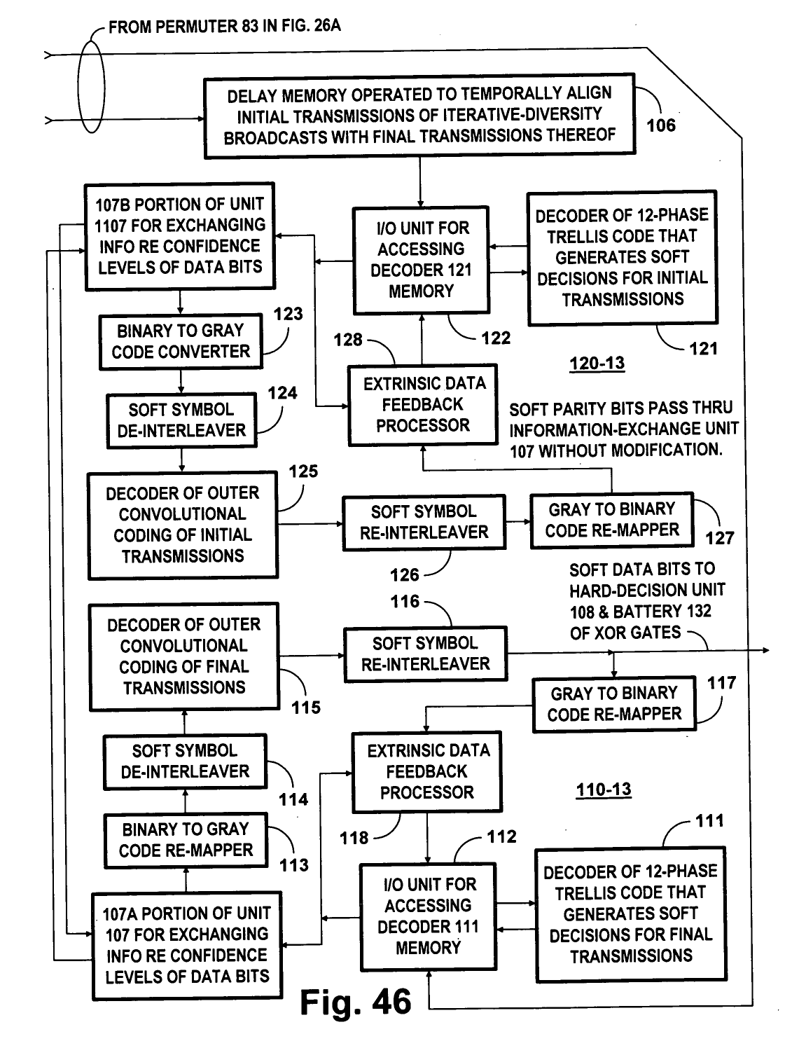

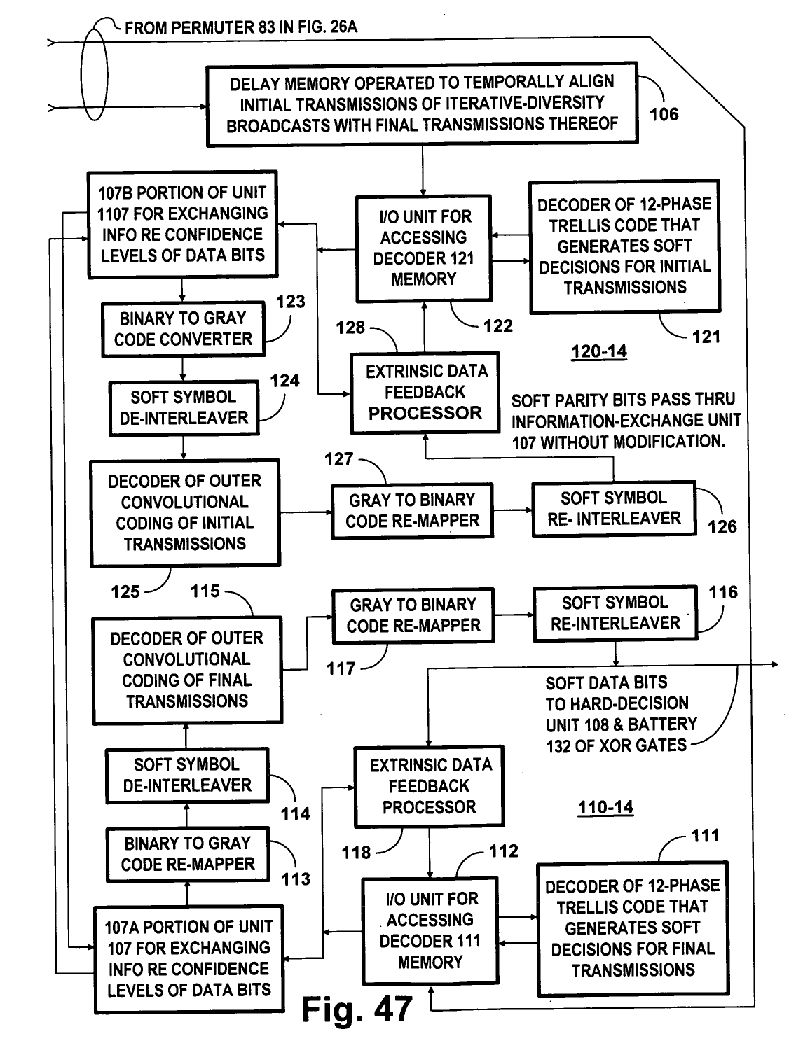

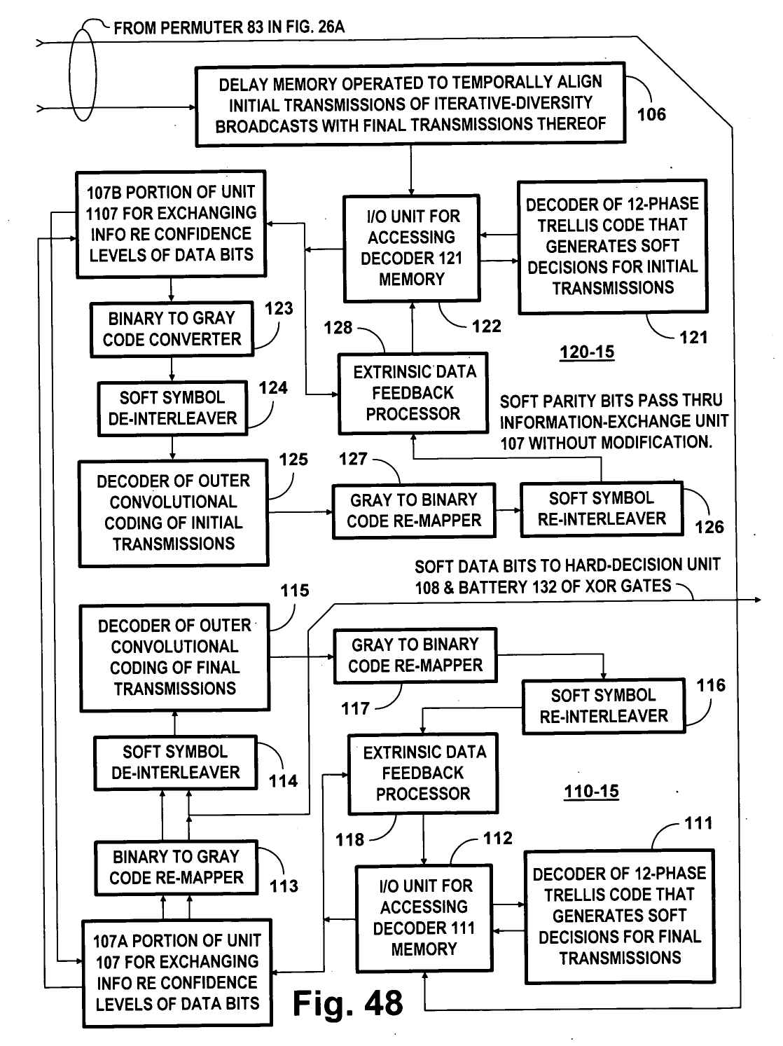

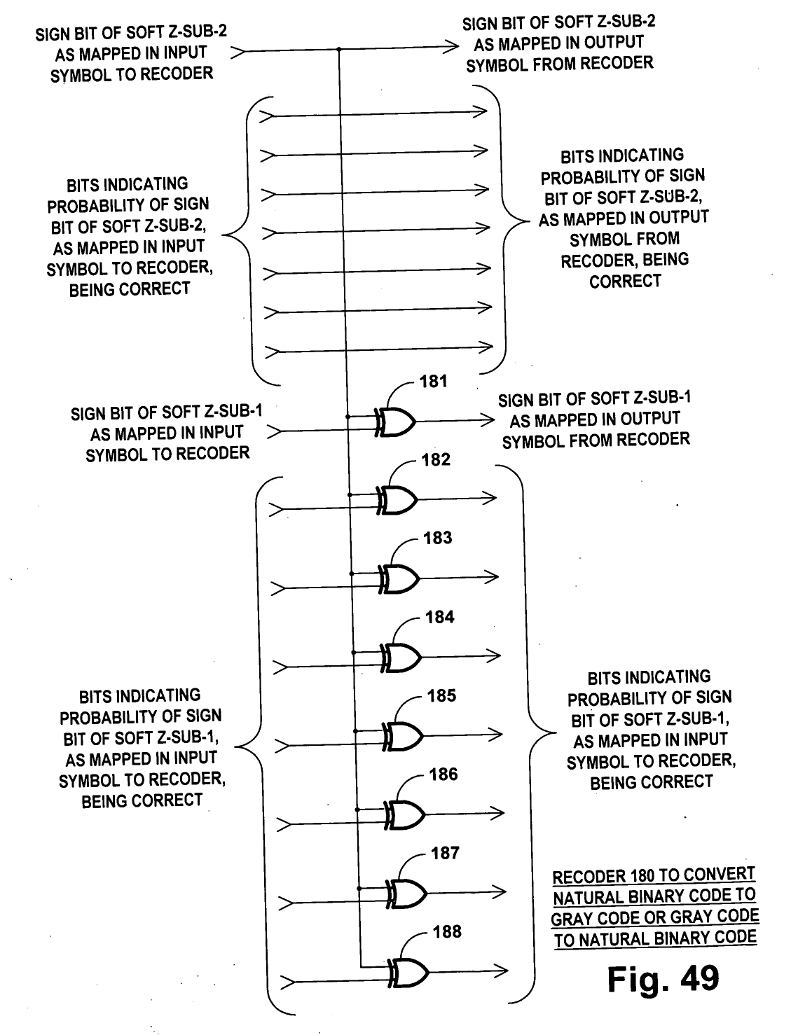

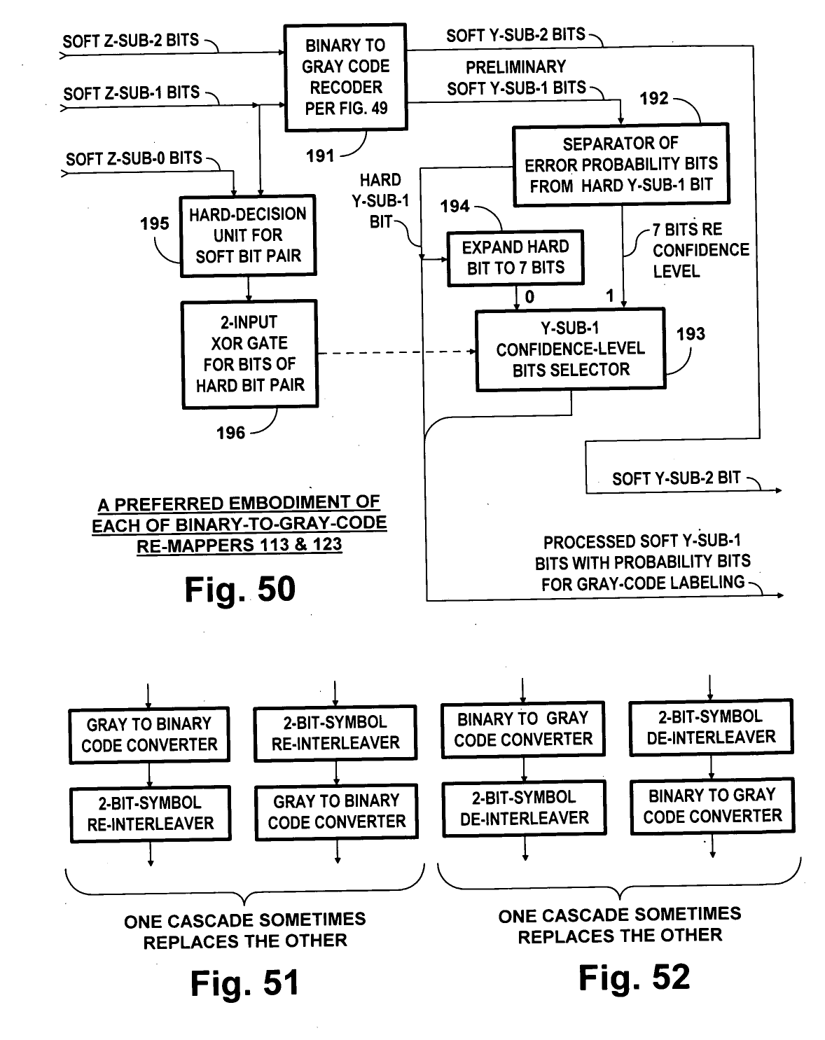

FIG. 49 shows a recoder 180 composed of simple logic circuitry. The recoder 180 can be used as a natural-binary-code-to-reflected-binary-code converter for soft 2-bit symbols. So, the binary-to-Gray-code re-mappers 113 and 123 can each be constructed like the recoder 180. The recoder 180 can be used alternatively as a reflected-binary-code-to-natural-binary-code converter for soft 2-bit symbols. So, the Gray-to-binary-code re-mappers 117 and 127 can each be constructed like the recoder 180. Supposing the 2-bit symbols to be composed of a soft Z-sub-2 “more significant” bit and a soft Z-sub-1 “less significant” bit when natural-binary-coded, the soft Z-sub-2 bit stays the same when Gray-coded, but the soft Z-sub-1 bits are “reflected”. Positive-going amplitude modulation of the 8-VSB AM signal is associated with the recoded Z-sub-2 “hard” bit being a logic ONE, and negative-going amplitude modulation of the 8-VSB AM signal is associated with the recoded Z-sub-2 bit “hard” being a logic ZERO. Irrespective of the sense of modulation, the Z-sub-1 “hard” bit of a Gray-coded symbol being a logic ONE is associated with lesser amplitude modulation of the 8-VSB AM signal. The Z-sub-1 “hard” bit of a Gray-coded symbol being a logic ZERO is associated with greater amplitude modulation of the 8-VSB AM signal. The remaining bits of each soft bit express the probability of the preceding “hard” bit being correct.

The initial one of the two soft bits in the symbol supplied to the recoder 180 is passed therethrough without change to provide the initial one of the two soft bits in a respective symbol of the recoder 180 response. Each of the component eight simple bits in the final one of the two soft bits in the symbol supplied to the recoder 180 is supplied to a first of two input connections of a respective one of exclusive-OR gates 181, 182, 183, 184, 185, 186, 187 and 188 included within the recoder 180. The component bit of the initial one of the two soft bits in the symbol supplied to the recoder 180 that is variously referred to as its sign bit or “hard” bit is applied to the respective second input connections of the exclusive-OR gates 181, 182, 183, 184, 185, 186, 187 and 188. The final one of the two soft bits in each symbol of the recoder 180 response is supplied from via output connections from the exclusive-OR gates 181, 182, 183, 184, 185, 186, 187 and 188.

FIG. 50 shows a preferred embodiment of each of the binary-to-Gray-code re-mappers 113 and 123 employed in each of FIGS. 34-48. The FIG. 50 binary-to-Gray-code re-mapper is connected for receiving soft decisions in regard to contemporaneous Z-sub-2, Z-sub-1 and Z-sub-0 bits. FIG. 50 shows the soft Z-sub-2 and Z-sub-1 bits being applied to a binary-to-Gray-code recoder 191 as input signal thereto. The recoder 191 corresponds in structure and operation to the FIG. 49 binary-to-Gray-code recoder 180. The soft Y-sub-2 bits of the recoder 191 response reproduce the Z-sub-2 bits applied thereto and are supplied as part of the ultimate response of the FIG. 50 binary-to-Gray-code re-mapper.

FIG. 50 shows preliminary soft Y-sub-1 bits in the recoder 191 response being supplied to a separator 192 that separates the hard Y-sub-1 bit (its sign bit) of each preliminary soft Y-sub-1 bit from the seven or so bits indicative of the level of confidence that that hard Y-sub-1 bit is correct. The separator 192 can be simply constructed by appropriate hard wiring. The groups of seven or so bits indicative of the level of confidence that that hard Y-sub-1 bits are correct, as separated by the separator 192, are applied to a first of two 7-or-so-bits-wide input ports of a Y-sub-1 confidence-level-bits selector 193. FIG. 50 shows an expander 194 for expanding each successive hard Y-sub-1 bit to seven or so bits for application to the second of the two 7-or-so-bits-wide input ports of the selector 193. The hard Y-sub-1 bits are joined with the Y-sub-1 confidence-level-bits that the selector 193 reproduces as its response, thus to form processed soft Y-sub-1 bits supplied as a further part of the ultimate response of the FIG. 50 binary-to-Gray-code re-mapper. In variations of the FIG. 50 binary-to-Gray-code re-mapper, the expander 194 of the hard Y-sub-1 bits ones' complement each hard Y-sub-1 bit to form the least significant bit or a few of the less significant bits of the 7-or-so-bit-wide confidence level applied to the second input port of the selector 193.

The selection of the Y-sub-1 confidence-level-bits reproduced by the selector 193 is controlled responsive to the Z-sub-1 and Z-sub-0 bits descriptive of binary-coded modulation conditions. A hard-decision unit 195 is connected for receiving soft Z-sub-1 bits and soft Z-sub-0 bits descriptive of binary-coded modulation conditions and for supplying contemporaneous hard Z-sub-1 bits and hard Z-sub-0 bits extracted from those soft bits. A 2-input exclusive-OR gate 196 is connected for receiving each successive pair of contemporaneous hard Z-sub-1 bits and hard Z-sub-0 bits that the hard-decision unit 195 extracts from an 8-VSB symbol conveying M/H data. The response of the XOR gate 196 is applied to the selector 193 as a control signal for controlling the selection of Y-sub-1 confidence-level-bits to be reproduced by the selector 193.

If the binary-coded 8-VSB modulation signal encodes ‘000’ level, the Gray-labeled outer convolutional code will have a value ‘00’ in which the ZERO-valued soft Y-sub-1 bit should have a high confidence level that the ZERO-valued hard Y-sub-1 bit is correct. The XOR gate response to the hard Z-sub-1 bit and the hard Z-sub-0 bit both being ZEROes will be a ZERO, conditioning the selector 193 to reproduce the ‘000 0000’ expanded ZERO hard Y-sub-1 bit. This ‘000 0000’ joins with the ‘0’ hard Y-sub-1 bit to supply a processed soft Y-sub-1 bit having a high confidence level that the ZERO-valued hard Y-sub-1 bit is correct.

If the binary-coded 8-VSB modulation signal encodes ‘011’ level, the Gray-labeled outer convolutional code will have a value ‘01’ in which the ONE-valued soft Y-sub-1 bit should have a high confidence level that the ONE-valued hard Y-sub-1 bit is correct. The XOR gate response to the hard Z-sub-1 bit and the hard Z-sub-0 bit both being ONEs will be a ZERO, conditioning the selector 193 to reproduce the ‘111 1111’ expanded ONE hard Y-sub-1 bit. This ‘111 1111’ joins with the ‘1’ hard Y-sub-1 bit to supply a processed soft Y-sub-1 bit having a high confidence level that the ONE-valued hard Y-sub-1 bit is correct.

If the binary-coded 8-VSB modulation signal encodes ‘100’ level, the Gray-labeled outer convolutional code will have a value ‘11’ in which the ONE-valued soft Y-sub-1 bit should have a high confidence level that the ONE-valued hard Y-sub-1 bit is correct. The XOR gate response to the hard Z-sub-1 bit and the hard Z-sub-0 bit both being ZEROes will be a ZERO, conditioning the selector 193 to reproduce the ‘111 1111’ expanded ONE hard Y-sub-1 bit. This ‘111 1111’ joins with the ‘1’ hard Y-sub-1 bit to supply a processed soft Y-sub-1 bit having a high confidence level that the ONE-valued hard Y-sub-1 bit is correct.

If the binary-coded 8-VSB modulation signal encodes ‘111’ level, the Gray-labeled outer convolutional code will have a value ‘10’ in which the ZERO-valued soft Y-sub-1 bit should have a high confidence level that the ZERO-valued hard Y-sub-1 bit is correct. The XOR gate response to the hard Z-sub-1 bit and the hard Z-sub-0 bit both being ONEs will be a ZERO, conditioning the selector 193 to reproduce the ‘000 0000’ expanded ZERO hard Z-sub-1 bit. This ‘000 0000’ joins with the ‘0’ hard Y-sub-1 bit to supply a processed soft Y-sub-1 bit having a high confidence level that the ZERO-valued hard Y-sub-1 bit is correct.

If the binary-coded 8-VSB modulation signal encodes ‘001’, ‘010’, ‘101’ or ‘110’ level, the XOR gate will supply a ONE in response to the hard Z-sub-1 bit and the hard Z-sub-0 bit having different values. This ONE supplied as control signal to the selector 193 conditions the selector 193 to reproduce the 7 or so confidence-level bits that the separator 192 separated from the preliminary Y-sub-1 bit supplied thereto from the binary-to-Gray-code recoder 191. These confidence-level bits as reproduced in the selector 193 response are rejoined with the hard Y-sub-1 bit separated by the separator 192 to supply a processed soft Y-sub-1 bit that reproduces the preliminary soft Y-sub-1 bit supplied from the binary-to-Gray-code recoder 191.

As one skilled in the art of designing DTV receivers will understand from the foregoing specification other pairs of turbo decoders 110 and 120 operated in parallel for receiving one-third-code-rate CCC can be constructed to provide still further embodiments of the invention besides the fifteen specifically described. Many of these still further embodiments can be generated simply by modifying ones of the arrangements shown in one of the FIGS. 34-48. FIGS. 51 and 52 illustrate modifications that can be made to some of the arrangements shown in some of the FIGS. 34-48 to generate such other pairs of turbo decoders 110 and 120 operated in parallel for receiving one-third-code-rate CCC. Each of the arrangements shown in FIGS. 34-37, 39, 40 and 42-46 can be modified to extract the soft data bits applied to the hard-decision unit 108 from a point before, rather than after, the decoder 115 for the outer convolutional coding of CCC.

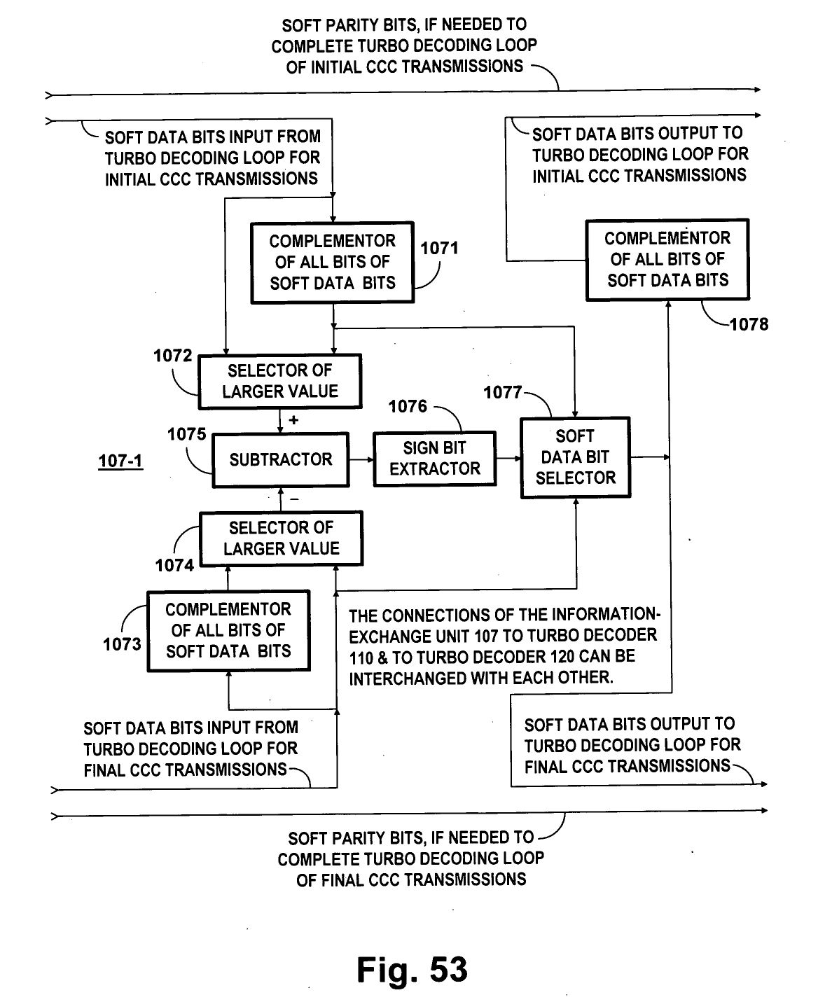

FIG. 53 shows in detail a first embodiment 107-1 of the information-exchange unit 107 for exchanging information regarding data bits between the turbo decoders 110 and 120 shown in FIGS. 34-48. This specific embodiment 107-1 of the information-exchange unit 107 comprises elements 1071, 1072, 1073, 1074, 1075, 1076, 1077 and 1078. The information-exchange unit 107-1 compares each soft data bit from a breakpoint in the turbo coding loop of the turbo decoder 120 for initial transmissions with the corresponding soft data bit from a like breakpoint in the turbo coding loop of the turbo decoder 110 for final transmissions. The information-exchange unit 107-1 then selects the soft data bit with the better confidence level as the basis for continuing the paired turbo-decoding loops of the turbo decoders 110 and 120. The structure and operation of the FIG. 53 information-exchange unit 1070 are described in further detail, following.

A breakpoint in the turbo-decoding loop of the turbo decoder 120 is connected for supplying successive soft data bits to a complementor 1071 of all of the bits in each successive soft bit and to a first of two input ports of a selector 1072. The second of the two input ports of the selector 1072 is connected for receiving the complemented soft data bits that the complementor 1071 supplies as the response therefrom. The selector 1072 is operable for reproducing in its response the larger of each pair of soft data bits concurrently received at its first and second input ports. The confidence level bits reproduced by the selector 1072 in its response are an absolute-value indication of the level of confidence that the data bit from the turbo decoder 120 is correct.

A breakpoint in the turbo-decoding loop of the turbo decoder 110 is connected for supplying successive soft data bits to a complementor 1073 of all of the bits in each successive soft bit and to a first of two input ports of a selector 1074. The second of the two input ports of the selector 1074 is connected for receiving the complemented soft data bits that the complementor 1073 supplies as the response therefrom. The selector 1074 is operable for reproducing in its response the larger of each pair of soft data bits concurrently received at its first and second input ports. The confidence level bits reproduced by the selector 1074 in its response are an absolute-value indication of the level of confidence that the data bit from the turbo decoder 110 is correct.

A digital subtractor 1075 is connected for receiving the responses of the selectors 1072 and 1074 as its minuend input signal and as its subtrahend input signal, respectively. The subtractor 1075 is connected for supplying its difference output signal to a sign-bit extractor 1076. In practice, the sign-bit extractor 1076 is realized simply by discarding all bits except the sign bit. The sign-bit from the sign-bit extractor 1076 is applied as control signal to a soft-data-bit selector 1077. The soft-data-bit selector 1077 is connected to receive, as one of its two input signals, the response of the complementor 1071 to the successive soft data bits from the turbo decoder 120. The soft-data-bit selector 1077 is connected to receive, as the other of its two input signals, the successive soft data bits from the turbo decoder 110. The soft-data-bit selector 1077 is connected to supply successively selected soft data bits for completing the turbo loop in the turbo decoder 110 for final CCC transmissions. The soft-data-bit selector 1077 is also connected to supply successively selected soft data bits to a complementor 1078 of all of the bits in each successive soft bit. The complementor 1078 is connected to supply the complementary soft data bits reproduced therefrom for completing the turbo loop in the turbo decoder 120 for initial CCC transmissions.

If the sign bit extracted by the sign-bit extractor 1076 is positive, this indicates that the confidence level as to the correctness of the soft data bit supplied from the breakpoint in the turbo loop of the turbo decoder 120 for initial CCC transmissions is better than the confidence level as to the correctness of the soft data bit supplied from the breakpoint in the turbo loop of the turbo decoder 110 for final CCC transmissions. Responsive to this indication received as control signal, the soft-data-bit selector 1077 is conditioned to reproduce from its output port the soft data bit from the output port of the complementor 1071.

If the sign bit extracted by the sign-bit extractor 1076 is negative, this indicates that the confidence level as to the correctness of the soft data bit supplied from the breakpoint in the turbo loop of the turbo decoder 110 for final CCC transmissions 120 is better than the confidence level as to the correctness of the soft data bit supplied from the breakpoint in the turbo loop in the turbo decoder 120 for initial CCC transmissions. Responsive to this indication received as control signal, the soft-data-bit selector 1077 is conditioned to reproduce from its output port the soft data bit from the breakpoint in the turbo loop of the turbo decoder 110 for final CCC transmissions.

The FIG. 53 embodiment of the information-exchange unit 107 for exchanging information regarding data bits between the turbo decoders 110 and 120 shown in FIGS. 34-48 can be connected to the turbo decoders 110 and 120 differently than as described thusfar. The connections of the information-exchange unit 107 to the turbo decoder 110 and to the turbo decoder 120, respectively, can be interchanged with each other. In such an interchange the complementor 1078 of all bits in the soft data bits is included in the turbo decoder loop of the turbo decoder 110 for final-component transmissions rather than in the turbo decoder loop of the turbo decoder 120 for initial-component transmissions.

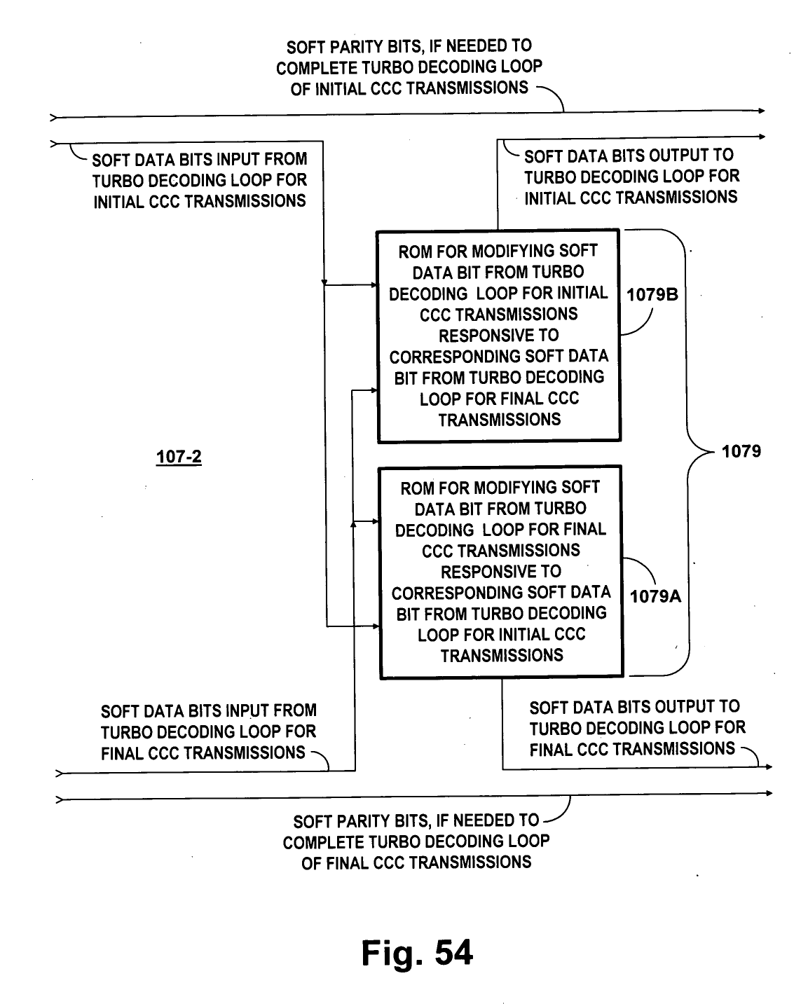

FIG. 54 shows a second embodiment 107-2 of the information-exchange unit 107, which is implemented with read-only memory (ROM) 1079 divided into two halves 1079A and 1079B. Soft data bits from corresponding points in the turbo-decoding loops of the decoders 110 and 120 provide each of the ROM halves 1079A and 1079B its input addressing. The ROM half 1079A is connected to supply adjusted soft data bits for continuing the turbo-decoding loop of the decoder 110. The ROM half 1079B is connected to supply adjusted soft data bits for continuing the turbo-decoding loop of the decoder 120. The output response of the ROM half 1079A adjusts the soft data bit received from the turbo-decoding loop of the decoder 110 as one half of its input addressing. This adjustment is responsive to the soft data bit received from the turbo-decoding loop of the decoder 120 as the other half of its input address. The output response of the ROM half 1079B adjusts the soft data bit received from the turbo-decoding loop of the decoder 120 as one half of its input addressing. This adjustment is responsive to the soft data bit received from the turbo-decoding loop of the decoder 110 as the other half of its input address.

Suppose one of the hard-decision portions of the two soft bits contemporaneously supplied by the turbo-decoding loops of the decoders 110 and 120 as input addressing for the two ROM halves 1079A and 1079B is a ONE and the other is a ZERO. Each of the two soft bits supports increased likelihood that itself and the other bit are correct. If the chance of one of the bits being in error is 1/n, the chance of both being in error is (1/n)×(1/n)=1/n². So, the chance of both being correct is 1−(1/n²)=(n²−1)/n². That is, the chance of both bits being correct is (n²−1) times as likely as both being erroneous. Accordingly, if possible, the output response of the ROM half 1079A increases the confidence level of the soft data bit received from the turbo-decoding loop of the turbo decoder 110 in the adjusted soft data bit it supplies for continuing that turbo-decoding loop. The hard-decision portion of the soft bit received from the turbo-decoding loop of the turbo decoder 110 is kept the same in the soft bit that the ROM half 1079A supplies for continuing that turbo-decoding loop. Furthermore, if possible, the output response of the ROM half 1079B increases the confidence level of the soft data bit received from the turbo-decoding loop of the turbo decoder 120 in the adjusted soft data bit it supplies for continuing that turbo-decoding loop. The hard-decision portion of the soft bit received from the turbo-decoding loop of the turbo decoder 120 is kept the same in the soft bit that the ROM half 1079B supplies for continuing that turbo-decoding loop.

Suppose that the hard-decision portions of the two soft data bits contemporaneously supplied as first and second halves of the input addressing for the ROM halves 1079A and 1079B are the same, rather than being different. This means that the hard-decision portion of one of the two soft bits is in error. If the confidence levels of both of the soft bits are fairly similar, the soft data bit that the ROM half 1079A supplies for continuing the turbo-decoding loop of the turbo decoder 110 is, if possible, decreased to be somewhat lower than that of the soft data bit that the ROM half 1079A received from that turbo-decoding loop. The hard-decision portion of the soft bit that the ROM half 1079A supplies for continuing the turbo-decoding loop of the turbo decoder 110 is kept the same as that of the soft data bit received from that turbo-decoding loop. Furthermore, the soft data bit that the ROM half 1079B supplies for continuing the turbo-decoding loop of the turbo decoder 120 is if possible decreased to be somewhat lower than that of the soft data bit that the ROM half 1079B received from that turbo-decoding loop. The hard-decision portion of the soft bit that the ROM half 1079B supplies for continuing the turbo-decoding loop of the turbo decoder 120 is kept the same as that of the soft data bit received from that turbo-decoding loop.

Suppose that the hard-decision portions of the first and second halves of the input addressing for the ROM halves 1079A and 1079B are the same, rather than being different, but the confidence level of the soft data bit supplied from the turbo decoder 110 is much higher than the confidence level of the soft data bit supplied from the turbo decoder 120. This indicates increased likelihood that the soft bit supplied from the turbo decoder 110 is correct and decreased likelihood that the soft bit supplied from the turbo decoder 120 is correct. Accordingly, if possible, the output response of the ROM half 1079A adjusts the soft data bit supplied from the turbo decoder 110 increasing the confidence level of that soft data bit somewhat for continuing the turbo-decoding loop of the turbo decoder 110. The hard-decision portion of that adjusted soft data bit is kept the same as that of the soft data bit supplied from the turbo decoder 110. Furthermore, if possible, the output response of the ROM half 1079B adjusts the soft data bit supplied from the turbo decoder 120 decreasing the confidence level of that soft data bit somewhat for continuing the turbo-decoding loop of the turbo decoder 120. Suppose the difference between the confidence levels of the soft data bits contemporaneously supplied from the turbo decoders 110 and 120 is not too great. Then, the hard-decision portion of that adjusted soft data bit is kept the same as that of the soft data bit supplied from the turbo decoder 120. Suppose the difference is great because the confidence level of the soft bit supplied from the decoder 120 is very low. Then, turbo decoding is apt to progress faster if the hard-decision portion of that soft data bit is ones' complemented in the adjusted soft data bit supplied for continuing the turbo-decoding loop in the turbo decoder 120.

Suppose that the hard-decision portions of the first and second halves of the input addressing for the ROM halves 1079A and 1079B are the same, rather than being different, but the confidence level of the soft data bit supplied from the turbo decoder 120 is much higher than the confidence level of the soft data bit supplied from the turbo decoder 110. This indicates increased likelihood that the soft bit supplied from the turbo decoder 120 is correct and decreased likelihood that the soft bit supplied from the turbo decoder 110 is correct. Accordingly, if possible, the output response of the ROM half 1079B adjusts the soft data bit supplied from the turbo decoder 120 increasing the confidence level of that soft data bit somewhat for continuing the turbo-decoding loop of the turbo decoder 120. The hard-decision portion of that adjusted soft data bit is kept the same as that of the soft data bit supplied from the turbo decoder 120. Furthermore, if possible, the output response of the ROM half 1079A adjusts the soft data bit supplied from the turbo decoder 110 decreasing the confidence level of that soft data bit somewhat for continuing the turbo-decoding loop of the turbo decoder 110. Suppose the difference between the confidence levels of the soft data bits contemporaneously supplied from the turbo decoders 110 and 120 is not too great. Then, the hard-decision portion of that adjusted soft data bit is kept the same as that of the soft data bit supplied from the turbo decoder 110. Suppose the difference is great because the confidence level of the soft bit supplied from the decoder 110 is very low. Then, turbo decoding is apt to progress faster if the hard-decision portion of that soft data bit is ones' complemented in the adjusted soft data bit supplied for continuing the turbo-decoding loop in the turbo decoder 110.

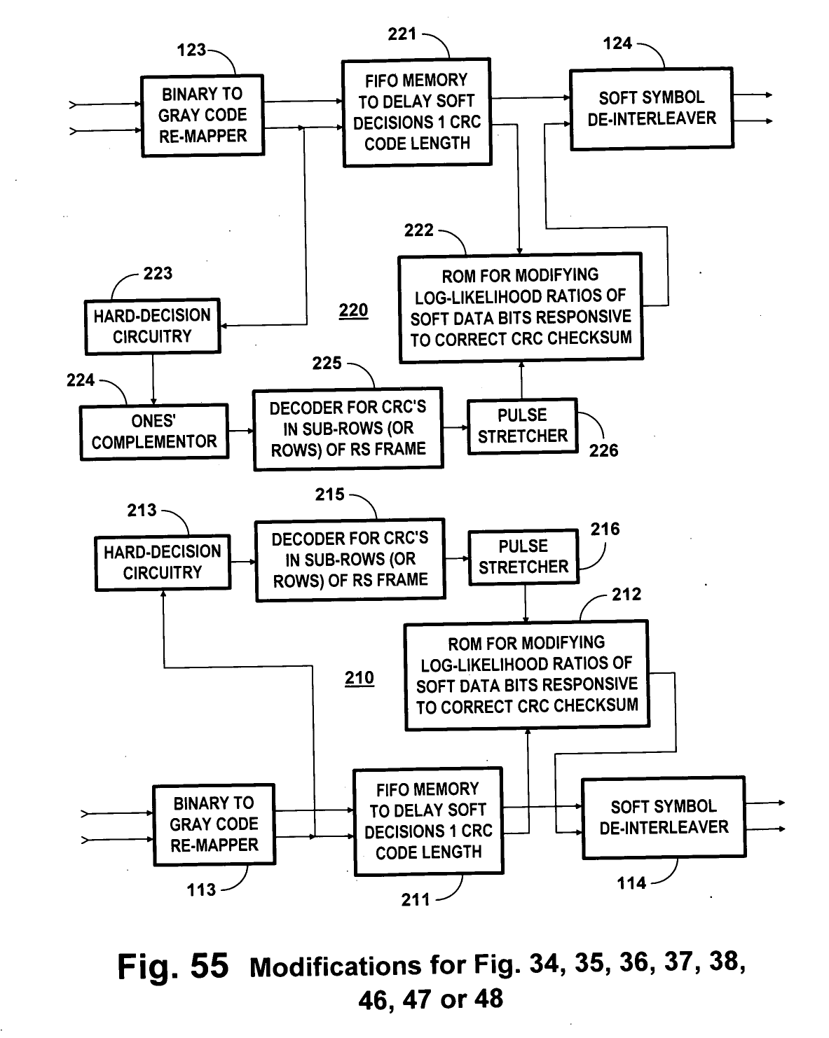

FIG. 55 shows how CRC decoding results can be used to adjust the confidence levels of soft data bits supplied from the binary-to-Gray-code re-mappers 113 and 123 in any of the arrangements for iterative-diversity reception shown in any of FIGS. 34-38 and 46-48. Apparatus 210 using CRC decoding results for adjusting the confidence levels of soft data bits supplied from the re-mapper 113 comprises elements 211, 212, 213, 215 and 216. Apparatus 220 using CRC decoding results for adjusting the confidence levels of soft data bits supplied from the re-mapper 123 comprises elements 221, 222, 223, 224, 225 and 226.

In FIG. 55 the apparatus 210 modifies the confidence levels of soft data bits supplied from the binary-to-Gray-code re-mapper 113 responsive to CRC decoding of CRC codewords contained within the rows of bytes in the RS Frames for the final ones of iterative-diversity transmissions. After a delay as long as the time taken for decoding each of the CRC codewords, a first-in/first-out memory 211 reproduces the soft data bits supplied from the re-mapper 113 and supplies them to a read-only memory 212 as partial input addressing thereto. The ROM 212 is used to modify the confidence levels of those soft data bits. The soft data bits written to the FIFO memory 211 as input addressing are also applied as input signal to a hard-decision unit 213 for extracting hard data bits from them. The hard-decision circuitry 213 responds to the soft data bits it receives to supply hard data bits as the input signal to the input port of a decoder 215 for cyclic-redundancy-check (CRC) coding. The CRC decoder 215 is operable to decode CRC codewords contained within each row or sub-row of bytes in each successive RS Frame for the final transmissions. The CRC decoder 215 includes input circuitry therein for converting the data bits received serially from the hard-decision circuitry 213 to 16-parallel-bit format for the CRC decoding procedures. The CRC decoder 215 is connected for supplying the CRC decoding result to a pulse stretcher 216. The pulse stretcher 216 reproduces the CRC decoding result for the duration of a CRC codeword read from the FIFO memory 211 and is connected for applying that reproduced CRC decoding result to the ROM 212 for completing its input addressing. If the CRC decoder 215 does not detect any error in the CRC codeword, the decoder 215 supplies a ONE to the pulse stretcher 216. The stretched-in-time ONE from the pulse stretcher 216 conditions the ROM 212 to increase the confidence levels of the soft data bits in the CRC codeword as supplied from the ROM 212 to the soft-symbol de-interleaver 114. If the CRC decoder 215 detects error in the CRC codeword, the decoder 215 supplies a ZERO to the pulse stretcher 216. The stretched-in-time ZERO from the pulse stretcher 216 conditions the ROM 212 to leave unaltered the confidence levels of the soft data bits in the CRC codeword as supplied from the ROM 212 to the soft-symbol de-interleaver 114.

In FIG. 55 the apparatus 220 modifies the confidence levels of soft data bits supplied from the binary-to-Gray-code re-mapper 123 responsive to CRC decoding of CRC codewords contained within the rows of bytes in the RS Frames for the final ones of iterative-diversity transmissions. After a delay as long as the time taken for decoding each of the CRC codewords, a first-in/first-out memory 221 reproduces the soft data bits supplied from the re-mapper 123 and supplies them to a read-only memory 222 as partial input addressing thereto. The ROM 222 is used to modify the confidence levels of those soft data bits. The soft data bits written to the FIFO memory 221 as input addressing are also applied as input signal to a hard-decision unit 223 for extracting hard data bits from them. The hard data bits supplied from the hard-decision unit 223 are ones' complements of the hard data bits from the hard-decision unit 213 and need to be one's complemented in order to decode the CRC coding contained therein. A ones' complementor 224 is connected for receiving hard data bits from the hard-decision unit 223 and supplying their ones' complements as the input signal to the input port of a decoder 225 for cyclic-redundancy-check coding. The CRC decoder 225 is operable to decode CRC codewords contained within each row or sub-row of bytes in each successive RS Frame for the initial transmissions. The CRC decoder 225 includes input circuitry therein for converting the data bits received serially from the ones' complementor 224 to 16-parallel-bit format for the CRC decoding procedures. The CRC decoder 225 is connected for supplying the CRC decoding result to a pulse stretcher 226. The pulse stretcher 226 reproduces the CRC decoding result for the duration of a CRC codeword read from the FIFO memory 221 and is connected for applying that reproduced CRC decoding result to the ROM 222 for completing its input addressing. If the CRC decoder 225 does not detect any error in the CRC codeword, the decoder 225 supplies a ONE to the pulse stretcher 226. The stretched-in-time ONE from the pulse stretcher 226 conditions the ROM 222 to increase the confidence levels of the soft data bits in the CRC codeword as supplied from the ROM 222 to the soft-symbol de-interleaver 124. If the CRC decoder 225 detects error in the CRC codeword, the decoder 225 supplies a ZERO to the pulse stretcher 226. The stretched-in-time ZERO from the pulse stretcher 226 conditions the ROM 222 to leave unaltered the confidence levels of the soft data bits in the CRC codeword as supplied from the ROM 222 to the symbol de-interleaver 124.

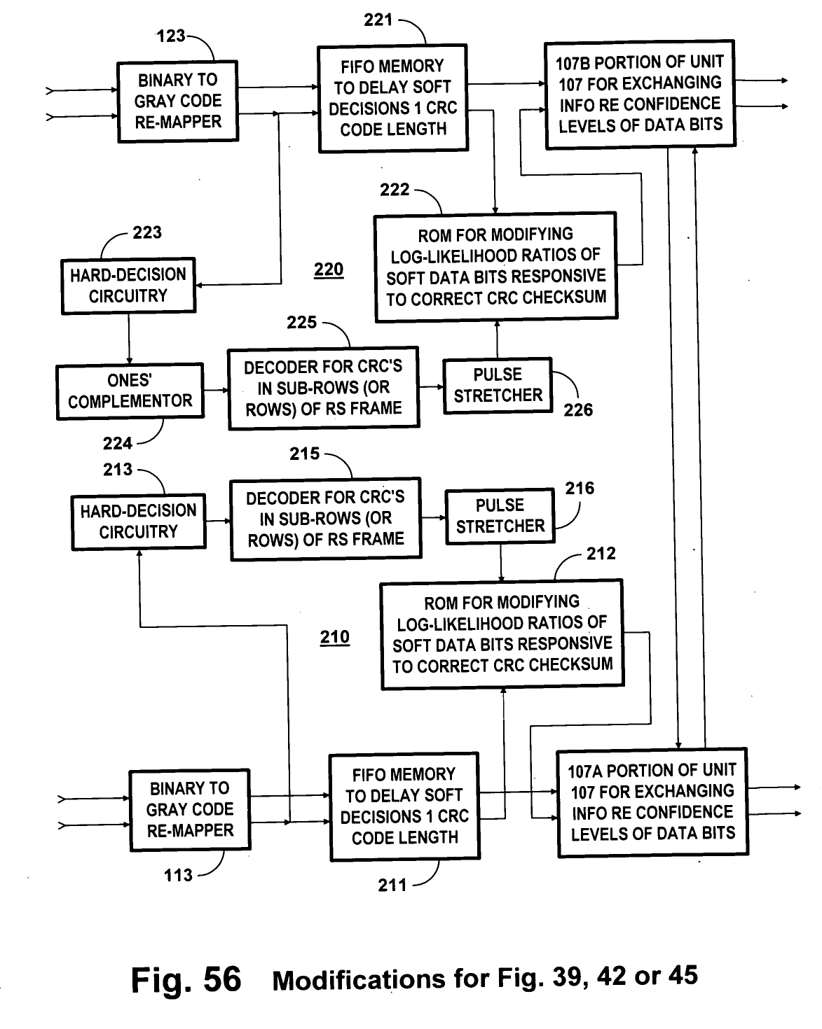

FIG. 56 shows the apparatuses 210 and 220 connected for adjusting the confidence levels of data bits of soft decisions supplied from the binary-to-Gray-code re-mappers 113 and 123 in either of the arrangements for diversity reception shown in FIGS. 39, 42 and 45. In FIG. 56 the responses of the apparatuses 210 and 220 are applied to the portions 107A and 107B, respectively, of the information-exchange unit 107. Placing the apparatuses 210 and 220 first in their respective cascade connections with the portions 107A and 107B of the information-exchange unit 107 is preferable to placing them last. Then, if either of the apparatuses 210 and 220 finds a correct CRC codeword and updates the confidence levels of the data bits therein, the information-exchange unit 107 will be able to update the corresponding data bits from the other of the apparatuses 210 and 220. This is apt to reduce the number of iterations needed in turbo decoding procedures.

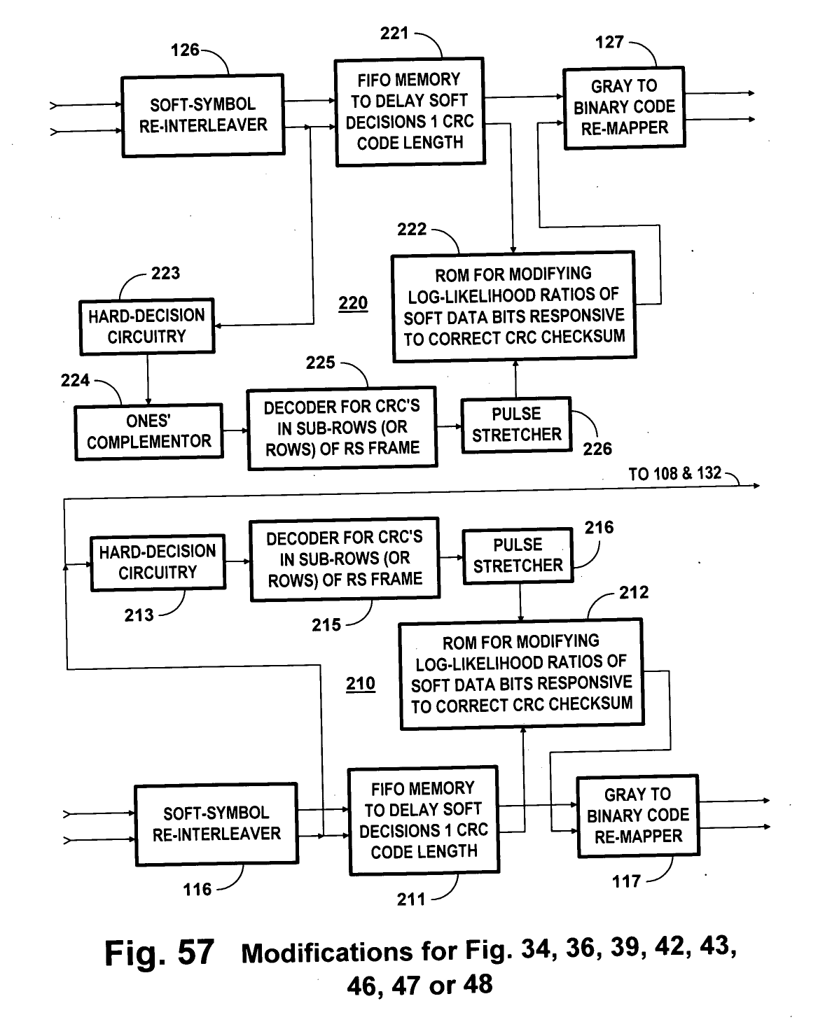

FIG. 57 shows the apparatuses 210 and 220 connected for adjusting the confidence levels of data bits of soft decisions supplied from the soft-symbol re-interleavers 116 and 126 in any of the arrangements for iterative-diversity reception shown in FIGS. 34, 36, 39, 42, 43 and 46-48. FIG. 57 shows the apparatus 210 connected for applying its response to the input port of the Gray-to-binary-code re-mapper 117 and the apparatus 220 connected for applying its response to the input port of the Gray-to-binary-code re-mapper 127. The hard-decision unit 213 can be identical with the hard-decision unit 108 shown in FIG. 26C.

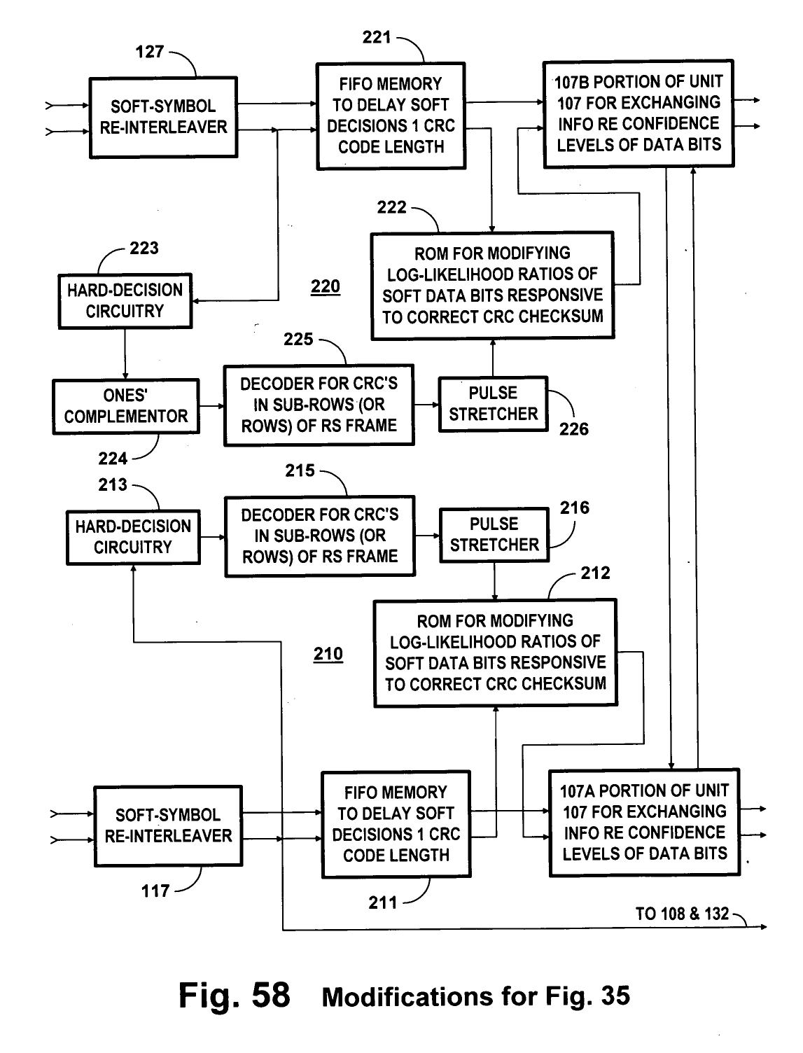

FIG. 58 shows the apparatuses 210 and 220 connected for adjusting the confidence levels of data bits in soft decisions supplied from the information-exchange unit 107 in the FIG. 35 arrangement for diversity reception. FIG. 58 shows the apparatuses 210 and 220 connected for applying their responses to the input port of the Gray-to-binary-code re-mapper 117 and to the input port of the Gray-to-binary-code re-mapper 127, respectively. The hard-decision unit 213 can be identical with the hard-decision unit 108 shown in FIG. 26C.

In the arrangements shown in FIGS. 40-44 the binary-to-Gray-code re-mappers 113 and 123 re-code soft symbols that have already been de-interleaved. So, in each of the arrangements shown in FIGS. 39, 40, 41, 43 44 the output signals from the binary-to-Gray-code re-mappers 113 and 123 are not suitable input signals for the apparatuses 210 and 220. Accordingly, the apparatuses 210 and 220 cannot be located in the connections from the input/output units 112 and 122 to the decoders 115 and 125, respectively. In the arrangements shown in FIGS. 37, 38, 40, 41, 44, 45, 47 and 48 the Gray-to-binary-code re-mappers 116 and 127 re-code soft symbols before their re-interleaving by the symbol re-interleavers 117 and 118. So, the output signals from the symbol re-interleavers 117 and 118 are not suitable input signals for the apparatuses 210 and 220. Accordingly, the apparatuses 210 and 220 cannot be located in the connections from the decoders 115 and 125 to the extrinsic data feedback processors 118 and 128, respectively. The arrangements shown in FIGS. 34-39, 42, 43 and 45-48 can be modified to use CRC decoding to improve turbo decoding performance, which modified arrangements are preferable to the arrangements shown in FIGS. 40, 41 and 44 that cannot be so modified.

Generally, PCCC transmissions are preferred over SCCC transmissions, supposing CRC decoding of sub-rows in the RS Frames is used to improve turbo decoding performance. The arrangements shown in FIGS. 34-36, 38, 39, 42, 43, 45, 46 and 48 are then preferred over the arrangements shown in FIGS. 37, 40, 41, 44 and 47. The arrangements shown in FIGS. 34, 35, 42 and 46 will tend to be favored because the symbol de-interleaving and symbol re-interleaving are readily subsumed into the memories within the SISO decoders 115 and 125. In the appended claims the terms soft-symbol de-interleaver and soft-symbol re-interleaver should be interpreted as encompassing such elements whether or not they are subsumed into the memories within the SISO decoders. If PCCC transmissions supplant SCCC transmissions, the soft-symbol re-interleavers shown in FIGS. 34-36, 38, 39, 42, 43, 45, 46 and 48 can be of a degenerate form in which soft parity bits are disregarded and only soft data bits are reinterleaved. The terms “soft-symbol re-interleaver” as used in the appended claims should be interpreted as encompassing re-interleavers of such degenerate form, as well as re-interleavers which re-interleave soft parity bits together with soft data bits.

In further embodiments of the transmitter and receiver aspects of the invention the CRC coding of sub-rows in RS Frames may be replaced by other types of block coding. The confidence-level adjusters in receivers that embody further aspects of the invention will then be adapted to use decoders for these other types of block coding, rather than decoders for CRC decoding. This specification and its drawing specifically describe decoding procedures in which 12-phase codes are decoded on a time-interleaved basis. However, persons skilled in the art are aware that alternative decoding procedures exist in which the twelve phases of 12-phase codes are de-interleaved and each decoded separately. These alternative decoding procedures are functionally equivalent. They offer an advantage of lower clocking rates for some digital operations, but require additional de-interleaving and re-interleaving procedures.

It will be apparent to those skilled in the art that various other modifications and variations can be made in the specifically described apparatus without departing from the spirit or scope of the invention. Accordingly, it is intended that these modifications and variations of the specifically described apparatus be considered to result in further embodiments of the invention provided they come within the scope of the appended claims and their equivalents.

In the claims which follow, the word “said” rather than the definite article “the” is used to indicate the existence of an antecedent basis for a term having being provided earlier in the claims. The definite article “the” is used for purposes other than to indicate the existence of an antecedent basis for a term having being provided earlier in the claims, the usage of the definite article “the” for other purposes being consistent with normal grammar in the American English language.

What is claimed is:

1. A receiver for iterative-diversity reception of data transmitted by concatenated convolutional code (CCC) from at least one vestigial-sideband amplitude-modulation (8-VSB) transmitter transmitting using a respective radio-frequency carrier wave modulated in accordance with portions of said CCC, each said portion of said CCC being transmitted a respective initial time and a respective final time after a prescribed delay, said CCC formed from a Gray-coded outer convolutional code and a subsequent binary-coded inner convolutional code forming a 12-phase trellis code in accordance with a Gray-labeling procedure, said outer convolutional code encoding de-interleaved data and being symbol-interleaved before encoding within said inner convolutional code so said inner convolutional code has implied symbol interleaving in which the original order of data bits is preserved, said receiver comprising:
tuner apparatus connected for selecting said modulated radio-frequency carrier waves from said at least one vestigial-sideband amplitude-modulation (8-VSB) transmitter and converting them to baseband, for generating reproductions of said portions of said finally transmitted CCC and for earlier generating reproductions of said portions of said initially transmitted CCC;
delay memory connected for delaying said reproductions of said portions of said initially transmitted CCC to supply delayed reproductions of said portions of said initially transmitted CCC that are contemporaneous with corresponding ones of said reproductions of said portions of said finally transmitted CCC;
a first turbo decoder connected for recovering respective first sets of successive soft data bits from said reproductions of said portions of said finally transmitted CCC;
a second turbo decoder connected for recovering respective second sets of successive soft data bits from said delayed reproductions of said portions of said initially transmitted CCC, said first and said second turbo decoders being similar in construction, each of said first and said second turbo decoders being adapted for decoding said CCC formed from said Gray-coded outer convolutional code and said subsequent binary-coded inner convolutional code having implied symbol interleaving in which the original order of data bits is preserved;
an information-exchange unit connected for exchanging decoding information between said first turbo decoder and said second turbo decoder; and
a hard-decision unit connected for generating a respective set of hard data bits responsive to each of said first sets of successive soft data bits.

2. The receiver set forth in claim 1, wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first binary-to-Gray-code re-mapper connected via said first memory input/output unit for receiving from said memory within said first SISO decoder said soft output symbols descriptive of binary-coded symbol-interleaved outer convolutional coding of said reproductions of said portions of said finally transmitted CCC as periodically updated, response from said first binary-to-Gray-code re-mapper re-mapping binary-coded symbol-interleaved outer convolutional coding of said reproductions of said portions of said finally transmitted CCC to symbol-interleaved outer convolutional coding of said portions of said finally transmitted CCC;
a first soft-symbol de-interleaver connected for de-interleaving said symbol-interleaved outer convolutional coding of said portions of said finally transmitted CCC, thus to regenerate the outer convolutional coding of said portions of said finally transmitted CCC;
a second soft-input/soft-output (SISO) decoder connected for decoding the outer convolutional coding of said portions of said finally transmitted CCC as regenerated by said first soft-symbol de-interleaver, said second SISO decoder including memory for temporarily storing soft input symbols from said regenerated outer convolutional coding of said portions of said finally transmitted CCC and for temporarily storing soft output symbols of decoded portions of said finally transmitted CCC;
a first soft-symbol re-interleaver connected for re-interleaving said soft output symbols of decoded portions of said finally transmitted CCC, thus to generate interleaved soft output symbols of decoded portions of said finally transmitted CCC, said first soft-symbol re-interleaver further connected for supplying soft data bits from said interleaved soft output symbols of decoded portions of said finally transmitted CCC to said hard-decision unit as an input signal thereto;
a first Gray-to-binary-code re-mapper connected for supplying to said information-exchange unit a binary-coded response to said interleaved soft output symbols of decoded portions of said finally transmitted CCC; and
a first extrinsic data feedback processor connected for generating a first extrinsic data feedback signal by combining said binary-coded response of said first Gray-to-binary-code re-mapper as processed by said information-exchange unit with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said CCC as initially transmitted, as periodically updated by results from decoding the inner convolutional coding of said reproductions of said portions of said initially transmitted CCC;
a second binary-to-Gray-code re-mapper connected via said second memory input/output unit for receiving from said memory within said third SISO decoder said soft output symbols descriptive of binary-coded symbol-interleaved outer convolutional coding of said reproductions of said portions of said initially transmitted CCC as periodically updated, response from said second binary-to-Gray-code re-mapper re-mapping binary-coded symbol-interleaved outer convolutional coding of said delayed reproductions of said portions of said initially transmitted CCC to symbol-interleaved outer convolutional coding of said delayed reproductions of said portions of said initially transmitted CCC;
a second soft-symbol de-interleaver connected for de-interleaving said symbol-interleaved outer convolutional coding of said delayed reproductions of said portions of said initially transmitted CCC, thus to regenerate the outer convolutional coding of said portions of said initially transmitted CCC;
a fourth soft-input/soft-output (SISO) decoder connected for decoding said outer convolutional coding of said portions of said finally transmitted CCC as regenerated by said second soft-symbol de-interleaver, said fourth SISO decoder including memory for temporarily storing soft input symbols from said regenerated outer convolutional coding of said portions of said initially transmitted CCC and for temporarily storing soft output symbols of decoded portions of said initially transmitted CCC;
a second soft-symbol re-interleaver connected for re-interleaving said soft output symbols of decoded portions of said initially transmitted CCC, thus to generate interleaved soft output symbols of decoded portions of said initially transmitted CCC;
a second Gray-to-binary-code re-mapper connected for supplying said information-exchange unit said second sets of successive soft data bits as a binary-coded response to said interleaved soft output symbols of decoded portions of said initially transmitted CCC; and
a second extrinsic data feedback processor connected for generating a second extrinsic data feedback signal by combining said binary-coded response of said second Gray-to-binary-code re-mapper as processed by said information-exchange unit with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

3. The receiver set forth in claim 2, wherein said first turbo decoder further comprises:
a first CRC decoder connected to respond to cyclic redundancy coding within said response from said first binary-to-Gray-code re-mapper for processing soft symbols in said response from said first binary-to-Gray-code re-mapper before their de-interleaving by said first soft-symbol de-interleaver—and wherein said second turbo decoder further comprises:
a second CRC decoder connected to respond to cyclic redundancy coding within said response from said second binary-to-Gray-code re-mapper for processing soft symbols in said response from said second binary-to-Gray-code re-mapper before their de-interleaving by said second soft-symbol de-interleaver.

4. The receiver set forth in claim 2, wherein said first turbo decoder further comprises:
a first CRC decoder connected to respond to cyclic redundancy coding within said response from said first soft-symbol re-interleaver for processing soft symbols in said response from said first soft-symbol re-interleaver before their re-coding by said first Gray-to-binary-code re-mapper—and wherein said second turbo decoder further comprises:
a second CRC decoder connected to respond to cyclic redundancy coding within said response from said second soft-symbol re-interleaver for processing soft symbols in said response from said second soft-symbol re-interleaver before their re-coding by said second Gray-to-binary-code re-mapper.

5. The receiver set forth in claim 1, wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first binary-to-Gray-code re-mapper connected via said first memory input/output unit for receiving from said memory within said first SISO decoder said soft output symbols descriptive of binary-coded symbol-interleaved outer convolutional coding of said reproductions of said portions of said finally transmitted CCC as periodically updated, response from said first binary-to-Gray-code re-mapper re-mapping binary-coded symbol-interleaved outer convolutional coding of said reproductions of said portions of said finally transmitted CCC to symbol-interleaved outer convolutional coding of said portions of said finally transmitted CCC;
a first soft-symbol de-interleaver connected for de-interleaving said symbol-interleaved outer convolutional coding of said portions of said finally transmitted CCC, thus to regenerate the outer convolutional coding of said portions of said finally transmitted CCC;
a second soft-input/soft-output (SISO) decoder connected for decoding said outer convolutional coding of said portions of said finally transmitted CCC as regenerated by said first soft-symbol de-interleaver, said second SISO decoder including memory for temporarily storing soft input symbols from said regenerated outer convolutional coding of said portions of said finally transmitted CCC and for temporarily storing soft output symbols of decoded portions of said finally transmitted CCC;
a first soft-symbol re-interleaver connected for symbol-interleaving said soft output symbols of decoded portions of said finally transmitted CCC, thus to generate as a response therefrom interleaved soft output symbols of decoded portions of said finally transmitted CCC, said first soft-symbol re-interleaver further connected for supplying said response thereof to said information-exchange unit as a first input signal thereto and for supplying soft data bits from said response thereof to said hard-decision unit as an input signal thereto;
a first Gray-to-binary-code re-mapper connected for re-coding said response of said first soft-symbol re-interleaver as processed by said information-exchange unit, thus to generate a binary-coded response from said first Gray-to-binary-code re-mapper; and
a first extrinsic data feedback processor connected for generating a first extrinsic data feedback signal by combining said binary-coded response from said first Gray-to-binary-code re-mapper with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder for temporarily storing soft input symbols, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC;
a second binary-to-Gray-code re-mapper connected via said second memory input/output unit for receiving said soft output symbols descriptive of binary-coded symbol-interleaved outer convolutional coding of said reproductions of said portions of said initially transmitted CCC as periodically updated, response from said second binary-to-Gray-code re-mapper re-mapping binary-coded symbol-interleaved outer convolutional coding of said delayed reproductions of said portions of said initially transmitted CCC to symbol-interleaved outer convolutional coding of said delayed reproductions of said portions of said initially transmitted CCC;
a second soft-symbol de-interleaver connected for de-interleaving said symbol-interleaved outer convolutional coding of said delayed reproductions of said portions of said initially transmitted CCC, thus to regenerate the outer convolutional coding of said portions of said initially transmitted CCC;
a fourth soft-input/soft-output (SISO) decoder connected for decoding the outer convolutional coding of said portions of said finally transmitted CCC as regenerated by said second soft-symbol de-interleaver, said fourth SISO decoder including memory for temporarily storing soft input symbols from said regenerated outer convolutional coding of said portions of said initially transmitted CCC and for temporarily storing soft output symbols of decoded portions of said initially transmitted CCC;
a second soft-symbol re-interleaver connected for symbol-interleaving said soft output symbols of decoded portions of said initially transmitted CCC, thus to generate as a response therefrom interleaved soft output symbols of decoded portions of said initially transmitted CCC, said second soft-symbol re-interleaver further connected for supplying said response therefrom to said information-exchange unit as a second input signal thereto;
a second Gray-to-binary-code re-mapper connected for responding to said response of said second soft-symbol re-interleaver as processed by said information-exchange unit, thus to generate a binary-coded response from said second Gray-to-binary-code re-mapper; and
a second extrinsic data feedback processor connected for generating a second extrinsic data feedback signal by combining said binary-coded response from said second Gray-to-binary-code re-mapper with soft input symbols extracted via said second memory input/output unit from said memory within said third SISO decoder, said second extrinsic data feedback processor further connected via said second memory input/output unit for updating said memory within said third SISO decoder with said second extrinsic data feedback signal.

6. The receiver set forth in claim 5, wherein said first turbo decoder further comprises:
a first CRC decoder connected to respond to cyclic redundancy coding within said response from said first binary-to-Gray-code re-mapper for processing soft symbols in said response from said first binary-to-Gray-code re-mapper before their de-interleaving by said first soft-symbol de-interleaver—and wherein said second turbo decoder further comprises:
a second CRC decoder connected to respond to cyclic redundancy coding within said response from said second binary-to-Gray-code re-mapper for processing soft symbols in said response from said second binary-to-Gray-code re-mapper before their de-interleaving by said second soft-symbol de-interleaver.

7. The receiver set forth in claim 7, wherein said first turbo decoder further comprises:
a first CRC decoder connected to respond to cyclic redundancy coding within said response from said first soft-symbol re-interleaver for processing soft symbols in said response from said first soft-symbol re-interleaver before their being supplied to said information-exchange unit as a first input signal thereto—and wherein said second turbo decoder further comprises:
a second CRC decoder connected to respond to cyclic redundancy coding within said response from said second soft-symbol re-interleaver for processing soft symbols in said response from said second soft-symbol re-interleaver before their being supplied to said information-exchange unit as a second input signal thereto.

8. The receiver set forth in claim 1, wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first binary-to-Gray-code re-mapper connected via said first memory input/output unit for receiving said soft output symbols descriptive of binary-coded symbol-interleaved outer convolutional coding of said reproductions of said portions of said finally transmitted CCC as periodically updated, response from said first binary-to-Gray-code re-mapper re-mapping binary-coded symbol-interleaved outer convolutional coding of said reproductions of said portions of said finally transmitted CCC to symbol-interleaved outer convolutional coding of said portions of said finally transmitted CCC;
a first soft-symbol de-interleaver connected for de-interleaving said symbol-interleaved outer convolutional coding of said portions of said finally transmitted CCC, thus to regenerate the outer convolutional coding of said portions of said finally transmitted CCC;
a second soft-input/soft-output (SISO) decoder connected for decoding said outer convolutional coding of said portions of said finally transmitted CCC as regenerated by said first soft-symbol de-interleaver, further connected for supplying said information-exchange unit with a first input signal composed of soft output symbols of decoded portions of said finally transmitted CCC, and including memory for temporarily storing soft input symbols from said regenerated outer convolutional coding of said portions of said finally transmitted CCC and for temporarily storing soft output symbols of decoded portions of said finally transmitted CCC;
a first soft-symbol re-interleaver connected for symbol-interleaving said soft output symbols of said response from said second SISO decoder as processed by said information-exchange unit, thus to generate as a response therefrom interleaved soft output symbols of decoded portions of said finally transmitted CCC, said first soft-symbol re-interleaver further connected for supplying soft data bits from said interleaved soft output symbols of decoded portions of said finally transmitted CCC to said hard-decision unit as an input signal thereto;
a first Gray-to-binary-code re-mapper connected for supplying a binary-coded response to said interleaved soft output symbols of decoded portions of said finally transmitted CCC; and
a first extrinsic data feedback processor connected for generating a first extrinsic data feedback signal by combining said binary-coded response of said first Gray-to-binary-code re-mapper with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC;
a second binary-to-Gray-code re-mapper connected via said second memory input/output unit for receiving said soft output symbols descriptive of binary-coded symbol-interleaved outer convolutional coding of said reproductions of said portions of said initially transmitted CCC as periodically updated, response from said second binary-to-Gray-code re-mapper re-mapping binary-coded symbol-interleaved outer convolutional coding of said delayed reproductions of said portions of said initially transmitted CCC to symbol-interleaved outer convolutional coding of said delayed reproductions of said portions of said initially transmitted CCC;
a second soft-symbol de-interleaver connected for de-interleaving said symbol-interleaved outer convolutional coding of said delayed reproductions of said portions of said initially transmitted CCC, thus to regenerate the outer convolutional coding of said portions of said initially transmitted CCC;
a fourth soft-input/soft-output (SISO) decoder connected for decoding said outer convolutional coding of said portions of said initially transmitted CCC as regenerated by said second soft-symbol de-interleaver, further connected for supplying said information-exchange unit with a second input signal composed of soft output symbols of decoded portions of said initially transmitted CCC, and including memory for temporarily storing soft input symbols from said regenerated outer convolutional coding of said portions of said initially transmitted CCC and for temporarily storing soft output symbols of decoded portions of said initially transmitted CCC;
a second soft-symbol re-interleaver connected for symbol-interleaving said soft output symbols of said response from said fourth SISO decoder as processed by said information-exchange unit to generate as a response therefrom interleaved soft output symbols of decoded portions of said initially transmitted CCC;
a second Gray-to-binary-code re-mapper connected for supplying a binary-coded response to said interleaved soft output symbols of decoded portions of said initially transmitted CCC; and
a second extrinsic data feedback processor connected for generating a second extrinsic data feedback signal by combining said binary-coded response of said second Gray-to-binary-code re-mapper with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

9. The receiver set forth in claim 8, wherein said first turbo decoder further comprises:
a first CRC decoder connected to respond to cyclic redundancy coding within said response from said first binary-to-Gray-code re-mapper for processing soft symbols in said response from said first binary-to-Gray-code re-mapper before their de-interleaving by said first soft-symbol de-interleaver—and wherein said second turbo decoder further comprises:
a second CRC decoder connected to respond to cyclic redundancy coding within said response from said second binary-to-Gray-code re-mapper for processing soft symbols in said response from said second binary-to-Gray-code re-mapper before their de-interleaving by said second soft-symbol de-interleaver.

10. The receiver set forth in claim 8, wherein said first turbo decoder further comprises:
a first CRC decoder connected to respond to cyclic redundancy coding within said response from said first soft-symbol re-interleaver for processing soft symbols in said response from said first soft-symbol re-interleaver before their re-coding by said first Gray-to-binary-code re-mapper—and wherein said second turbo decoder further comprises:
a second CRC decoder connected to respond to cyclic redundancy coding within said response from said second soft-symbol re-interleaver for processing soft symbols in said response from said second soft-symbol re-interleaver before their re-coding by said second Gray-to-binary-code re-mapper.

11. The receiver set forth in claim 1, wherein said CCC is serially concatenated convolutional coding and wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first binary-to-Gray-code re-mapper connected via said first memory input/output unit for receiving said soft output symbols descriptive of binary-coded symbol-interleaved outer convolutional coding of said reproductions of said portions of said finally transmitted CCC as periodically updated, response from said first binary-to-Gray-code re-mapper re-mapping binary-coded symbol-interleaved outer convolutional coding of said reproductions of said portions of said finally transmitted CCC to symbol-interleaved outer convolutional coding of said portions of said finally transmitted CCC;
a first soft-symbol de-interleaver connected for de-interleaving said symbol-interleaved outer convolutional coding of said portions of said finally transmitted CCC, thus to regenerate the outer convolutional coding of said portions of said finally transmitted CCC;
a second soft-input/soft-output (SISO) decoder connected for decoding said outer convolutional coding of said portions of said finally transmitted CCC as regenerated by said first soft-symbol de-interleaver, further connected for supplying said information-exchange unit with a first input signal composed of soft output symbols of decoded portions of said finally transmitted CCC, and including memory for temporarily storing soft input symbols from said regenerated outer convolutional coding of said portions of said finally transmitted CCC and for temporarily storing soft output symbols of decoded portions of said finally transmitted CCC;
a first Gray-to-binary-code re-mapper connected for supplying a binary-coded response to decoding results from said second SISO decoder, as processed by said information-exchange unit;
a first soft-symbol re-interleaver connected for symbol-interleaving said binary-coded response from said first Gray-to-binary-code re-mapper, thus to generate interleaved soft output symbols of decoded portions of said finally transmitted CCC as a response from said first soft-symbol re-interleaver, said first soft-symbol re-interleaver further connected for supplying soft data bits from said response thereof to said hard-decision unit as an input signal thereto; and
a first extrinsic data feedback processor connected for generating a first extrinsic data feedback signal by combining said response from said first soft-symbol re-interleaver with soft input symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC;
a second binary-to-Gray-code re-mapper connected via said second memory input/output unit for receiving said soft output symbols descriptive of binary-coded symbol-interleaved outer convolutional coding of said reproductions of said portions of said initially transmitted CCC as periodically updated, response from said second binary-to-Gray-code re-mapper re-mapping binary-coded symbol-interleaved outer convolutional coding of said delayed reproductions of said portions of said initially transmitted CCC to symbol-interleaved outer convolutional coding of said delayed reproductions of said portions of said initially transmitted CCC;
a second soft-symbol de-interleaver connected for de-interleaving said symbol-interleaved outer convolutional coding of said delayed reproductions of said portions of said initially transmitted CCC to regenerate the outer convolutional coding of said portions of said initially transmitted CCC;
a fourth soft-input/soft-output (SISO) decoder connected for decoding said outer convolutional coding of said portions of said initially transmitted CCC as regenerated by said second soft-symbol de-interleaver, being further connected for supplying said information-exchange unit with a second input signal composed of soft output symbols of decoded portions of said initially transmitted CCC, said fourth SISO decoder including memory for temporarily storing soft input symbols from said regenerated outer convolutional coding of said portions of said initially transmitted CCC and for temporarily storing soft output symbols of decoded portions of said initially transmitted CCC;
a second Gray-to-binary-code re-mapper connected for supplying a binary-coded response to decoding results from said fourth SISO decoder, as processed by said information-exchange unit;
a second soft-symbol re-interleaver connected for symbol-interleaving said binary-coded response from said second Gray-to-binary-code re-mapper, thus to generate interleaved soft output symbols of decoded portions of said initially transmitted CCC as a response from said second soft-symbol re-interleaver; and
a second extrinsic data feedback processor connected for generating a second extrinsic data feedback signal by combining said response from said second soft-symbol re-interleaver with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

12. The receiver set forth in claim 11, wherein said first turbo decoder further comprises:
a first CRC decoder connected to respond to cyclic redundancy coding within said response from said first binary-to-Gray-code re-mapper for processing soft symbols in said response from said first binary-to-Gray-code re-mapper before their de-interleaving by said first soft-symbol de-interleaver—and wherein said second turbo decoder further comprises:
a second CRC decoder connected to respond to cyclic redundancy coding within said response from said second binary-to-Gray-code re-mapper for processing soft symbols in said response from said second binary-to-Gray-code re-mapper before their de-interleaving by said second soft-symbol de-interleaver.

13. The receiver set forth in claim 1, wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first binary-to-Gray-code re-mapper connected via said first memory input/output unit for receiving said soft output symbols descriptive of binary-coded symbol-interleaved outer convolutional coding of said reproductions of said portions of said finally transmitted CCC as periodically updated, response from said first binary-to-Gray-code re-mapper re-mapping binary-coded symbol-interleaved outer convolutional coding of said reproductions of said portions of said finally transmitted CCC to symbol-interleaved outer convolutional coding of said portions of said finally transmitted CCC, said first binary-to-Gray-code re-mapper further connected for supplying soft data bits from said response thereof to said hard-decision unit as an input signal thereto;
a first soft-symbol de-interleaver connected for de-interleaving said symbol-interleaved outer convolutional coding of said portions of said finally transmitted CCC to regenerate the outer convolutional coding of said portions of said finally transmitted CCC;
a second soft-input/soft-output (SISO) decoder connected for decoding said outer convolutional coding of said portions of said finally transmitted CCC as regenerated by said first soft-symbol de-interleaver, further connected for supplying said information-exchange unit with a first input signal composed of soft output symbols of decoded portions of said finally transmitted CCC, and including memory for temporarily storing soft input symbols from said regenerated outer convolutional coding of said portions of said finally transmitted CCC and for temporarily storing soft output symbols of decoded portions of said finally transmitted CCC;
a first Gray-to-binary-code re-mapper connected for supplying a binary-coded response to said response of said third SISO decoder, as processed by said information-exchange unit;
a first soft-symbol re-interleaver connected for symbol-interleaving said binary-coded response from said first Gray-to-binary-code re-mapper, thus to generate interleaved soft output symbols of decoded portions of said finally transmitted CCC as a response from said first soft-symbol re-interleaver; and
a first extrinsic data feedback processor connected for generating a first extrinsic data feedback signal by combining said response from said first soft-symbol re-interleaver with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC;
a second binary-to-Gray-code re-mapper connected via said second memory input/output unit for receiving said soft output symbols descriptive of binary-coded symbol-interleaved outer convolutional coding of said reproductions of said portions of said initially transmitted CCC as periodically updated, response from said second binary-to-Gray-code re-mapper re-mapping binary-coded symbol-interleaved outer convolutional coding of said delayed reproductions of said portions of said initially transmitted CCC to symbol-interleaved outer convolutional coding of said delayed reproductions of said portions of said initially transmitted CCC;
a second soft-symbol de-interleaver connected for de-interleaving said symbol-interleaved outer convolutional coding of said delayed reproductions of said portions of said initially transmitted CCC to regenerate the outer convolutional coding of said portions of said initially transmitted CCC;
a fourth soft-input/soft-output (SISO) decoder connected for decoding said outer convolutional coding of said portions of said initially transmitted CCC as regenerated by said second soft-symbol de-interleaver, further connected for supplying said information-exchange unit with a second input signal composed of soft output symbols of decoded portions of said initially transmitted CCC, and including memory for temporarily storing soft input symbols from said regenerated outer convolutional coding of said portions of said initially transmitted CCC and for temporarily storing soft output symbols of decoded portions of said initially transmitted CCC;
a second Gray-to-binary-code re-mapper connected for supplying a binary-coded response to said response of said fourth SISO decoder, as processed by said information-exchange unit;
a second soft-symbol re-interleaver connected for symbol-interleaving said binary-coded response from said second Gray-to-binary-code re-mapper, thus to generate interleaved soft output symbols of decoded portions of said initially transmitted CCC as a response from said second soft-symbol re-interleaver; and
a second extrinsic data feedback processor connected for generating a second extrinsic data feedback signal by combining said response from said second soft-symbol re-interleaver with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

14. The receiver set forth in claim 13, wherein said first turbo decoder further comprises:
a first CRC decoder connected to respond to cyclic redundancy coding within said response from said first binary-to-Gray-code re-mapper for processing soft symbols in said response from said first binary-to-Gray-code re-mapper before their de-interleaving by said first soft-symbol de-interleaver—and wherein said second turbo decoder further comprises:
a second CRC decoder connected to respond to cyclic redundancy coding within said response from said second binary-to-Gray-code re-mapper for processing soft symbols in said response from said second binary-to-Gray-code re-mapper before their de-interleaving by said second soft-symbol de-interleaver.

15. The receiver set forth in claim 1, wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first soft-symbol de-interleaver connected for de-interleaving said soft output symbols descriptive of binary-coded symbol-interleaved outer convolutional coding of said reproductions of said portions of said finally transmitted CCC as periodically updated, thus to generate binary-coded outer convolutional coding of said reproductions of said portions of said finally transmitted CCC;
a first binary-to-Gray-code re-mapper connected for responding to said binary-coded outer convolutional coding of said reproductions of said portions of said finally transmitted CCC, response from said first binary-to-Gray-code re-mapper re-mapping binary-coded outer convolutional coding of said reproductions of said portions of said finally transmitted CCC to first sets of soft symbols descriptive of the outer convolutional coding of said portions of said finally transmitted CCC, said first binary-to-Gray-code re-mapper further connected for supplying said first sets of soft symbols to said information-exchange unit as a first input signal thereto;
a second soft-input/soft-output (SISO) decoder connected for receiving said first sets of soft symbols as processed by said information-exchange unit and for decoding them to generate decoding results composed of soft output symbols of decoded portions of said finally transmitted CCC, said second SISO decoder including memory for temporarily storing said first sets of soft symbols as processed by said information-exchange unit and for temporarily storing said soft output symbols generated by said second SISO decoder;
a first soft-symbol re-interleaver connected for symbol-interleaving said soft output symbols of decoded portions of said finally transmitted CCC to generate interleaved soft output symbols of decoded portions of said finally transmitted CCC, said first soft-symbol re-interleaver further connected for supplying soft data bits from said interleaved soft output symbols of decoded portions of said finally transmitted CCC to said hard-decision unit as an input signal thereto;
a first Gray-to-binary-code re-mapper connected for supplying to said information-exchange unit a binary-coded response to said interleaved soft output symbols of decoded portions of said finally transmitted CCC; and
a first extrinsic data feedback processor connected for generating a first extrinsic data feedback signal by combining said binary-coded response of said first Gray-to-binary-code re-mapper with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC;
a second soft-symbol de-interleaver connected for de-interleaving said soft output symbols descriptive of binary-coded symbol-interleaved outer convolutional coding of said reproductions of said portions of said initially transmitted CCC as periodically updated, thus to generate binary-coded outer convolutional coding of said reproductions of said portions of said initially transmitted CCC;
a second binary-to-Gray-code re-mapper connected for responding to said binary-coded outer convolutional coding of said reproductions of said portions of said initially transmitted CCC, response from said second binary-to-Gray-code re-mapper re-mapping binary-coded outer convolutional coding of said reproductions of said portions of said initially transmitted CCC to second sets of soft symbols descriptive of the outer convolutional coding of said portions of said initially transmitted CCC, said second binary-to-Gray-code re-mapper further connected for supplying said second sets of soft symbols to said information-exchange unit as a second input signal thereto;
a fourth soft-input/soft-output (SISO) decoder connected for receiving said second sets of soft symbols as processed by said information-exchange unit and for decoding them to generate decoding results composed of soft output symbols of decoded portions of said initially transmitted CCC, said fourth SISO decoder including memory for temporarily storing said second sets of soft symbols as processed by said information-exchange unit and for temporarily storing said soft output symbols generated by said fourth SISO decoder;
a second soft-symbol re-interleaver connected for symbol-interleaving said soft output symbols of decoded portions of said initially transmitted CCC to generate interleaved soft output symbols of decoded portions of said initially transmitted CCC;
a second Gray-to-binary-code re-mapper connected for supplying said information-exchange unit with said second sets of successive soft data bits as a binary-coded response to said interleaved soft output symbols of decoded portions of said initially transmitted CCC; and
a second extrinsic data feedback processor connected for generating a second extrinsic data feedback signal by combining said binary-coded response of said second Gray-to-binary-code re-mapper with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

16. The receiver set forth in claim 15, wherein said first turbo decoder further comprises:
a first CRC decoder connected to respond to cyclic redundancy coding within said response from said first soft-symbol re-interleaver for processing soft symbols in said response from said first soft-symbol re-interleaver before their re-coding by said first Gray-to-binary-code re-mapper—and wherein said second turbo decoder further comprises:
a second CRC decoder connected to respond to cyclic redundancy coding within said response from said second soft-symbol re-interleaver for processing soft symbols in said response from said second soft-symbol re-interleaver before their re-coding by said second Gray-to-binary-code re-mapper.

17. The receiver set forth in claim 1, wherein said CCC is serially concatenated convolutional coding and wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first soft-symbol de-interleaver connected for de-interleaving said soft output symbols descriptive of binary-coded symbol-interleaved outer convolutional coding of said reproductions of said portions of said finally transmitted CCC as periodically updated, thus to generate binary-coded outer convolutional coding of said reproductions of said portions of said finally transmitted CCC;
a first binary-to-Gray-code re-mapper connected for responding to said binary-coded outer convolutional coding of said reproductions of said portions of said finally transmitted CCC, response from said first binary-to-Gray-code re-mapper re-mapping binary-coded outer convolutional coding of said reproductions of said portions of said finally transmitted CCC to first sets of soft symbols descriptive of the outer convolutional coding of said portions of said finally transmitted CCC, said first binary-to-Gray-code re-mapper further connected for supplying soft data bits from the response thereof to said information-exchange unit as a first input signal thereto;
a second soft-input/soft-output (SISO) decoder connected for receiving said first sets of soft symbols as processed by said information-exchange unit and for decoding them to generate decoding results composed of soft output symbols of decoded portions of said finally transmitted CCC, said second SISO decoder including memory for temporarily storing said first sets of soft symbols as processed by said information-exchange unit and for temporarily storing said soft output symbols generated by said second SISO decoder;
a first Gray-to-binary-code re-mapper connected for supplying a binary-coded response to said decoding results from said second SISO decoder;
a first soft-symbol re-interleaver connected for symbol-interleaving said binary-coded response from said first Gray-to-binary-code re-mapper, thus to generate a response from said first soft-symbol re-interleaver composed of soft output symbols of decoded portions of said finally transmitted CCC, said first soft-symbol re-interleaver further connected for supplying soft data bits from said soft output symbols of its said response to said hard-decision unit as an input signal thereto; and
a first extrinsic data feedback processor connected for generating a first extrinsic data feedback signal by combining said response from said first soft-symbol re-interleaver with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said delayed reproductions of said portions of said initially transmitted CCC, as periodically updated by results from decoding the inner convolutional coding of said reproductions of said portions of said initially transmitted CCC;
a second soft-symbol de-interleaver connected for de-interleaving said soft output symbols descriptive of binary-coded symbol-interleaved outer convolutional coding of said reproductions of said portions of said initially transmitted CCC as periodically updated, thus to generate binary-coded outer convolutional coding of said reproductions of said portions of said initially transmitted CCC;
a second binary-to-Gray-code re-mapper connected for responding to said binary-coded outer convolutional coding of said reproductions of said portions of said initially transmitted CCC, response from said second binary-to-Gray-code re-mapper re-mapping binary-coded outer convolutional coding of said reproductions of said portions of said initially transmitted CCC to second sets of soft symbols descriptive of the outer convolutional coding of said portions of said initially transmitted CCC, said second binary-to-Gray-code re-mapper further connected for supplying said second sets of soft symbols to said information-exchange unit as a second input signal thereto;
a fourth soft-input/soft-output (SISO) decoder connected for receiving said second sets of soft symbols as processed by said information-exchange unit and for decoding them to generate decoding results composed of soft output symbols of decoded portions of said initially transmitted CCC, said fourth SISO decoder including memory for temporarily storing said second sets of soft symbols as processed by said information-exchange unit and for temporarily storing said soft output symbols generated by said fourth SISO decoder;
a second Gray-to-binary-code re-mapper connected for supplying a binary-coded response to said decoding results from said fourth SISO decoder;
a second soft-symbol re-interleaver connected for symbol-interleaving said binary-coded response from said second Gray-to-binary-code re-mapper, thus to generate a response from said second soft-symbol re-interleaver composed of soft output symbols of decoded portions of said initially transmitted CCC; and
a second extrinsic data feedback processor connected for generating a second extrinsic data feedback signal by combining said response from said second soft-symbol re-interleaver with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

18. The receiver set forth in claim 1, wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first binary-to-Gray-code re-mapper connected via said first memory input/output unit for receiving said soft output symbols descriptive of binary-coded symbol-interleaved outer convolutional coding of said reproductions of said portions of said finally transmitted CCC, response from said first binary-to-Gray-code re-mapper re-mapping binary-coded symbol-interleaved outer convolutional coding of said reproductions of said portions of said finally transmitted CCC to symbol-interleaved outer convolutional coding of said portions of said finally transmitted CCC, said first binary-to-Gray-code re-mapper further connected for supplying soft data bits of said response therefrom to said hard-decision unit as an input signal thereto;
a first soft-symbol de-interleaver connected for de-interleaving said soft output symbols descriptive of binary-coded symbol-interleaved outer convolutional coding of said reproductions of said portions of said finally transmitted CCC as periodically updated, thus to generate binary-coded outer convolutional coding of said reproductions of said portions of said finally transmitted CCC;
a second binary-to-Gray-code re-mapper connected for responding to said binary-coded outer convolutional coding of said reproductions of said portions of said finally transmitted CCC, response from said second binary-to-Gray-code re-mapper re-mapping binary-coded outer convolutional coding of said reproductions of said portions of said finally transmitted CCC, thus to generate first sets of soft symbols descriptive of the outer convolutional coding of said portions of said finally transmitted CCC, said second binary-to-Gray-code re-mapper further connected for supplying said first sets of soft symbols to said information-exchange unit as a first input signal thereto;
a second soft-input/soft-output (SISO) decoder connected for receiving said first sets of soft symbols as processed by said information-exchange unit and for decoding them to generate decoding results composed of soft output symbols of decoded portions of said finally transmitted CCC, said second SISO decoder including memory for temporarily storing said first sets of soft symbols as processed by said information-exchange unit and for temporarily storing said soft output symbols generated by said second SISO decoder;
a first Gray-to-binary-code re-mapper connected for supplying a binary-coded response to said decoding results from said second SISO decoder;
a first soft-symbol re-interleaver connected for symbol-interleaving said binary-coded response from said first Gray-to-binary-code re-mapper, thus to generate soft symbols of decoded portions of said finally transmitted CCC as a response of said first soft-symbol re-interleaver; and
a first extrinsic data feedback processor connected for generating a first extrinsic data feedback signal by combining said response of said first soft-symbol re-interleaver with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC;
a second soft-symbol de-interleaver connected for de-interleaving said soft output symbols descriptive of binary-coded symbol-interleaved outer convolutional coding of said reproductions of said portions of said initially transmitted CCC as periodically updated, thus to generate binary-coded outer convolutional coding of said reproductions of said portions of said initially transmitted CCC;
a third binary-to-Gray-code re-mapper connected for responding to said binary-coded outer convolutional coding of said reproductions of said portions of said initially transmitted CCC, response from said third binary-to-Gray-code re-mapper re-mapping binary-coded outer convolutional coding of said reproductions of said portions of said initially transmitted CCC, thus to generate second sets of soft symbols descriptive of the outer convolutional coding of said portions of said initially transmitted CCC, said third binary-to-Gray-code re-mapper further connected for supplying said second sets of soft symbols to said information-exchange unit as a second input signal thereto;
a fourth soft-input/soft-output (SISO) decoder connected for receiving said second sets of soft symbols as processed by said information-exchange unit and for decoding them to generate decoding results composed of soft output symbols of decoded portions of said initially transmitted CCC, said fourth SISO decoder including memory for temporarily storing said second sets of soft symbols as processed by said information-exchange unit and for temporarily storing said soft output symbols generated by said fourth SISO decoder;
a third Gray-to-binary-code re-mapper connected for supplying a binary-coded response to said decoding results from said fourth SISO decoder;
a second soft-symbol re-interleaver connected for symbol-interleaving said binary-coded response from said third Gray-to-binary-code re-mapper, thus to generate soft symbols of decoded portions of said initially transmitted CCC as a response of said second soft-symbol re-interleaver; and
a second extrinsic data feedback processor connected for generating a second extrinsic data feedback signal by combining said response of said second soft-symbol re-interleaver with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

19. The receiver set forth in claim 1, wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first binary-to-Gray-code re-mapper connected via said first memory input/output unit for receiving said soft output symbols descriptive of binary-coded symbol-interleaved outer convolutional coding of said reproductions of said portions of said finally transmitted CCC as periodically updated, response from said first binary-to-Gray-code re-mapper re-mapping binary-coded symbol-interleaved outer convolutional coding of said reproductions of said portions of said finally transmitted CCC to symbol-interleaved outer convolutional coding of said portions of said finally transmitted CCC, said first binary-to-Gray-code re-mapper further connected for supplying said response thereof to said information-exchange unit as a first input signal thereto;
a first soft-symbol de-interleaver connected for de-interleaving said symbol-interleaved outer convolutional coding of said portions of said finally transmitted CCC and as subsequently processed by said information-exchange unit, thus to generate as a response therefrom reproductions of said outer convolutional coding of said portions of said finally transmitted CCC;
a second soft-input/soft-output (SISO) decoder connected for decoding said reproductions of said outer convolutional coding of said portions of said finally transmitted CCC, said second SISO decoder including memory for temporarily storing soft input symbols of said reproductions of said outer convolutional coding of said portions of said finally transmitted CC and for temporarily storing soft output symbols of decoded portions of said finally transmitted CCC;
a first soft-symbol re-interleaver connected for symbol-interleaving said soft output symbols of decoded portions of said finally transmitted CCC to generate interleaved soft output symbols of decoded portions of said finally transmitted CCC as a response of said first soft-symbol re-interleaver, for supplying said response thereof to said information-exchange unit as a first input signal thereto, and for supplying soft data bits from said response thereof to said hard-decision unit as an input signal thereto;
a first Gray-to-binary-code re-mapper connected for responding to said response of said first soft-symbol re-interleaver as processed by said information-exchange unit to re-code that information to binary-coded form, thus to generate a binary-coded response of said first Gray-to-binary-code re-mapper;
a first extrinsic data feedback processor connected for generating a first extrinsic data feedback signal by combining said binary-coded response of said first Gray-to-binary-code re-mapper with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder, said third SISO decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC;
a second binary-to-Gray-code re-mapper connected via said second memory input/output unit for receiving said soft output symbols descriptive of binary-coded symbol-interleaved outer convolutional coding of said reproductions of said portions of said initially transmitted CCC as periodically updated, response from said second binary-to-Gray-code re-mapper re-mapping binary-coded symbol-interleaved outer convolutional coding of said reproductions of said portions of said initially transmitted CCC to symbol-interleaved outer convolutional coding of said portions of said initially transmitted CCC, said second binary-to-Gray-code re-mapper further connected for supplying said response thereof to said information-exchange unit as a first input signal thereto;
a second soft-symbol de-interleaver connected for de-interleaving said symbol-interleaved outer convolutional coding of said portions of said initially transmitted CCC and as subsequently processed by said information-exchange unit, thus to generate as a response therefrom reproductions of said outer convolutional coding of said portions of said initially transmitted CCC;
a fourth soft-input/soft-output (SISO) decoder connected for receiving said reproductions of said outer convolutional coding of said portions of said initially transmitted CCC, said fourth SISO decoder including memory for temporarily storing soft input symbols of said reproductions of said outer convolutional coding of said portions of said initially transmitted CC and for soft output symbols of decoded portions of said initially transmitted CCC;
a second soft-symbol re-interleaver connected for symbol-interleaving said soft output symbols of decoded portions of said initially transmitted CCC, thus to generate as a response therefrom interleaved soft output symbols of decoded portions of said initially transmitted CCC;
a second Gray-to-binary-code re-mapper connected for responding to said response of said second soft-symbol re-interleaver to re-code that information to binary-coded form, thus to generate a binary-coded response of said second Gray-to-binary-code re-mapper; and
a second extrinsic data feedback processor connected for generating a second extrinsic data feedback signal by combining said binary-coded response of said second Gray-to-binary-code re-mapper with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

20. The receiver set forth in claim 19, wherein said first turbo decoder further comprises:
a first CRC decoder connected to respond to cyclic redundancy coding within said response from said first soft-symbol re-interleaver for processing soft symbols in said response from said first soft-symbol re-interleaver before their re-coding by said first Gray-to-binary-code re-mapper—and wherein said second turbo decoder further comprises:
a second CRC decoder connected to respond to cyclic redundancy coding within said response from said second soft-symbol re-interleaver for processing soft symbols in said response from said second soft-symbol re-interleaver before their re-coding by said second Gray-to-binary-code re-mapper.

21. The receiver set forth in claim 19, wherein said first turbo decoder further comprises:
a first CRC decoder connected to respond to cyclic redundancy coding within said response from said first binary-to-Gray-code re-mapper for processing soft symbols in said response from said first binary-to-Gray-code re-mapper before supplying them to said information-exchange unit as said first input signal thereto—and wherein said second turbo decoder further comprises:
a second CRC decoder connected to respond to cyclic redundancy coding within said response from said second binary-to-Gray-code re-mapper for processing soft symbols in said response from said second binary-to-Gray-code re-mapper before supplying them to said information-exchange unit as said second input signal thereto.

22. The receiver set forth in claim 1, wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first soft-symbol de-interleaver connected for de-interleaving said soft output symbols descriptive of binary-coded symbol-interleaved outer convolutional coding of said reproductions of said portions of said finally transmitted CCC as periodically updated, thus to generate binary-coded outer convolutional coding of said reproductions of said portions of said CCC as finally transmitted to said information-exchange unit as a first input signal thereto;
a first binary-to-Gray-code re-mapper connected for receiving from said information-exchange unit said soft output symbols descriptive of binary-coded outer convolutional coding of said reproductions of said portions of said finally transmitted CCC after their processing by said information-exchange unit, response from said first binary-to-Gray-code re-mapper re-mapping binary-coded symbol-interleaved outer convolutional coding of said reproductions of said portions of said finally transmitted CCC, thus to regenerate said outer convolutional coding of said portions of said finally transmitted CCC;
a second soft-input/soft-output (SISO) decoder connected for decoding said outer convolutional coding of said portions of said finally transmitted CCC as regenerated by said first binary-to-Gray-code re-mapper, said second SISO decoder including memory for temporarily storing soft input symbols from said regenerated outer convolutional coding of said portions of said finally transmitted CCC and for temporarily storing soft output symbols of decoded portions of said finally transmitted CCC;
a first soft-symbol re-interleaver connected for symbol-interleaving said soft output symbols of decoded portions of said finally transmitted CCC, thus to generate a response from said first soft-symbol re-interleaver composed of interleaved soft output symbols of decoded portions of said finally transmitted CCC, said first soft-symbol re-interleaver connected for supplying the response therefrom to said information-exchange unit as a first input signal thereto, and said first soft-symbol re-interleaver connected for supplying soft data bits from said response thereof to said hard-decision unit as an input signal thereto;
a first Gray-to-binary-code re-mapper connected for responding to said response of said first soft-symbol re-interleaver to re-code that information to binary-coded form, thus to generate a binary-coded response of said first Gray-to-binary-code re-mapper; and
a first extrinsic data feedback processor connected for generating a first extrinsic data feedback signal by combining said binary-coded response of said first Gray-to-binary-code re-mapper with soft output symbols extracted via said first memory input/output unit from said memory within said first SISO decoder, said first extrinsic data feedback processor further connected for updating said memory within said first SISO decoder with said first extrinsic data feedback signal via said first memory input/output unit—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC;
a second soft-symbol de-interleaver connected for de-interleaving said soft output symbols descriptive of binary-coded symbol-interleaved outer convolutional coding of said reproductions of said portions of said initially transmitted CCC as periodically updated, as periodically updated by results from decoding the inner convolutional coding of said reproductions of said portions of said initially transmitted CCC, thus to generate binary-coded outer convolutional coding of said reproductions of said portions of said initially transmitted CCC to said information-exchange unit as a second input signal thereto;
a second binary-to-Gray-code re-mapper connected for receiving from said information-exchange unit said soft output symbols descriptive of binary-coded outer convolutional coding of said reproductions of said portions of said initially transmitted CCC after their processing by said information-exchange unit, response from said second binary-to-Gray-code re-mapper re-mapping binary-coded symbol-interleaved outer convolutional coding of said reproductions of said portions of said initially transmitted CCC, thus to regenerate said outer convolutional coding of said portions of said initially transmitted CCC;
a fourth soft-input/soft-output (SISO) decoder connected for decoding said outer convolutional coding of said portions of said initially transmitted CCC as regenerated by said second binary-to-Gray-code re-mapper, said fourth SISO decoder including memory for temporarily storing soft input symbols from said regenerated outer convolutional coding of said portions of said initially transmitted CCC and for temporarily storing soft output symbols of decoded portions of said initially transmitted CCC;
a second soft-symbol re-interleaver connected for symbol-interleaving said soft output symbols of decoded portions of said initially transmitted CCC, thus to generate a response from said second soft-symbol re-interleaver composed of interleaved soft output symbols of decoded portions of said initially transmitted CCC;
a second Gray-to-binary-code re-mapper connected for responding to said response of said second soft-symbol re-interleaver to re-code that information to binary-coded form, thus to generate a binary-coded response of said second Gray-to-binary-code re-mapper; and
a second extrinsic data feedback processor connected for generating a second extrinsic data feedback signal by combining said binary-coded response of said second Gray-to-binary-code re-mapper with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

23. The receiver set forth in claim 22, wherein said first turbo decoder further comprises:
a first CRC decoder connected to respond to cyclic redundancy coding within said response from said first soft-symbol re-interleaver for processing soft symbols in said response from said first soft-symbol re-interleaver before their re-coding by said first Gray-to-binary-code re-mapper—and wherein said second turbo decoder further comprises:
a second CRC decoder connected to respond to cyclic redundancy coding within said response from said second soft-symbol re-interleaver for processing soft symbols in said response from said second soft-symbol re-interleaver before their re-coding by said second Gray-to-binary-code re-mapper.

24. The receiver set forth in claim 1, wherein said CCC is serially concatenated convolutional coding and wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first soft-symbol de-interleaver connected for de-interleaving said soft output symbols descriptive of binary-coded symbol-interleaved outer convolutional coding of said reproductions of said portions of said finally transmitted CCC as periodically updated, thus to generate binary-coded outer convolutional coding of said reproductions of said portions of said finally transmitted CCC to said information-exchange unit as a first input signal thereto;
a first binary-to-Gray-code re-mapper connected for receiving from said information-exchange unit said soft output symbols descriptive of binary-coded outer convolutional coding of said reproductions of said portions of said finally transmitted CCC after their processing by said information-exchange unit, response from said first binary-to-Gray-code re-mapper re-mapping binary-coded symbol-interleaved outer convolutional coding of said reproductions of said portions of said finally transmitted CCC, thus to regenerate the outer convolutional coding of said portions of said finally transmitted CCC;
a second soft-input/soft-output (SISO) decoder connected for decoding said outer convolutional coding of said portions of said finally transmitted CCC as regenerated by said first binary-to-Gray-code re-mapper, said second SISO decoder including memory for soft input symbols received from said first binary-to-Gray-code re-mapper and for soft output symbols of a response generated by said second SISO decoder;
a first Gray-to-binary-code re-mapper connected for supplying a binary-coded response to said response of said second SISO decoder;
a first soft-symbol re-interleaver connected for symbol-interleaving said binary-coded response from said first Gray-to-binary-code re-mapper, thus to generate as a response therefrom interleaved soft output symbols of decoded portions of said finally transmitted CCC, said first soft-symbol re-interleaver further connected for supplying soft data bits of said response therefrom to said hard-decision unit as an input signal thereto; and
a first extrinsic data feedback processor connected for generating a first extrinsic data feedback signal by combining said response of said first soft-symbol re-interleaver with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC;
a second soft-symbol de-interleaver connected for de-interleaving said soft output symbols descriptive of binary-coded symbol-interleaved outer convolutional coding of said reproductions of said portions of said initially transmitted CCC as periodically updated, thus to generate binary-coded outer convolutional coding of said reproductions of said portions of said initially transmitted CCC to said information-exchange unit as a second input signal thereto;
a second binary-to-Gray-code re-mapper connected for receiving from said information-exchange unit said periodically updated soft output symbols descriptive of binary-coded outer convolutional coding of said reproductions of said portions of said initially transmitted CCC after their processing by said information-exchange unit, response from said second binary-to-Gray-code re-mapper re-mapping binary-coded symbol-interleaved outer convolutional coding of said reproductions of said portions of said initially transmitted CCC, thus to regenerate said outer convolutional coding of said portions of said initially transmitted CCC;
a fourth soft-input/soft-output (SISO) decoder connected for decoding said outer convolutional coding of said portions of said initially transmitted CCC as regenerated by said second binary-to-Gray-code re-mapper, said fourth SISO decoder including memory for soft input symbols received from said second binary-to-Gray-code re-mapper and for soft output symbols and for soft output symbols of a response generated by said fourth SISO decoder;
a second Gray-to-binary-code re-mapper connected for supplying a binary-coded response to said response of said fourth SISO decoder;
a second soft-symbol re-interleaver connected for symbol-interleaving said binary-coded response from said second Gray-to-binary-code re-mapper, thus to generate as a response therefrom interleaved soft output symbols of decoded portions of said initially transmitted CCC; and
a second extrinsic data feedback processor connected for generating a second extrinsic data feedback signal by combining said response of said second soft-symbol re-interleaver with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

25. The receiver set forth in claim 1, wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC;
a first binary-to-Gray-code re-mapper connected via said first memory input/output unit for receiving said soft output symbols descriptive of binary-coded symbol-interleaved outer convolutional coding of said reproductions of said portions of said finally transmitted CCC as periodically updated, response from said first binary-to-Gray-code re-mapper re-mapping binary-coded symbol-interleaved outer convolutional coding of said reproductions of said portions of said finally transmitted CCC to symbol-interleaved outer convolutional coding of said portions of said finally transmitted CCC, said first binary-to-Gray-code re-mapper further connected for supplying said response thereof to said information-exchange unit as a first input signal thereto, and said first binary-to-Gray-code re-mapper also further connected for supplying soft data bits from said response thereof to said hard-decision unit as an input signal thereto;
a first soft-symbol de-interleaver connected for de-interleaving soft symbols of said symbol-interleaved outer convolutional coding of said portions of said finally transmitted CCC, as received from said information-exchange unit after being processed thereby, thus to regenerate the outer convolutional coding of said portions of said finally transmitted CCC;
a second soft-input/soft-output (SISO) decoder connected for decoding said outer convolutional coding of said portions of said finally transmitted CCC as regenerated by said first soft-symbol de-interleaver, said second SISO decoder including memory for temporarily storing soft input symbols from said regenerated outer convolutional coding of said portions of said finally transmitted CCC and for temporarily storing soft output symbols of decoded portions of said finally transmitted CCC;
a first Gray-to-binary-code re-mapper connected for supplying a binary-coded response to decoding results from said second SISO decoder;
a first soft-symbol re-interleaver connected for symbol-interleaving said binary-coded response from said first Gray-to-binary-code re-mapper, thus to generate a response of said first soft-symbol re-interleaver composed of interleaved soft output symbols of decoded portions of said finally transmitted CCC; and
a first extrinsic data feedback processor connected for generating a first extrinsic data feedback signal by combining said response of said first soft-symbol re-interleaver with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC;
a second binary-to-Gray-code re-mapper connected via said second memory input/output unit for receiving said soft output symbols descriptive of binary-coded symbol-interleaved outer convolutional coding of said reproductions of said portions of said initially transmitted CCC as periodically updated, response from said second binary-to-Gray-code re-mapper re-mapping binary-coded symbol-interleaved outer convolutional coding of said reproductions of said portions of said initially transmitted CCC to symbol-interleaved outer convolutional coding of said portions of said initially transmitted CCC, said second binary-to-Gray-code re-mapper further connected for supplying said response thereof to said information-exchange unit as a first input signal thereto;
a second soft-symbol de-interleaver connected for de-interleaving soft symbols of said symbol-interleaved outer convolutional coding of said portions of said initially transmitted CCC, as received from said information-exchange unit after being processed thereby, thus to regenerate the outer convolutional coding of said portions of said initially transmitted CCC;
a fourth soft-input/soft-output (SISO) decoder connected for decoding said outer convolutional coding of said portions of said initially transmitted CCC as regenerated by said second soft-symbol de-interleaver, said fourth SISO decoder including memory for temporarily storing soft input symbols from said regenerated outer convolutional coding of said portions of said initially transmitted CCC and for temporarily storing soft output symbols of decoded portions of said initially transmitted CCC;
a second Gray-to-binary-code re-mapper connected for supplying a binary-coded response to decoding results from said fourth SISO decoder;
a second soft-symbol re-interleaver connected for symbol-interleaving said binary-coded response from said second Gray-to-binary-code re-mapper, thus to generate a response of said second soft-symbol re-interleaver composed of interleaved soft output symbols of decoded portions of said initially transmitted CCC; and
a second extrinsic data feedback processor connected for generating a second extrinsic data feedback signal by combining said response of said second soft-symbol re-interleaver with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

26. The receiver set forth in claim 25, wherein said first turbo decoder further comprises:
a first CRC decoder connected to respond to cyclic redundancy coding within said response from said first binary-to-Gray-code re-mapper for processing soft symbols in said response from said first binary-to-Gray-code re-mapper before supplying them to said information-exchange unit as said first input signal thereto—and wherein said second turbo decoder further comprises:
a second CRC decoder connected to respond to cyclic redundancy coding within said response from said second binary-to-Gray-code re-mapper for processing soft symbols in said response from said second binary-to-Gray-code re-mapper before supplying them to said information-exchange unit as said second input signal thereto.

27. The receiver set forth in claim 1, wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC, said information-exchange unit being connected for receiving as a first input signal thereto said soft output symbols supplied from said first memory input/output unit at prescribed times;
a first binary-to-Gray-code re-mapper connected for receiving said soft output symbols supplied from said first memory input/output unit at prescribed times and subsequently processed by said information-exchange unit, response from said first binary-to-Gray-code re-mapper re-mapping binary-coded symbol-interleaved outer convolutional coding of said reproductions of said portions of said finally transmitted CCC to symbol-interleaved outer convolutional coding of said portions of said finally transmitted CCC;
a first soft-symbol de-interleaver connected for de-interleaving said symbol-interleaved outer convolutional coding of said portions of said finally transmitted CCC, thus to regenerate the outer convolutional coding of said portions of said finally transmitted CCC;
a second soft-input/soft-output (SISO) decoder connected for decoding said outer convolutional coding of said portions of said finally transmitted CCC as regenerated by said first soft-symbol de-interleaver, said second SISO decoder including memory for temporarily storing soft input symbols from said regenerated outer convolutional coding of said portions of said finally transmitted CCC and for temporarily storing soft output symbols of a response generated by said third SISO decoder;
a first soft-symbol re-interleaver connected for re-interleaving said soft output symbols of decoded portions of said finally transmitted CCC, thus to generate interleaved soft output symbols of said response generated by said secondd SISO decoder, said first soft-symbol re-interleaver further connected for supplying soft data bits of said interleaved soft output symbols of decoded portions of said finally transmitted CCC to said hard-decision unit as an input signal thereto;
a first Gray-to-binary-code re-mapper connected for supplying a binary-coded response to said interleaved soft output symbols of decoded portions of said finally transmitted CCC; and
a first extrinsic data feedback processor connected for generating a first extrinsic data feedback signal by combining said binary-coded response of said first Gray-to-binary-code re-mapper with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory for soft input symbols and for soft output symbols within said third SISO decoder, said second memory input/output unit operable for supplying soft input symbols from said delayed reproductions of said portions of said initially transmitted CCC to said memory for soft input symbols and for soft output symbols within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC, said information-exchange unit being connected for receiving as a second input signal thereto said soft output symbols supplied from said second memory input/output unit at prescribed times;
a second binary-to-Gray-code re-mapper connected for receiving said soft output symbols supplied from said second memory input/output unit at prescribed times and subsequently processed by said information-exchange unit, response from said second binary-to-Gray-code re-mapper re-mapping binary-coded symbol-interleaved outer convolutional coding of said reproductions of said portions of said initially transmitted CCC to symbol-interleaved outer convolutional coding of said portions of said initially transmitted CCC;
a second soft-symbol de-interleaver connected for de-interleaving said symbol-interleaved outer convolutional coding of said portions of said initially transmitted CCC to regenerate the outer convolutional coding of said portions of said initially transmitted CCC;
a fourth soft-input/soft-output (SISO) decoder connected for decoding said outer convolutional coding of said portions of said initially transmitted CCC as regenerated by said second soft-symbol de-interleaver, said fourth SISO decode including memory for soft input symbols from said regenerated outer convolutional coding of said portions of said initially transmitted CCC and for soft output symbols of decoded portions of said initially transmitted CCC;
a second soft-symbol re-interleaver connected for symbol-interleaving said soft output symbols of decoded portions of said initially transmitted CCC to generate interleaved soft output symbols of decoded portions of said initially transmitted CCC;
a second Gray-to-binary-code re-mapper connected for supplying a binary-coded response to said interleaved soft output symbols of decoded portions of said initially transmitted CCC; and
a second extrinsic data feedback processor connected for generating a second extrinsic data feedback signal by combining said binary-coded response of said second Gray-to-binary-code re-mapper with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

28. The receiver set forth in claim 27, wherein said first turbo decoder further comprises:
a first CRC decoder connected to respond to cyclic redundancy coding within said response from said first binary-to-Gray-code re-mapper for processing soft symbols in said response from said first binary-to-Gray-code re-mapper before their de-interleaving by said first soft-symbol de-interleaver—and wherein said second turbo decoder further comprises:
a second CRC decoder connected to respond to cyclic redundancy coding within said response from said second binary-to-Gray-code re-mapper for processing soft symbols in said response from said second binary-to-Gray-code re-mapper before their de-interleaving by said second soft-symbol de-interleaver.

29. The receiver set forth in claim 27, wherein said first turbo decoder further comprises:
a first CRC decoder connected to respond to cyclic redundancy coding within said response from said first soft-symbol re-interleaver for processing soft symbols in said response from said first soft-symbol re-interleaver before their re-coding by said first Gray-to-binary-code re-mapper—and wherein said second turbo decoder further comprises:
a second CRC decoder connected to respond to cyclic redundancy coding within said response from said second soft-symbol re-interleaver for processing soft symbols in said response from said second soft-symbol re-interleaver before their re-coding by said second Gray-to-binary-code re-mapper.

30. The receiver set forth in claim 1, wherein said CCC is serially concatenated convolutional coding and wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC, said information-exchange unit being connected for receiving as a first input signal thereto said soft output symbols supplied from said first memory input/output unit at prescribed times;
a first binary-to-Gray-code re-mapper connected for receiving said soft output symbols supplied from said first memory input/output unit at prescribed times and subsequently processed by said information-exchange unit, response from said first binary-to-Gray-code re-mapper re-mapping binary-coded symbol-interleaved outer convolutional coding of said reproductions of said portions of said finally transmitted CCC to symbol-interleaved outer convolutional coding of said portions of said finally transmitted CCC;
a first soft-symbol de-interleaver connected for de-interleaving said symbol-interleaved outer convolutional coding of said portions of said finally transmitted CCC to regenerate the outer convolutional coding of said portions of said finally transmitted CCC;
a second soft-input/soft-output (SISO) decoder connected for decoding said outer convolutional coding of said portions of said finally transmitted CCC as regenerated by said first soft-symbol de-interleaver, said second SISO decoder including memory for temporarily storing soft input symbols from said regenerated outer convolutional coding of said portions of said finally transmitted CCC and for temporarily storing soft output symbols of a response generated by said second SISO decoder;
a first Gray-to-binary-code re-mapper connected for supplying a binary-coded response to decoding results from said second SISO decoder;
a first soft-symbol re-interleaver connected for symbol-interleaving said binary-coded response from said first Gray-to-binary-code re-mapper, thus to generate symbol-interleaved soft output symbols of decoded portions of said finally transmitted CCC as a response from said first soft-symbol re-interleaver, said first soft-symbol re-interleaver further connected for supplying soft data bits of said response from said first soft-symbol re-interleaver to said hard-decision unit as an input signal thereto; and
a first extrinsic data feedback processor connected for generating a first extrinsic data feedback signal by combining said response from said first soft-symbol re-interleaver with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC, said information-exchange unit being connected for receiving as a second input signal thereto said soft output symbols supplied from said second memory input/output unit at prescribed times;
a second binary-to-Gray-code re-mapper connected for receiving said soft output symbols supplied from said second memory input/output unit at prescribed times and subsequently processed by said information-exchange unit, response from said second binary-to-Gray-code re-mapper re-mapping binary-coded symbol-interleaved outer convolutional coding of said reproductions of said portions of said initially transmitted CCC to symbol-interleaved outer convolutional coding of said portions of said initially transmitted CCC;
a second soft-symbol de-interleaver connected for de-interleaving said symbol-interleaved outer convolutional coding of said portions of said initially transmitted CCC to regenerate the outer convolutional coding of said portions of said initially transmitted CCC;
a fourth soft-input/soft-output (SISO) decoder connected for decoding said outer convolutional coding of said portions of said initially transmitted CCC as regenerated by said second soft-symbol de-interleaver, said fourth SISO decoder including memory for temporarily storing soft input symbols from said regenerated outer convolutional coding of said portions of said initially transmitted CCC and for temporarily storing soft output symbols of a response generated by said fourth SISO decoder;
a second Gray-to-binary-code re-mapper connected for supplying a binary-coded response to said response of said fourth SISO decoder;
a second soft-symbol re-interleaver connected for symbol-interleaving said binary-coded response from said second Gray-to-binary-code re-mapper, thus to generate interleaved soft output symbols of decoded portions of said initially transmitted CCC as a response from said second soft-symbol re-interleaver; and
a second extrinsic data feedback processor connected for generating a second extrinsic data feedback signal by combining said response from said second soft-symbol re-interleaver with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

31. The receiver set forth in claim 30, wherein said first turbo decoder further comprises:
a first CRC decoder connected to respond to cyclic redundancy coding within said response from said first binary-to-Gray-code re-mapper for processing soft symbols in said response from said first binary-to-Gray-code re-mapper before their de-interleaving by said first soft-symbol de-interleaver—and wherein said second turbo decoder further comprises:
a second CRC decoder connected to respond to cyclic redundancy coding within said response from said second binary-to-Gray-code re-mapper for processing soft symbols in said response from said second binary-to-Gray-code re-mapper before their de-interleaving by said second soft-symbol de-interleaver.

32. The receiver set forth in claim 1, wherein said first turbo decoder comprises:
a first soft-input/soft-output (SISO) decoder connected for decoding 12-phase trellis coding that includes the inner convolutional coding of said reproductions of said portions of said finally transmitted CCC, said first SISO decoder including memory for temporarily storing soft input symbols for decoding and for temporarily storing soft output symbols from decoding;
a first memory input/output unit for accessing said memory within said first SISO decoder, said first memory input/output unit operable for supplying soft input symbols from said reproductions of said portions of said finally transmitted CCC to be temporarily stored in said memory within said first SISO decoder, said first memory input/output unit further operable for supplying soft output symbols descriptive of binary-coded symbol-interleaved outer convolutional coding of said reproductions of said portions of said finally transmitted CCC, as periodically updated by results from decoding the inner convolutional coding of said reproductions of said portions of said finally transmitted CCC, said information-exchange unit being connected for receiving as a first input signal thereto said soft output symbols supplied from said first memory input/output unit at prescribed times;
a first binary-to-Gray-code re-mapper connected for receiving said soft output symbols supplied from said first memory input/output unit at prescribed times and subsequently processed by said information-exchange unit, response from said first binary-to-Gray-code re-mapper re-mapping binary-coded symbol-interleaved outer convolutional coding of said reproductions of said portions of said finally transmitted CCC to symbol-interleaved outer convolutional coding of said portions of said finally transmitted CCC, said first binary-to-Gray-code re-mapper further connected for supplying soft data bits from said response thereof to said hard-decision unit as an input signal thereto;
a first soft-symbol de-interleaver connected for de-interleaving said symbol-interleaved outer convolutional coding of said portions of said finally transmitted CCC to regenerate the outer convolutional coding of said portions of said finally transmitted CCC;
a second soft-input/soft-output (SISO) decoder connected for decoding said outer convolutional coding of said portions of said finally transmitted CCC as regenerated by said first soft-symbol de-interleaver, said second SISO decoder including memory for temporarily storing soft input symbols from said regenerated outer convolutional coding of said portions of said finally transmitted CCC and for temporarily storing soft output symbols of a response generated by said second SISO decoder;
a first Gray-to-binary-code re-mapper connected for supplying a binary-coded response to decoding results from said second SISO decoder;
a first soft-symbol re-interleaver connected for symbol-interleaving said binary-coded response from said first Gray-to-binary-code re-mapper, thus to generate symbol-interleaved soft output symbols of decoded portions of said finally transmitted CCC as a response from said first soft-symbol re-interleaver; and
a first extrinsic data feedback processor connected for generating a first extrinsic data feedback signal by combining said response from said first soft-symbol re-interleaver with soft output symbols extracted via said first memory input/output unit from said memory within said first SISO decoder, said first extrinsic data feedback processor further connected via said first memory input/output unit for updating said memory within said first SISO decoder with said first extrinsic data feedback signal—and wherein said second turbo decoder comprises:
a third soft-input/soft-output (SISO) decoder connected for decoding 12-phase trellis coding that includes the inner convolutional coding of said reproductions of said portions of said initially transmitted CCC, said third SISO decoder including memory for temporarily storing soft input symbols for decoding and for temporarily storing soft output symbols from decoding;
a second memory input/output unit for accessing said memory within said third SISO decoder, said second memory input/output unit operable for supplying soft input symbols from said delayed reproductions of said portions of said initially transmitted CCC to be temporarily stored in said memory within said third SISO decoder, said second memory input/output unit further operable for supplying soft output symbols descriptive of binary-coded symbol-interleaved outer convolutional coding of said reproductions of said portions of said initially transmitted CCC, as periodically updated by results from decoding the inner convolutional coding of said reproductions of said portions of said initially transmitted CCC, said information-exchange unit being connected for receiving as a second input signal thereto said soft output symbols supplied from said second memory input/output unit at prescribed times;
a second binary-to-Gray-code re-mapper connected for receiving said soft output symbols supplied from said second memory input/output unit at prescribed times and subsequently processed by said information-exchange unit, response from said second binary-to-Gray-code re-mapper re-mapping binary-coded symbol-interleaved outer convolutional coding of said reproductions of said portions of said initially transmitted CCC to symbol-interleaved outer convolutional coding of said portions of said initially transmitted CCC;
a second soft-symbol de-interleaver connected for de-interleaving said symbol-interleaved outer convolutional coding of said portions of said initially transmitted CCC to regenerate the outer convolutional coding of said portions of said initially transmitted CCC;
a fourth soft-input/soft-output (SISO) decoder connected for decoding said outer convolutional coding of said portions of said initially transmitted CCC as regenerated by said second soft-symbol de-interleaver, said fourth SISO decoder including memory for temporarily storing soft input symbols from said regenerated outer convolutional coding of said portions of said initially transmitted CCC and for temporarily storing soft output symbols of a response generated by said fourth SISO decoder;
a second Gray-to-binary-code re-mapper connected for supplying a binary-coded response to said response of said fourth SISO decoder;
a second soft-symbol re-interleaver connected for symbol-interleaving said binary-coded response from said second Gray-to-binary-code re-mapper, thus to generate interleaved soft output symbols of decoded portions of said initially transmitted CCC as a response of said second soft-symbol re-interleaver, said second soft-symbol re-interleaver further connected for supplying soft data bits from binary-coded soft output symbols as so symbol-interleaved to said hard-decision unit as an input signal thereto; and
a second extrinsic data feedback processor connected for generating a second extrinsic data feedback signal by combining said response of said second soft-symbol re-interleaver with soft output symbols extracted via said second memory input/output unit from said memory within said third SISO decoder, said second extrinsic data feedback processor further connected via said second memory input/output unit for updating said memory within said third SISO decoder with said second extrinsic data feedback signal.

33. The receiver set forth in claim 32, wherein said first turbo decoder further comprises:
a first CRC decoder connected to respond to cyclic redundancy coding within said response from said first binary-to-Gray-code re-mapper for processing soft symbols in said response from said first binary-to-Gray-code re-mapper before their de-interleaving by said first soft-symbol de-interleaver—and wherein said second turbo decoder further comprises:
a second CRC decoder connected to respond to cyclic redundancy coding within said response from said second binary-to-Gray-code re-mapper for processing soft symbols in said response from said second binary-to-Gray-code re-mapper before their de-interleaving by said second soft-symbol de-interleaver.

34. The receiver set forth in claim 32, wherein said first turbo decoder further comprises:
a first CRC decoder connected to respond to cyclic redundancy coding within said response from said first symbol re-interleaver for processing soft symbols therein before their re-mapping by said first Gray-to-binary-code re-mapper—and wherein said second turbo decoder further comprises:
a second CRC decoder connected to respond to cyclic redundancy coding within said response from said second symbol re-interleaver for processing soft symbols therein before their re-interleaving by said second Gray-to-binary-code re-mapper de-interleaver.
